(19) United States
(12) Patent Application Publication
(10) Pub. No.: US 2024/0155937 A1
(43) Pub. Date: May 9, 2024

(54) LIGHT EMITTING DEVICE AND DISPLAY APPARATUS INCLUDING THE SAME

(71) Applicant: Samsung Display Co., Ltd., Yongin-si (KR)

(72) Inventor: HYUNYOUNG KIM, Yongin-si (KR)

(21) Appl. No.: 18/357,774

(22) Filed: Jul. 24, 2023

(30) Foreign Application Priority Data
Oct. 12, 2022 (KR) 10-2022-0130902

(51) Int. Cl. H10K 85/40; C07F 7/08; H10K 50/11; H10K 50/15; H10K 50/16; H10K 85/60

(52) U.S. Cl. CPC H10K 85/40; C07F 7/0812; H10K 50/11; H10K 50/15; H10K 50/16; H10K 85/658

(57) ABSTRACT

A light emitting device includes a first electrode, a second electrode facing the first electrode, and a plurality of functional layers between the first electrode and the second electrode, wherein at least one functional layer among the plurality of functional layers includes a first compound represented by Formula 1, a second compound represented by Formula 2, and a third compound represented by Formula 3. Formula 1, Formula 2 and Formula 3 are the same as described in the detailed descriptions.

### CROSS-REFERENCE TO RELATED APPLICATION

This application claims priority to and the benefit of Korean Patent Application No. 10-2022-0130902, filed on Oct. 12, 2022, in the Korean Intellectual Property Office, the entire content of which is hereby incorporated by reference.

### BACKGROUND

### 1. Field

The present disclosure herein relates to a light emitting device and a display apparatus including the same, and for example, to a light emitting device having improved luminous efficiency and a display apparatus including the same.

### 2. Description of the Related Art

Recently, the development of an organic electroluminescence display apparatus as an image display apparatus is being actively conducted. Unlike liquid crystal display apparatuses and/or the like, the organic electroluminescence display apparatus is a so-called self-luminescent display apparatus in which holes and electrons injected from a first electrode and a second electrode recombine in an emission layer, and thus a luminescent material including an organic compound in the emission layer emits light to implement display (e.g., of an image).

In the application of an organic electroluminescence device to a display apparatus, there is a demand for an organic electroluminescence device having a low driving voltage, high luminous efficiency, and/or a long service life, and the development on materials, for an organic electroluminescence device, capable of stably attaining such characteristics is being continuously pursued or required.

In recent years, particularly in order to implement a highly efficient organic electroluminescence device, technologies pertaining to phosphorescence emission utilizing triplet state energy or delayed fluorescence utilizing triplet-triplet annihilation (TTA) (in which singlet excitons are generated by collision of triplet excitons) are being developed, and thermally activated delayed fluorescence (TADF) materials utilizing delayed fluorescence phenomenon are being developed.

### SUMMARY

An aspect according to embodiments of the present disclosure is directed toward a light emitting device with improved luminous efficiency.

An aspect according to embodiments of the present disclosure is directed toward a display apparatus with improved luminous efficiency.

According to an embodiment of the present disclosure, a light emitting device includes: a first electrode; a second electrode facing the first electrode; and a plurality of functional layers between the first electrode and the second electrode, wherein at least one functional layer among the plurality of functional layers includes a first compound represented by Formula 1, a second compound represented by Formula 2, and a third compound represented by Formula 3:

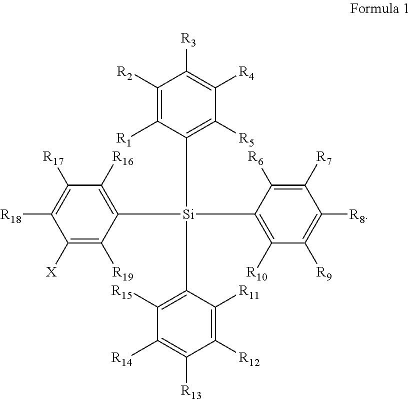

In Formula 1 above, X may be a substituted or unsubstituted aryl group having 6 to 30 ring-forming carbon atoms, or a substituted or unsubstituted heteroaryl group having 2 to 30 ring-forming carbon atoms, R₁ to R₁₉ may each independently be a hydrogen atom, a deuterium atom, a halogen atom, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and at least one pair among adjacent pairs of R₁ to R₁₈ are positions at which a substituent represented by Formula C is fused.

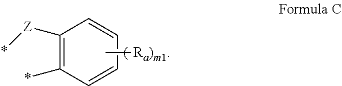

In Formula C above, ^{—}* may be a position which is fused to any adjacent one pair among R₁ to R₁₈ in Formula 1 above, Z is O or S, Rₐ may be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and m1 may be an integer of 0 to 4.

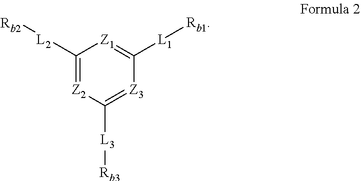

In Formula 2 above, at least one among Z₁ to Z₃ is N, any remainder thereof are each independently CR_{b4}, R_{b1} to R_{b3} may each independently be a hydrogen atom, a deuterium atom, a halogen atom, a substituted or unsubstituted silyl group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, R_{b4} may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and L₁ to L₃ may each independently be a substituted or unsubstituted arylene group having 6 to 30 ring-forming carbon atoms, or a substituted or unsubstituted heteroarylene group having 2 to 30 ring-forming carbon atoms.

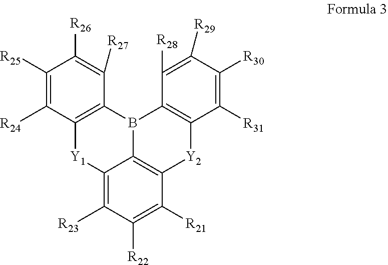

In Formula 3 above, Y₁ and Y₂ may each independently be NR₃₂ or O, and R₂₁ to R₃₂ may each independently be a hydrogen atom, a deuterium atom, a halogen atom, a cyano group, a nitro group, a substituted or unsubstituted amine group, a substituted or unsubstituted boron group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

In an embodiment, the plurality of functional layers may include a hole transport region on the first electrode, an emission layer on the hole transport region, and an electron transport region on the emission layer, and the emission layer may include the first compound, the second compound, and the third compound.

In an embodiment, the plurality of functional layers may include a hole injection layer on the first electrode, a hole transport layer on the hole injection layer, an emission layer on the hole transport region, and an electron transport region on the emission layer, and the hole transport layer may include the first compound represented by Formula 1 above.

In an embodiment, the emission layer may be to emit blue light.

In an embodiment, the first compound represented by Formula 1 above may be represented by Formula 1-1-1 or Formula 1-1-2:

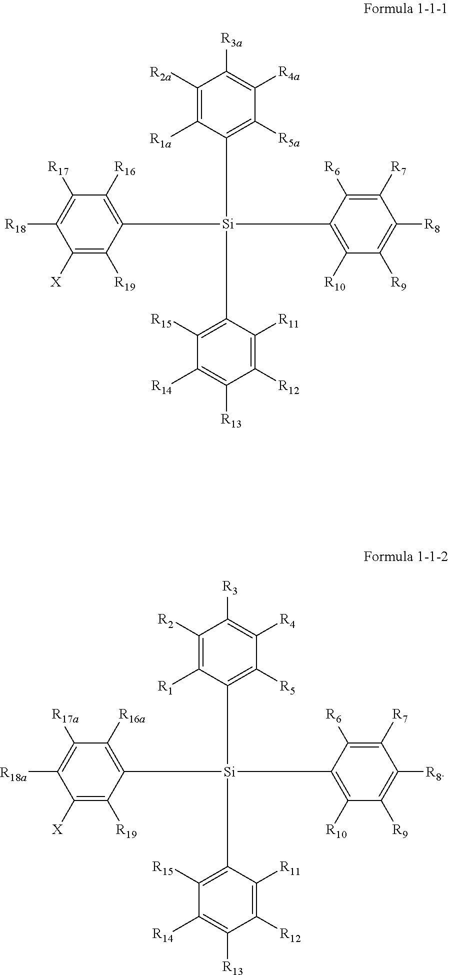

In Formula 1-1-1 and Formula 1-1-2 above, R₁ₐ to R₅ₐ and R₁₆ₐ to R₁₈ₐ may each independently be a hydrogen atom, a deuterium atom, a halogen atom, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and in Formula 1-1-1 above, one adjacent pair of R₁ₐ to R₅ₐ are positions at which a substituent represented by Formula C above is fused, and in Formula 1-1-2 above, one adjacent pair of R₁₆ₐ to R₁₈ₐ are positions at which a substituent represented by Formula C above is fused.

In an embodiment, in Formula 1-1-1 and Formula 1-1-2 above, the same as defined in Formula 1 above may be applied to X and R₁ to R₁₉.

In an embodiment, the first compound represented by Formula 1 above may be represented by any one among Formula 1-2-1 to Formula 1-2-5:

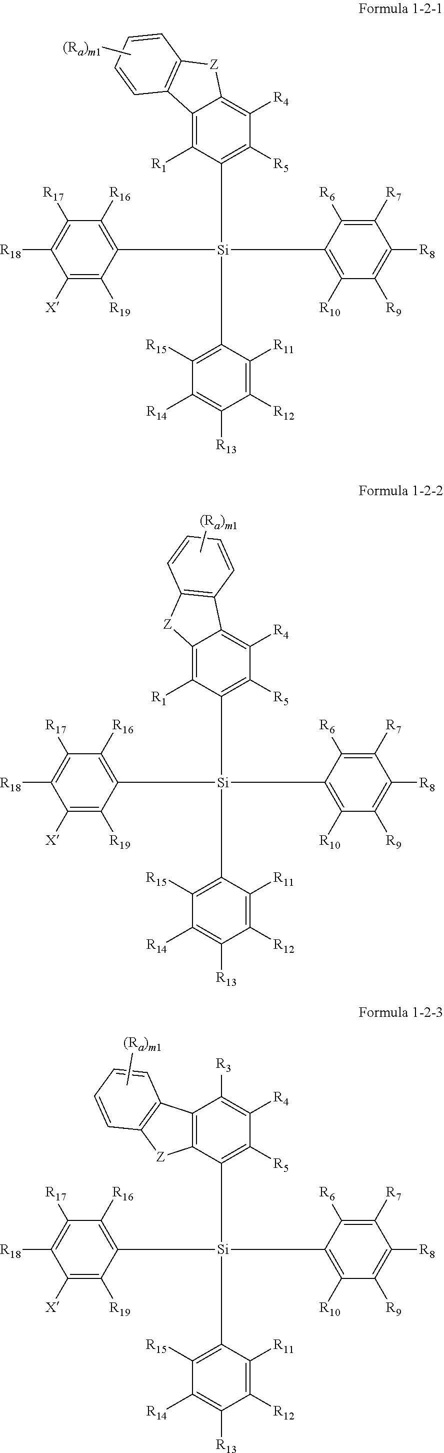

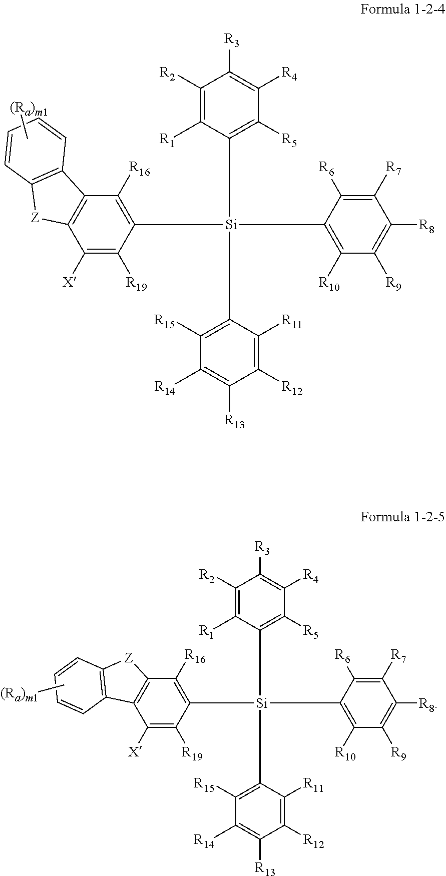

In Formula 1-2-1 to Formula 1-2-5 above, X′ may be represented by any one among Formula S-1 to Formula S-3:

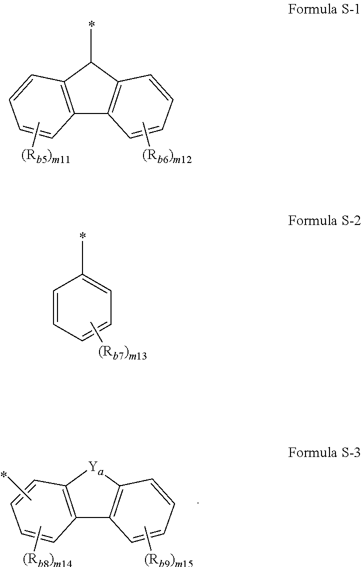

In Formula S-1 to Formula S-3 above, Yₐ is NR_{b10}, R_{b5} to R_{b10} may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, m11, m12, and m15 may each independently be an integer of 0 to 4, m13 may be an integer of 0 to 5, and m14 may be an integer of 0 to 3.

In Formula 1-2-1 to Formula 1-2-5 above, the same as defined in Formula 1 and Formula C above may be applied to R₁ to R₁₉, Z, Rₐ, and m1.

In an embodiment, the first compound represented by Formula 1 above may be represented by any one among Formula 1-3-1 to Formula 1-3-3:

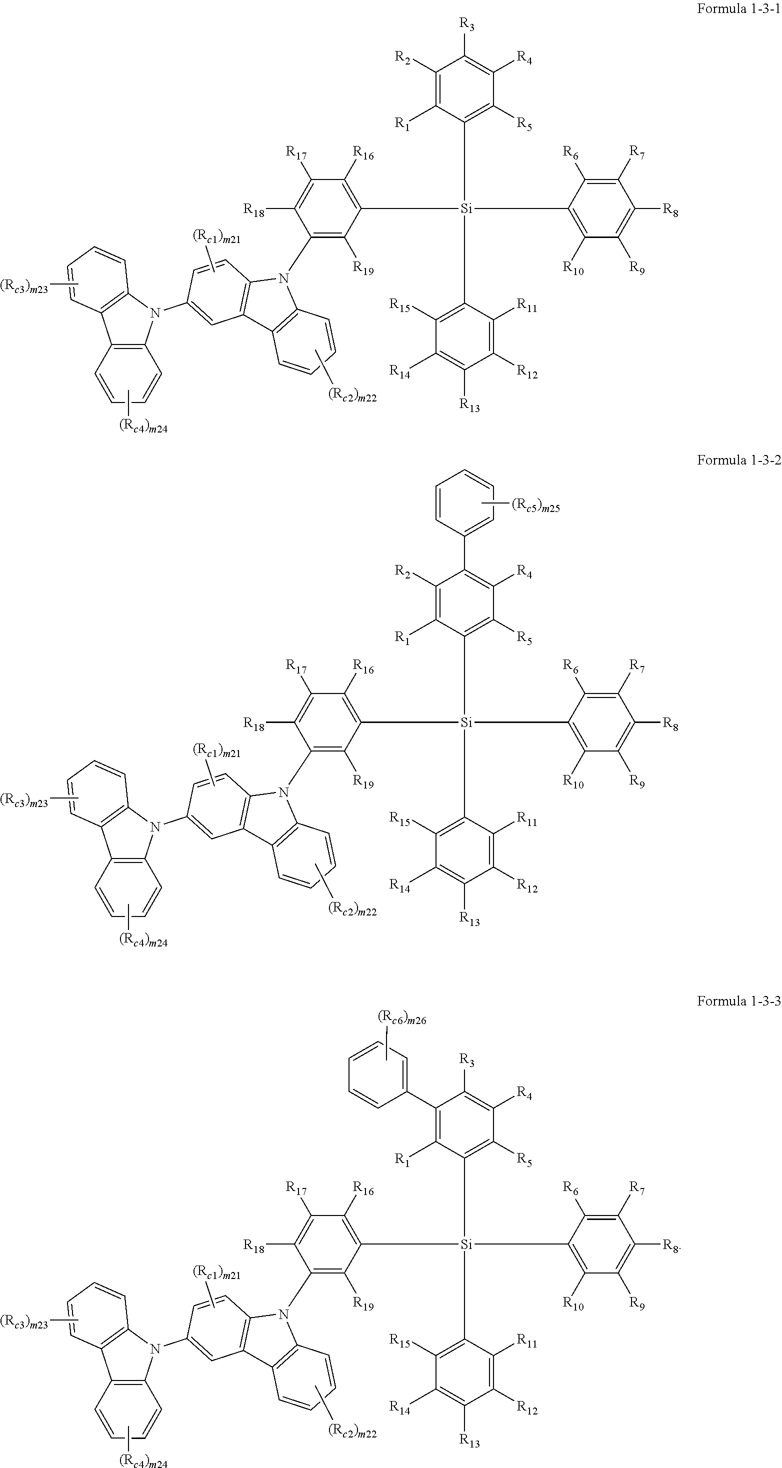

In Formula 1-3-1 to Formula 1-3-3 above, R_{c1} to R_{c6} may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, m21 may be an integer of 0 to 3, m22 to m24 may each independently be an integer of 0 to 4, and m25 and m26 may each independently be an integer of 0 to 5.

In Formula 1-3-1 to Formula 1-3-3 above, the same as defined in Formula 1 above may be applied to R₁ to R₁₉.

In an embodiment, the second compound represented by Formula 2 above may be represented by any one among Formula 2-1-1 to Formula 2-1-3:

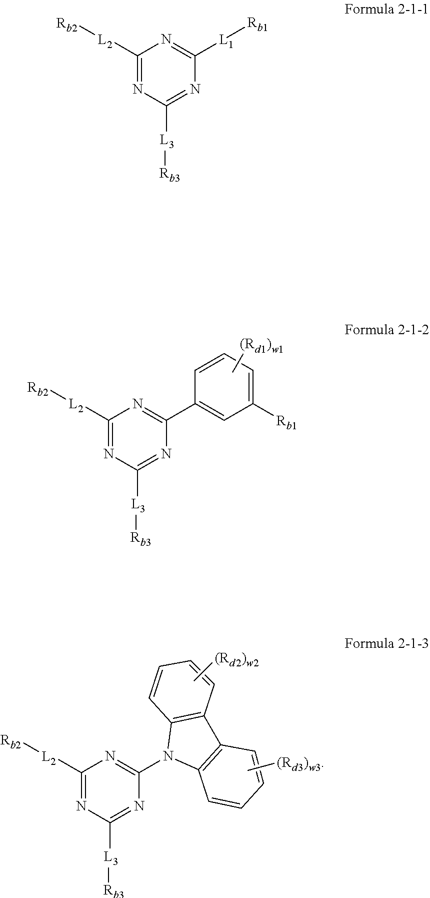

In Formula 2-1-1 to Formula 2-1-3 above, R_{d1} to R_{d3} may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and w1 to w3 may each independently be an integer of 0 to 4.

In Formula 2-1-1 to Formula 2-1-3 above, the same as defined in Formula 2 above may be applied to R_{b1} to R_{b3}, and L₁ to L₃.

In an embodiment, the third compound represented by Formula 3 above may be represented by any one among Formula 3-1 to Formula 3-3:

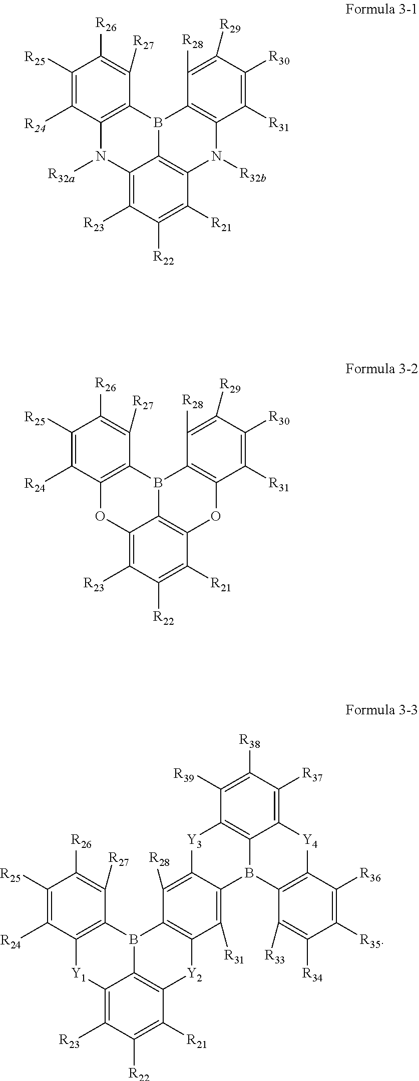

In Formula 3-1 to Formula 3-3 above, R₃₂ₐ and R_{32b} may each independently be a substituted or unsubstituted aryl group having 6 to 30 ring-forming carbon atoms, or a substituted or unsubstituted heteroaryl group having 2 to 30 ring-forming carbon atoms, Y₃ and Y₄ may each independently be NR₄₀ or O, R₃₃ to R₄₀ may each independently be a hydrogen atom, a deuterium atom, a halogen atom, a cyano group, a nitro group, a substituted or unsubstituted amine group, a substituted or unsubstituted boron group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

In Formula 3-1 to Formula 3-3 above, the same as defined in Formula 3 above may be applied to Y₁, Y₂, R₂₁ to R₂₈, and R₃₁.

In an embodiment, the at least one functional layer may further include a fourth compound represented by Formula 4:

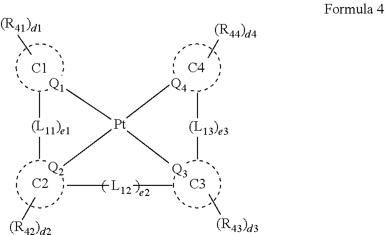

In Formula 4 above, Q₁ to Q₄ may each independently be C or N, C1 to C4 may each independently be a substituted or unsubstituted hydrocarbon ring having 5 to 30 ring-forming carbon atoms, or a substituted or unsubstituted heterocycle having 2 to 30 ring-forming carbon atoms, L₁₁ to L₁₃ may each independently be a direct linkage,

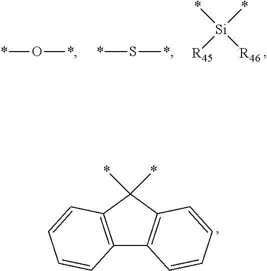

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, R₄₁ to R₄₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, d1 to d4 may each independently be an integer of 0 to 4, and e1 to e3 may each independently be 0 or 1.

In an embodiment of the present disclosure, a display apparatus includes a base layer having a first light emitting region configured to emit a first light and a second light emitting region configured to emit a second light having different light emitting wavelength from the first light, a first electrode on the base layer and overlaps the first light emitting region and the second light emitting region, a hole transport region on the first electrode, a first emission layer on the hole transport region, overlapping the first light emitting region, and being to emit the first light, a second emission layer on the hole transport region, overlapping the second light emitting region, and being to emit the second light, an electron transport region on the first emission layer and the second emission layer, a second electrode on the electron transport region, and a capping layer on the second electrode, wherein the first emission layer includes a first compound represented by Formula 1 above and a third compound represented by Formula 3 above, and the capping layer has a refractive index of about 1.6 or more.

In an embodiment, the first emission layer may further include a second compound represented by Formula 2 above.

In an embodiment, the first emission layer may further include a fourth compound represented by Formula 4 above.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure. In the drawings:

FIG. 1 is a plan view of a display apparatus according to an embodiment of the present disclosure;

FIG. 2 is a cross-sectional view of a display apparatus according to an embodiment of the present disclosure;

FIG. 3 is a cross-sectional view schematically illustrating a light emitting device according to an embodiment of the present disclosure;

FIG. 4 is a cross-sectional view schematically illustrating a light emitting device according to an embodiment of the present disclosure;

FIG. 5 is a cross-sectional view schematically illustrating a light emitting device according to an embodiment of the present disclosure;

FIG. 6 is a cross-sectional view schematically illustrating a light emitting device according to an embodiment of the present disclosure;

FIG. 7 is a cross-sectional view of a display apparatus according to an embodiment of the present disclosure;

FIG. 8 is a cross-sectional view of a display apparatus according to an embodiment of the present disclosure;

FIG. 9 is a cross-sectional view illustrating a display apparatus according to an embodiment of the present disclosure;

FIG. 10 is a cross-sectional view illustrating a display apparatus according to an embodiment of the present disclosure; and

FIG. 11 is a perspective view schematically illustrating an electronic apparatus including a display apparatus according to an embodiment of the present disclosure.

### DETAILED DESCRIPTION

The present disclosure may be modified in one or more suitable manners and have many suitable forms, and thus specific embodiments will be exemplified in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are used for referring to like elements. In the accompanying drawings, the dimensions of each structure are exaggeratingly illustrated for clarity of the present disclosure. It will be understood that, although the terms “first,” “second,” etc., may be used herein to describe various components, these components should not be limited by these terms. These terms are only used to distinguish one component from another. For example, a first component could be termed a second component, and, similarly, a second component could be termed a first component, without departing from the scope of example embodiments of the present disclosure. As used herein, the singular forms, “a,” “an,” and “the” are intended to include the plural forms as well, unless the context clearly indicates otherwise.

In the present application, it will be understood that the terms “include,” “have” and/or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present application, when a layer, a film, a region, or a plate is referred to as being “on” or “in an upper portion of” another layer, film, region, or plate, it may be not only “directly on” the layer, film, region, or plate, but intervening layers, films, regions, or plates may also be present. On the contrary to this, when a layer, a film, a region, or a plate is referred to as being “below” or “in a lower portion of” another layer, film, region, or plate, it can be not only directly under the layer, film, region, or plate, but intervening layers, films, regions, or plates may also be present. In addition, it will be understood that when a part is referred to as being “on” another part, it can be disposed above the other part, or disposed under the other part as well.

In the specification, the term “substituted or unsubstituted” may refer to that a group is unsubstituted or substituted with at least one substituent selected from the group consisting of a deuterium atom, a halogen atom, a cyano group, a nitro group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be a linear, branched or cyclic type or kind. The number of carbons in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the present disclosure is not limited thereto.

In the specification, the alkenyl group refers to a hydrocarbon group including at least one carbon-carbon double bond in the middle and/or at the terminal end of an alkyl group having 2 or more carbon atoms. The alkenyl group may be linear or branched. The number of carbon atoms in the alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but the embodiment of the present disclosure is not limited thereto.

In the specification, an alkynyl group refers to a hydrocarbon group including at least one carbon-carbon triple bond in the middle and/or at the terminal end of an alkyl group having 2 or more carbon atoms. The alkynyl group may be linear or branched. Although the number of carbon atoms is not specifically limited, it may be 2 to 30, 2 to 20, or 2 to 10. Specific examples of the alkynyl group may include an ethynyl group, a propynyl group, etc., but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

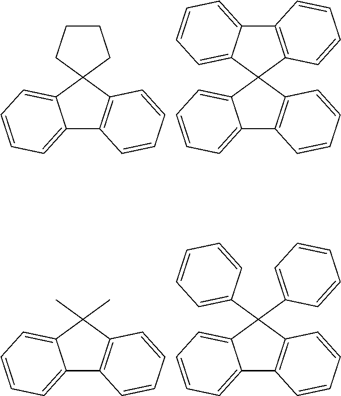

The heterocyclic group herein refers to any functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group and may include a heteroaryl group. The number of ring-forming carbon atoms in the heterocyclic group may be 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the embodiment of the present disclosure is not limited thereto.

In the specification, the heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isooxazole group, an oxazole group, an oxadiazole group, a thiadiazole group, a phenothiazine group, a dibenzosilole group, a dibenzofuran group, etc., but the embodiment of the present disclosure is not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

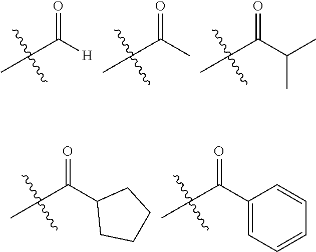

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but the embodiment of the present disclosure is not limited thereto.

In the specification, an oxy group may refer to that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but the embodiment of the present disclosure is not limited thereto.

The boron group herein may refer to that a boron atom is bonded to the alkyl group or the aryl group as defined above. The boron group includes an alkyl boron group and an aryl boron group. Examples of the boron group may include a dimethylboron group, a trimethylboron group, a t-butyldimethylboron group, a diphenylboron group, a phenylboron group, etc., but the embodiment of the present disclosure is not limited thereto.

In the specification, the alkenyl group may be linear or branched. The number of carbon atoms in the alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but the embodiment of the present disclosure is not limited thereto.

In the specification, the alkyl group in the alkylthio group, the alkyl sulfoxy group, the alkyl aryl group, the alkyl boron group, the alkyl silyl group and the alkyl amine group is the same as the examples of the alkyl group described above.

In the specification, the aryl group in the aryloxy group, the arylthio group, the aryl sulfoxy group, the aryl boron group, the aryl silyl group, and the aryl amine group is the same as the examples of the aryl group described above.

In the specification, a direct linkage may refer to a single bond.

In some embodiments, in the specification,

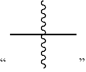

and “^{—}*” refer to a position to be connected.

Hereinafter, embodiments of the present disclosure will be described with reference to the accompanying drawings.

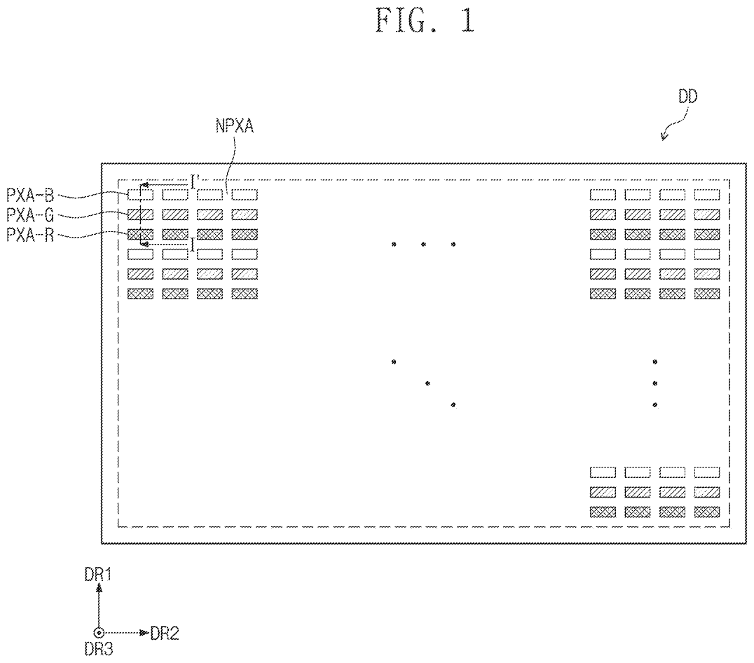

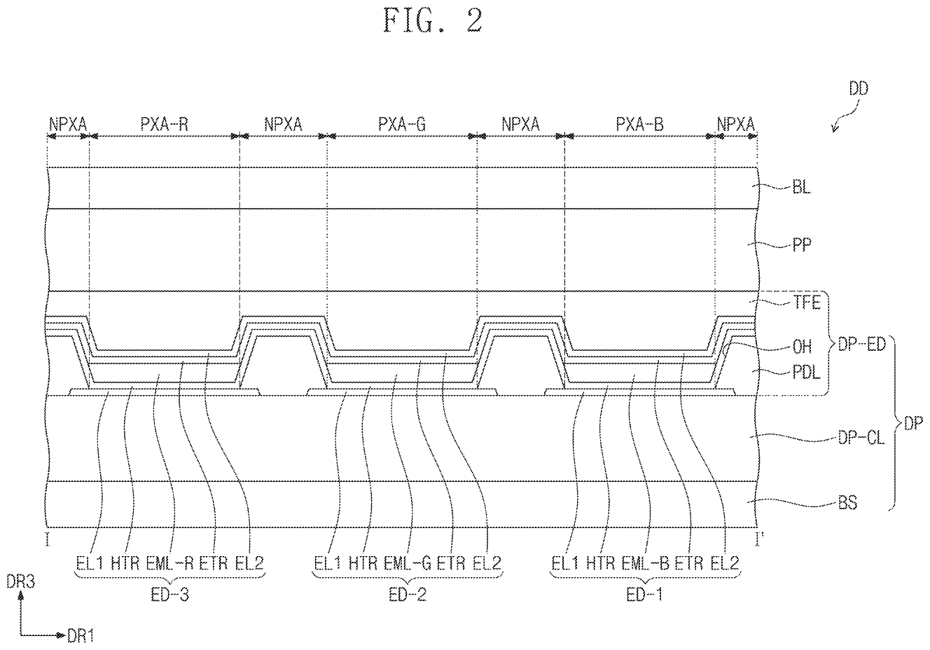

FIG. 1 is a plan view illustrating an embodiment of a display apparatus DD. FIG. 2 is a cross-sectional view of the display apparatus DD of the embodiment. FIG. 2 is a cross-sectional view illustrating a part taken along line I-I′ of FIG. 1.

The display apparatus DD may include a display panel DP and an optical layer PP disposed on the display panel DP. The display panel DP includes light emitting devices ED-1, ED-2, and ED-3. The display apparatus DD may include a plurality of light emitting devices ED-1, ED-2, and ED-3. The optical layer PP may be disposed on the display panel DP to control reflection of external light at the display panel DP. The optical layer PP may include, for example, a polarization layer or a color filter layer. In some embodiments, unlike the configuration illustrated in the drawing, the optical layer PP may not be provided in the display apparatus DD of an embodiment.

A base substrate BL may be disposed on the optical layer PP. The base substrate BL may be a member which provides a base surface on which the optical layer PP is disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike the configuration illustrated, in an embodiment, the base substrate BL may not be provided.

The display apparatus DD according to an embodiment may further include a filling layer. The filling layer may be disposed between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. For example, the display panel DP may include the base layer BS, the circuit layer DP-CL, and the display device layer DP-ED that are sequentially stacked. The display device layer DP-ED may include a pixel defining film PDL, the light emitting devices ED-1, ED-2, and ED-3 disposed between portions of the pixel defining film PDL, and an encapsulation layer TFE disposed on the light emitting devices ED-1, ED-2, and ED-3.

The base layer BS may be a member which provides a base surface on which the display device layer DP-ED is disposed. The base layer BS may be a glass substrate, a metal substrate, a plastic substrate, etc. However, the embodiment is not limited thereto, and the base layer BS may be an inorganic layer, an organic layer, or a composite material layer.

In an embodiment, the circuit layer DP-CL is disposed on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting devices ED-1, ED-2, and ED-3 of the display device layer DP-ED.

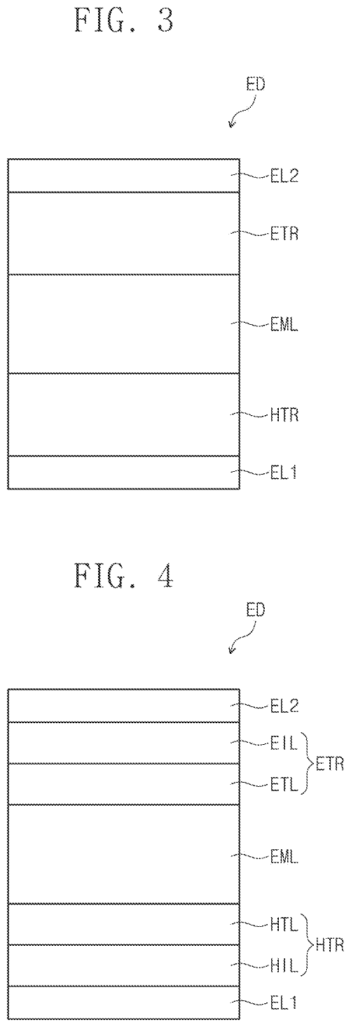

Each of the light emitting devices ED-1, ED-2, and ED-3 may have a structure of each light emitting device ED of embodiments according to FIGS. 3 to 6, which will be described in more detail later. The light emitting device ED may include a plurality of light emitting devices ED-1, ED-2, and ED-3. Each of the light emitting devices ED-1, ED-2, and ED-3 may include a first electrode EL1, a hole transport region HTR, emission layers EML-R, EML-G, and EML-B (e.g., a corresponding one of the emission layer EML-R, the emission layer EML-G, or the emission layer EML-B), an electron transport region ETR, and a second electrode EL2.

The first light emitting device ED-1 may include a first emission layer EML-B overlapping a first light emitting region PXA-R. The second light emitting device ED-2 may include a second emission layer EML-G overlapping a second light emitting region PXA-G. The third light emitting device ED-3 may include a third emission layer EML-R overlapping a third light emitting region PXA-R.

The pixel defining film PDL may be disposed on the circuit layer DP-CL. Predetermined openings OH may be defined in the pixel defining film PDL. The openings OH defined in the pixel defining film PDL may correspond to a plurality of light emitting regions PXA-R, PXA-G, and PXA-B, respectively. The light shielding regions NPXA may be regions between the adjacent light emitting regions PXA-R, PXA-G, and PXA-B, which correspond to portions of the pixel defining film PDL.

The pixel defining film PDL may include an organic resin or an inorganic material. For example, the pixel defining film PDL may include a polyacrylate-based resin, a polyimide-based resin, or silicon nitride (SiNₓ), silicon oxide (SiOₓ), silicon nitrate (SiOₓN_{y}), etc.

FIG. 2 illustrates an embodiment in which the emission layers EML-R, EML-G, and EML-B of the light emitting devices ED-1, ED-2, and ED-3 are disposed in openings OH defined in the pixel defining film PDL, and the hole transport region HTR, the electron transport region ETR, and the second electrode EL2 are provided as a common layer in the entire light emitting devices ED-1, ED-2, and ED-3. However, the embodiment of the present disclosure is not limited thereto, and unlike the configuration illustrated in FIG. 2, the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in an embodiment may be provided by being patterned utilizing an inkjet printing method.

The emission layer EML may be disposed on the first electrode EL1. The emission layer EML may include a plurality of emission layers EML-R, EML-G, and EML-B. The first emission layer EML-B may overlap the first light emitting region PXA-B and emit a first light. The second emission layer EML-G may overlap the second light emitting region PXA-G and emit a second light. The third emission layer EML-R may overlap the third light emitting region PXA-R and emit a third light. In the light emitting devices ED-1, ED-2, and ED-3 according to an embodiment, the first to third light may be light having a substantially different wavelength range. For example, the first light may be red light having a wavelength range of about 410 nm to about 480 nm. For example, the second light may be green light having a wavelength range of about 500 nm to about 570 nm. For example, the third light may be blue light having a wavelength range of about 625 nm to about 675 nm.

In an embodiment, the first emission layer EML-B may include a first compound, which will be described in more detail later. The first emission layer EML-B may include a plurality of luminescent materials. In the light emitting device ED of an embodiment, the first emission layer EML-B may include at least one of a first compound, a second compound, a third compound, or a fourth compound. The first emission layer EML-B of an embodiment may include a first compound represented by Formula 1, which will be described in more detail later, or a third compound represented by Formula 3, which will be described in more detail later. In some embodiments, the first emission layer EML-B of an embodiment may include the first compound, the second compound, and the third compound. In some embodiments, the first emission layer EML-B of an embodiment may include all of the first compound, the second compound, the third compound, and the fourth compound. The first to fourth compounds will be described in more detail later.

The encapsulation layer TFE may cover the light emitting devices ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be disposed on the second electrode EL2 and may be disposed filling the opening OH.

Referring to FIGS. 1 and 2, the display apparatus DD may include a non-light emitting region NPXA and light emitting regions PXA-R, PXA-G, and PXA-B. The light emitting regions PXA-R, PXA-G, and PXA-B may be regions in which light generated by the respective light emitting devices ED-1, ED-2, and ED-3 is emitted. The light emitting regions PXA-R, PXA-G, and PXA-B may be spaced apart from each other on a plane (e.g., in a plan view).

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In some embodiments, in the specification, the light emitting regions PXA-R, PXA-G, and PXA-B may respectively correspond to pixels. The pixel defining film PDL may divide the light emitting devices ED-1, ED-2, and ED-3. The emission layers EML-R, EML-G, and EML-B of the light emitting devices ED-1, ED-2, and ED-3 may be disposed in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD of an embodiment illustrated in FIGS. 1 and 2, three light emitting regions PXA-R, PXA-G, and PXA-B, which emit red light, green light, and blue light, respectively, are exemplarily illustrated. For example, the display apparatus DD of an embodiment may include the red light emitting region PXA-R, the green light emitting region PXA-G, and the blue light emitting region PXA-B that are separated from each other.

In the display apparatus DD according to an embodiment, the plurality of light emitting devices ED-1, ED-2 and ED-3 may be to emit light (e.g., light beams) having wavelengths different from each other. For example, in an embodiment, the display apparatus DD may include a first light emitting device ED-1 emitting blue light, a second light emitting device ED-2 emitting green light, and a third light emitting device ED-3 emitting red light. For example, the red light emitting region PXA-R, the green light emitting region PXA-G, and the red light emitting region PXA-B of the display apparatus DD may correspond to the first light emitting device ED-1, the second light emitting device ED-2, and the third light emitting device ED-3, respectively.

However, the embodiment of the present disclosure is not limited thereto, and the first to third light emitting devices ED-1, ED-2, and ED-3 may be to emit light (e.g., light beams) in substantially the same wavelength range or at least one light emitting device may be to emit a light (e.g., light beam) in a wavelength range different from the others. For example, the first to third light emitting devices ED-1, ED-2, and ED-3 may all emit blue light.

The light emitting regions PXA-R, PXA-G, and PXA-B in the display apparatus DD according to an embodiment may be arranged in a stripe form. Referring to FIG. 1, the plurality of red light emitting regions PXA-R may be arranged with each other along a second directional axis DR2, the plurality of green luminous areas PXA-G may be arranged with each other along the second directional axis DR2, and the plurality of blue luminous areas PXA-B may be arranged with each other along the second directional axis DR2. In some embodiments, the (one) red light emitting region PXA-R, the (one) green light emitting region PXA-G, and the (one) blue light emitting region PXA-B may be alternately arranged in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2 (e.g., in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, the arrangement form of the light emitting regions PXA-R, PXA-G, and PXA-B may be a pentile (PENTILE®) arrangement form or a diamond (Diamond Pixel™) arrangement form. PENTILE® and Diamond Pixel™ are trademarks of Samsung Display Co., Ltd.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but the embodiment of the present disclosure is not limited thereto.

Hereinafter, FIGS. 3 to 6 are cross-sectional views schematically illustrating light emitting devices according to embodiments. Each of the light emitting devices ED according to embodiments may include a first electrode EL1, a hole transport region HTR, an emission layer EML, an electron transport region ETR, and a second electrode EL2 that are sequentially stacked.

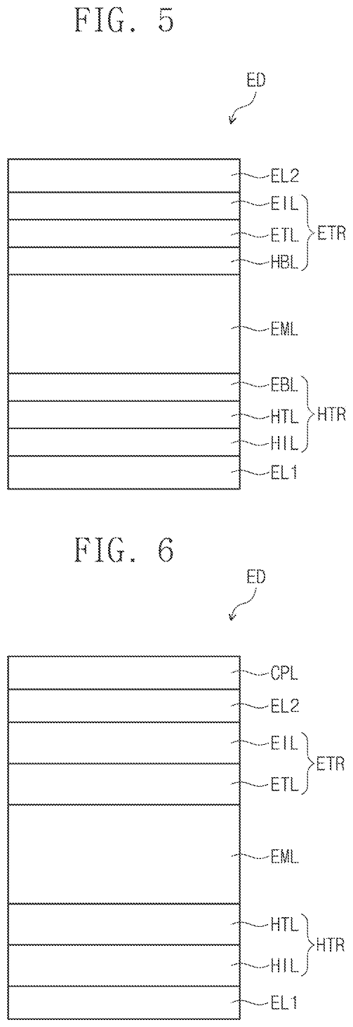

Compared with FIG. 3, FIG. 4 illustrates a cross-sectional view of a light emitting device ED of an embodiment, in which a hole transport region HTR includes a hole injection layer HIL and a hole transport layer HTL, and an electron transport region ETR includes an electron injection layer EIL and an electron transport layer ETL. In some embodiments, compared with FIG. 3, FIG. 5 illustrates a cross-sectional view of a light emitting device ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting device ED of an embodiment including a capping layer CPL disposed on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the embodiment of the present disclosure is not limited thereto. In addition, the embodiment of the present disclosure is not limited thereto, and the first electrode EL1 may include the above-described metal materials, combinations of at least two metal materials of the above-described metal materials, oxides of the above-described metal materials, and/or the like. The thickness of the first electrode EL1 may be from about 700 Å to about 10,000 Å. For example, the thickness of the first electrode EL1 may be from about 1,000 Å to about 3,000 Å.

The light emitting device ED may include a plurality of functional layers disposed between the first electrode EL1 and the second electrode EL2. For example, the functional layers of the light emitting device ED may include a hole transport region HTR, an emission layer EML, and an electron transport region ETR. However, the embodiment of the present disclosure is not limited thereto.

At least one functional layer among the plurality of functional layers included in the light emitting device ED of an embodiment includes a first compound represented by Formula 1, a second compound represented by Formula 2, and a third compound represented by Formula 3. For example, the plurality of functional layers may include the hole transport region HTR disposed on the first electrode EL1, the emission layer EML disposed on the hole transport region HTR, and the electron transport region ETR disposed on the emission layer EML, and at least one layer of the hole transport region HTR, the emission layer EML, or the electron transport region ETR may include the first compound, the second compound, and the third compound. In an embodiment, the emission layer EML among the plurality of functional layers may include the first compound, the second compound, and the third compound of an embodiment.

The first compound may include a silicon atom and a structure in which first to fourth benzene rings are linked to the silicon atom. In an embodiment, the first benzene ring may include a first substituent. In an embodiment, the first substituent may be a substituted or unsubstituted aryl group having 6 to 30 ring-forming carbon atoms, or a substituted or unsubstituted heteroaryl group having 2 to 30 ring-forming carbon atoms. The first substituent may be linked at the meta-position with the silicon atom. For example, the first substituent may be linked to the first benzene ring at the meta-position carbon, with respect to the silicon atom, among carbon atoms constituting the first benzene ring. The first substituent may be directly bonded to the first benzene ring.

The first compound of an embodiment may include a structure in which a fifth benzene ring is fused, via a first atom, to at least one benzene ring among the first to fourth benzene rings. In an embodiment, the first atom may be an oxygen atom or a sulfur atom. For example, the fifth benzene ring may be fused to at least one benzene ring among the first to fourth benzene rings, and in this case, the fifth benzene ring may be fused via an oxygen atom or a sulfur atom.

In an embodiment, the first compound may be represented by Formula 1:

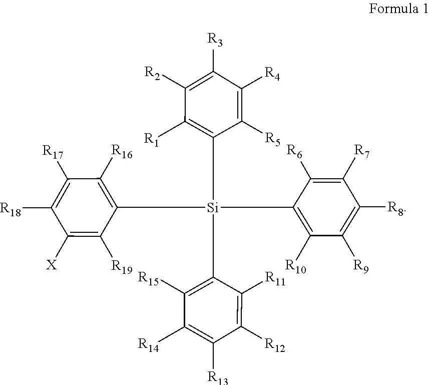

The first compound represented by Formula 1 may include a silicon atom and the first to fourth benzene rings linked to the silicon atom. The benzene ring substituted with a substituent represented by R₁ to R₁₉ may correspond to the above-described first benzene ring, the benzene ring substituted with a substituent represented by R₁ to R₅ may correspond to the above-described second benzene ring, the benzene ring substituted with a substituent represented by R₆ to R₁₀ may correspond to the above-described third benzene ring, and the benzene ring substituted with a substituent represented by R₁₁ to R₁₅ may correspond to the above-described fourth benzene ring. In some embodiments, X in Formula 1 may correspond to the above-described first substituent.

In Formula 1, X is a substituted or unsubstituted aryl group having 6 to 30 ring-forming carbon atoms, or a substituted or unsubstituted heteroaryl group having 2 to 30 ring-forming carbon atoms. In an embodiment, X may be a phenyl group substituted with a substituted or unsubstituted heteroaryl group having 2 to 30 ring-forming carbon atoms, the heteroaryl group containing a nitrogen atom as a ring-forming atom, or a substituted or unsubstituted heteroaryl group having 2 to 30 ring-forming carbon atoms, the heteroaryl group containing a nitrogen atom as a ring-forming atom. For example, X may be a phenyl group substituted with a substituted or unsubstituted carbazole group, or a substituted or unsubstituted carbazole group. For example, X may be a carbazole group substituted with a carbazole group.

In Formula 1, R₁ to R₁₉ may each independently be a hydrogen atom, a deuterium atom, a halogen atom, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, one or more (e.g., each) of R₁ to R₁₉ may be bonded to an adjacent group to form a ring. For example, R₁ to R₁₉ may each independently be a hydrogen atom or a substituted or unsubstituted phenyl group.

In Formula 1, at least one pair among adjacent pairs of R₁ to R₁₈ are positions at which a substituent represented by Formula C is fused.

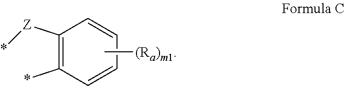

In Formula C above, ^{—}* is a position which is fused to any adjacent one pair among R₁ to R₁₈ in Formula 1 above, and Z is O or S.

In Formula C, Rₐ may be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ may be a hydrogen atom, a substituted or unsubstituted t-butyl group, or a substituted or unsubstituted phenyl group.

In Formula C, m1 is an integer of 0 to 4. In Formula C, when m1 is 0, the first compound of an embodiment may not be substituted with Rₐ. In Formula C, the case where m1 is 4 and Rₐ's are all hydrogen atoms may be the same as the case where m1 is 0 in Formula 1. When m1 is an integer of 2 or greater, a plurality of Rₐ's may all be the same, or at least one among the plurality of Rₐ's may be different from the others.

In an embodiment, the first compound represented by Formula 1 above may be represented by Formula 1-1-1 or Formula 1-1-2:

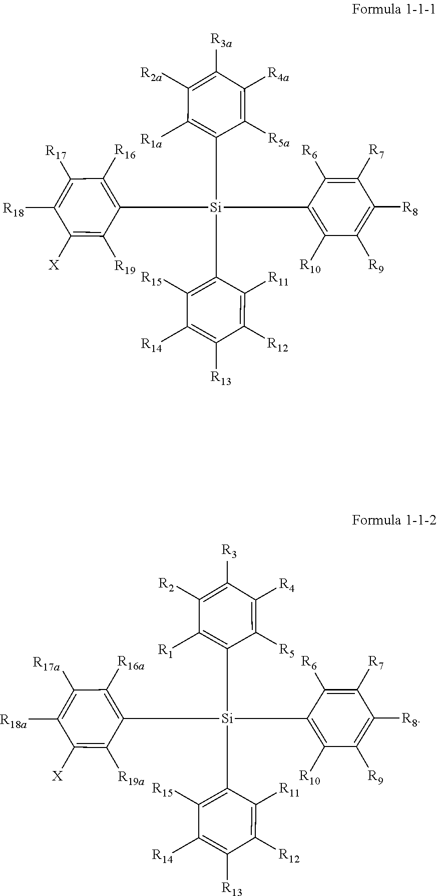

Formula 1-1-1 and Formula 1-1-2 each represent that the fused position of the substituent represented by Formula C is specified in Formula 1.

In Formula 1-1-1 to Formula 1-1-2, R₁ₐ to R₅ₐ and R₁₆ₐ to R₁₈ₐ may each independently be a hydrogen atom, a deuterium atom, a halogen atom, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₁ₐ to R₅ₐ, and R₁₆ₐ to R₁₈ₐ may be bonded to an adjacent group to form a ring. For example, R₁ₐ to R₅ₐ, and R₁₆ₐ to R₁₈ₐ may each independently be a hydrogen atom, or a substituted or unsubstituted phenyl group.

In Formula 1-1-1, adjacent one pair among R₁ₐ to R₅ₐ may be positions at which the substituent represented by Formula C above is fused. For example, in Formula 1-1-1, the substituent represented by Formula C may be substituted to the positions of R₁ₐ and R₂ₐ. In some embodiments, in Formula 1-1-1, the substituent represented by Formula C may be substituted to the positions of R₂ₐ and R₃ₐ. In Formula 1-1-1, at least one pair among adjacent pairs of R₆ to R₁₈ may be positions at which a substituent represented by Formula C is fused. However, the embodiment of the present disclosure is not limited thereto, and at the positions other than R₁ₐ to R₅ₐ, the substituent represented by Formula C may not be further fused.

In Formula 1-1-2, adjacent one pair among R₁₆ₐ to R₁₈ₐ may be positions at which the substituent represented by Formula C above is fused. For example, in Formula 1-1-2, the substituent represented by Formula C may be substituted to the positions of R₁₇ₐ and R₁₈ₐ. In Formula 1-1-2, at least one pair among adjacent pairs of R₁ to R₁₅ may be positions at which a substituent represented by Formula C is fused. However, the embodiment of the present disclosure is not limited thereto, and at the positions other than R₁₆ₐ to R₁₈ₐ, the substituent represented by Formula C may not be further fused.

In Formula 1-1-1 and Formula 1-1-2, the same as described in Formula 1 may be applied to X and R₁ to R₁₉.

In an embodiment, the first compound represented by Formula 1 may be represented by any one among Formula 1-2-1 to Formula 1-2-5:

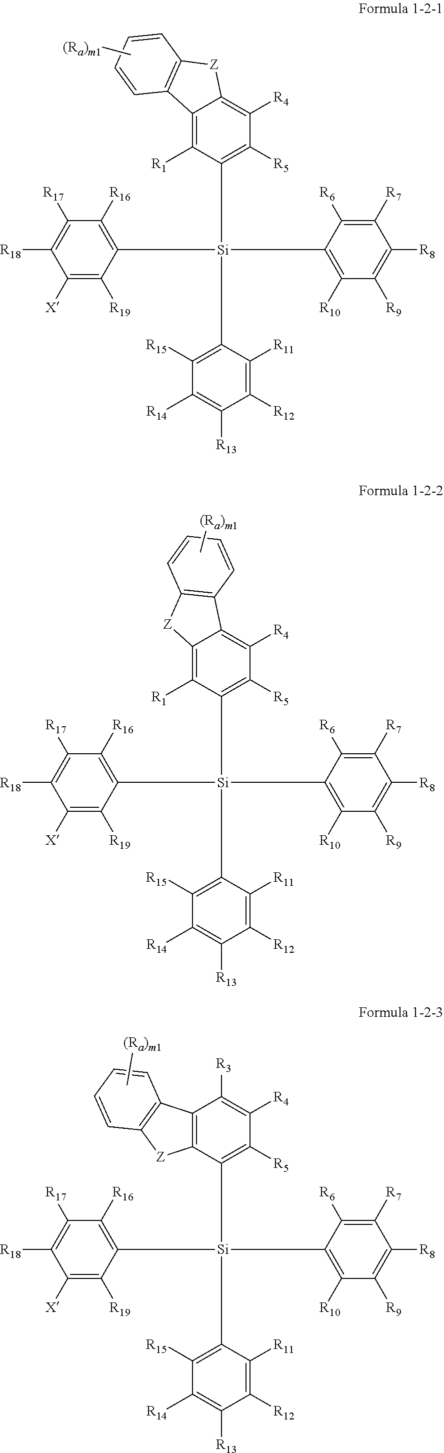

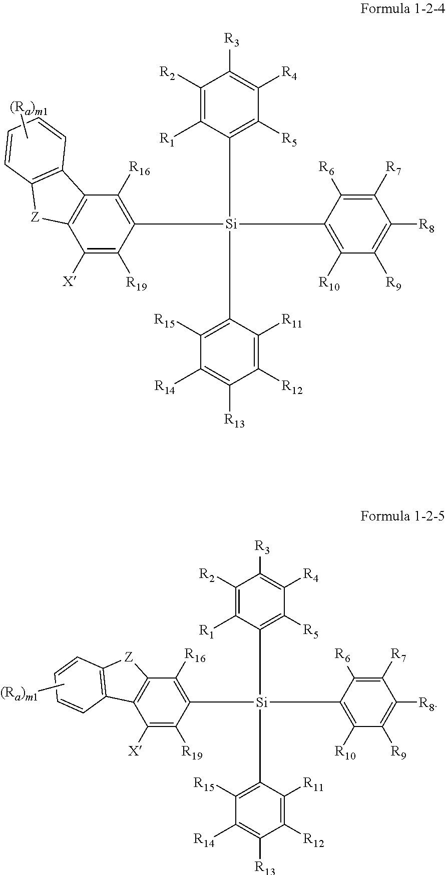

Formula 1-2-1 to Formula 1-2-5 represent that the substituent represented by Formula C is fused in Formula 1.

In Formula 1-2-1 to Formula 1-2-5, X′ may be represented by any one among Formula S-1 to Formula S-3:

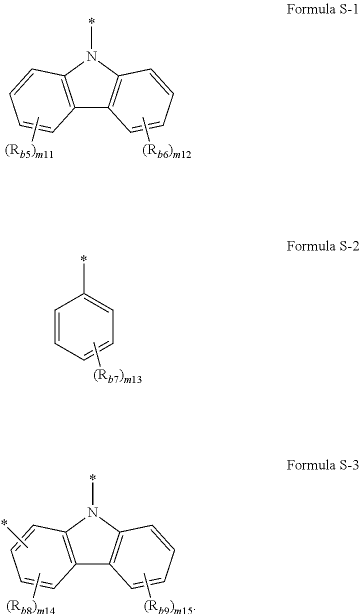

In Formula S-3, Yₐ may be NR_{b10}.

In Formula S-1 to Formula S-3, R_{b5} to R_{b10} may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{b5} to R_{b9} may each independently be a hydrogen atom, a substituted or unsubstituted t-butyl group, or a substituted or unsubstituted carbazole group. R_{b10} may be a substituted or unsubstituted phenyl group.

In Formula S-1 and Formula S-3, m11, m12, and m15 may each independently be an integer of 0 to 4. In Formula S-1 and Formula S-3, when each of m1, m12 and m15 is 0, the first compound of an embodiment may not be substituted with each of R_{b5}, R_{b6}, and R_{b9}. In Formula S-1 and Formula S-3, the case where each of m11, m12, and m15 is 4 and R_{b5}'s, R_{b6}'s, and R_{b9}'s are each hydrogen atoms may be the same as the case where each of m11, m12, and m15 is 0 in Formula S-1 and Formula S-3. When each of m11, m12, and m15 is an integer of 2 or more, a plurality of R_{b5}'s, R_{b6}'s, and R_{b9}'s each may be the same or at least one among the plurality of R_{b5}'s, R_{b6}'s, and R_{b9}'s may be different from the others.

In Formula S-2, m13 is an integer of 0 to 5. In Formula S-2, when m13 is 0, the first compound of an embodiment may not be substituted with R_{b7}. In Formula S-2, the case where m13 is 5 and R_{b7}'s are all hydrogen atoms may be the same as the case where m13 is 0 in Formula S-2. When m13 is an integer of 2 or greater, a plurality of R_{b7}'s may all be the same, or at least one among the plurality of R_{b7}'s may be different from the others.

In Formula S-3, m14 is an integer of 0 to 3. In Formula S-3, when m14 is 0, the first compound of an embodiment may not be substituted with Rub. In Formula S-3, the case where m14 is 3 and R_{b8}'s are all hydrogen atoms may be the same as the case where m14 is 0 in Formula S-3. When m14 is an integer of 2 or greater, a plurality of R_{b8}'s may be all the same or at least one among the plurality of R_{b8}'s may be different from the others.

In Formula 1-2-1 to Formula 1-2-5 above, the same as described in Formula 1 and Formula C above may be applied to R₁ to R₁₉, Z, Rₐ, and m1.

In an embodiment, the first compound represented by Formula 1 may be represented by any one among Formula 1-3-1 to Formula 1-3-3:

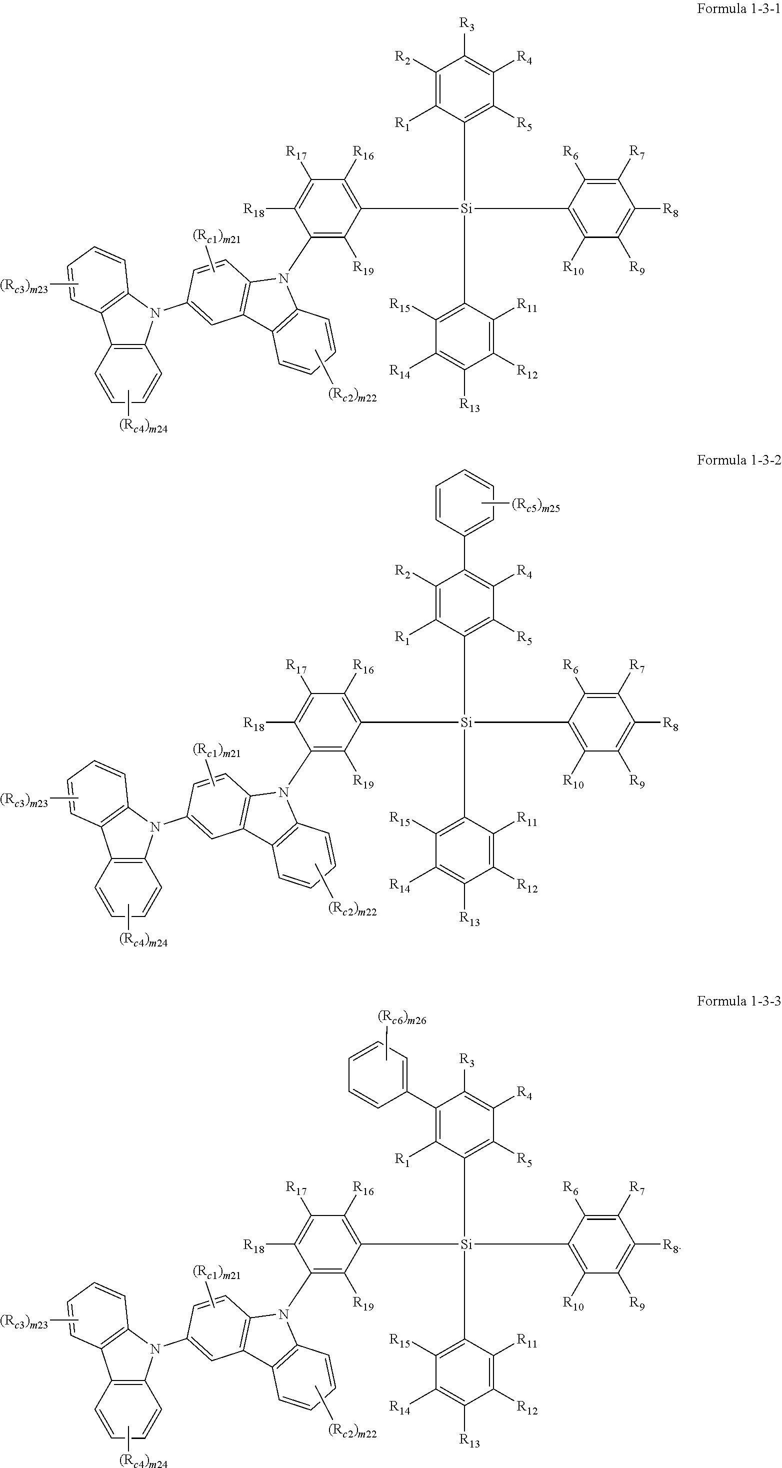

Formula 1-3-1 to Formula 1-3-3 represent the cases where the types (kinds) of X in Formula 1 are specified.

In Formula 1-3-1 to Formula 1-3-3, R_{c1} to R_{c6} may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{c1} to R_{c6} may each independently be a hydrogen atom.

In Formula 1-3-1 to Formula 1-3-3, m21 is an integer of 0 to 3, m22 to m24 may each independently be an integer of 0 to 4, and m25 and m26 may each independently be an integer of 0 to 5.

In Formula 1-3-1 to Formula 1-3-3, when m21 is 0, the fused polycyclic compound of an embodiment may not be substituted with R_{c1}. In Formula 1-3-1 to Formula 1-3-3, the case where m21 is 3 and R_{c1}'s are all hydrogen atoms may be the same as the case where m21 is 0 in Formula 1-3-1 to Formula 1-3-3. When m21 is an integer of 2 or greater, a plurality of R_{c1}'s may be all the same or at least one among the plurality of R_{c1}'s may be different from the others.

In Formula 1-3-1 to Formula 1-3-3, when each of m22 to m24 is 0, the fused polycyclic compound of an embodiment may not be substituted with each of R_{c2} to R_{c4}. In Formula 1-3-1 to Formula 1-3-3, the case where each of m22 to m24 is 4 and R_{c2}'s to R_{c4}'s are each hydrogen atoms may be the same as the case where each of m22 to m24 is 0 in Formula 1-3-1 to Formula 1-3-3. When each of m22 to m24 is an integer of 2 or greater, a plurality of R_{c5}'s and R_{c6}'s may each be the same or at least one among the plurality of R_{c5}'s and R_{c6}'s may be different from the others.

In Formula 1-3-2 and Formula 1-3-3, when each of m25 to m26 is 0, the fused polycyclic compound of an embodiment may not be substituted with R_{c5} and R_{c6}. In Formula 1-3-2 and Formula 1-3-3, the case where each of m25 and m26 is 5 and R_{c5}'s and R_{c6}'s are each hydrogen atoms may be the same as the case where each of m25 and m26 is 0 in Formula 1-3-2 and Formula 1-3-3. When each of m25 and m26 is an integer of 2 or more, a plurality of R_{c5}'s and R_{c6}'s may each be the same or at least one among the plurality of R_{c5}'s and R_{c6}'s may be different from the others.

In Formula 1-3-1 to Formula 1-3-3, the same as described in Formula 1 above may be applied to R₁ to R₁₉.

In an embodiment, the first compound represented by Formula 1 may be represented by any one among Formula 1-4-1 to Formula 1-4-3:

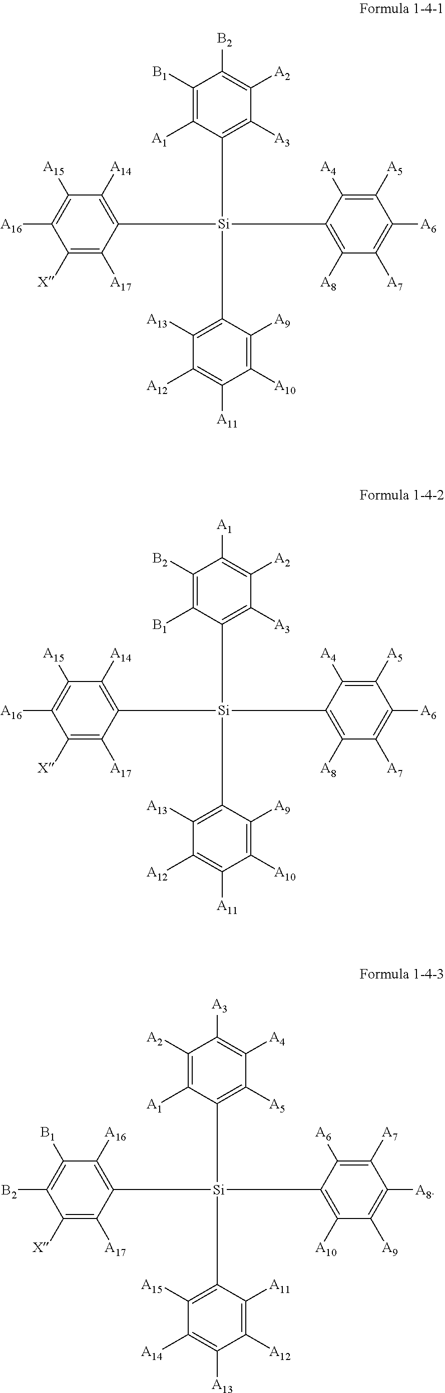

Formula 1-4-1 to Formula 1-4-3 each represent that in Formula 1, the fused position of the substituent represented by Formula C is specified and the types (kinds) of the substituents represented by X are specified.

In Formula 1-4-1 to Formula 1-4-3, A₁ to A₁₇ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, A₁ to A₁₇ may each independently be a hydrogen atom or a substituted or unsubstituted phenyl group.

In Formula 1-4-1 and Formula 1-4-3, B₁ and B₂ may be positions at which the substituent represented by Formula C above is fused. In the first compounds represented by Formula 1-4-1 to Formula 1-4-3, one substituent represented by Formula C may be linked and fused at the positions of B₁ and B₂.

In Formula 1-4-1 to Formula 1-4-3, X″ may be a substituted or unsubstituted phenyl group, or a substituted or unsubstituted heteroaryl group having 2 to 30 ring-forming carbon atoms, the heteroaryl group containing a nitrogen atom as a ring-forming atom. In an embodiment, X″ may be represented by Formula T-1 or Formula T-2:

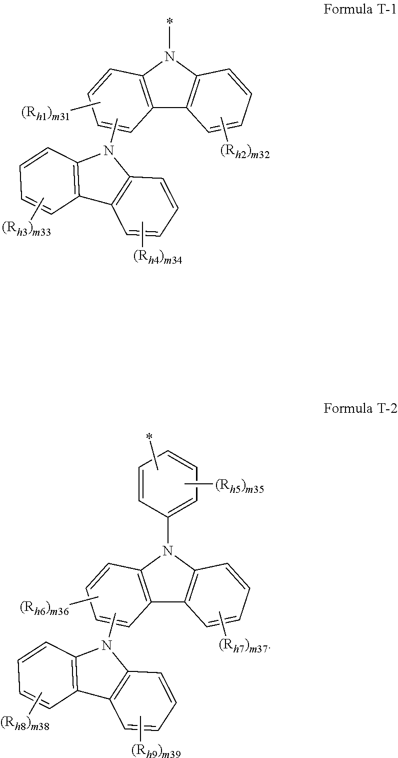

In Formula T-1 and Formula T-2, Rₕ₁ to Rₕ₉ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₕ₁ to Rₕ₉ may each independently be a hydrogen atom or a deuterium atom.

In Formula T-1 and Formula T-2, m31 and m36 may each independently be an integer of 0 to 3. In Formula T-1 and Formula T-2, when each of m31 and m36 is 0, the fused polycyclic compound of an embodiment may not be substituted with each of Rₕ₁ and Rₕ₆. In Formula T-1 and Formula T-2, the case where each of m31 and m36 is 3 and Rₕ₁'s and Rₕ₆'s are each hydrogen atoms may be the same as the case where each of m31 and m36 is 0 in Formula T-1 and Formula T-2. When each of m31 and m36 is an integer of 2 or greater, a plurality of Rₕ₁'s and Rₕ₆'s may each be the same or at least one among the plurality of Rₕ₁'s and Rₕ₆'s may be different from the others.

In Formula T-1 and Formula T-2, m32 to m34, m35, and m37 to m39 may each independently be an integer of 0 to 4. In Formula T-1 and Formula T-2, when each of m32 to m34, m35, and m37 to m39 is 0, the fused polycyclic compound of an embodiment may not be substituted with each of Rₕ₂ to Rₕ₄, Rₕ₅, and Rₕ₇ to Rₕ₉. In Formula T-1 and Formula T-2, the case where each of m32 to m34, m35, and m37 to m39 is 4 and Rₕ₂'s to Rₕ₄'s, Rₕ₅'s, and Rₕ₇'s to Rₕ₉'s are each hydrogen atoms may be the same as the case where each of m32 to m34, m35, and m37 to m39 is 0 in Formula T-1 and Formula T-2. When each of m32 to m34, m35, and m37 to m39 is an integer of 2 or greater, a plurality of Rₕ₂'s to Rₕ₄'s, Rₕ₅'s, and Rₕ₇'s to Rₕ₉'s may each be the same or at least one among the plurality of Rₕ₂'s to Rₕ₄'s, Rₕ₅'s, and Rₕ₇'s to Rₕ₉'s may be different from the others.

In an embodiment, the first compound represented by Formula 1 may be represented by any one among the compounds represented by Compound Group 1. In the light emitting device ED of an embodiment, at least any one among the plurality of functional layers may include at least one among compounds represented by Compound Group 1. For example, the emission layer EML may include at least one from among the compounds represented by Compound Group 1 as a hole transporting host material. In some embodiments, the hole transport region HTR may include at least one from among the compounds represented by Compound Group 1:

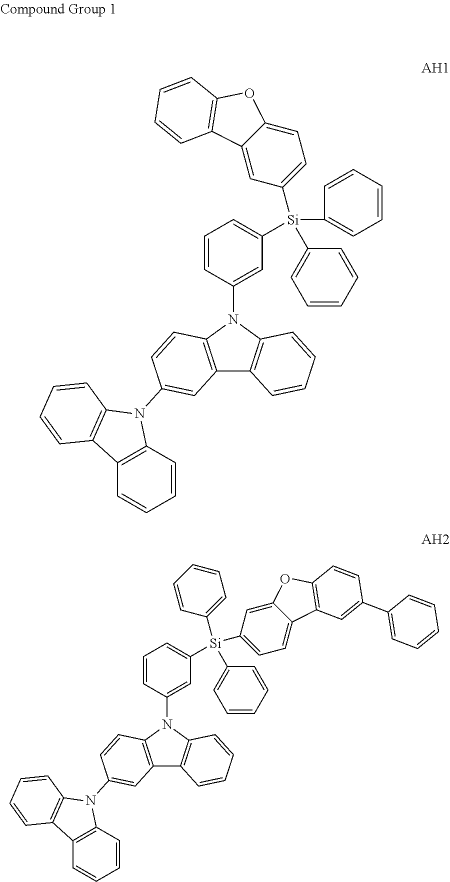 [SMILES: c1ccc([Si](c2ccccc2)(c2cccc(-n3c4ccccc4c4cc(-n5c6ccccc6c6ccccc65)ccc43)c2)c2ccc3oc4ccccc4c3c2)cc1 ; c1ccc(-c2ccc3oc4cc([Si](c5ccccc5)(c5ccccc5)c5cccc(-n6c7ccccc7c7cc(-n8c9ccccc9c9ccccc98)ccc76)c5)ccc4c3c2)cc1]

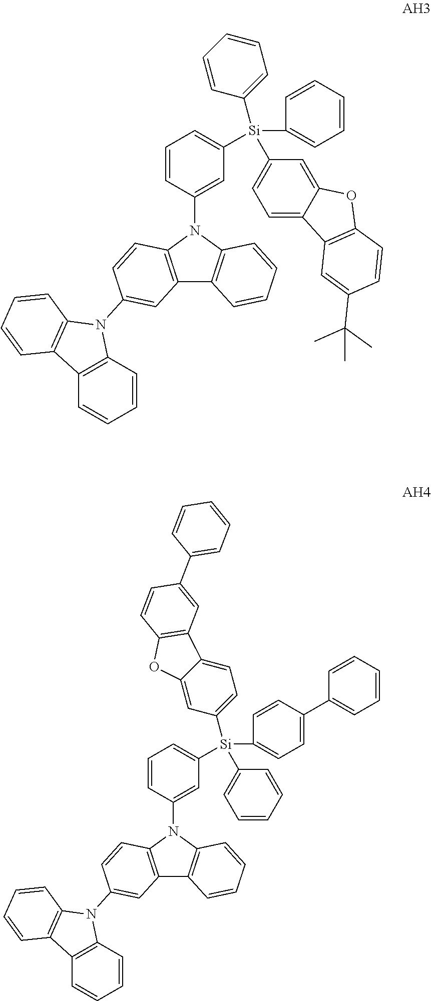 [SMILES: CC(C)(C)c1ccc2oc3cc([Si](c4ccccc4)(c4ccccc4)c4cccc(-n5c6ccccc6c6cc(-n7c8ccccc8c8ccccc87)ccc65)c4)ccc3c2c1 ; c1ccc(-c2ccc([Si](c3ccccc3)(c3cccc(-n4c5ccccc5c5cc(-n6c7ccccc7c7ccccc76)ccc54)c3)c3ccc4c(c3)oc3ccc(-c5ccccc5)cc34)cc2)cc1]

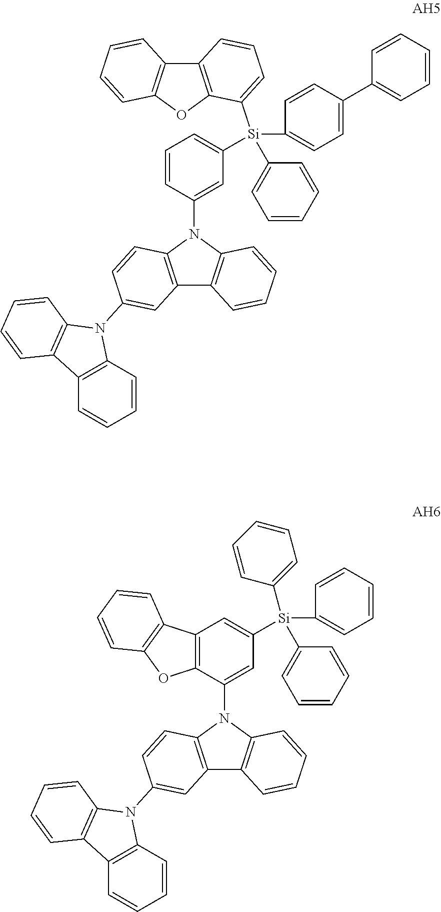 [SMILES: c1ccc(-c2ccc([Si](c3ccccc3)(c3cccc(-n4c5ccccc5c5cc(-n6c7ccccc7c7ccccc76)ccc54)c3)c3cccc4c3oc3ccccc34)cc2)cc1 ; c1ccc([Si](c2ccccc2)(c2ccccc2)c2cc(-n3c4ccccc4c4cc(-n5c6ccccc6c6ccccc65)ccc43)c3oc4ccccc4c3c2)cc1]

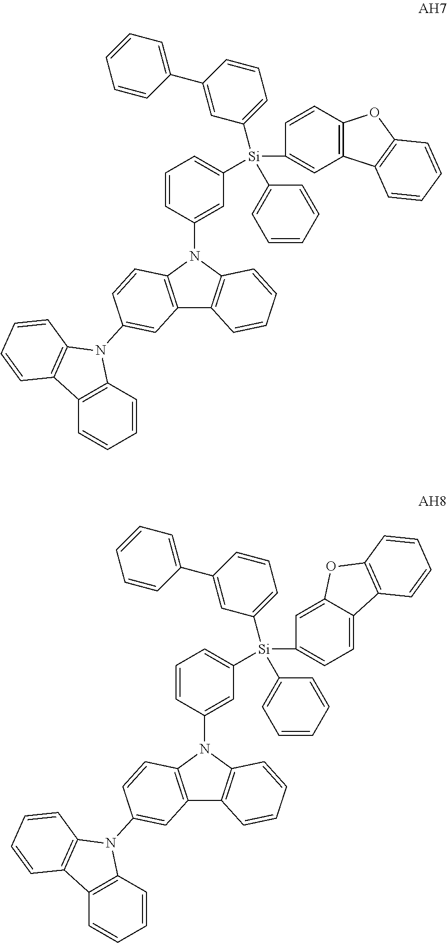 [SMILES: c1ccc(-c2cccc([Si](c3ccccc3)(c3cccc(-n4c5ccccc5c5cc(-n6c7ccccc7c7ccccc76)ccc54)c3)c3ccc4oc5ccccc5c4c3)c2)cc1 ; c1ccc(-c2cccc([Si](c3ccccc3)(c3cccc(-n4c5ccccc5c5cc(-n6c7ccccc7c7ccccc76)ccc54)c3)c3ccc4c(c3)oc3ccccc34)c2)cc1]

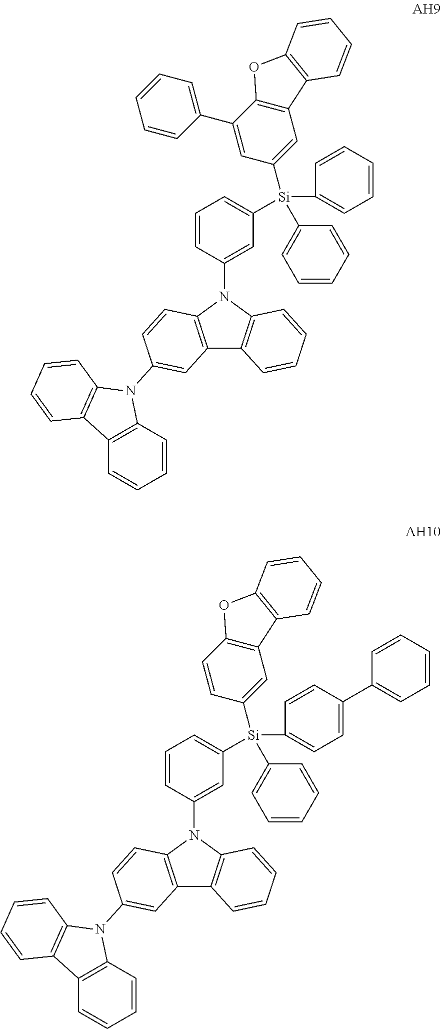 [SMILES: c1ccc(-c2cc([Si](c3ccccc3)(c3ccccc3)c3cccc(-n4c5ccccc5c5cc(-n6c7ccccc7c7ccccc76)ccc54)c3)cc3c2oc2ccccc23)cc1 ; c1ccc(-c2ccc([Si](c3ccccc3)(c3cccc(-n4c5ccccc5c5cc(-n6c7ccccc7c7ccccc76)ccc54)c3)c3ccc4oc5ccccc5c4c3)cc2)cc1]

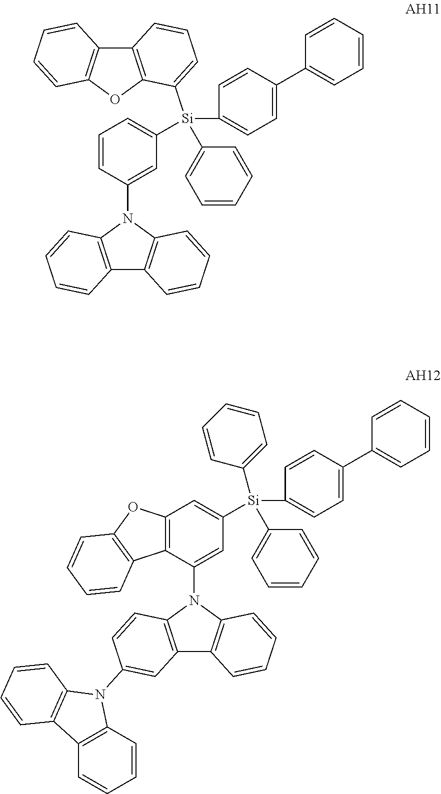 [SMILES: c1ccc(-c2ccc([Si](c3ccccc3)(c3cccc(-n4c5ccccc5c5ccccc54)c3)c3cccc4c3oc3ccccc34)cc2)cc1 ; c1ccc(-c2ccc([Si](c3ccccc3)(c3ccccc3)c3cc(-n4c5ccccc5c5cc(-n6c7ccccc7c7ccccc76)ccc54)c4c(c3)oc3ccccc34)cc2)cc1]

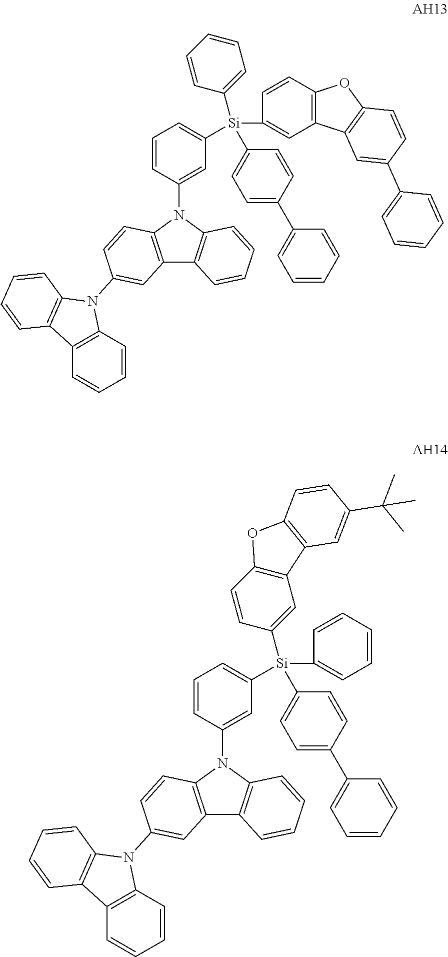 [SMILES: c1ccc(-c2ccc([Si](c3ccccc3)(c3cccc(-n4c5ccccc5c5cc(-n6c7ccccc7c7ccccc76)ccc54)c3)c3ccc4oc5ccc(-c6ccccc6)cc5c4c3)cc2)cc1 ; CC(C)(C)c1ccc2oc3ccc([Si](c4ccccc4)(c4ccc(-c5ccccc5)cc4)c4cccc(-n5c6ccccc6c6cc(-n7c8ccccc8c8ccccc87)ccc65)c4)cc3c2c1]

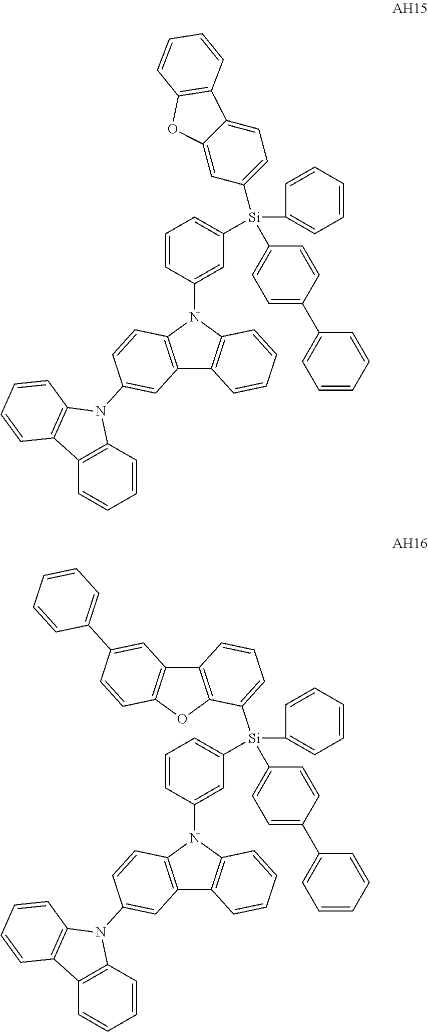 [SMILES: c1ccc(-c2ccc([Si](c3ccccc3)(c3cccc(-n4c5ccccc5c5cc(-n6c7ccccc7c7ccccc76)ccc54)c3)c3ccc4c(c3)oc3ccccc34)cc2)cc1 ; c1ccc(-c2ccc([Si](c3ccccc3)(c3cccc(-n4c5ccccc5c5cc(-n6c7ccccc7c7ccccc76)ccc54)c3)c3cccc4c3oc3ccc(-c5ccccc5)cc34)cc2)cc1]

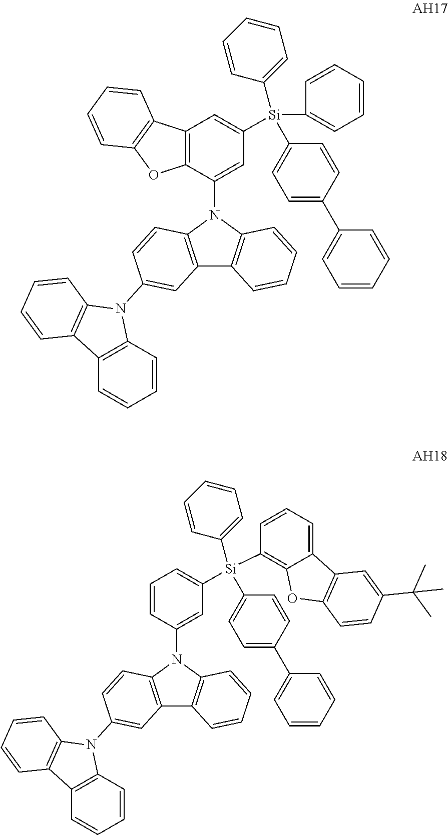 [SMILES: c1ccc(-c2ccc([Si](c3ccccc3)(c3ccccc3)c3cc(-n4c5ccccc5c5cc(-n6c7ccccc7c7ccccc76)ccc54)c4oc5ccccc5c4c3)cc2)cc1 ; CC(C)(C)c1ccc2oc3c([Si](c4ccccc4)(c4ccc(-c5ccccc5)cc4)c4cccc(-n5c6ccccc6c6cc(-n7c8ccccc8c8ccccc87)ccc65)c4)cccc3c2c1]

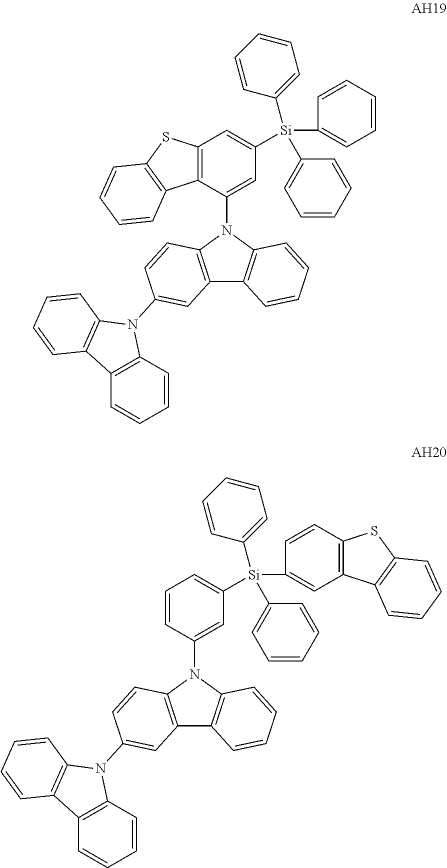 [SMILES: c1ccc([Si](c2ccccc2)(c2ccccc2)c2cc(-n3c4ccccc4c4cc(-n5c6ccccc6c6ccccc65)ccc43)c3c(c2)sc2ccccc23)cc1 ; c1ccc([Si](c2ccccc2)(c2cccc(-n3c4ccccc4c4cc(-n5c6ccccc6c6ccccc65)ccc43)c2)c2ccc3sc4ccccc4c3c2)cc1]

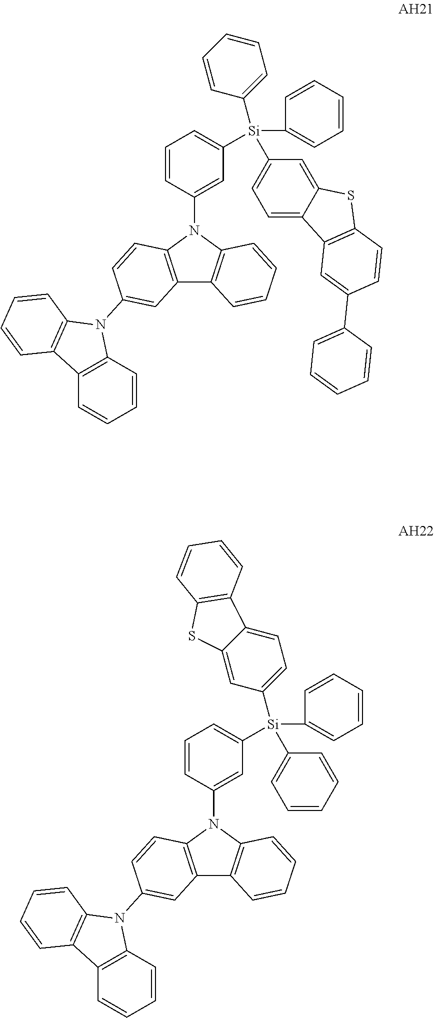 [SMILES: c1ccc(-c2ccc3sc4cc([Si](c5ccccc5)(c5ccccc5)c5cccc(-n6c7ccccc7c7cc(-n8c9ccccc9c9ccccc98)ccc76)c5)ccc4c3c2)cc1 ; c1ccc([Si](c2ccccc2)(c2cccc(-n3c4ccccc4c4cc(-n5c6ccccc6c6ccccc65)ccc43)c2)c2ccc3c(c2)sc2ccccc23)cc1]

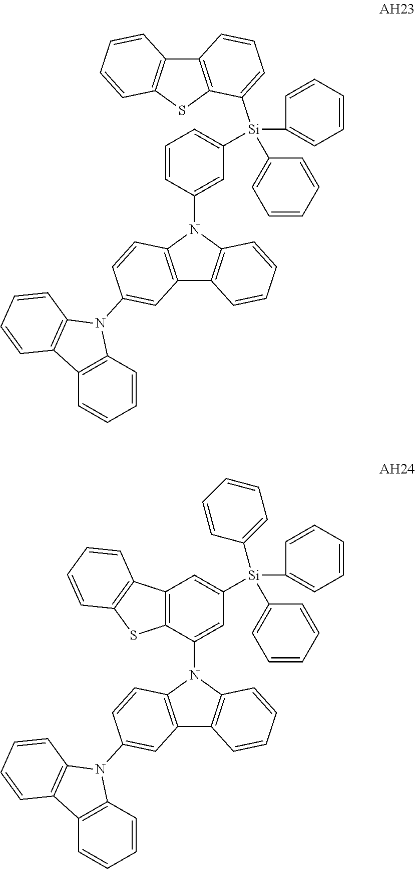 [SMILES: c1ccc([Si](c2ccccc2)(c2cccc(-n3c4ccccc4c4cc(-n5c6ccccc6c6ccccc65)ccc43)c2)c2cccc3c2sc2ccccc23)cc1 ; c1ccc([Si](c2ccccc2)(c2ccccc2)c2cc(-n3c4ccccc4c4cc(-n5c6ccccc6c6ccccc65)ccc43)c3sc4ccccc4c3c2)cc1]

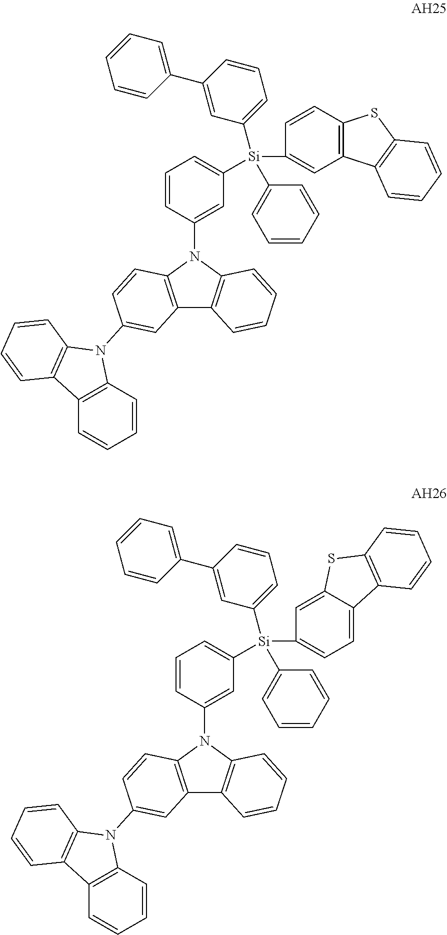 [SMILES: c1ccc(-c2cccc([Si](c3ccccc3)(c3cccc(-n4c5ccccc5c5cc(-n6c7ccccc7c7ccccc76)ccc54)c3)c3ccc4sc5ccccc5c4c3)c2)cc1 ; c1ccc(-c2cccc([Si](c3ccccc3)(c3cccc(-n4c5ccccc5c5cc(-n6c7ccccc7c7ccccc76)ccc54)c3)c3ccc4c(c3)sc3ccccc34)c2)cc1]

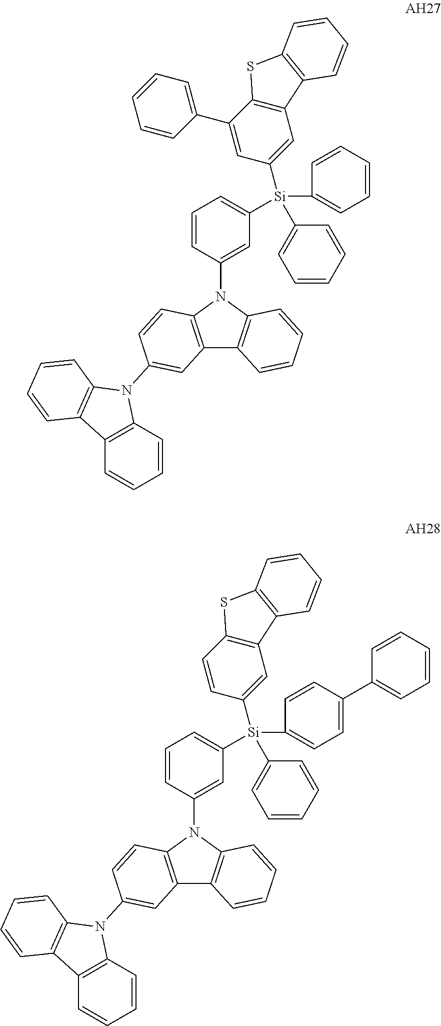 [SMILES: c1ccc(-c2cc([Si](c3ccccc3)(c3ccccc3)c3cccc(-n4c5ccccc5c5cc(-n6c7ccccc7c7ccccc76)ccc54)c3)cc3c2sc2ccccc23)cc1 ; c1ccc(-c2ccc([Si](c3ccccc3)(c3cccc(-n4c5ccccc5c5cc(-n6c7ccccc7c7ccccc76)ccc54)c3)c3ccc4sc5ccccc5c4c3)cc2)cc1]

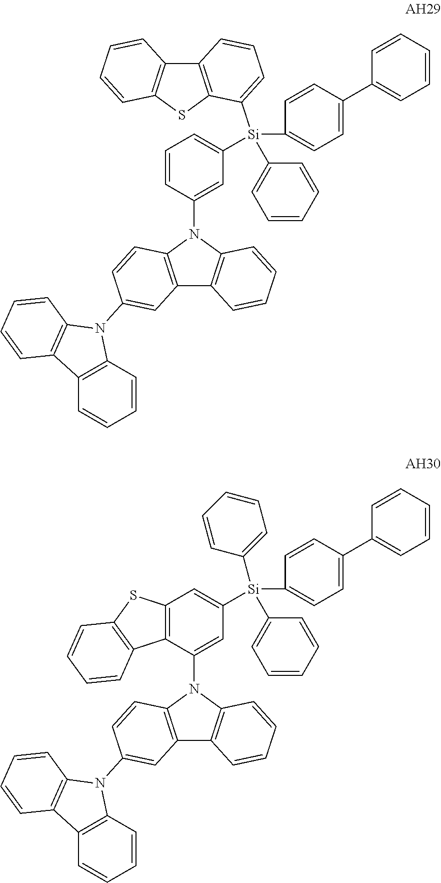 [SMILES: c1ccc(-c2ccc([Si](c3ccccc3)(c3cccc(-n4c5ccccc5c5cc(-n6c7ccccc7c7ccccc76)ccc54)c3)c3cccc4c3sc3ccccc34)cc2)cc1 ; c1ccc(-c2ccc([Si](c3ccccc3)(c3ccccc3)c3cc(-n4c5ccccc5c5cc(-n6c7ccccc7c7ccccc76)ccc54)c4c(c3)sc3ccccc34)cc2)cc1]

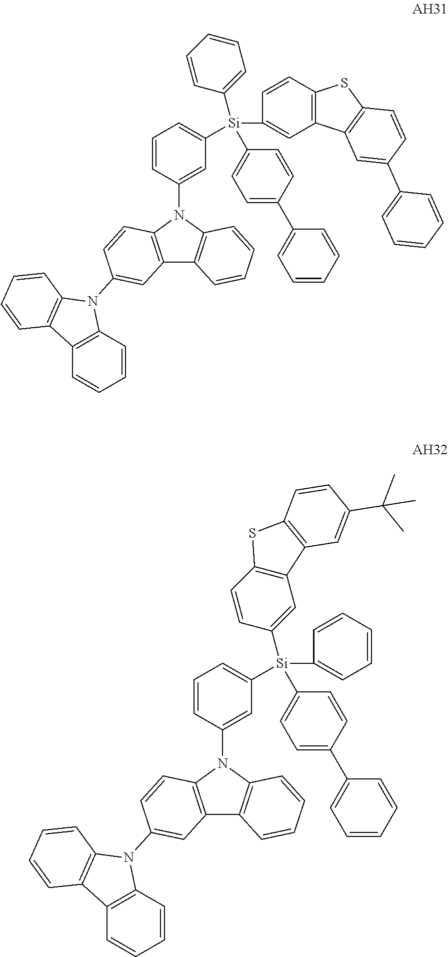 [SMILES: c1ccc(-c2ccc([Si](c3ccccc3)(c3cccc(-n4c5ccccc5c5cc(-n6c7ccccc7c7ccccc76)ccc54)c3)c3ccc4sc5ccc(-c6ccccc6)cc5c4c3)cc2)cc1 ; CC(C)(C)c1ccc2sc3ccc([Si](c4ccccc4)(c4ccc(-c5ccccc5)cc4)c4cccc(-n5c6ccccc6c6cc(-n7c8ccccc8c8ccccc87)ccc65)c4)cc3c2c1]

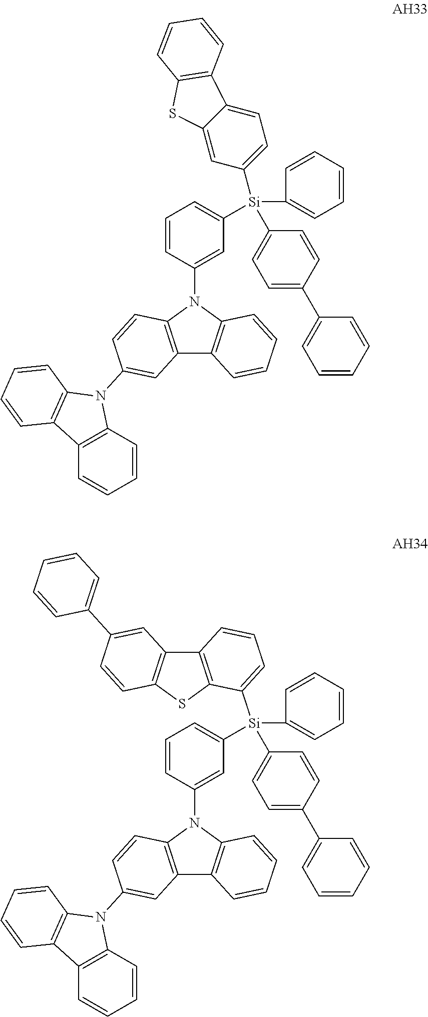 [SMILES: c1ccc(-c2ccc([Si](c3ccccc3)(c3cccc(-n4c5ccccc5c5cc(-n6c7ccccc7c7ccccc76)ccc54)c3)c3ccc4c(c3)sc3ccccc34)cc2)cc1 ; c1ccc(-c2ccc([Si](c3ccccc3)(c3cccc(-n4c5ccccc5c5cc(-n6c7ccccc7c7ccccc76)ccc54)c3)c3cccc4c3sc3ccc(-c5ccccc5)cc34)cc2)cc1]

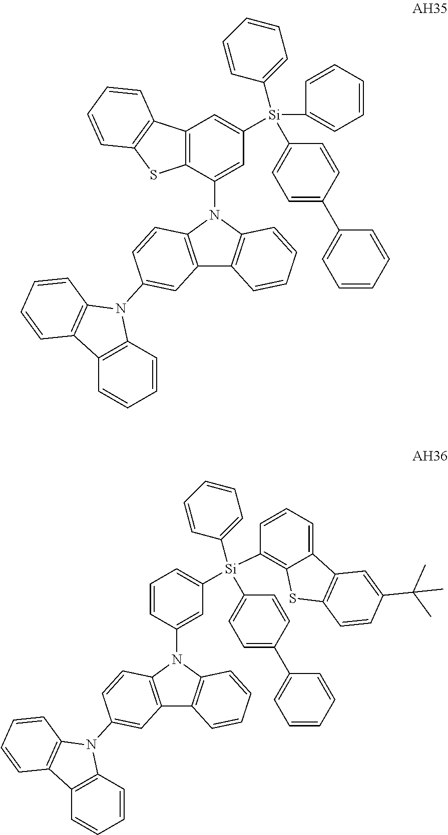 [SMILES: c1ccc(-c2ccc([Si](c3ccccc3)(c3ccccc3)c3cc(-n4c5ccccc5c5cc(-n6c7ccccc7c7ccccc76)ccc54)c4sc5ccccc5c4c3)cc2)cc1 ; CC(C)(C)c1ccc2sc3c([Si](c4ccccc4)(c4ccc(-c5ccccc5)cc4)c4cccc(-n5c6ccccc6c6cc(-n7c8ccccc8c8ccccc87)ccc65)c4)cccc3c2c1]

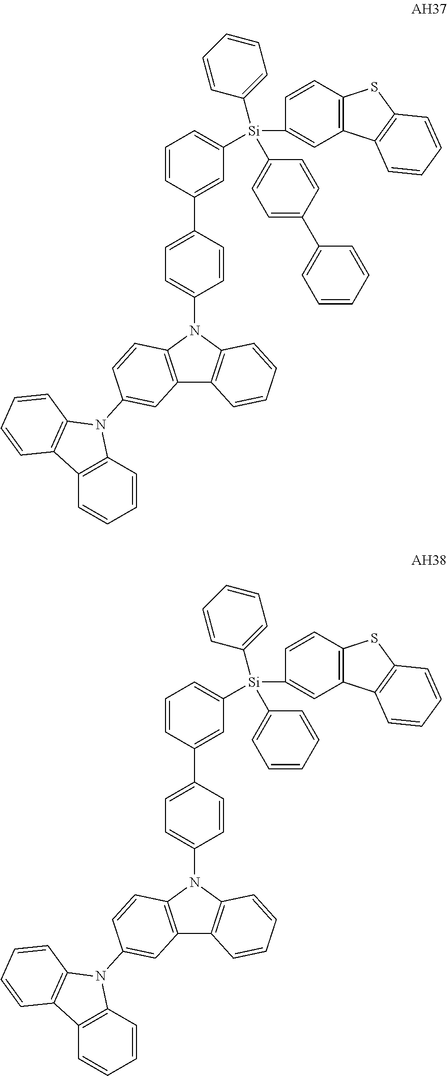 [SMILES: c1ccc(-c2ccc([Si](c3ccccc3)(c3cccc(-c4ccc(-n5c6ccccc6c6cc(-n7c8ccccc8c8ccccc87)ccc65)cc4)c3)c3ccc4sc5ccccc5c4c3)cc2)cc1 ; c1ccc([Si](c2ccccc2)(c2cccc(-c3ccc(-n4c5ccccc5c5cc(-n6c7ccccc7c7ccccc76)ccc54)cc3)c2)c2ccc3sc4ccccc4c3c2)cc1]

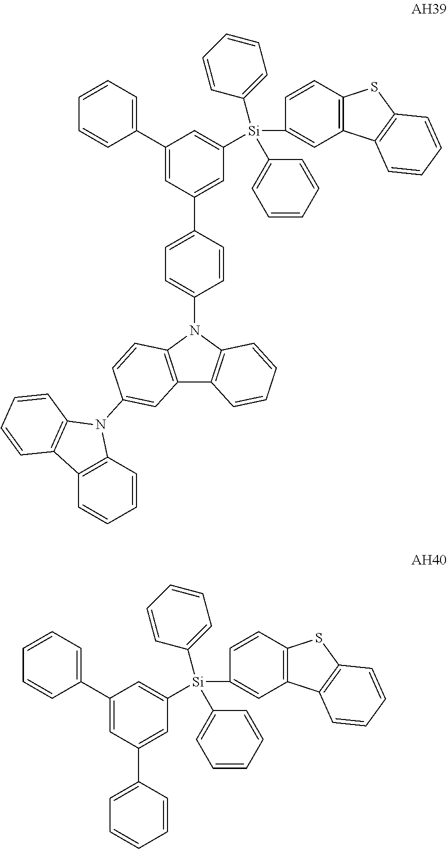 [SMILES: c1ccc(-c2cc(-c3ccc(-n4c5ccccc5c5cc(-n6c7ccccc7c7ccccc76)ccc54)cc3)cc([Si](c3ccccc3)(c3ccccc3)c3ccc4sc5ccccc5c4c3)c2)cc1 ; c1ccc(-c2cc(-c3ccccc3)cc([Si](c3ccccc3)(c3ccccc3)c3ccc4sc5ccccc5c4c3)c2)cc1]

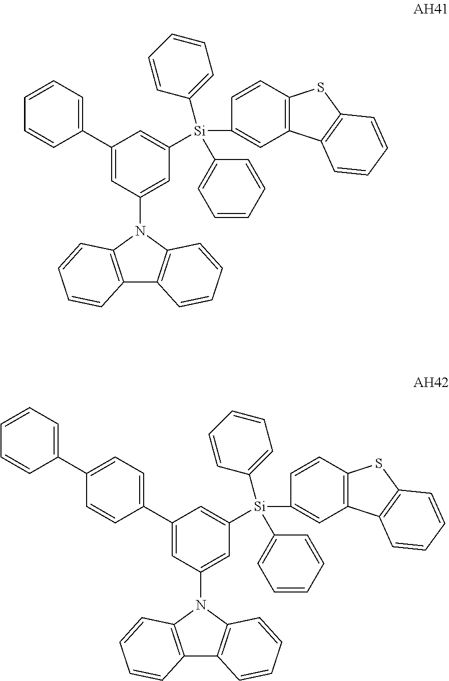 [SMILES: c1ccc(-c2cc(-n3c4ccccc4c4ccccc43)cc([Si](c3ccccc3)(c3ccccc3)c3ccc4sc5ccccc5c4c3)c2)cc1 ; c1ccc(-c2ccc(-c3cc(-n4c5ccccc5c5ccccc54)cc([Si](c4ccccc4)(c4ccccc4)c4ccc5sc6ccccc6c5c4)c3)cc2)cc1]

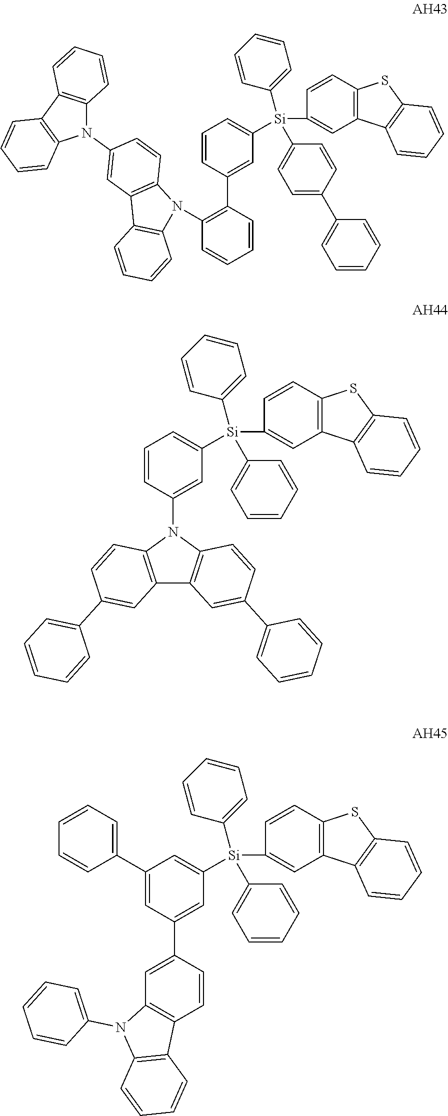 [SMILES: c1ccc(-c2ccc([Si](c3ccccc3)(c3cccc(-c4ccccc4-n4c5ccccc5c5cc(-n6c7ccccc7c7ccccc76)ccc54)c3)c3ccc4sc5ccccc5c4c3)cc2)cc1 ; c1ccc(-c2ccc3c(c2)c2cc(-c4ccccc4)ccc2n3-c2cccc([Si](c3ccccc3)(c3ccccc3)c3ccc4sc5ccccc5c4c3)c2)cc1 ; c1ccc(-c2cc(-c3ccc4c5ccccc5n(-c5ccccc5)c4c3)cc([Si](c3ccccc3)(c3ccccc3)c3ccc4sc5ccccc5c4c3)c2)cc1]

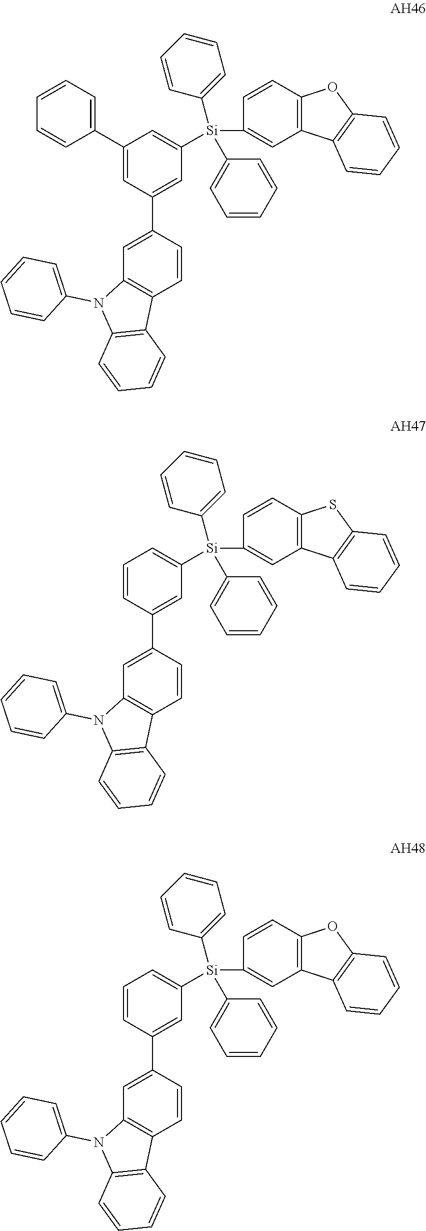 [SMILES: c1ccc(-c2cc(-c3ccc4c5ccccc5n(-c5ccccc5)c4c3)cc([Si](c3ccccc3)(c3ccccc3)c3ccc4oc5ccccc5c4c3)c2)cc1 ; c1ccc(-n2c3ccccc3c3ccc(-c4cccc([Si](c5ccccc5)(c5ccccc5)c5ccc6sc7ccccc7c6c5)c4)cc32)cc1 ; c1ccc(-n2c3ccccc3c3ccc(-c4cccc([Si](c5ccccc5)(c5ccccc5)c5ccc6oc7ccccc7c6c5)c4)cc32)cc1]

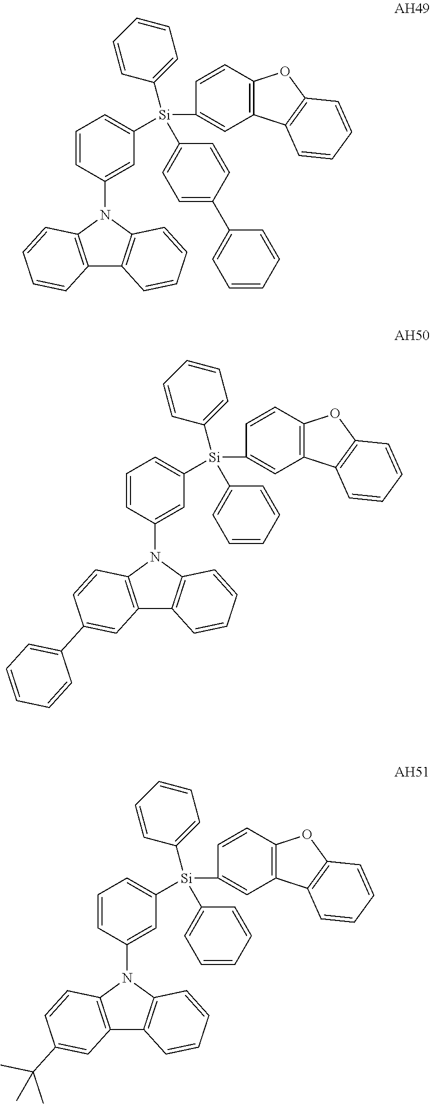 [SMILES: c1ccc(-c2ccc([Si](c3ccccc3)(c3cccc(-n4c5ccccc5c5ccccc54)c3)c3ccc4oc5ccccc5c4c3)cc2)cc1 ; c1ccc(-c2ccc3c(c2)c2ccccc2n3-c2cccc([Si](c3ccccc3)(c3ccccc3)c3ccc4oc5ccccc5c4c3)c2)cc1 ; CC(C)(C)c1ccc2c(c1)c1ccccc1n2-c1cccc([Si](c2ccccc2)(c2ccccc2)c2ccc3oc4ccccc4c3c2)c1]

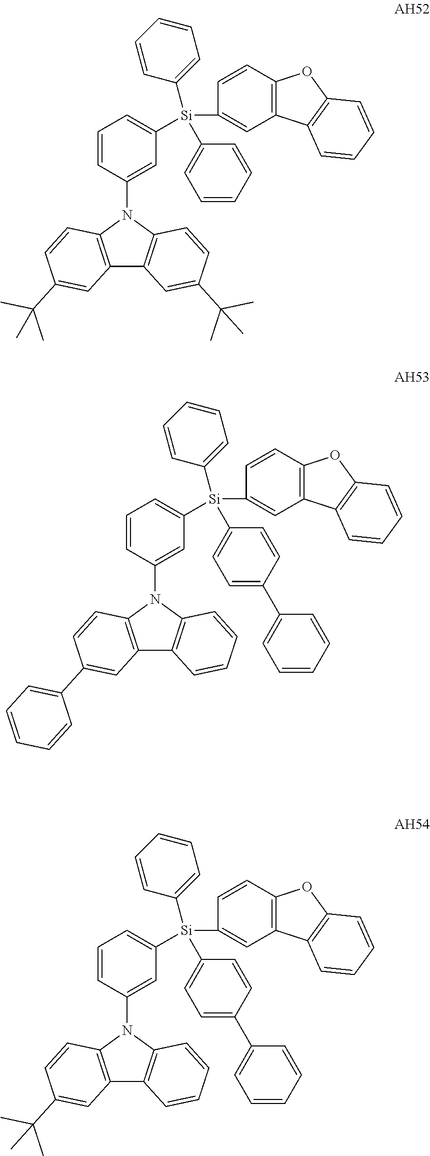 [SMILES: CC(C)(C)c1ccc2c(c1)c1cc(C(C)(C)C)ccc1n2-c1cccc([Si](c2ccccc2)(c2ccccc2)c2ccc3oc4ccccc4c3c2)c1 ; c1ccc(-c2ccc([Si](c3ccccc3)(c3cccc(-n4c5ccccc5c5cc(-c6ccccc6)ccc54)c3)c3ccc4oc5ccccc5c4c3)cc2)cc1 ; CC(C)(C)c1ccc2c(c1)c1ccccc1n2-c1cccc([Si](c2ccccc2)(c2ccc(-c3ccccc3)cc2)c2ccc3oc4ccccc4c3c2)c1]

The first compound represented by Formula 1 according to an embodiment has a structure which includes a silicon atom and first to fourth benzene rings substituted at the silicon atom, and in which a first substituent is introduced to a specific position of the first benzene ring and a fifth benzene ring is fused via an oxygen atom or a sulfur atom to at least one benzene ring among the first to fourth benzene rings, and thus may have excellent or suitable hole transport characteristics and a high triplet energy level. Therefore, when the first compound of an embodiment is applied to at least one among a plurality of functional layers included in the light emitting device ED, high luminous efficiency may be achieved.

The first compound of an embodiment may have a high triplet energy level (T1 level). In an embodiment, the first compound represented by Formula 1 may have a triplet energy level of about 2.9 eV or more. For example, the first compound may have a triplet energy level of about 2.9 eV to about 3.25 eV. When the triplet energy level of the first compound satisfies the above range, the excitons in the emission layer EML of the light emitting device ED may be trapped effectively. For example, the first compound represented by Formula 1 exhibits relatively high triplet energy level, and thus the excitons may be effectively captured in the light emitting device ED. Accordingly, a charge balance in the light emitting device ED of an embodiment is improved and thus high efficiency may be achieved.

In an embodiment, the second compound may be represented by Formula 2: At least any one functional layer among the plurality of functional layers of a light emitting device ED may include a second compound represented by Formula 2. For example, the second compound may be utilized as an electron transport host material for the emission layer EML.

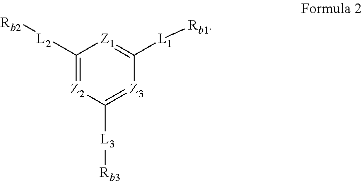

In Formula 2, at least one among Z₁ to Z₃ is N, and any remainder thereof are each independently CR_{b4}. For example, any one among Z₁ to Z₃ may be N, and the rest may be CR_{b4}. In this case, the second compound represented by Formula 2 may include a pyridine moiety. In some embodiments, two among Z₁ to Z₃ may be N, and the rest may be CR_{b4}. In this case, the second compound represented by Formula 2 may include a pyrimidine moiety. In some embodiments, Z₁ to Z₃ may all be N. In this case, the second compound represented by Formula 2 may include a triazine moiety.

In Formula 2, R_{b1} to R_{b3} may each independently be a hydrogen atom, a deuterium atom, a halogen atom, a substituted or unsubstituted silyl group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula 2, R_{b4} is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 2, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

In an embodiment, the second compound represented by Formula 2 may be represented by any one among Formula 2-1-1 to Formula 2-1-3:

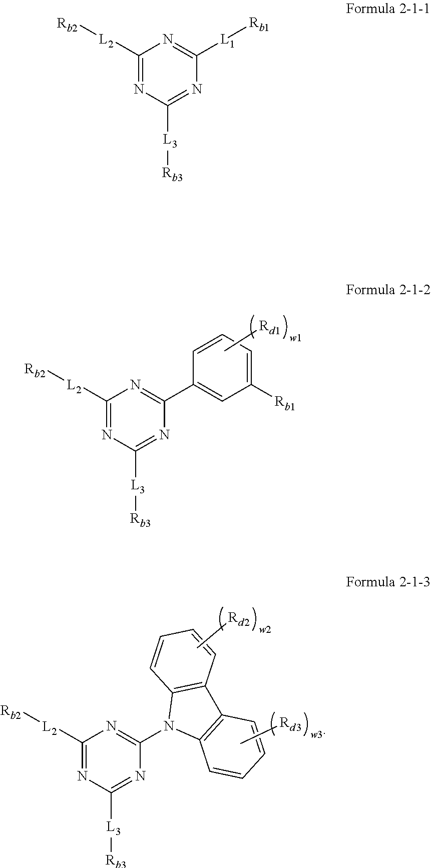

In Formula 2-1-1 to Formula 2-1-3, R_{d1} to R_{d3} may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{d1} to R_{d3} may each independently be a hydrogen atom.

In Formula 2-1-2 and Formula 2-1-3, w1 to w3 may each independently be an integer of 0 to 4. In Formula 2-1-2 and Formula 2-1-3, when each of w1 to w3 is 0, the second compound of an embodiment may not be substituted with each of R_{d1} to R_{d3}. In Formula 2-1-2 and Formula 2-1-3, the case where each of w1 to w3 is 4 and R_{d1}'s to R_{d3}'s are each hydrogen atoms may be the same as the case where each of w1 to w3 is 0 in Formula 2-1-2 and Formula 2-1-3. When each of w1 to w3 is an integer of 2 or greater, a plurality of R_{d1}'s and R_{d3}'s may each be the same or at least one among the plurality of R_{d1}'s and R_{d3}'s may be different from the others.

In Formula 2-1-1 to Formula 2-1-3, the same as described in Formula 2 above may be applied to R_{b1} to R_{b3}, and L₁ to L₃.

In an embodiment, the second compound may be represented by any one among compounds in Compound Group 2. The light emitting device ED of an embodiment may include any one among the compounds in Compound Group 2. Any one among the compounds in Compound Group 2 may be utilized in at least any one functional layer among the plurality of functional layers of the light emitting device ED of an embodiment. For example, the emission layer EML may include at least one from among the compounds represented by Compound Group 1 as an electron transporting host material.

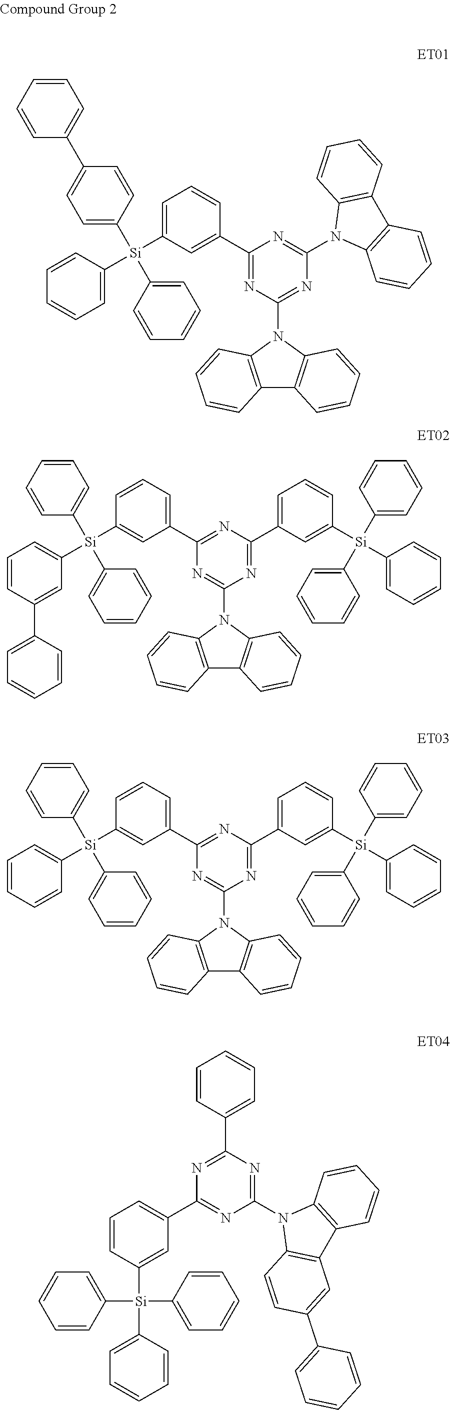 [SMILES: c1ccc(-c2ccc([Si](c3ccccc3)(c3ccccc3)c3cccc(-c4nc(-n5c6ccccc6c6ccccc65)nc(-n5c6ccccc6c6ccccc65)n4)c3)cc2)cc1 ; c1ccc(-c2cccc([Si](c3ccccc3)(c3ccccc3)c3cccc(-c4nc(-c5cccc([Si](c6ccccc6)(c6ccccc6)c6ccccc6)c5)nc(-n5c6ccccc6c6ccccc65)n4)c3)c2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc(-c2ccc3c(c2)c2ccccc2n3-c2nc(-c3ccccc3)nc(-c3cccc([Si](c4ccccc4)(c4ccccc4)c4ccccc4)c3)n2)cc1]

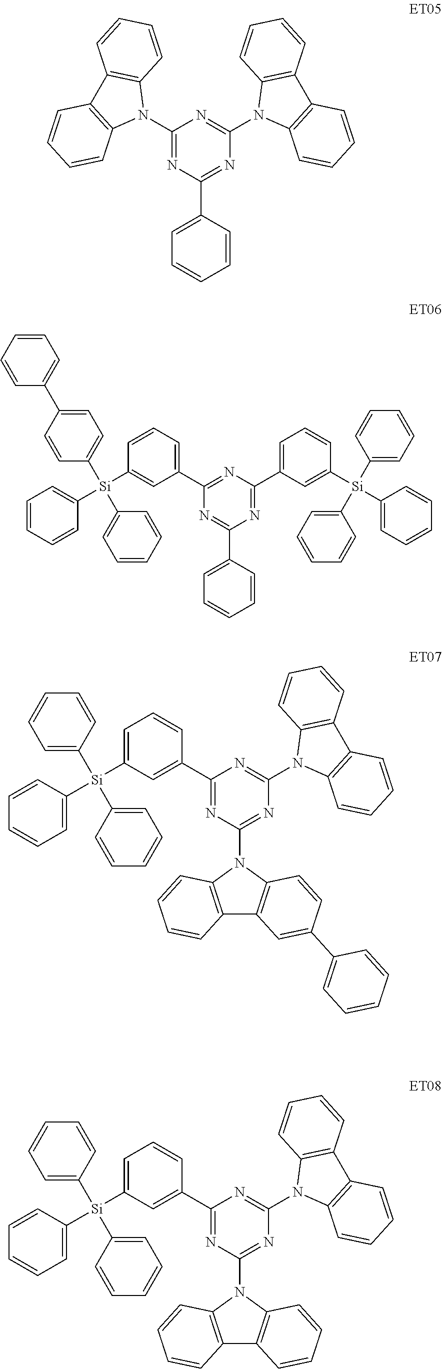 [SMILES: c1ccc(-c2nc(-n3c4ccccc4c4ccccc43)nc(-n3c4ccccc4c4ccccc43)n2)cc1 ; c1ccc(-c2ccc([Si](c3ccccc3)(c3ccccc3)c3cccc(-c4nc(-c5ccccc5)nc(-c5cccc([Si](c6ccccc6)(c6ccccc6)c6ccccc6)c5)n4)c3)cc2)cc1 ; c1ccc(-c2ccc3c(c2)c2ccccc2n3-c2nc(-c3cccc([Si](c4ccccc4)(c4ccccc4)c4ccccc4)c3)nc(-n3c4ccccc4c4ccccc43)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

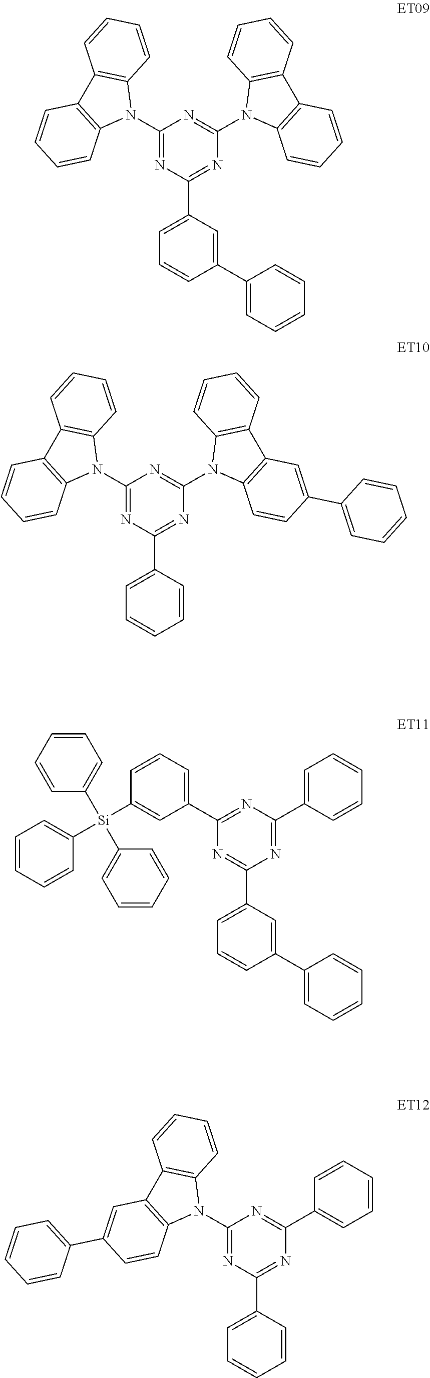 [SMILES: c1ccc(-c2cccc(-c3nc(-n4c5ccccc5c5ccccc54)nc(-n4c5ccccc5c5ccccc54)n3)c2)cc1 ; c1ccc(-c2ccc3c(c2)c2ccccc2n3-c2nc(-c3ccccc3)nc(-n3c4ccccc4c4ccccc43)n2)cc1 ; c1ccc(-c2cccc(-c3nc(-c4ccccc4)nc(-c4cccc([Si](c5ccccc5)(c5ccccc5)c5ccccc5)c4)n3)c2)cc1 ; c1ccc(-c2ccc3c(c2)c2ccccc2n3-c2nc(-c3ccccc3)nc(-c3ccccc3)n2)cc1]

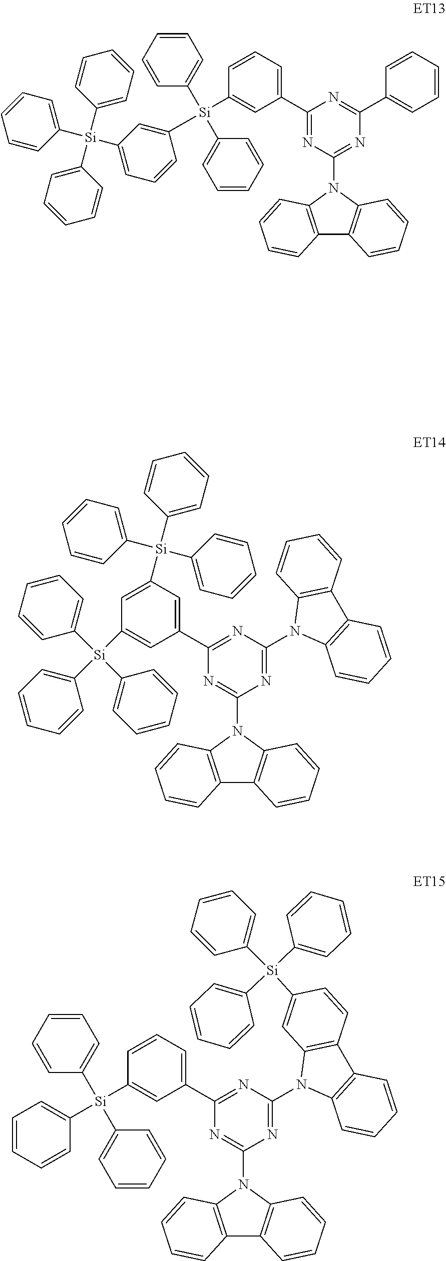 [SMILES: c1ccc(-c2nc(-c3cccc([Si](c4ccccc4)(c4ccccc4)c4cccc([Si](c5ccccc5)(c5ccccc5)c5ccccc5)c4)c3)nc(-n3c4ccccc4c4ccccc43)n2)cc1 ; c1ccc([Si](c2ccccc2)(c2ccccc2)c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1 ; c1ccc([Si](c2ccccc2)(c2ccccc2)c2cccc(-c3nc(-n4c5ccccc5c5ccccc54)nc(-n4c5ccccc5c5ccc([Si](c6ccccc6)(c6ccccc6)c6ccccc6)cc54)n3)c2)cc1]

In an embodiment, the third compound may be represented by Formula 3. At least any one functional layer among the plurality of functional layers of a light emitting device ED may include a third compound represented by Formula 3. For example, the third compound may be a dopant material for the emission layer EML.

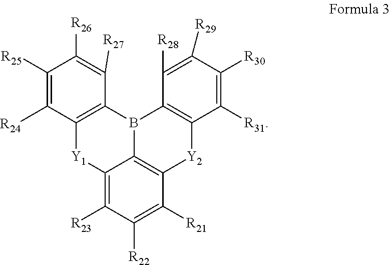

In Formula 3, Y₁ and Y₂ may each independently be NR₃₂ or O. For example, both (e.g., simultaneously) Y₁ and Y₂ may be NR₃₂. In some embodiments, both (e.g., simultaneously) Y₁ and Y₂ may be O.

In Formula 3, R₂₁ to R₃₂ may each independently be a hydrogen atom, a deuterium atom, a halogen atom, a cyano group, a nitro group, a substituted or unsubstituted amine group, a substituted or unsubstituted boron group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₂₁ to R₃₂ may be bonded to an adjacent group to form a ring. For example, R₂₁ to R₃₂ may each independently be a substituted or unsubstituted methyl group, a substituted or unsubstituted t-butyl group, a substituted or unsubstituted phenyl group, a substituted or unsubstituted arylamine group, or a substituted or unsubstituted carbazole group. In some embodiments, for example, R₂₅ and R₂₆, and R₂₉ and R₃₀, which are adjacent groups, may be respectively bonded together via an amine group, a boron group, an oxy group, a thio group, and/or the like to form a ring.

In an embodiment, the third compound represented by Formula 3 may be represented by any one among Formula 3-1-1 to Formula 3-1-3:

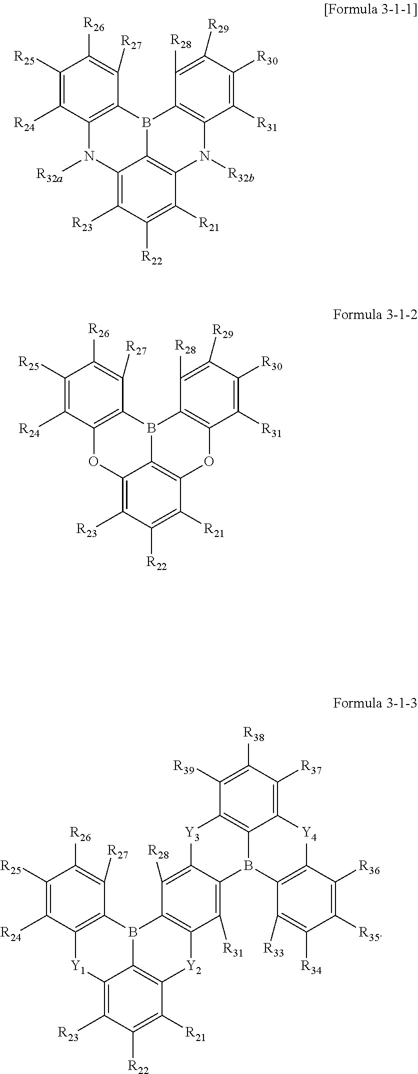

Formula 3-1-1 and Formula 3-1-2 represent the cases where the types (kinds) of Y₁ and Y₂ are specified in Formula 3. Formula 3-1-1 represents the case where bath (e.g., simultaneously) Y₁ and Y₂ are NR₃₂ in Formula 3. Formula 3-1-2 represents the case where bath (e.g., simultaneously) Y₁ and Y₂ are O in Formula 3. Formula 3-1-3 represents the case where R₂₉ and R₃₀ in Formula 3 are bonded together to form an additional ring. Formula 3-1-3 represents a structure in which two benzene rings in Formula 3 are further fused via B, Y₃, and Y₄.

In Formula 3-1-1, R₃₂ₐ and R_{32b} may each independently be a substituted or unsubstituted aryl group having 6 to 30 ring-forming carbon atoms, or a substituted or unsubstituted heteroaryl group having 2 to 30 ring-forming carbon atoms. For example, R₃₂ₐ and R_{32b} may each independently be a substituted or unsubstituted phenyl group.

In Formula 3-1-3, Y₃ and Y₄ may each independently be NR₄₀ or O. For example, both (e.g., simultaneously) Y₃ and Y₄ may be NR₄₀. In some embodiments, both (e.g., simultaneously) Y₃ and Y₄ may be O.

In Formula 3-1-3, R₃₃ to R₄₀ may each independently be a hydrogen atom, a deuterium atom, a halogen atom, a cyano group, a nitro group, a substituted or unsubstituted amine group, a substituted or unsubstituted boron group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₃₃ to R₄₀ may be bonded to an adjacent group to form a ring.

In Formula 3-1-1 to Formula 3-1-3, the same as described in Formula 3 above may be applied to Y₁, Y₂, R₂₁ to R₂₈, and R₃₁.

In an embodiment, the third compound represented by Formula 3 may be represented by Formula 3-2-1:

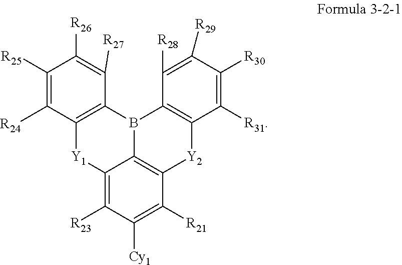

In Formula 3-2-1, Cy₁ may be represented by any one among Formula C-1 to C-3:

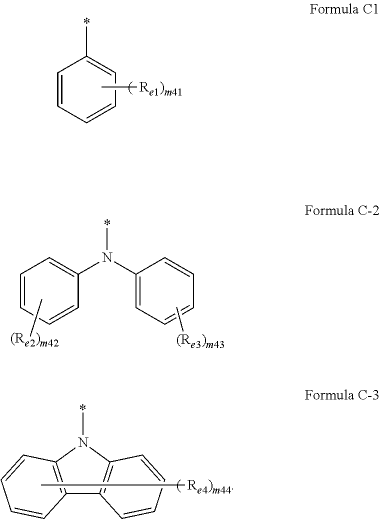

In Formula C-1 to Formula C-3, Rₑ₁ to Rₑ₄ may each independently be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₑ₁ to Rₑ₄ may each independently be a hydrogen atom, or a substituted or unsubstituted methyl group.

In Formula C-1 and Formula C-2, m41 to m43 may each independently be an integer of 0 to 5. When each of m41 to m43 is 0, the third compound of an embodiment may not be substituted with each of Rₑ₁ to Rₑ₃. The case where each of m41 to m43 is 5 and Rₑ₁'s to Rₑ₃'s each are hydrogen atoms may be the same as the case where each of m41 to m43 is 0. When each of m41 to m43 is an integer of 2 or greater, a plurality of Rₑ₁'s to Rₑ₃'s may each be the same or at least one among the plurality of Rₑ₁'s to Rₑ₃'s may be different from the others.

In Formula C-3, m44 is an integer of 0 to 8. In Formula C-3, when m44 is 0, the third compound of an embodiment may not be substituted with Rₑ₄. In Formula C-3, the case where m44 is 8 and Rₑ₄'s are hydrogen atoms may be the same as the case where m44 is 0 in Formula C-3. When m44 is an integer of 2 or greater, a plurality of Rₑ₄'s may be all the same or at least one among the plurality of Rₑ₄'s may be different from the others.

In Formula 3-2-1, the same as defined in Formula 3 above may be applied to Y₁, Y₂, R₂₁, and R₂₃ to R₃₁.

In an embodiment, the third compound may be represented by any one among compounds in Compound Group 3. The light emitting device ED of an embodiment may include any one among the compounds in Compound Group 3. Any one among the compounds in Compound Group 3 may be utilized in at least any one functional layer among the plurality of functional layers of the light emitting device ED of an embodiment. For example, the emission layer EML may include at least one from among the compounds represented by Compound Group 3 as a dopant material.

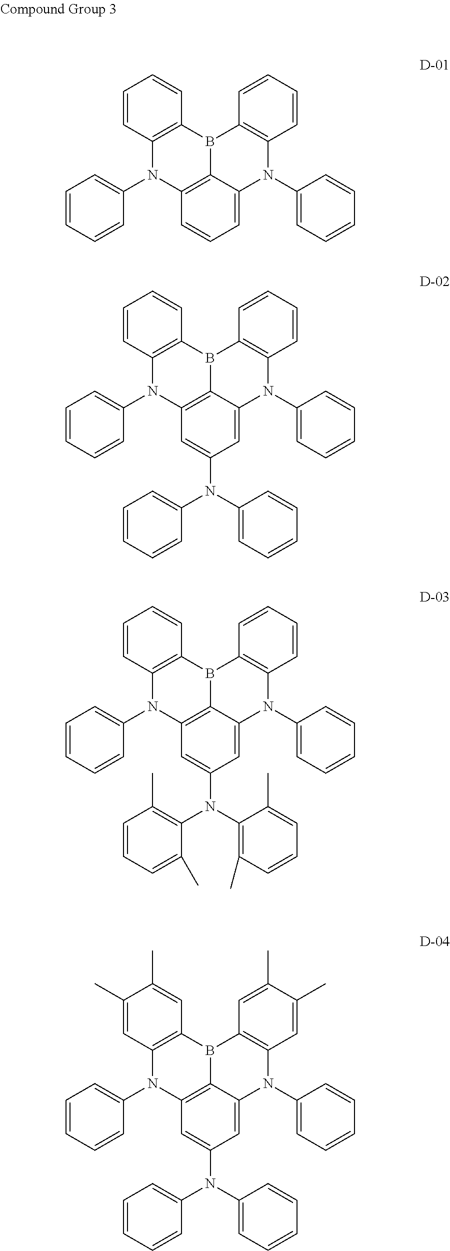 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; Cc1cccc(C)c1N(c1cc2c3c(c1)N(c1ccccc1)c1ccccc1B3c1ccccc1N2c1ccccc1)c1c(C)cccc1C ; Cc1cc2c(cc1C)N(c1ccccc1)c1cc(N(c3ccccc3)c3ccccc3)cc3c1B2c1cc(C)c(C)cc1N3c1ccccc1]

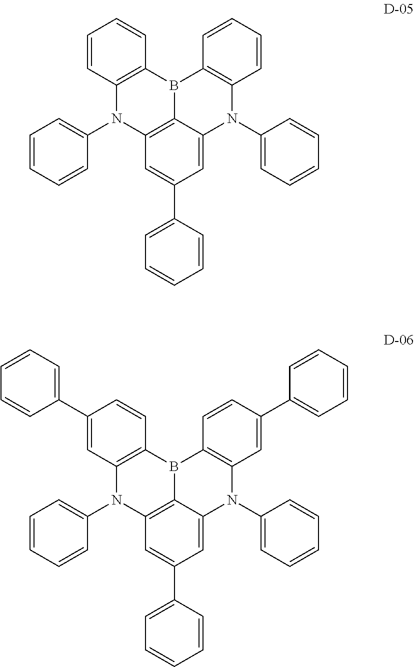 [SMILES: c1ccc(-c2cc3c4c(c2)N(c2ccccc2)c2ccccc2B4c2ccccc2N3c2ccccc2)cc1 ; c1ccc(-c2ccc3c(c2)N(c2ccccc2)c2cc(-c4ccccc4)cc4c2B3c2ccc(-c3ccccc3)cc2N4c2ccccc2)cc1]

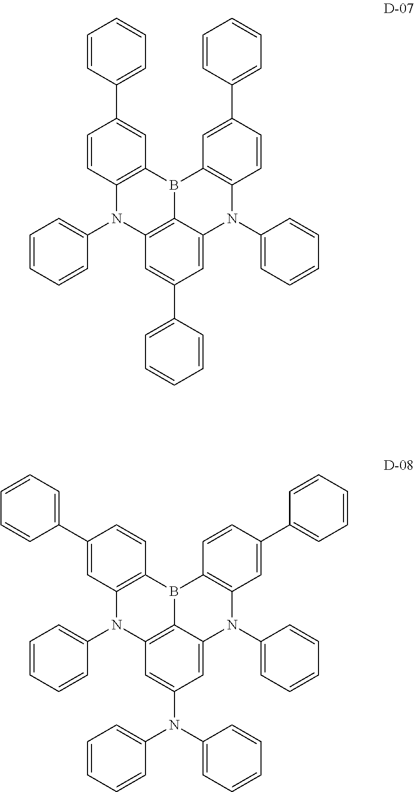 [SMILES: c1ccc(-c2ccc3c(c2)B2c4cc(-c5ccccc5)ccc4N(c4ccccc4)c4cc(-c5ccccc5)cc(c42)N3c2ccccc2)cc1 ; c1ccc(-c2ccc3c(c2)N(c2ccccc2)c2cc(N(c4ccccc4)c4ccccc4)cc4c2B3c2ccc(-c3ccccc3)cc2N4c2ccccc2)cc1]

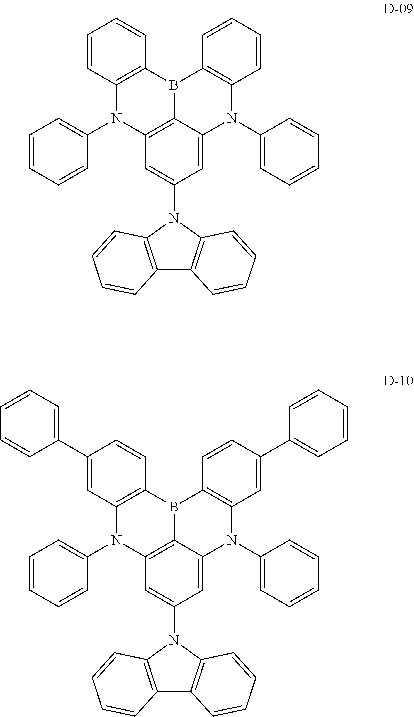 [SMILES: c1ccc(N2c3ccccc3B3c4ccccc4N(c4ccccc4)c4cc(-n5c6ccccc6c6ccccc65)cc2c43)cc1 ; c1ccc(-c2ccc3c(c2)N(c2ccccc2)c2cc(-n4c5ccccc5c5ccccc54)cc4c2B3c2ccc(-c3ccccc3)cc2N4c2ccccc2)cc1]

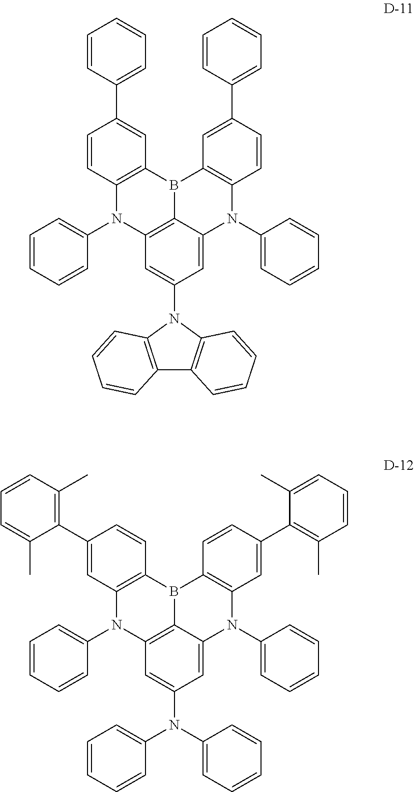 [SMILES: c1ccc(-c2ccc3c(c2)B2c4cc(-c5ccccc5)ccc4N(c4ccccc4)c4cc(-n5c6ccccc6c6ccccc65)cc(c42)N3c2ccccc2)cc1 ; Cc1cccc(C)c1-c1ccc2c(c1)N(c1ccccc1)c1cc(N(c3ccccc3)c3ccccc3)cc3c1B2c1ccc(-c2c(C)cccc2C)cc1N3c1ccccc1]

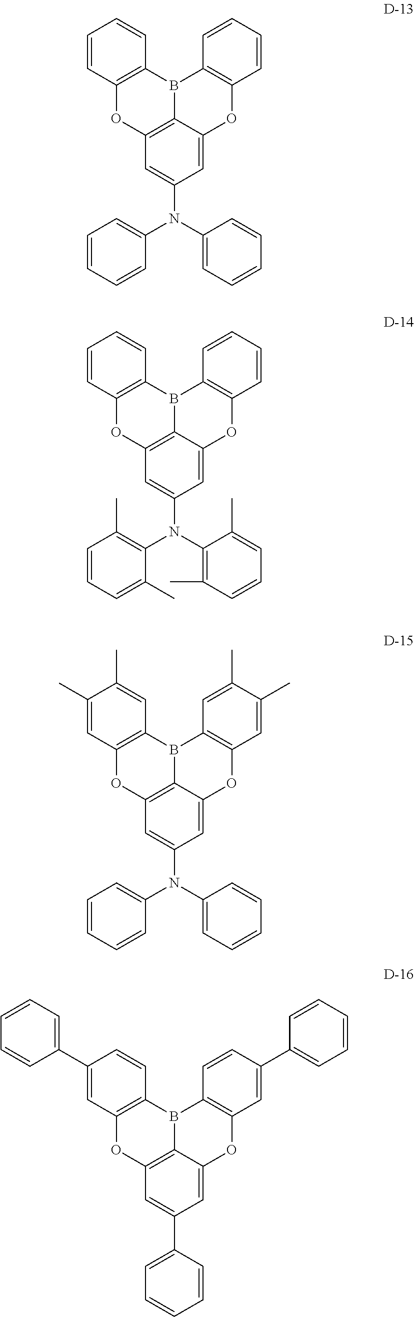

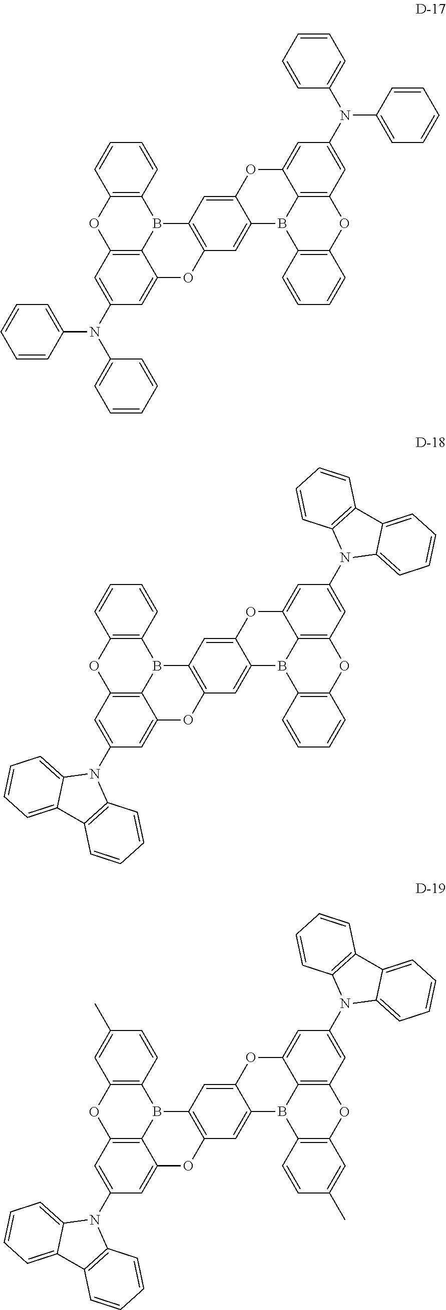 [SMILES: c1ccc(N(c2ccccc2)c2cc3c4c(c2)Oc2cc5c(cc2B4c2ccccc2O3)Oc2cc(N(c3ccccc3)c3ccccc3)cc3c2B5c2ccccc2O3)cc1 ; c1ccc2c(c1)Oc1cc(-n3c4ccccc4c4ccccc43)cc3c1B2c1cc2c(cc1O3)B1c3ccccc3Oc3cc(-n4c5ccccc5c5ccccc54)cc(c31)O2 ; Cc1ccc2c(c1)Oc1cc(-n3c4ccccc4c4ccccc43)cc3c1B2c1cc2c(cc1O3)B1c3ccc(C)cc3Oc3cc(-n4c5ccccc5c5ccccc54)cc(c31)O2]

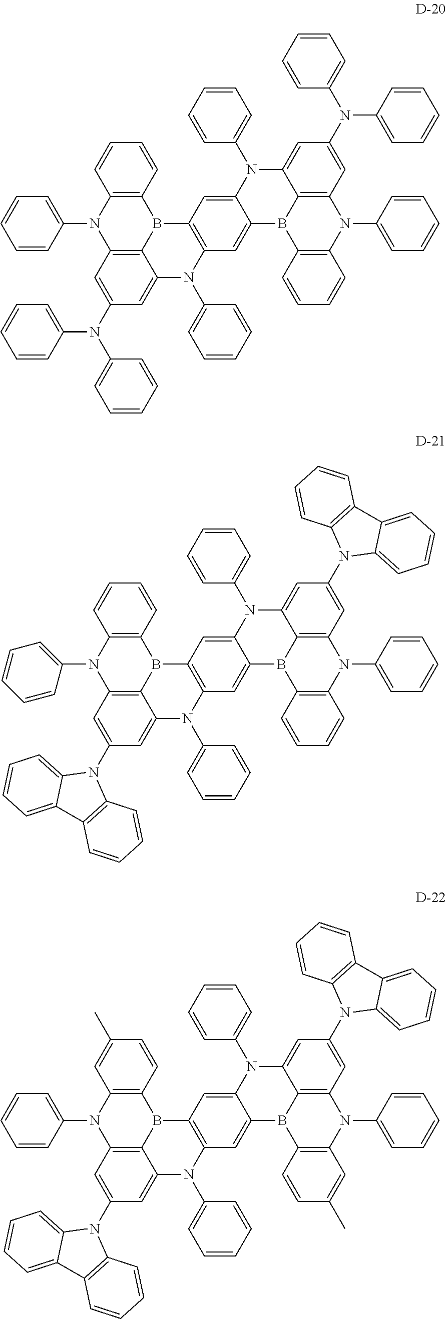 [SMILES: c1ccc(N(c2ccccc2)c2cc3c4c(c2)N(c2ccccc2)c2cc5c(cc2B4c2ccccc2N3c2ccccc2)N(c2ccccc2)c2cc(N(c3ccccc3)c3ccccc3)cc3c2B5c2ccccc2N3c2ccccc2)cc1 ; c1ccc(N2c3ccccc3B3c4cc5c(cc4N(c4ccccc4)c4cc(-n6c7ccccc7c7ccccc76)cc2c43)B2c3ccccc3N(c3ccccc3)c3cc(-n4c6ccccc6c6ccccc64)cc(c32)N5c2ccccc2)cc1 ; Cc1ccc2c(c1)N(c1ccccc1)c1cc(-n3c4ccccc4c4ccccc43)cc3c1B2c1cc2c(cc1N3c1ccccc1)B1c3ccc(C)cc3N(c3ccccc3)c3cc(-n4c5ccccc5c5ccccc54)cc(c31)N2c1ccccc1]

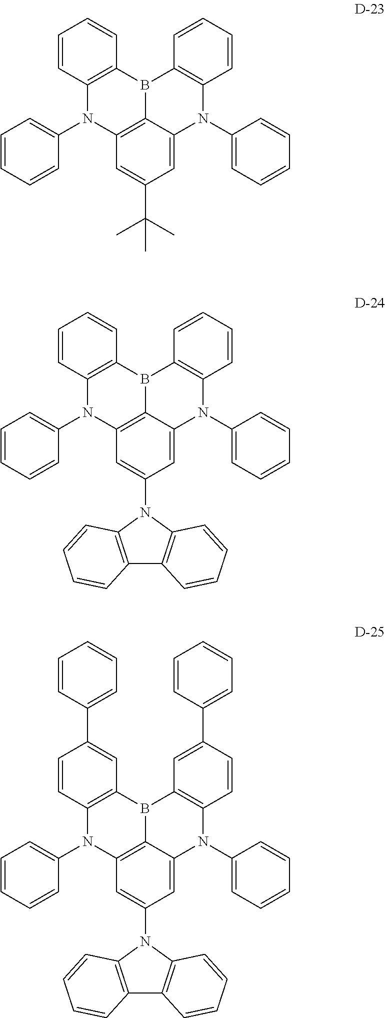 [SMILES: CC(C)(C)c1cc2c3c(c1)N(c1ccccc1)c1ccccc1B3c1ccccc1N2c1ccccc1 ; c1ccc(N2c3ccccc3B3c4ccccc4N(c4ccccc4)c4cc(-n5c6ccccc6c6ccccc65)cc2c43)cc1 ; c1ccc(-c2ccc3c(c2)B2c4cc(-c5ccccc5)ccc4N(c4ccccc4)c4cc(-n5c6ccccc6c6ccccc65)cc(c42)N3c2ccccc2)cc1]

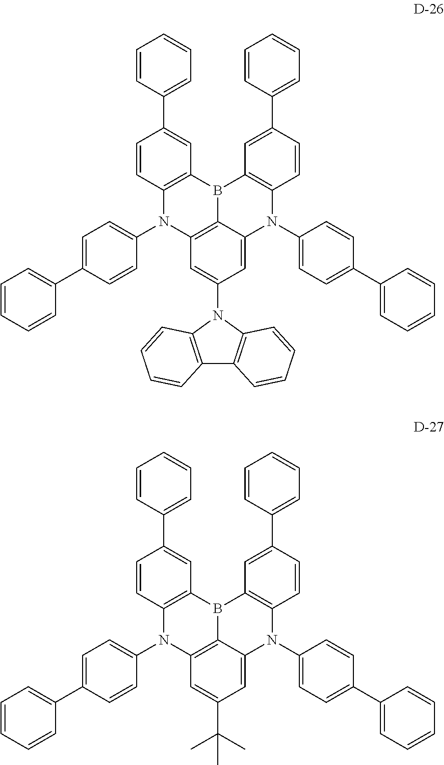 [SMILES: c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1 ; CC(C)(C)c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1]

In an embodiment, at least any one functional layer among the plurality of functional layers included in the light emitting device ED may include a fourth compound represented by Formula 4. For example, at least any one layer among the hole transport region HTR, the emission layer EML, and the electron transport region ETR may further include the fourth compound in addition to the first compound, the second compound, and the third compound. In an embodiment, the emission layer EML may include the fourth compound in addition to the first compound to the third compound as described above.

The fourth compound may contain platinum (Pt) as a central metal atom, and may be an organometallic complex containing ligands bonded to the central metal atom. In an embodiment, the fourth compound may be represented by Formula 4:

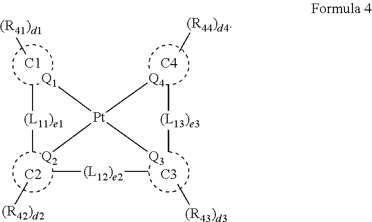

In Formula 4, Q₁ to Q₄ may each independently be C or N.

In Formula 4, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula 4, L₁₁ to L₁₃ may each independently be a direct linkage,

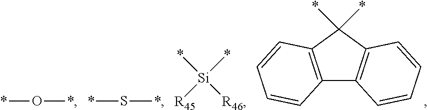

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “^{—}*” refers to a part linked to C1 to C4.

In Formula 4, e1 to e3 may each independently be 0 or 1. When e1 is 0, C1 and C2 may not be linked to each other. When e2 is 0, C2 and C3 may not be linked to each other. When e3 is 0, C3 and C4 may not be linked to each other.

In Formula 4, R₄₁ to R₄₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₄₁ to R₄₆ may be bonded to an adjacent group to form a ring. For example, R₄₁ to R₄₆ may each independently be a hydrogen atom, a substituted or unsubstituted methyl group, or a substituted or unsubstituted t-butyl group.

In Formula 4, d1 to d4 may each independently be an integer of 0 to 4. In Formula 4, when each of d1 to d4 is 0, the fourth compound may not be substituted with each of R₄₁ to R₄₄. The case where each of d1 to d4 is 4 and R₄₁'s to R₄₄′ are each hydrogen atoms may be the same as the case where each of d1 to d4 is 0. When each of d1 to d4 is an integer of 2 or more, a plurality of R₄₁'s to R₄₄'s may each be the same or at least one among the plurality of R₄₁'s to R₄₄'s may be different from the others.

In Formula 4, C1 to C4 may each independently be a substituted or unsubstituted hydrocarbon ring or a substituted or unsubstituted heterocycle represented by any one among D-1 to D-4:

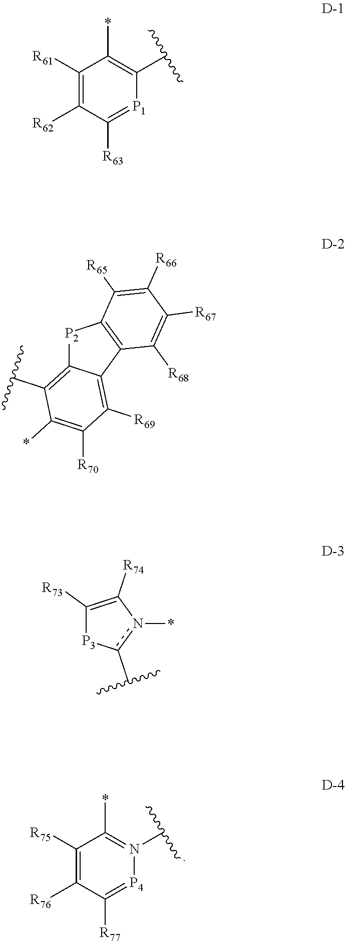

In D-1 to D-4, P₁ may be C^{—}* or CR₆₄, P₂ may be N^{—}* or NR₇₁, P₃ may be N^{—}* or NR₇₂, and P₄ may be C^{—}* or CR₇₈. R₆₁ to R₇₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In some embodiments, in D-1 to D-4,

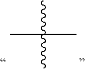

corresponds to a part linked to Pt that is a central metal atom, and “^{—}*” corresponds to a part linked to a neighboring cyclic group (C1 to C4) or a linker (L₁₁ to L₁₃).

In an embodiment, the fourth compound represented by Formula 4 may be represented by at least one among the compounds represented by Compound Group 4. The light emitting device ED of an embodiment may include any one among the compounds in Compound Group 4. Any one among the compounds in Compound Group 4 may be utilized in at least any one functional layer among the plurality of functional layers of the light emitting device ED of an embodiment. For example, the emission layer EML may include at least one from among the compounds represented by Compound Group 4 as a sensitizer material.

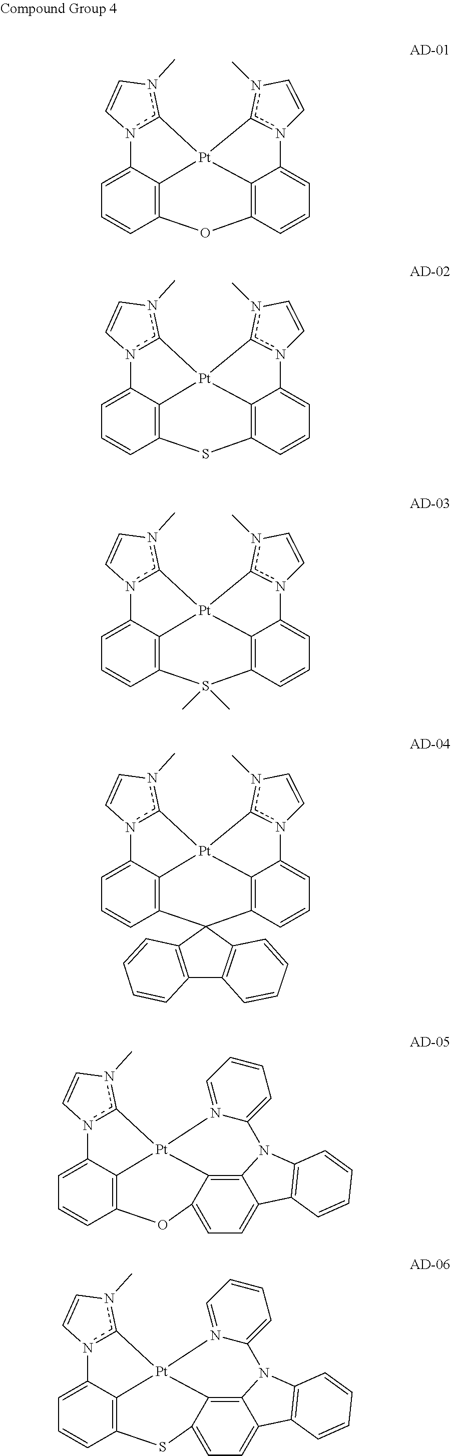

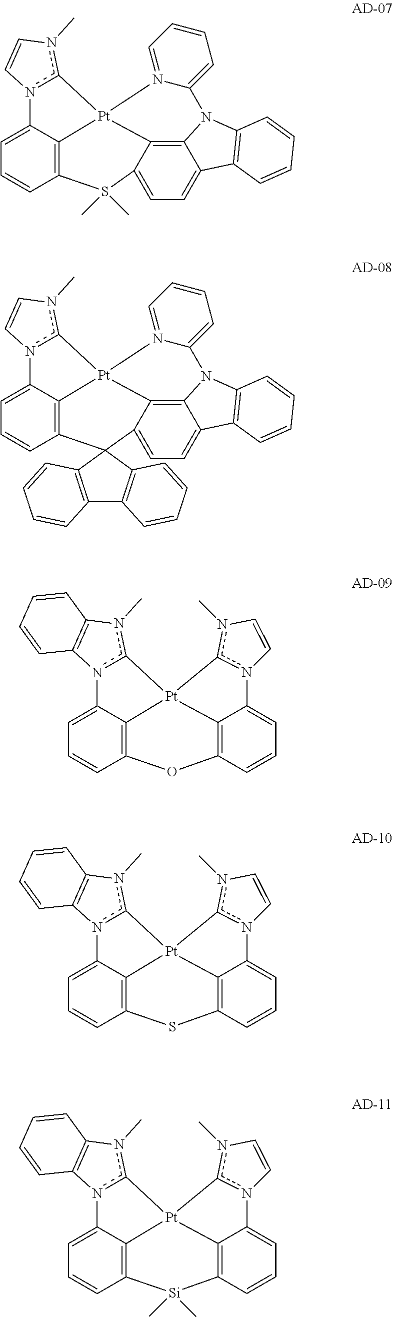

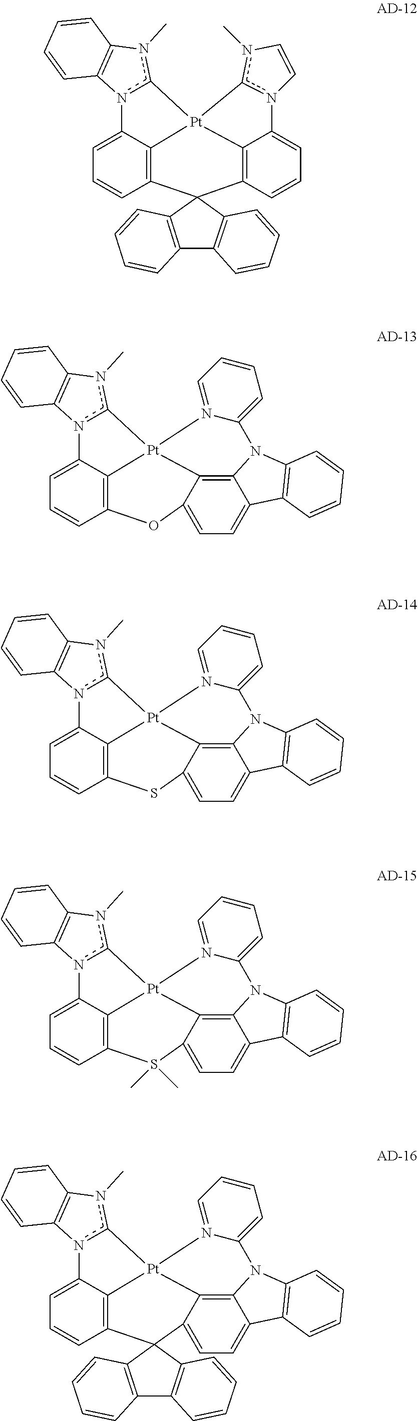

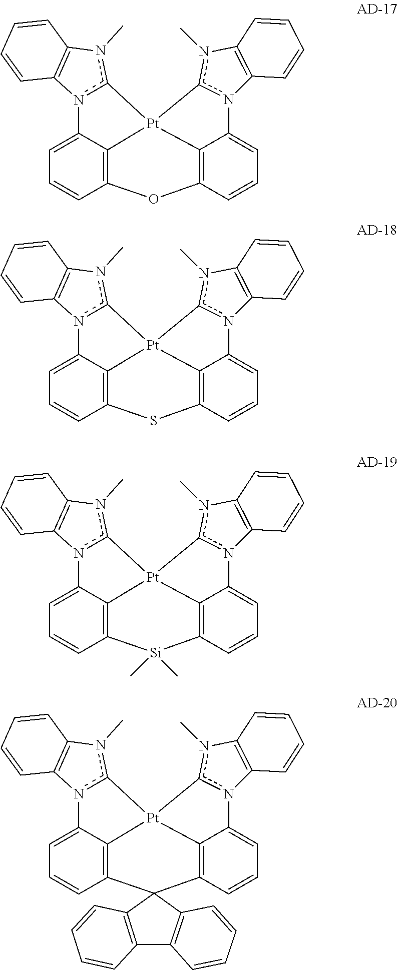

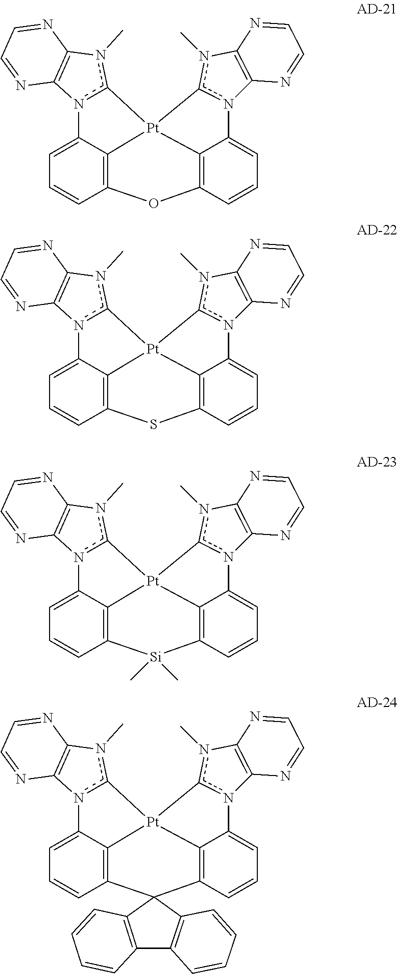

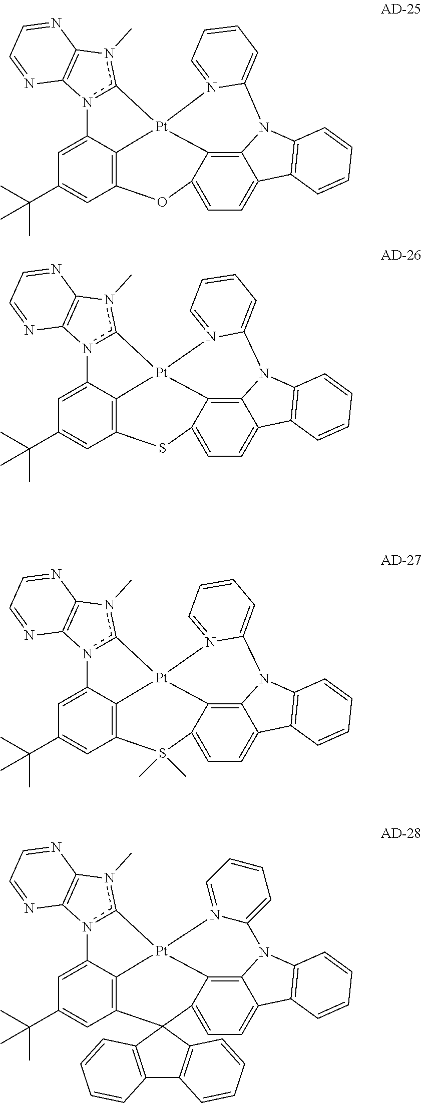

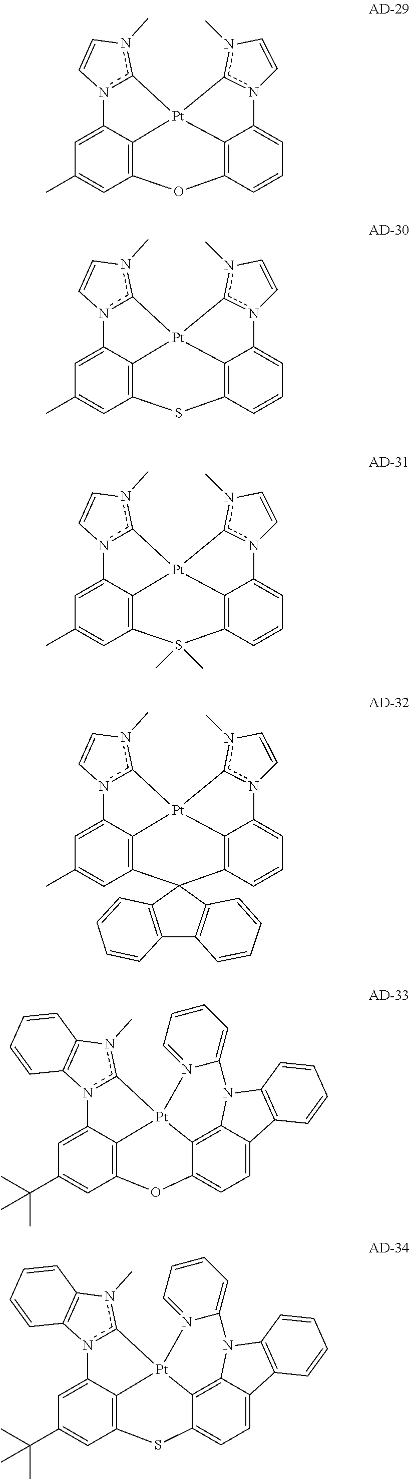

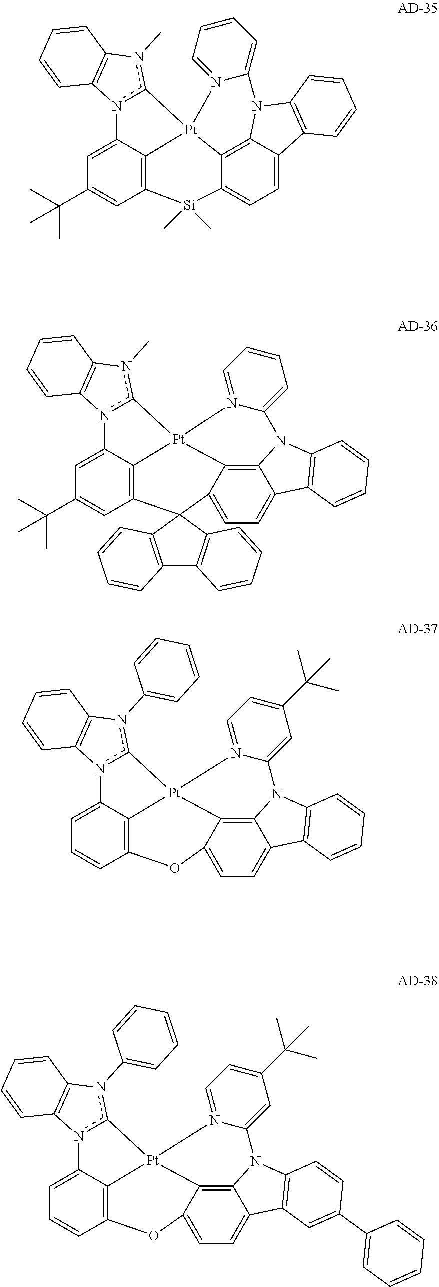

Referring to FIG. 3 to FIG. 6 again, the hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in the respective stated order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR in the light emitting device ED of an embodiment may include the first compound represented by Formula 1 above. In some embodiments, the hole transport region HTR in the light emitting device ED of an embodiment may include at least one of the hole injection layer HIL, the hole transport layer HTL, or electron blocking layer EBL, and at least one of the hole injection layer HIL, the hole transport layer HTL, or the electron blocking layer EBL may include the first compound represented by Formula 1 according to an embodiment. For example, the hole transport layer HTL in the light emitting device ED of an embodiment may include a polycyclic compound represented by Formula 1.

In the light emitting device ED of an embodiment, the hole transport layer HTL adjacent to the emission layer EML includes the first compound, and thus may achieve high efficiency of the light emitting device ED. The first compound represented by Formula 1 has relatively shallow highest occupied molecular orbital (HOMO) energy level, and thus may exhibit excellent or suitable hole mobility. In some embodiments, in the specification, the expression the energy level is “shallow” may refer to that the absolute value of the energy level becomes small towards minus from a vacuum level. In some embodiments, that the energy level is “deep” may refer to that the absolute value of the energy level becomes large towards minus from a vacuum level.

In an embodiment, the first compound represented by Formula 1 may have a HOMO energy level of about −4.9 eV to about −5.3 eV. The first compound has a HOMO energy level of about −4.9 eV to about −5.3 eV, and thus excellent or suitable hole transport characteristics may be exhibited. Therefore, when the first compound represented by Formula 1 is utilized in the hole transport layer, the light emitting device ED may exhibit excellent or suitable luminous efficiency characteristics. In some embodiments, in the specification, the HOMO energy level may refer to a value calculated utilizing a density functional theory (DFT).

The first compound of an embodiment may have a high triplet energy level (T1 level). The first compound of an embodiment may have a triplet energy level of about 2.9 eV or more. For example, the first compound may have a triplet energy level of about 2.9 eV to about 3.25 eV. When the triplet energy level of the first compound satisfies the above range, the excitons in the emission layer EML of the light emitting device ED may be trapped effectively. When the triplet energy level of the first compound is less than about 2.9 eV, the excitons generated in the emission layer EML are moved to the hole transport layer HTL, and thus a charge imbalance in the emission layer EML may occur. Accordingly, the hole transport layer HTL or the interface between the hole transport layer HTL and the emission layer EML other than the emission layer EML may be to emit light, and thus the luminous efficiency of the light emitting device ED may deteriorate. According to an embodiment, the hole transport layer HTL adjacent to the emission layer EML includes the first compound having relatively high triplet energy level, and thus the charge balance in the emission layer EML may be improved, thereby achieving high efficiency.

The hole transport region HTR may include a compound represented by Formula H-2:

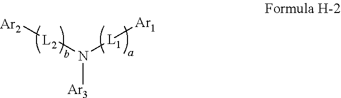

In Formula H-2 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-2, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-2, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-2 above may be a monoamine compound. In some embodiments, the compound represented by Formula H-2 above may be a diamine compound in which at least one among Ar₁ to Ar₃ includes the amine group as a substituent. In some embodiments, the compound represented by Formula H-2 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-2 may be represented by any one among the compounds in Compound Group H. However, the compounds listed in Compound Group H are examples, and the compounds represented by Formula H-2 are not limited to those represented by Compound Group H:

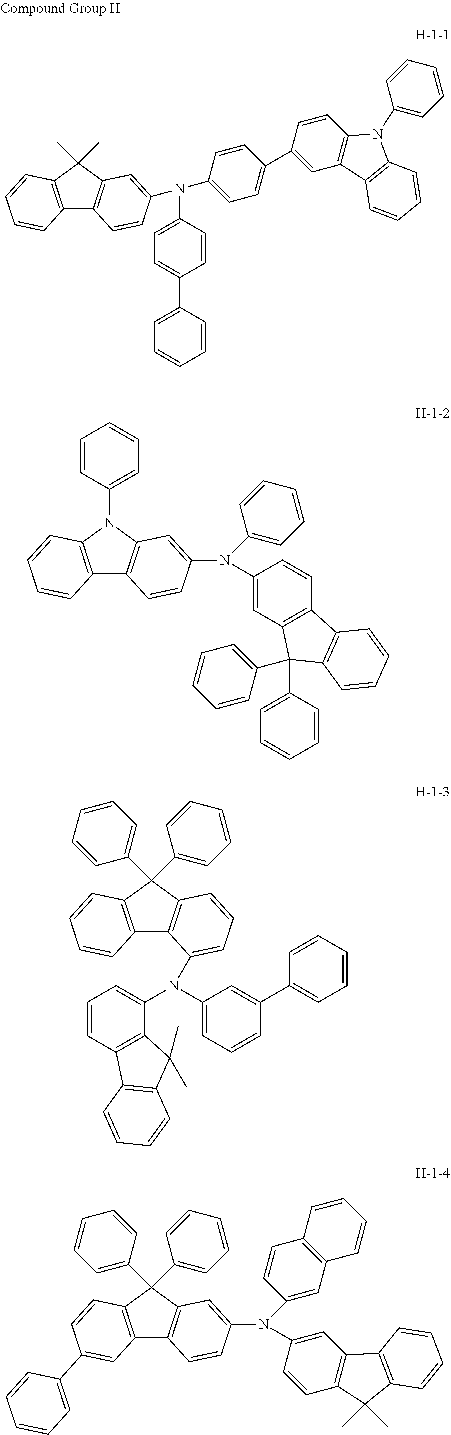 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

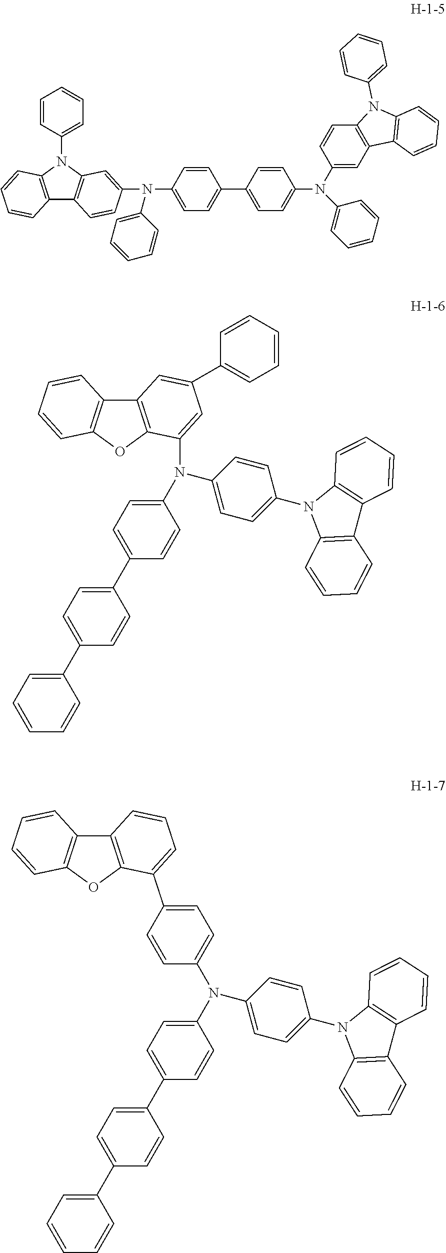 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

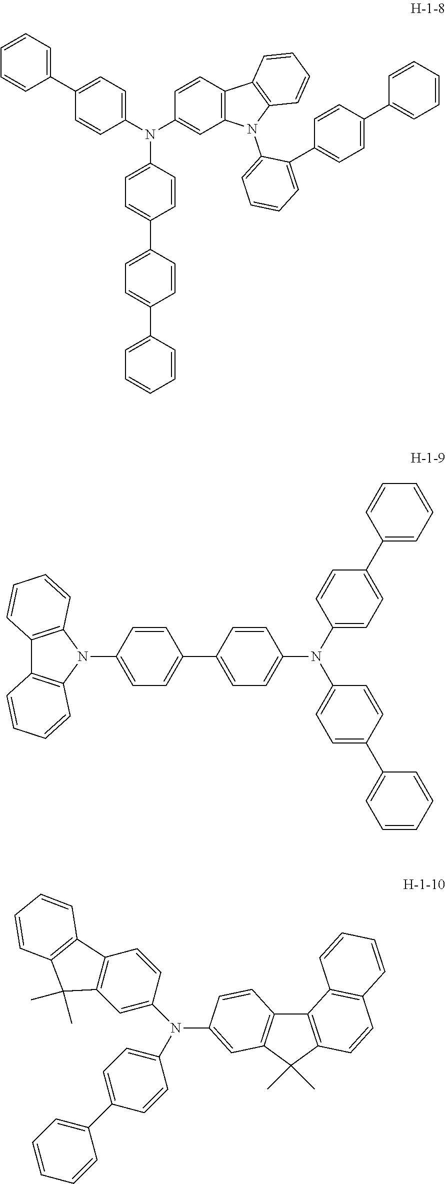 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

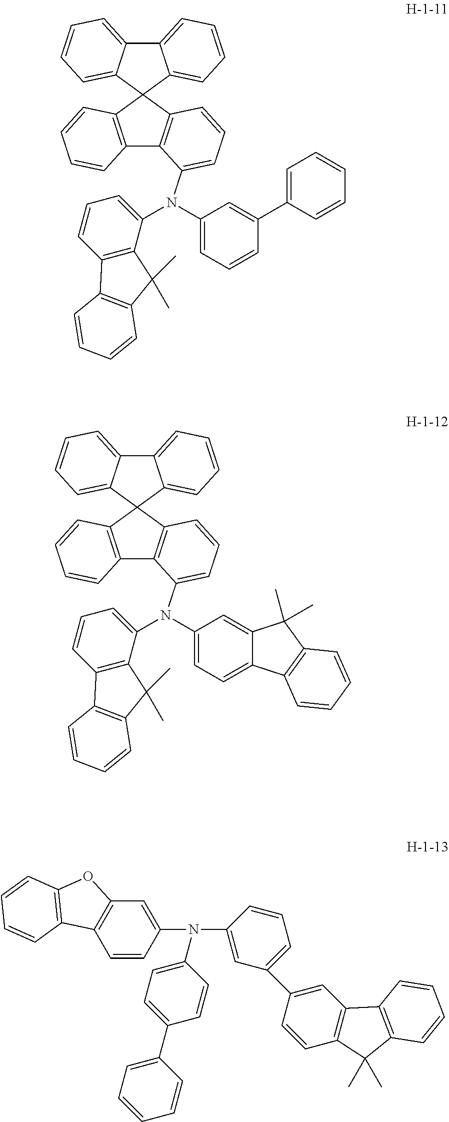 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

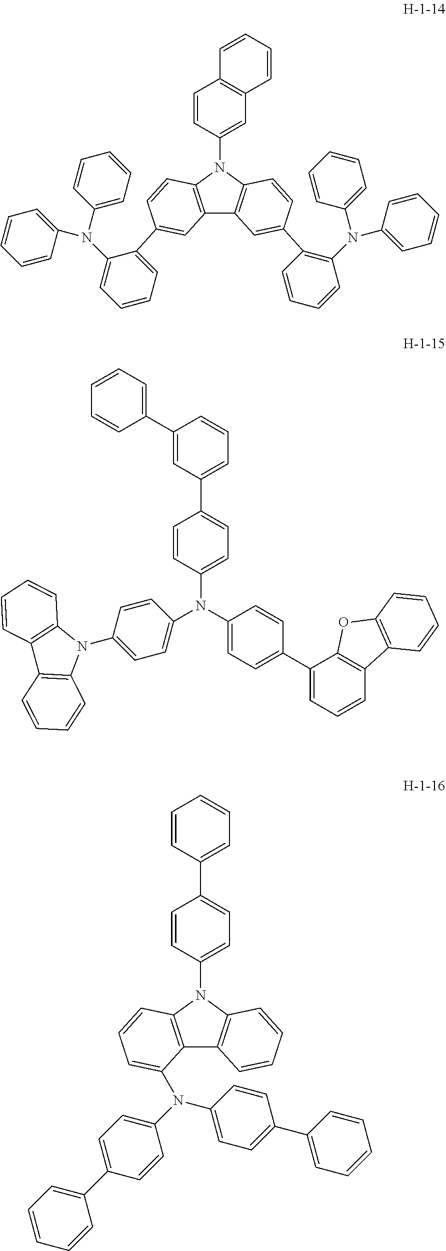 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

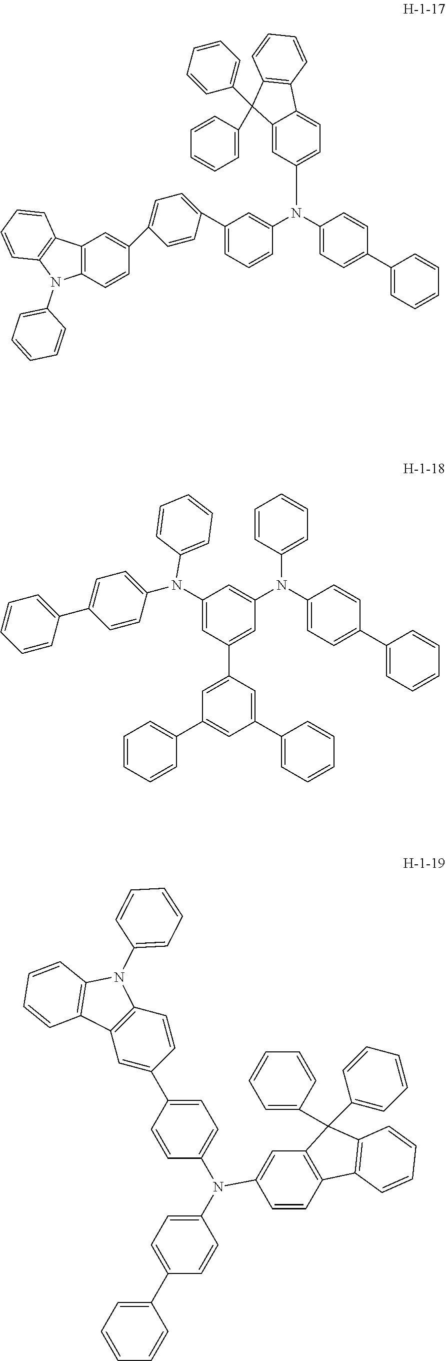 [SMILES: c1ccc(-c2ccc(N(c3cccc(-c4ccc(-c5ccc6c(c5)c5ccccc5n6-c5ccccc5)cc4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tis(3-methylphenyl)phenylamino]triphenylamine (m-MTDATA), 4,4′,4″-tis(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region HTR in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as CuI or RbI, a quinone derivative such as tetracyanoquinodimethane (TCNQ) and/or 2,3,5,6-tetrafluoro-7,7′8,8-tetracyanoquinodimethane (F4-TCNQ), a metal oxide such as tungsten oxide and/or molybdenum oxide, a cyano group-containing compound such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but the embodiment of the present disclosure is not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be utilized as a material to be included in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

The emission layer EML of the light emitting device ED of an embodiment includes a plurality of different luminescent materials. The light emitting device ED of an embodiment may include the first compound represented by Formula 1, the second compound represented by Formula 2, and the third compound represented by Formula 3 as described above.

The first compound of an embodiment may be included as a host material in the emission layer EML. The first compound of an embodiment may be utilized as a hole transporting host material for the emission layer EML. However, a usage of the first compound of an embodiment is not limited thereto.

The second compound of an embodiment may be included as a host material in the emission layer EML. The second compound of an embodiment may be utilized as an electron transporting host material for the emission layer EML. However, a usage of the first compound of an embodiment is not limited thereto.

In an embodiment, the emission layer EML may include the first compound and the second compound, and the first compound and the second compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 eV to about 3.0 eV. In some embodiments, the triplet energy of the exciplex may be a value smaller than an energy gap of each host material. The exciplex may have a triplet energy of about 3.0 eV or less that is an energy gap between the hole transporting host and the electron transporting host.

The third compound of an embodiment may be included as a dopant material in the emission layer EML. The third compound of an embodiment may be a thermally activated delayed fluorescence material. The fused polycyclic compound of an embodiment may be utilized as a thermally activated delayed fluorescence dopant. However, a usage of the fused polycyclic compound of an embodiment is not limited thereto.

The emission layer EML of an embodiment may include the first compound, the second compound, and the third compound, and may further include the fourth compound represented by Formula 4 as described above. The fourth compound may be utilized as a phosphorescent sensitizer of the emission layer EML. The energy may be transferred from the fourth compound to the first compound, thereby emitting light.

The emission layer EML of an embodiment may include the first compound, the second compound, and the third compound. In the emission layer EML, the first compound and the second compound may form an exciplex, and the energy may be transferred from the exciplex to the third compound, thereby emitting light.

In some embodiments, the emission layer EML may include the first compound, the second compound, the third compound, and the fourth compound. In the emission layer EML, the first compound and the second compound may form an exciplex, and the energy may be transferred from the exciplex to the third compound and the fourth compound, thereby emitting light.

In an embodiment, the fourth compound may be a sensitizer. The fourth compound included in the emission layer EML in the light emitting device ED of an embodiment may serve as a sensitizer to deliver energy from the host to the third compound that is a light emitting dopant. For example, the fourth compound serving as an auxiliary dopant accelerates energy delivery to the third compound that is a light emitting dopant, thereby increasing the emission ratio of the third compound. Therefore, the emission layer EML of an embodiment may improve luminous efficiency. In some embodiments, when the energy delivery to the third compound is increased, an exciton formed in the emission layer EML is not accumulated inside the emission layer EML and emits light rapidly, and thus deterioration of the device may be reduced. Therefore, the service life of the light emitting device ED of an embodiment may increase.

The light emitting device ED of an embodiment may include all of the first compound, the second compound, the third compound, and the fourth compound, and the emission layer EML may include the combination of two host materials and two dopant materials. In the light emitting device ED of an embodiment, the emission layer EML may concurrently (e.g., simultaneously) include the first compound and the second compound, which are two different hosts, the third compound that emits a delayed fluorescence, and the fourth compound including an organometallic complex, thereby exhibiting excellent or suitable luminous efficiency characteristics.

In an embodiment, the emission layer EML may be a fluorescence emission layer. For example, some of the light emitted from the emission layer EML may result from thermally activated delayed fluorescence (TADF). In an embodiment, the emission layer EML may be an emission layer which emits thermally delayed fluorescence and emits blue light. In some embodiments, the emission layer EML of an embodiment may have a light emission wavelength of about 440 nm to about 500 nm. However, the embodiment of the present disclosure is not limited thereto.

In some embodiments, the light emitting device ED of an embodiment may include a plurality of emission layers. The plurality of emission layers may be sequentially stacked and provided, and for example, the light emitting device ED including the plurality of emission layers may be to emit white light. The light emitting device including the plurality of emission layers may be a light emitting device having a tandem structure. When the light emitting device ED includes a plurality of emission layers, at least one emission layer EML may include the first compound represented by Formula 1 of an embodiment. When the light emitting device ED includes the plurality of emission layers, at least one emission layer EML may include the first compound, the second compound, and the third compound as described above. In some embodiments, when the light emitting device ED includes the plurality of emission layers, at least one emission layer EML may include all of the first compound, the second compound, the third compound, and the fourth compound.

When the emission layer EML in the light emitting device ED of an embodiment includes all of the first compound, the second compound, and the third compound, with respect to the total weight of the first compound, the second compound, and the third compound, the content (e.g., amount) of the third compound may be about 0.1 wt % to about 5 wt %. However, the embodiment of the present disclosure is not limited thereto. When the content (e.g., amount) of the third compound satisfies the above-described ratio, the energy transfer from the first compound and the second compound to the third compound may increase, and thus the luminous efficiency may increase.

The contents of the first compound and the second compound in the emission layer EML may be the rest excluding the weight of the third compound as described above. For example, the contents of the first compound and the second compound in the emission layer EML may be about 50 wt % to about 95 wt % with respect to the total weight of the first compound, the second compound, and the third compound.

In the total weight of the first compound and the second compound, the weight ratio of the first compound and the second compound may be about 3:7 to about 7:3.

When the contents of the first compound and the second compound satisfy the above-described ratio, a charge balance characteristic in the emission layer EML is improved, and thus the luminous efficiency may increase. When the contents of the first compound and the second compound deviate from the above-described ratio range, a charge balance in the emission layer EML may be broken, and thus the luminous efficiency may be reduced and the device may be easily deteriorated.

When the emission layer EML includes the fourth compound, the content (e.g., amount) of the fourth compound in the emission layer EML may be about 4 wt % to about 30 wt % with respect to the total weight of the first compound, the second compound, the third compound, and the fourth compound. However, the embodiment of the present disclosure is not limited thereto. When the content (e.g., amount) of the fourth compound satisfies the above-described content (e.g., amount), the energy delivery from the host to the third compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the above-described content (e.g., amount) ratio range, excellent or suitable luminous efficiency may be achieved.

In the light emitting device ED of an embodiment, the emission layer EML may include an anthracene derivative, a pyrene derivative, a fluoranthene derivative, a chrysene derivative, a dehydrobenzanthracene derivative, and/or a triphenylene derivative. For example, the emission layer EML may further include an anthracene derivative and/or a pyrene derivative.

In each light emitting device ED of embodiments illustrated in FIGS. 3 to 6, the emission layer EML may further include a suitable host and dopant besides the above-described host and dopant, and for example the emission layer EML may include a compound represented by Formula E-1. The compound represented by Formula E-1 may be utilized as a fluorescent host material.

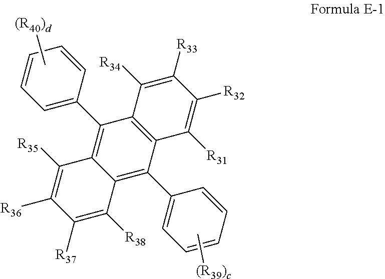

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

Formula E-1 may be represented by any one among Compound E1 to Compound E19:

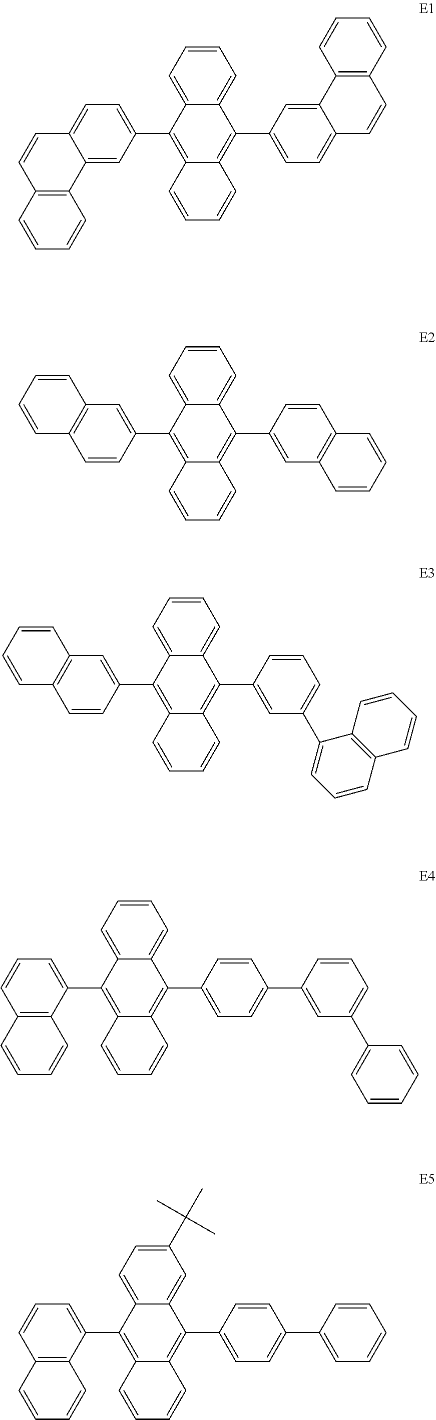

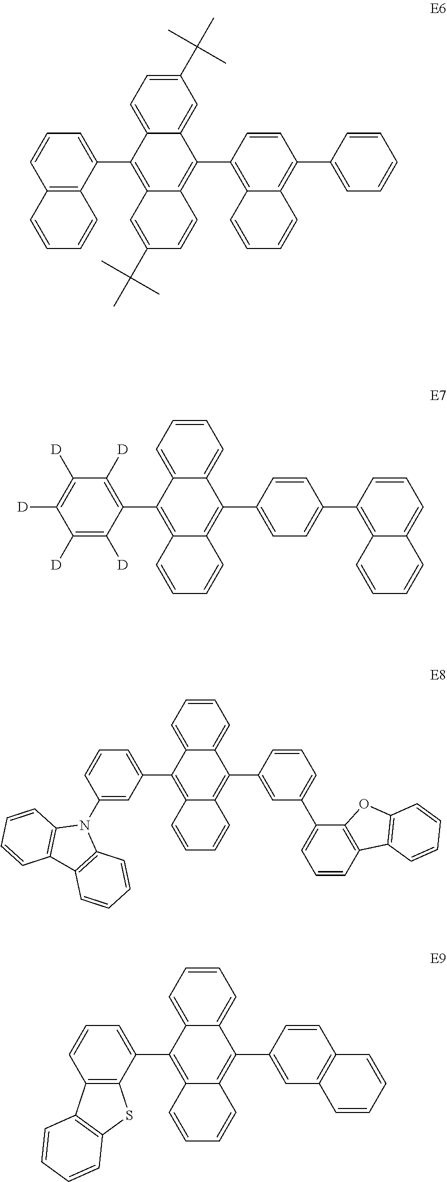

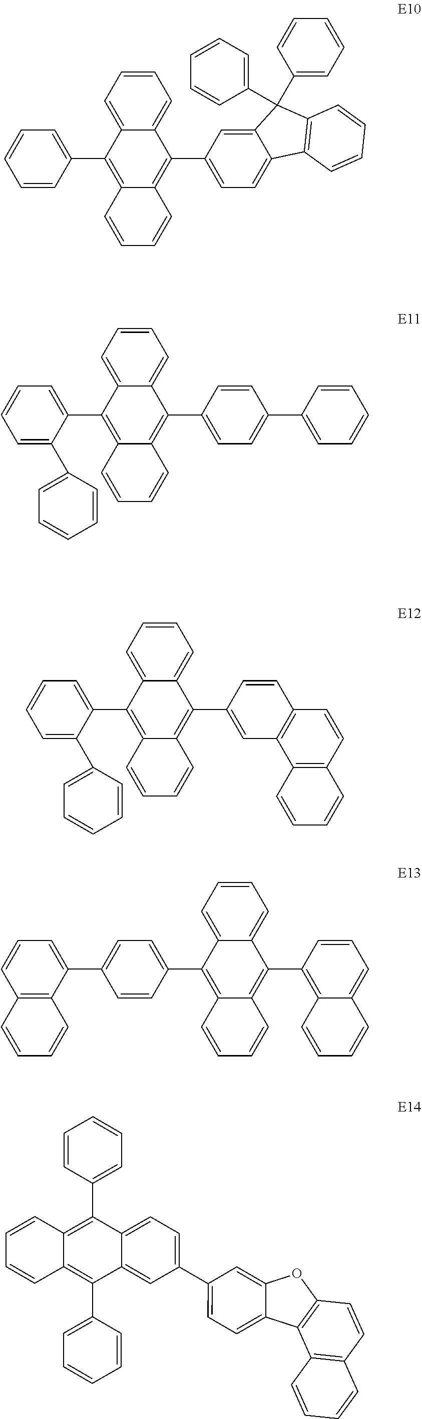

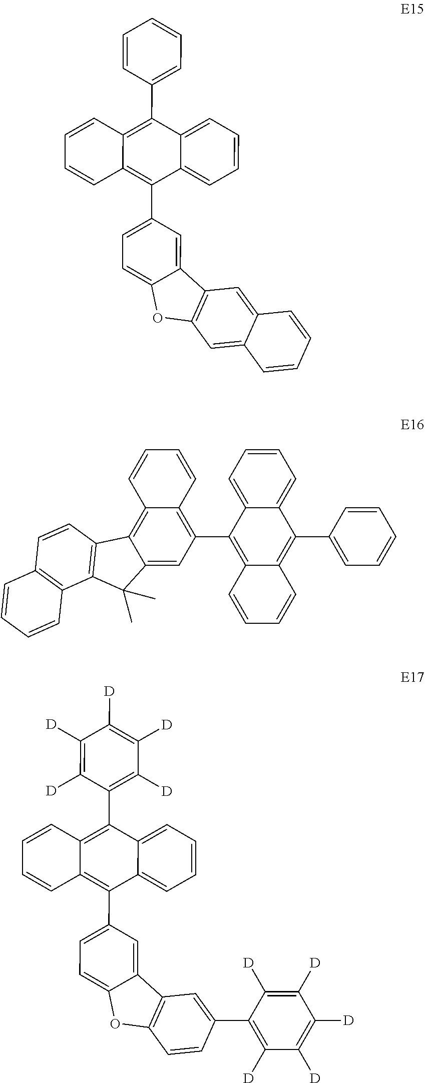

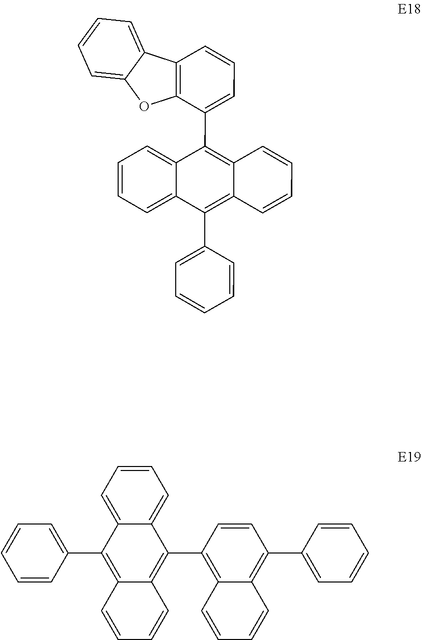

In an embodiment, the emission layer EML may include a compound represented by Formula E-2a or Formula E-2b. The compound represented by Formula E-2a or Formula E-2b may be utilized as a phosphorescent host material.

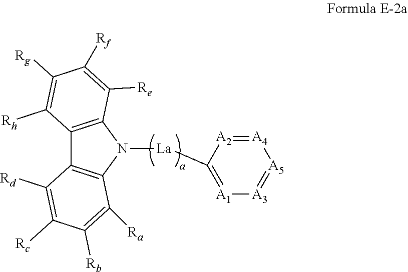

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of Lₐ's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. Rₐ to Rᵢ may be bonded to an adjacent group to form a hydrocarbon ring or a heterocycle containing N, O, S, etc., as a ring-forming atom.

In some embodiments, in Formula E-2a, two or three selected from among A₁ to A₅ may be N, and the rest may be CRᵢ.

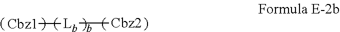

In Formula E-2b, Cbz1 and Cbz2 may each independently be an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In some embodiments, b is an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among the compounds of Compound Group E-2. However, the compounds listed in Compound Group E-2 are example, and the compound represented by Formula E-2a or Formula E-2b is not limited to those represented in Compound Group E-2.

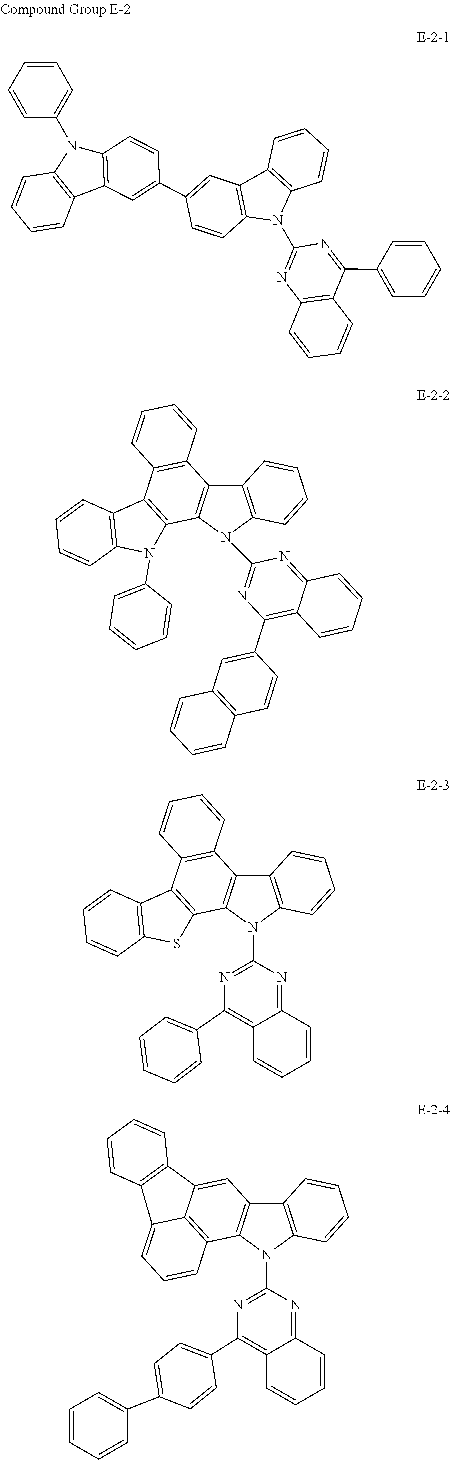

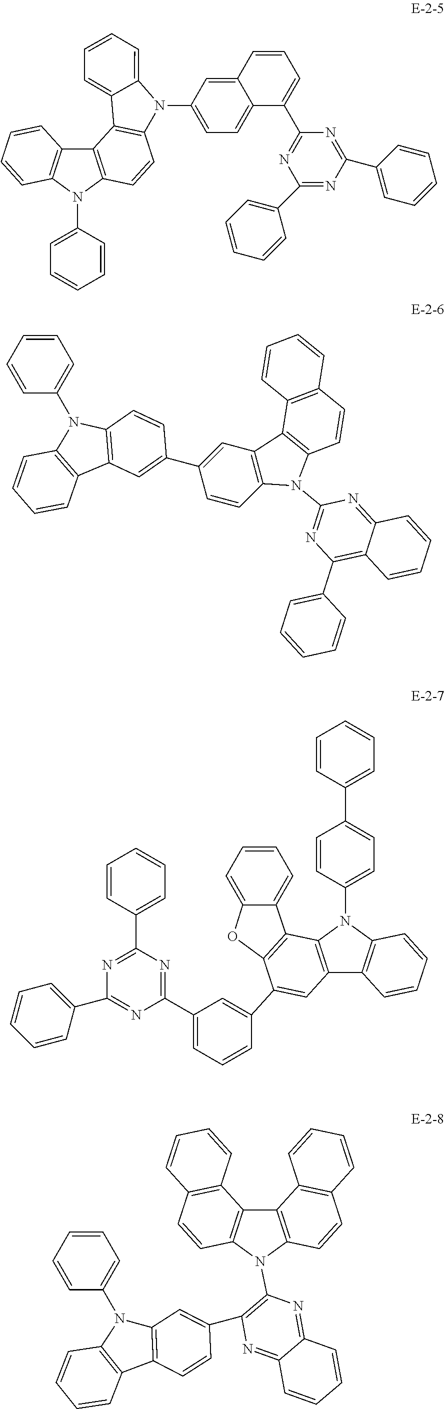 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

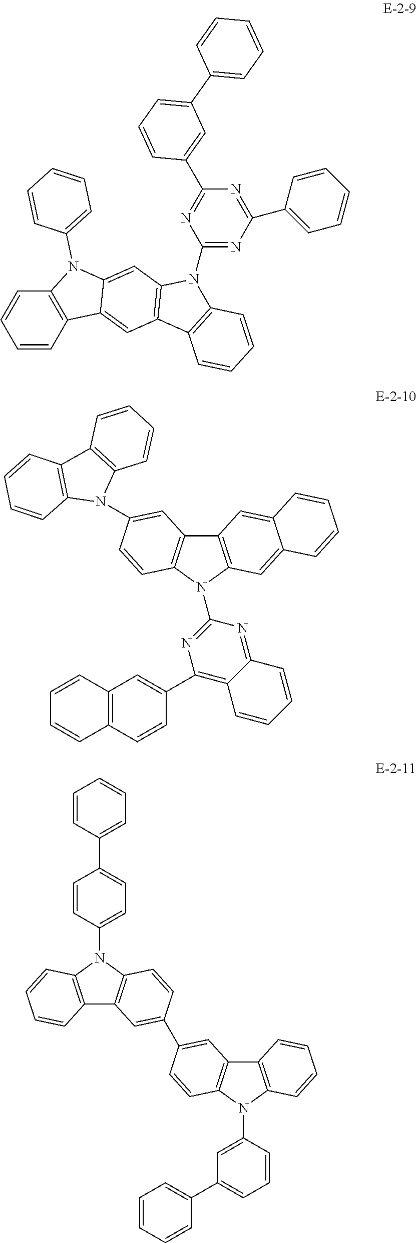

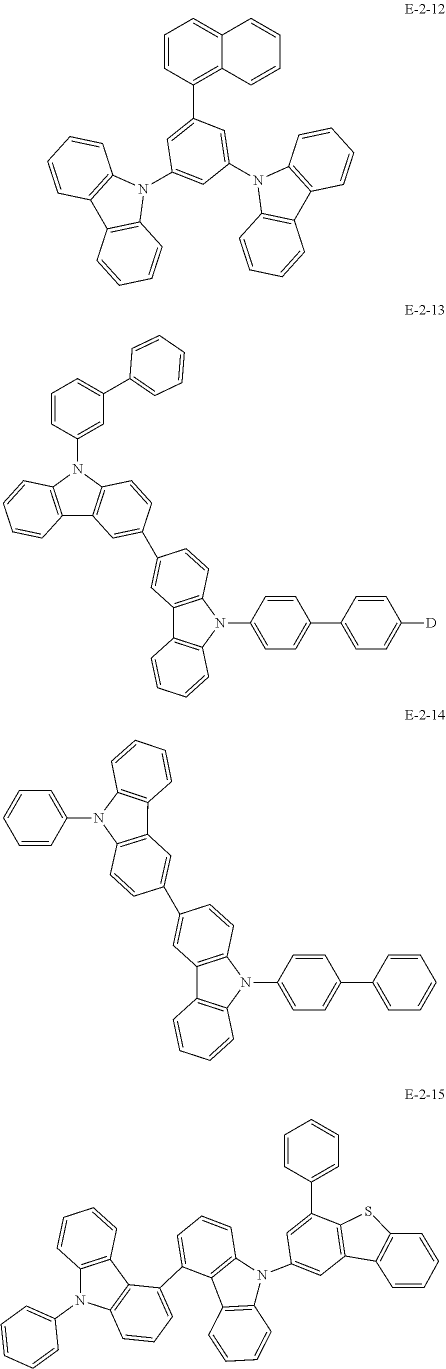 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

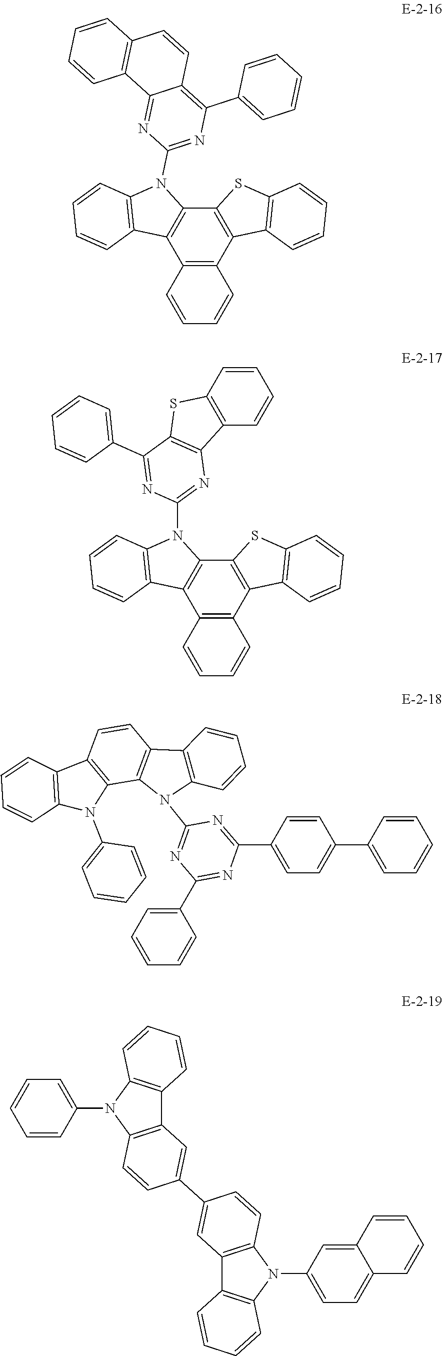

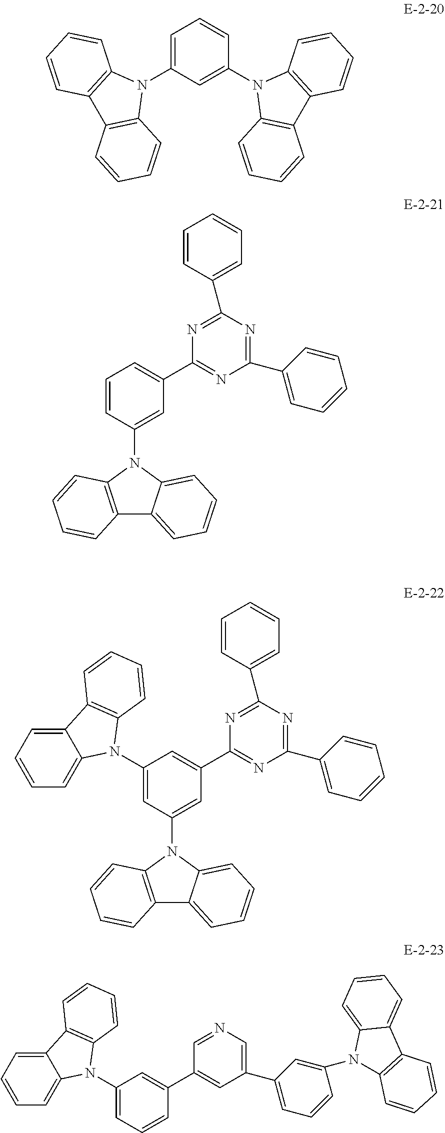 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

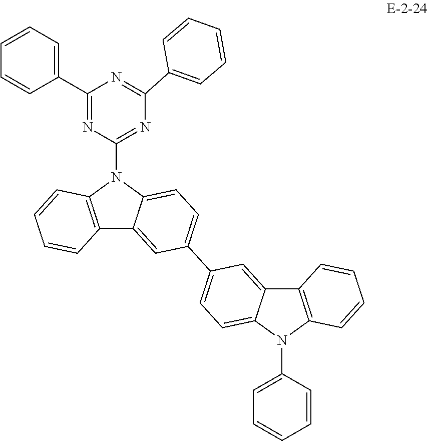 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment of the present disclosure is not limited thereto, for example, tis(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be utilized as a host material.

The emission layer EML may include the compound represented by Formula M-a. The compound represented by Formula M-a may be utilized as a phosphorescent dopant material.

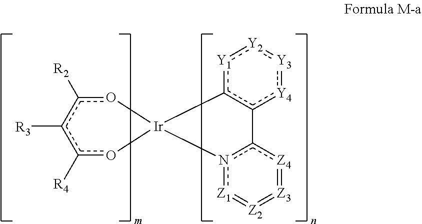

In Formula M-a above, Y₁ to Y₄ and Z₁ to Z₄ may each independently be CR₁ or N, and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant.

The compound represented by Formula M-a may be represented by any one among Compound M-a1 to Compound M-a25. However, Compounds M-a1 to M-a25 are examples, and the compound represented by Formula M-a is not limited to those represented by Compounds M-a1 to M-a25.

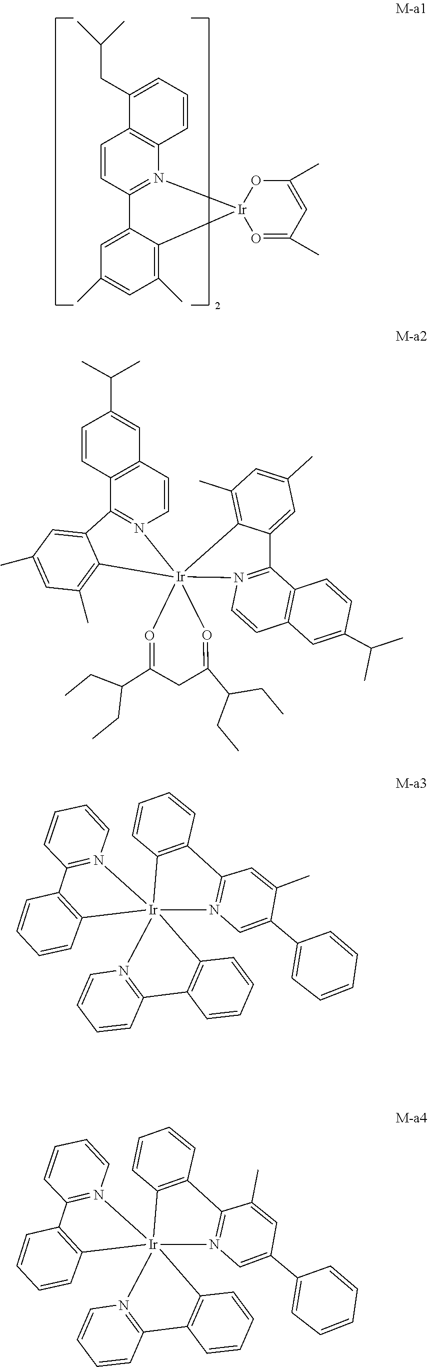

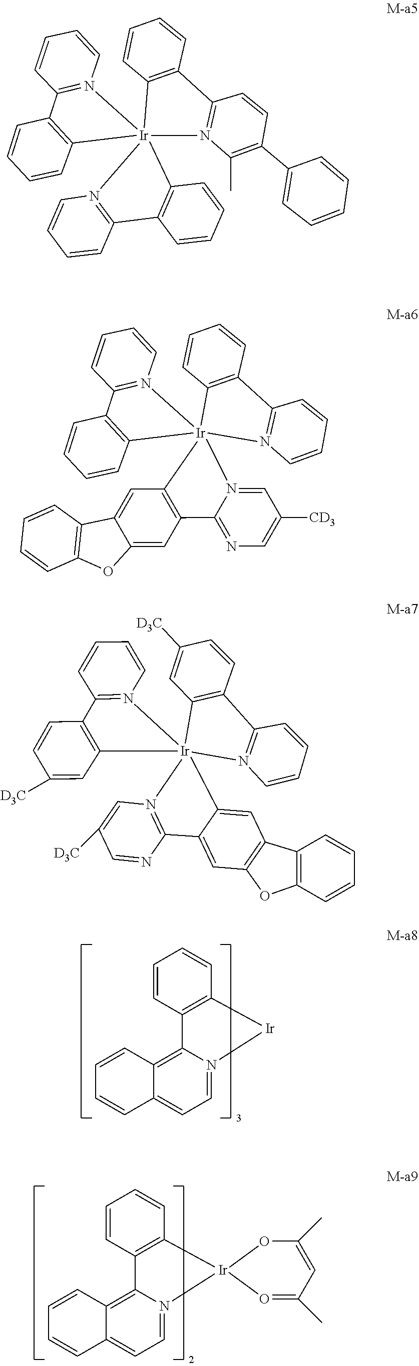

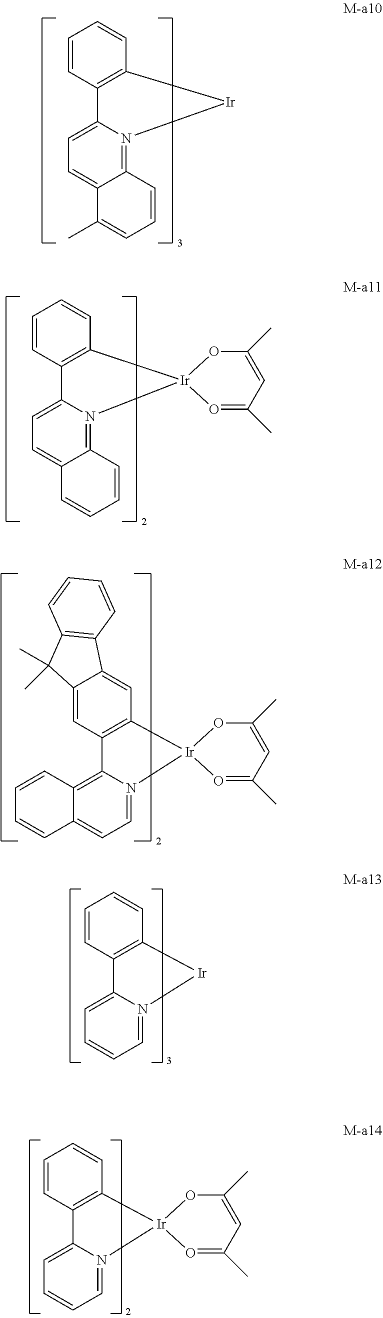

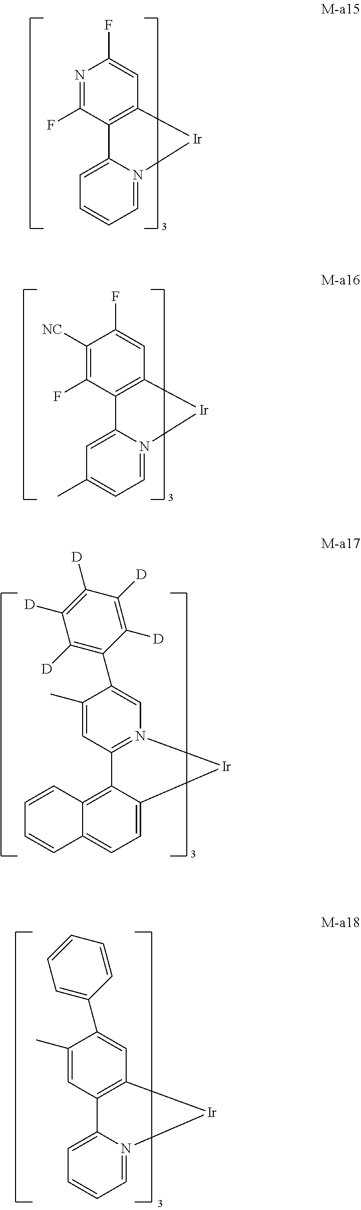

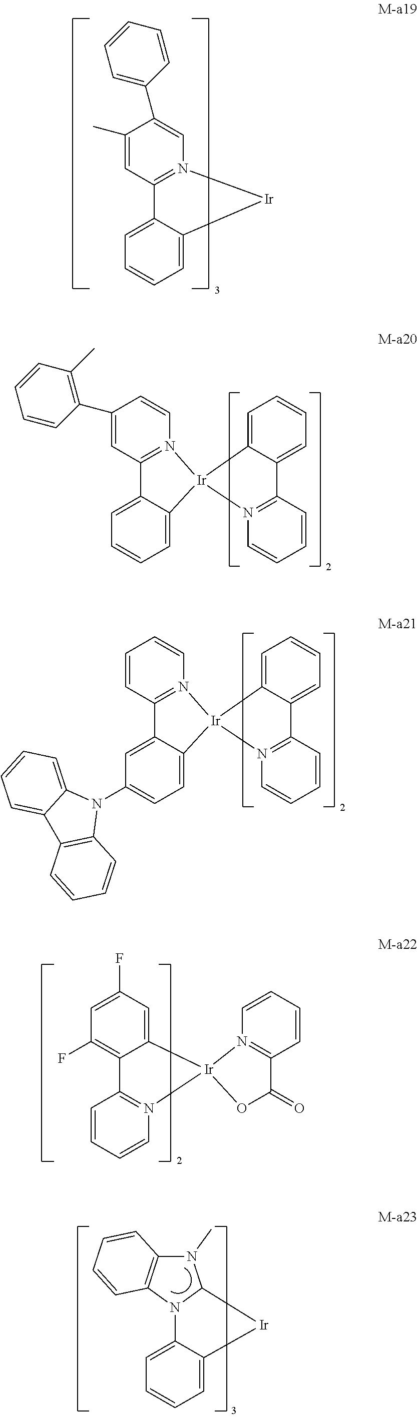

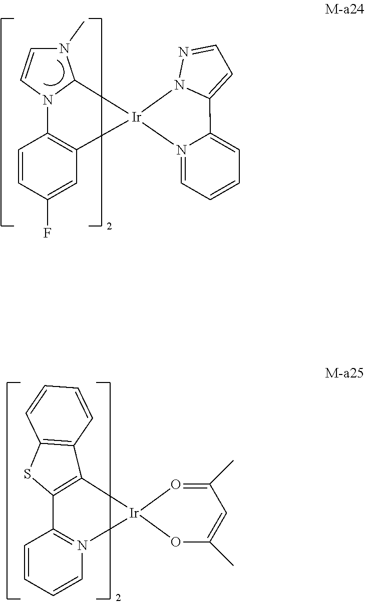

The emission layer EML may include a compound represented by any one among Formula F-a to Formula F-c. The compound represented by Formula F-a to Formula F-c may be utilized as a fluorescence dopant material.

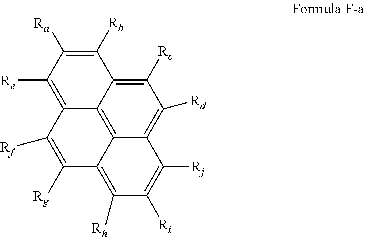

In Formula F-a above, two selected from among Rₐ to Rⱼ may each independently be substituted with *^{—}NAr₁Ar₂. Any remainder not substituted with *^{—}NAr₁Ar₂, among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *^{—}NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

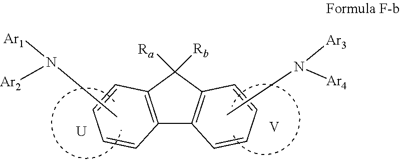

In Formula F-b above, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one among Ar₁ to Ar₄ may be a heteroaryl group containing O or S as a ring-forming atom.

In Formula F-b, the number of rings represented by U and V may each independently be 0 or 1. For example, in Formula F-b, when the number of U or V is 1, one ring indicated by U or V forms a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

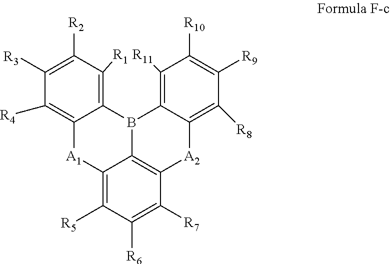

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-c, A₁ and A₂ may each independently be bonded to substituents of an adjacent ring to form a fused ring. For example, when A₁ and A₂ may each independently be NRₘ, A₁ may be bonded to R₄ or R₅ to form a ring. In some embodiments, A₂ may be bonded to R₇ or Re to form a ring.

In an embodiment, the emission layer EML may further include, as a suitable dopant material, one or more styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and the derivatives thereof (e.g., 2,5,8,11-tetra-t-butylperylene (TBP)), pyrene and the derivatives thereof (e.g., 1,1-dipyrene, 1,4-dipyrenylbenzene, 1,4-bis(N,N-diphenylamino)pyrene), etc.

The emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), and/or thulium (Tm) may be utilized as a phosphorescent dopant. For example, iridium(III) bis(4,6-difluorophenylpyridinato-N,C2′)picolinate (Firpic), bis(2,4-difluorophenylpyridinato)-tetrakis(1-pyrazolyl)borate iridium(III) (Fir6), and/or platinum octaethyl porphyrin (PtOEP) may be utilized as a phosphorescent dopant. However, the embodiment of the present disclosure is not limited thereto.

The emission layer EML may include a quantum dot material. The core of the quantum dot may be selected from among a Group II-VI compound, a Group III-VI compound, a Group I-III-IV compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, and a quaternary compound such as AgInGaS₂ and/or CulnGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and a mixture thereof. In some embodiments, the Group III-V compound may further include a Group II metal. For example, InZnP, etc., may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound, or the quaternary compound may be present in a particle with a substantially uniform concentration distribution, or may be present in the same particle with a partially different concentration distribution. In some embodiments, the quantum dot may have a core/shell structure in which one quantum dot is around (e.g., surrounds) another quantum dot. The core/shell structure may have a concentration gradient in which the concentration of elements present in the shell decreases toward the center of the core.

In some embodiments, the quantum dot may have the above-described core/shell structure including a core containing nanocrystals and a shell around (e.g., surrounding) the core. The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An example of the shell of the quantum dots may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but the embodiment of the present disclosure is not limited thereto.

Also, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the present disclosure is not limited thereto.

The quantum dot may have a full width of half maximum (FWHM) of a light emitting wavelength spectrum of about 45 nm or less, about 40 nm or less, or about 30 nm or less, and color purity or color reproducibility may be improved within the above ranges. In some embodiments, light emitted through such a quantum dot is emitted in all directions, and thus a wide viewing angle may be improved.

In some embodiments, although the form of the quantum dot is not particularly limited as long as it is a form commonly utilized in the art, for example, the quantum dot in the form of spherical, pyramidal, multi-arm, or cubic nanoparticles, nanotubes, nanowires, nanofibers, nanoplate particles, etc., may be utilized.

A quantum dot may control the color of emitted light according to the particle size thereof and thus the quantum dot may have one or more suitable light emission colors such as green, red, etc.

In each light emitting device ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in the respective stated order from the emission layer EML, but the embodiment of the present disclosure is not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1:

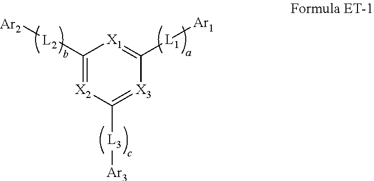

In Formula ET-1, at least one among X1 to X3 is N, and any remainder thereof are each independently CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer of 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c may each independently be an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), or a mixture thereof.

The electron transport region ETR may include at least one among Compound ET1 to Compound ET36:

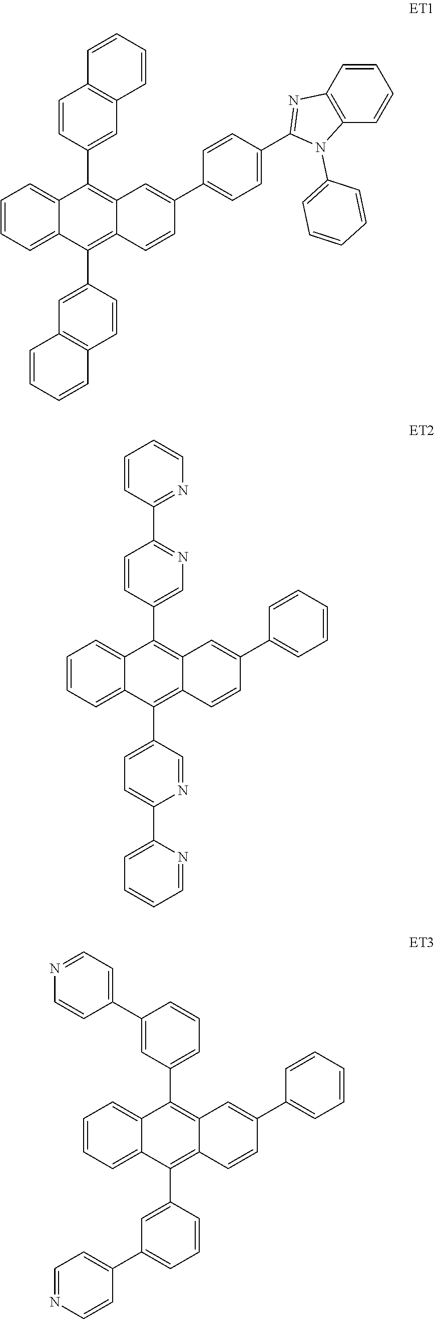 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

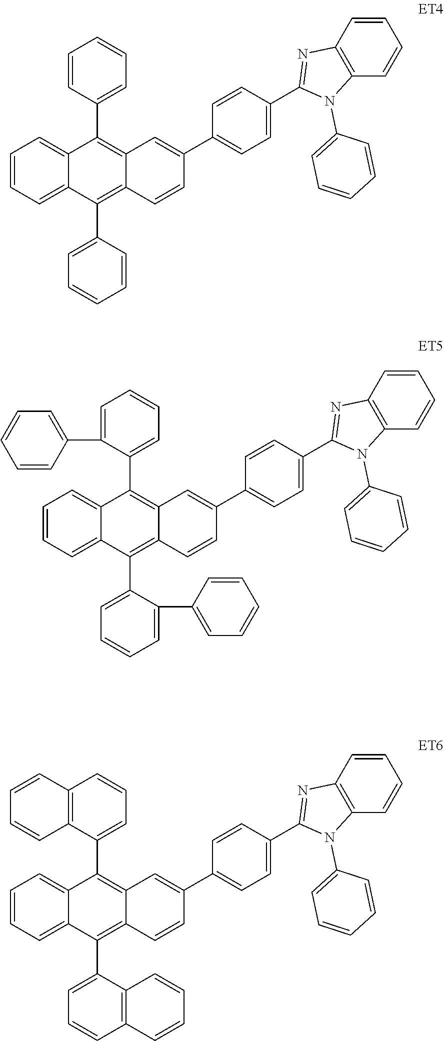 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

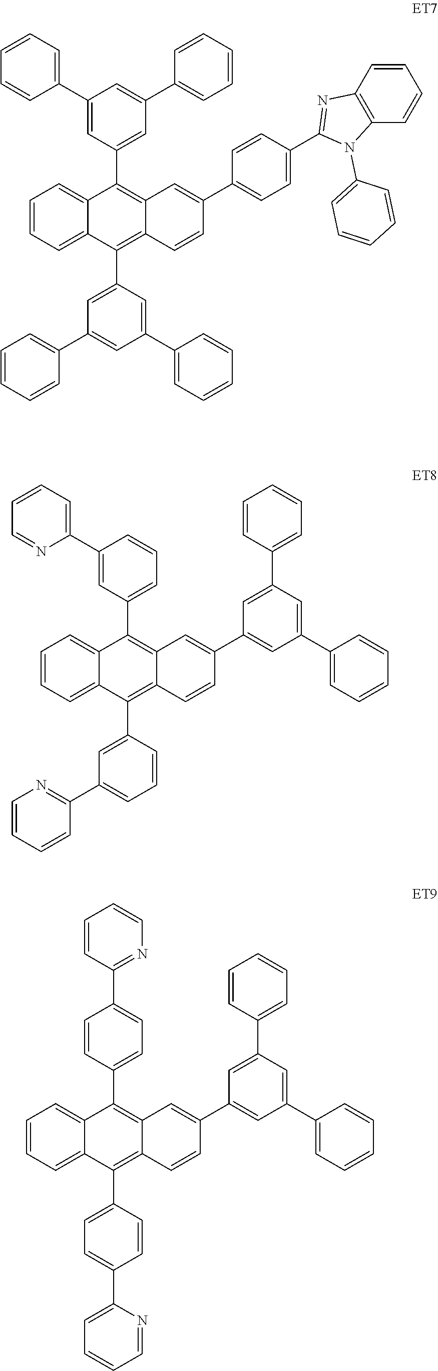 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

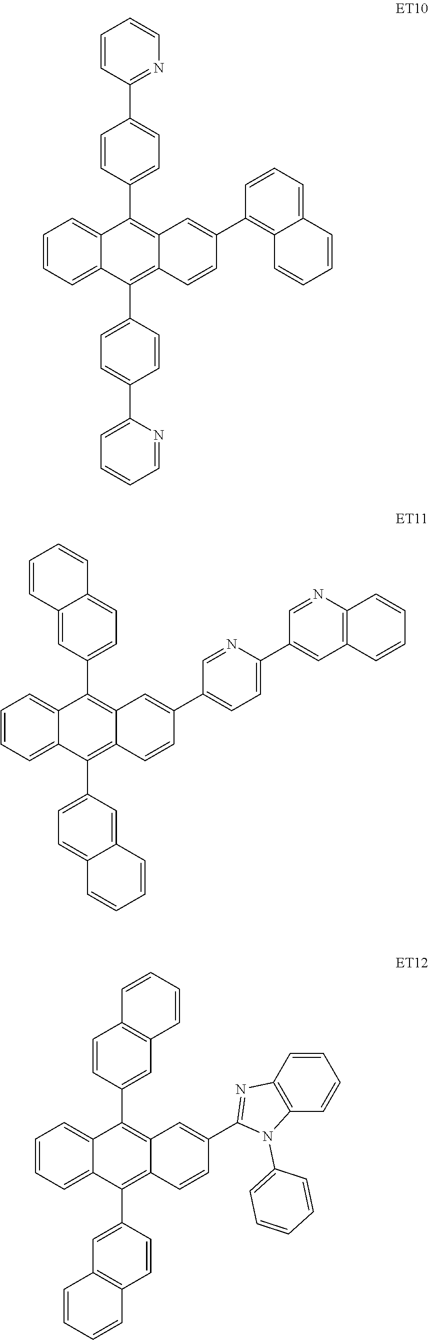 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

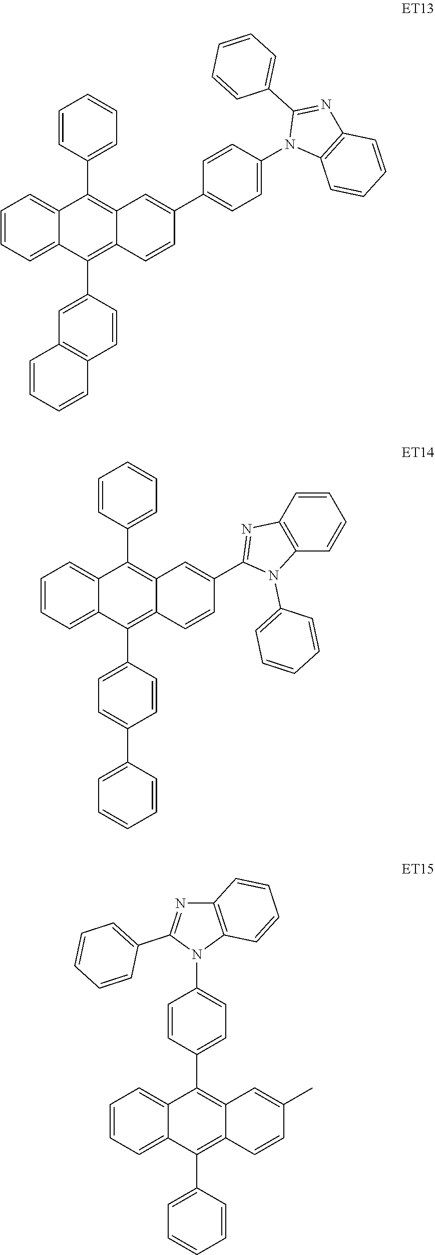 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

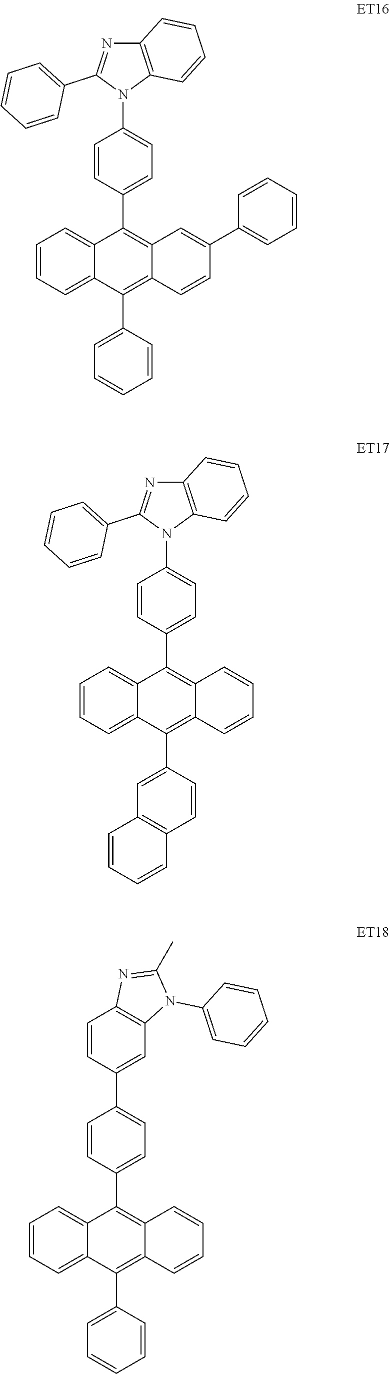 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

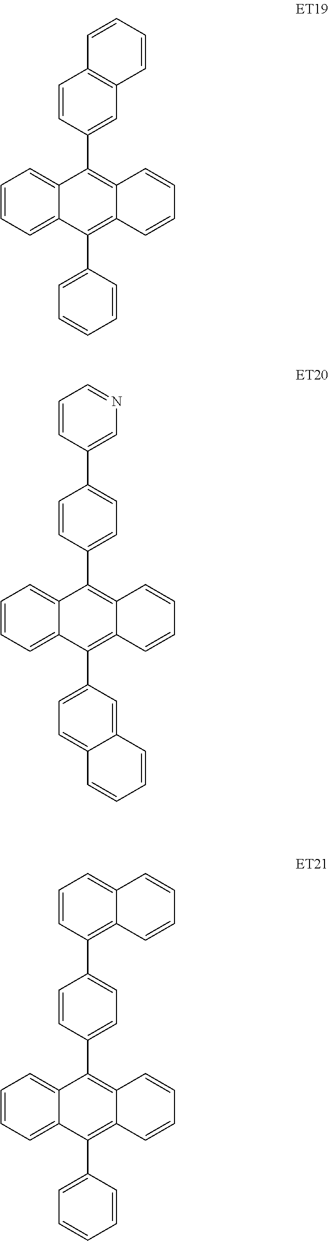

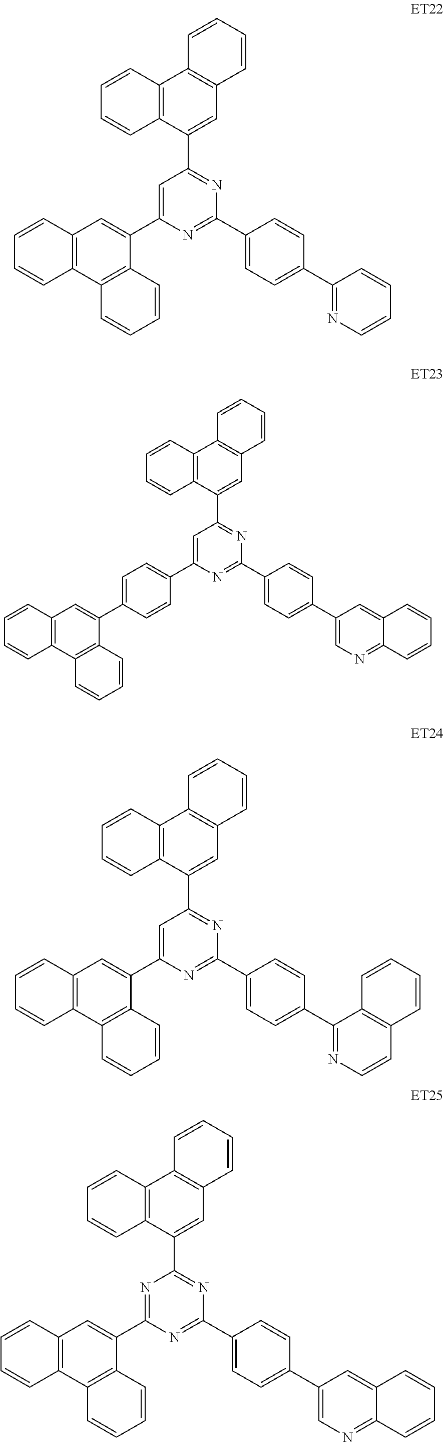 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

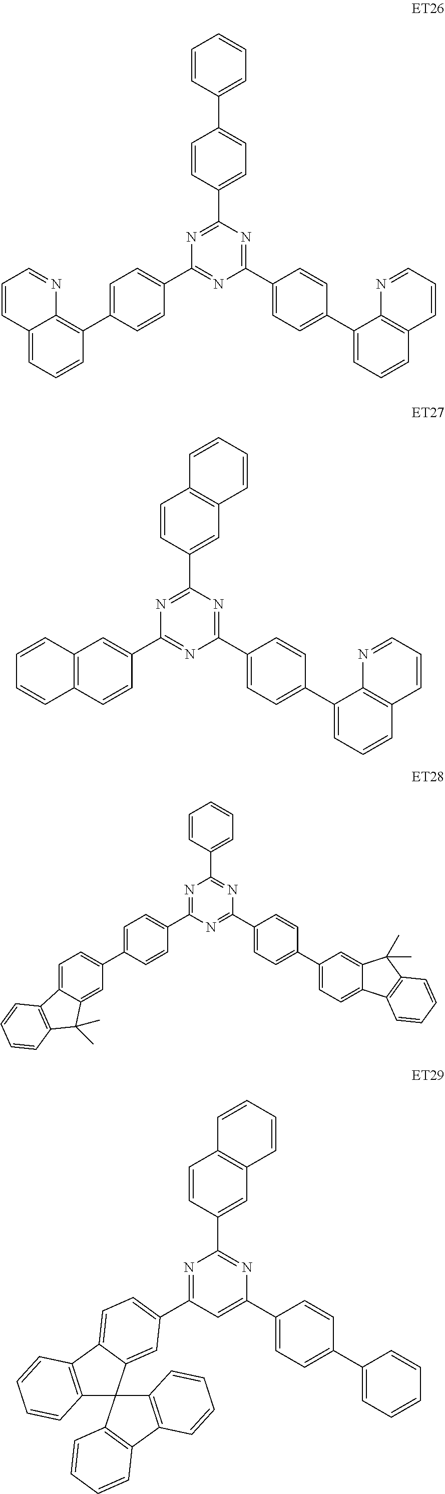 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

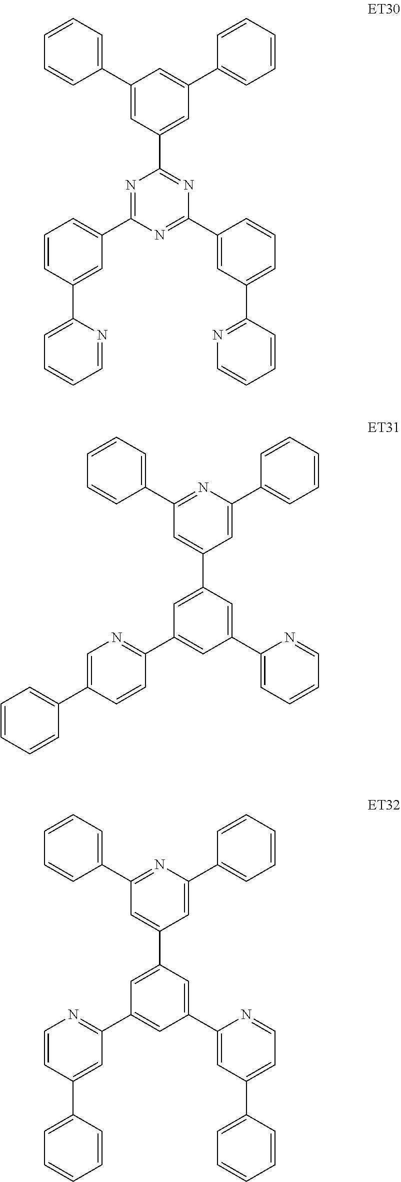 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

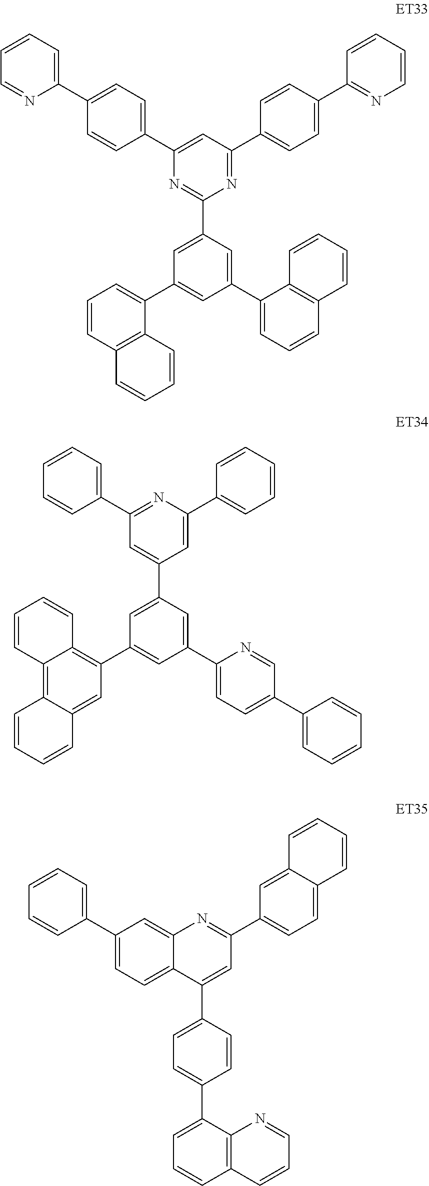 [SMILES: c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1]

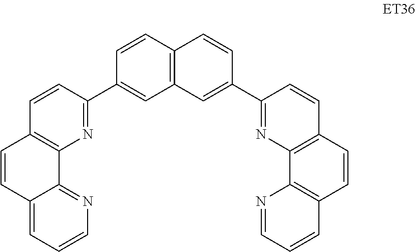 [SMILES: c1cnc2c(c1)ccc1ccc(-c3ccc4ccc(-c5ccc6ccc7cccnc7c6n5)cc4c3)nc12]

In some embodiments, the electron transport region ETR may include a metal halide such as LiF, NaCl, CsF, RbCl, RbI, CuI, and/or KI, a lanthanide metal such as Yb, and/or a co-deposited material of the metal halide and the lanthanide metal. For example, the electron transport region ETR may include KI:Yb, RbI:Yb, LiF:Yb, etc., as a co-deposited material. In some embodiments, the electron transport region ETR may be formed utilizing a metal oxide such as Li₂O and/or BaO, or 8-hydroxyl-lithium quinolate (Liq), etc., but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but the embodiment of the present disclosure is not limited thereto.

The electron transport region ETR may include the above-described compounds of the electron transport region ETR in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned ranges, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgAg). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, and/or the like.

The second electrode EL2 may be connected with an auxiliary electrode. When the second electrode EL2 is connected with the auxiliary electrode, the resistance of the second electrode EL2 may be decreased.

In some embodiments, a capping layer CPL may further be disposed on the second electrode EL2 of the light emitting device ED of an embodiment. The capping layer CPL may include a multilayer or a single layer.

In an embodiment, the capping layer CPL may be an organic layer or an inorganic layer. For example, when the capping layer CPL contains an inorganic material, the inorganic material may include an alkali metal compound (e.g., LiF), an alkaline earth metal compound (e.g., MgF₂), SiON, SiNₓ, SiO_{y}, etc.

For example, when the capping layer CPL includes an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., an epoxy resin, or acrylate such as methacrylate. However, the embodiment of the present disclosure is not limited thereto, and the capping layer CPL may include at least one among Compounds P1 to P5:

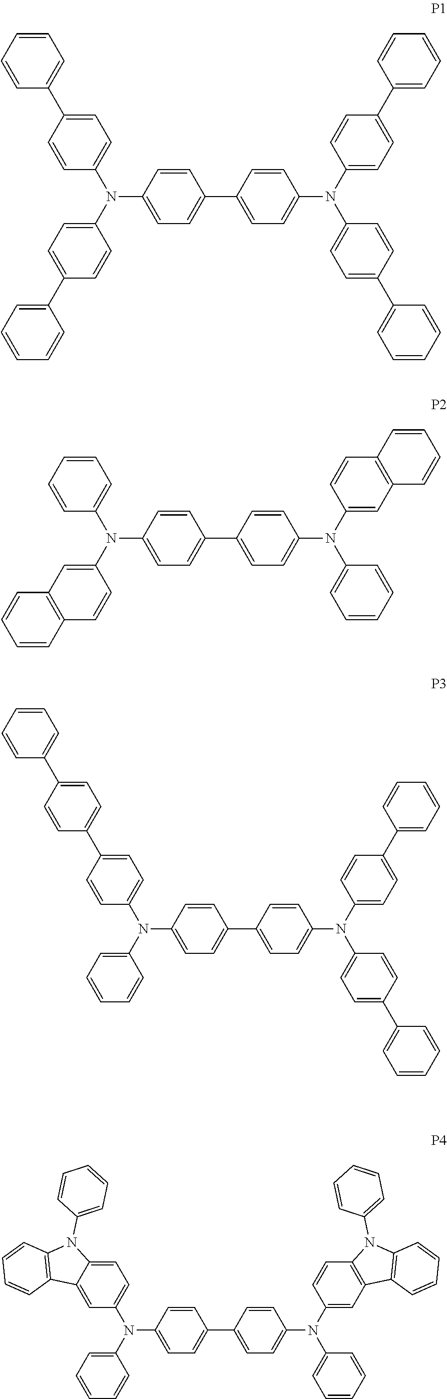 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

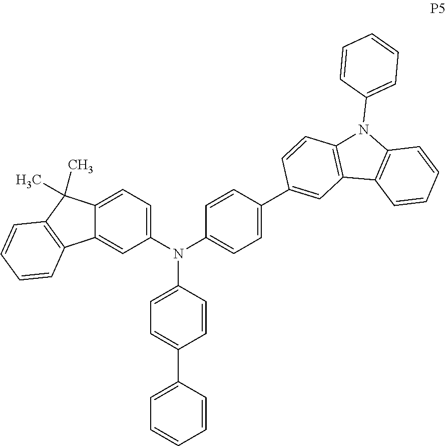 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

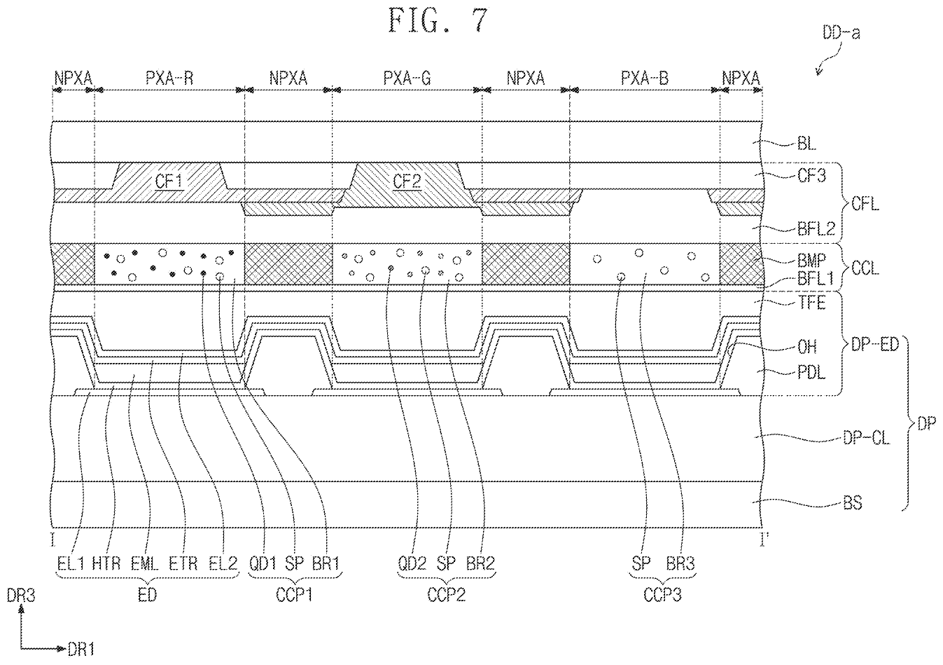

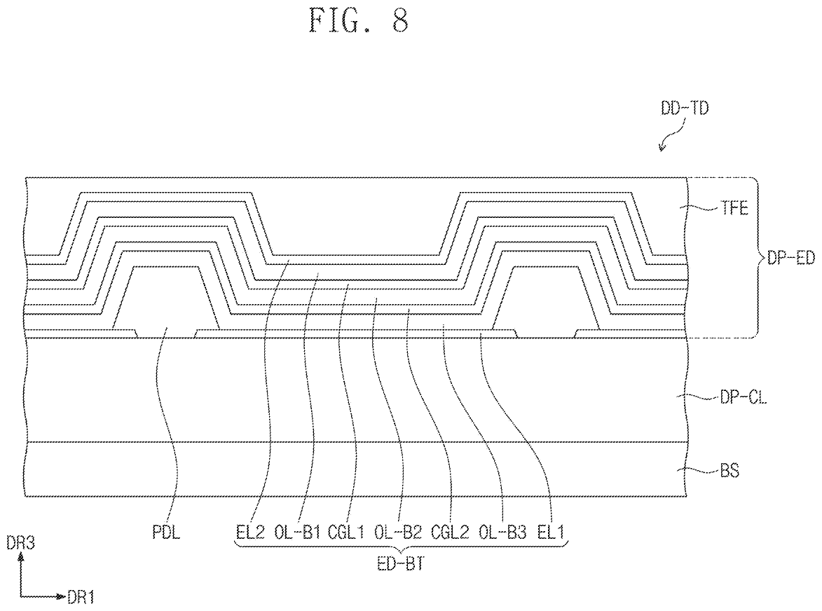

In some embodiments, the refractive index of the capping layer CPL may be about 1.6 or more. For example, the refractive index of the capping layer CPL may be about 1.6 or more with respect to light in a wavelength range of about 550 nm to about 660 nm. Each of FIGS. 7 and 8 is a cross-sectional view of a display apparatus according to an embodiment of the present disclosure. Hereinafter, in describing the display apparatuses of embodiments with reference to FIGS. 7 and 8, the duplicated features which have been described in FIGS. 1 to 6 are not described again, but their differences will be mainly described.

Referring to FIG. 7, the display apparatus DD-a according to an embodiment may include a display panel DP including a display device layer DP-ED, a light control layer CCL disposed on the display panel DP, and a color filter layer CFL. In an embodiment illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the structures of the light emitting devices of FIGS. 3 to 6 as described above may be equally applied to the structure of the light emitting device ED illustrated in FIG. 7.

In the display apparatus DD-a according to an embodiment, the emission layer EML of the light emitting device ED may include the above-described first compound of an embodiment. In the display apparatus DD-a according to an embodiment, the emission layer EML of the light emitting device ED may include at least one among the first to fourth compounds.

Referring to FIG. 7, the emission layer EML may be disposed in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display apparatus DD-a of an embodiment, the emission layer EML may be to emit blue light. In some embodiments, unlike the configuration illustrated, in an embodiment, the emission layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, and/or the like. The light conversion body may be to convert the wavelength of light provided and then emit. For example, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 7, divided patterns BMP may be disposed between the light control parts CCP1, CCP2 and CCP3 which are spaced apart from each other, but the embodiment of the present disclosure is not limited thereto. FIG. 7 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts a first color light provided from the light emitting device ED into a second color light, a second light control part CCP2 containing a second quantum dot QD2 which converts the first color light into a third color light, and a third light control part CCP3 which transmits the first color light. In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The same as described above may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but may include the scatterer SP.

The scatterer SP may be inorganic particles. For example, the scatterer SP may include at least one of TiO₂, ZnO, Al₂O₃, SiO₂, or hollow sphere silica. The scatterer SP may include any one among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include a corresponding one of the base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, and/or a metal thin film for securing light transmittance, etc. In some embodiments, the barrier layers BFL1 and BFL2 may further include an organic film. The barrier layers BFL1 and BFL2 may be formed of a single layer or a plurality of layers.

In the display apparatus DD-a of an embodiment, the color filter layer CFL may be disposed on the light control layer CCL. For example, the color filter layer CFL may be directly disposed on the light control layer CCL. In this case, the barrier layer BFL2 may not be provided.

The color filter layer CFL may include color filters CF1, CF2, and CF3. The first to third filters CF1, CF2, and CF3 may be disposed corresponding to the red light emitting region PXA-R, the green light emitting region PXA-G, and the blue light emitting region PXA-B, respectively.

The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In some embodiments, the embodiment of the present disclosure is not limited thereto, and the third filter CF3 may not include (e.g., may exclude) any pigment or dye. The third filter CF3 may include a polymeric photosensitive resin and may not include (e.g., may exclude) any pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated but may be provided as one filter.

Although not illustrated, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3.

A base substrate BL may be disposed on the color filter layer CFL. The base substrate BL may be a member which provides a base surface in which the color filter layer CFL, the light control layer CCL, and/or the like are disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike the configuration illustrated, in an embodiment, the base substrate BL may not be provided.

FIG. 8 is a cross-sectional view illustrating a portion of a display apparatus according to an embodiment. In the display apparatus DD-TD of an embodiment, the light emitting device ED-BT may include a plurality of light emitting structures OL-B1, OL-B2, and OL-B3. The light emitting device ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR disposed with the emission layer EML (FIG. 7) located therebetween.

For example, the light emitting device ED-BT included in the display apparatus DD-TD of an embodiment may be a light emitting device having a tandem structure and including a plurality of emission layers.

In an embodiment illustrated in FIG. 8, all light (e.g., light beams) respectively emitted from the light emitting structures OL-B1, OL-B2, and OL-B3 may be blue light. However, the embodiment of the present disclosure is not limited thereto, and the light (e.g., light beams) respectively emitted from the light emitting structures OL-B1, OL-B2, and OL-B3 may have wavelength ranges different from each other. For example, the light emitting device ED-BT including the plurality of light emitting structures OL-B1, OL-B2, and OL-B3 which emit light (e.g., light beams) having wavelength ranges different from each other may be to emit white light.

Charge generation layers CGL1 and CGL2 may be respectively disposed between two of the neighboring light emitting structures OL-B1, OL-B2, and OL-B3. The charge generation layers CGL1 and CGL2 may include a p-type or kind charge (e.g., P-charge) generation layer and/or an n-type or kind charge (e.g., N-Charge) generation layer.

At least one among the light emitting structures OL-B1, OL-B2, and OL-B3 included in the display apparatus DD-TD of an embodiment may include the above-described first compound of an embodiment. For example, at least one among the plurality of emission layers included in the light emitting device ED-BT may include at least one among the first to fourth compounds as described above.

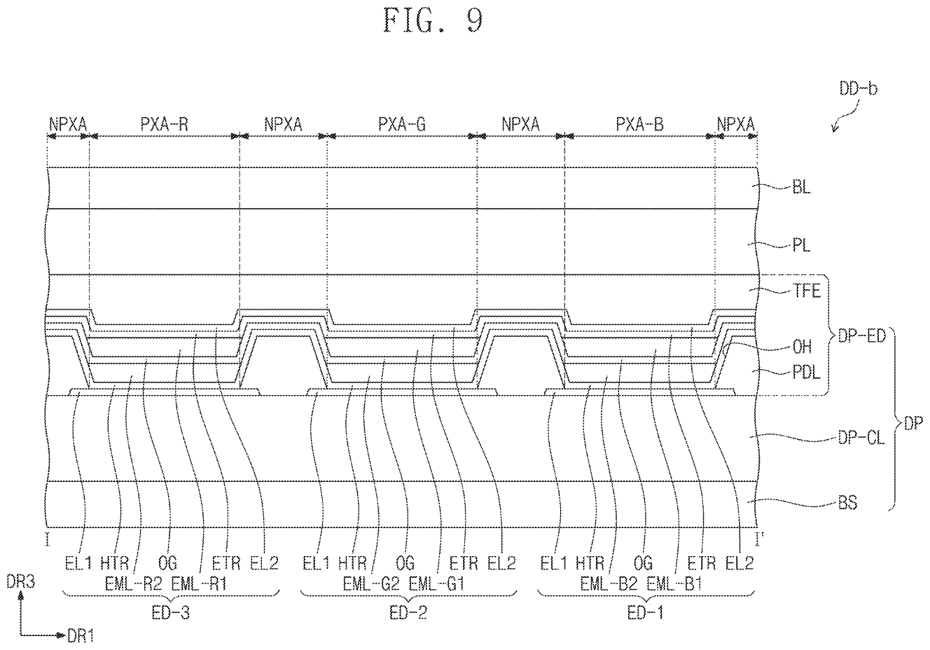

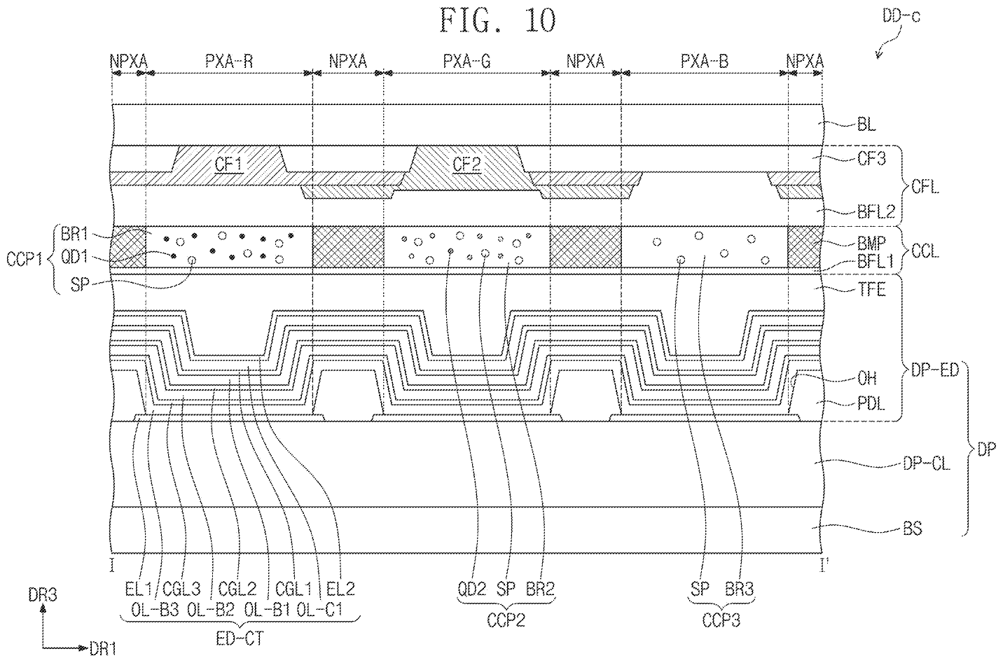

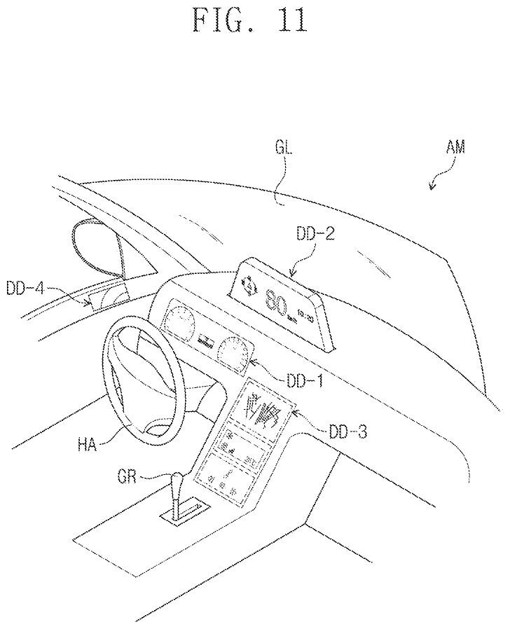

FIG. 9 is a cross-sectional view illustrating a display apparatus according to an embodiment of the present disclosure. FIG. 10 is a cross-sectional view illustrating a display apparatus according to an embodiment of the present disclosure.

Referring to FIG. 9, the display apparatus DD-b according to an embodiment may include light emitting devices ED-1, ED-2, and ED-3 in which two emission layers are stacked. Compared with the display apparatus DD of an embodiment illustrated in FIG. 2, an embodiment illustrated in FIG. 9 has a difference in that the first to third light emitting devices ED-1, ED-2, and ED-3 each include two emission layers stacked in the thickness direction. In each of the first to third light emitting devices ED-1, ED-2, and ED-3, the two emission layers may be to emit light in substantially the same wavelength region.

The first light emitting device ED-1 may include a first red emission layer EML-R₁ and a second red emission layer EML-R₂. The second light emitting device ED-2 may include a first green emission layer EML-G1 and a second green emission layer EML-G2. In some embodiments, the third light emitting device ED-3 may include a first blue emission layer EML-B1 and a second blue emission layer EML-B2. An emission auxiliary part OG may be disposed between the first red emission layer EML-R₁ and the second red emission layer EML-R₂, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked in the stated order. The emission auxiliary part OG may be provided as a common layer in the whole of the first to third light emitting devices ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R₁, the first green emission layer EML-G1, and the first blue emission layer EML-B1 may be disposed between the electron transport region ETR and the emission auxiliary part OG. The second red emission layer EML-R₂, the second green emission layer EML-G2, and the second blue emission layer EML-B2 may be disposed between the emission auxiliary part OG and the hole transport region HTR.

For example, the first light emitting device ED-1 may include the first electrode EL1, the hole transport region HTR, the second red emission layer EML-R₂, the emission auxiliary part OG, the first red emission layer EML-R₁, the electron transport region ETR, and the second electrode EL2 that are sequentially stacked in the stated order. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be disposed on the display device layer DP-ED. The optical auxiliary layer PL may include a polarizing layer. The optical auxiliary layer PL may be disposed on the display panel DP and control reflected light in the display panel DP due to external light. Unlike the configuration illustrated, the optical auxiliary layer PL in the display apparatus according to an embodiment may not be provided.

At least one emission layer included in the display apparatus DD-b of an embodiment illustrated in FIG. 9 may include the above-described first compound of an embodiment. For example, in an embodiment, at least one of the first blue emission layer EML-B1 or the second blue emission layer EML-B2 may include at least one among the first to fourth compounds as described above.

Unlike FIGS. 8 and 9, FIG. 10 illustrates that a display apparatus DD-c includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light (e.g., light beams) in different wavelength regions.

The charge generation layers CGL1, CGL2, and CGL3 disposed between adjacent light emitting structures OL-B1, OL-B2, OL-B3, and OL-C1 may include a p-type or kind charge generation layer and/or an n-type or kind charge generation layer.

At least one among the light emitting structures OL-B1, OL-B2, OL-B3, and OL-C1 included in the display apparatus DD-c of an embodiment may include the above-described first compound of an embodiment. For example, in an embodiment, at least one among the first to third light emitting structures OL-B1, OL-B2, and OL-B3 may include at least one among the first to fourth compounds as described above.

In an embodiment, the electronic apparatus may include a display apparatus including a plurality of light emitting devices, and a control part which controls the display apparatus. The electronic apparatus of an embodiment may be a device that is activated according to an electrical signal. The electronic apparatus may include display apparatuses of one or more suitable embodiments. For example, the electronic apparatus may include not only large-sized electronic apparatuses such as a television set, a monitor, and/or an outdoor billboard but also include small- and medium-sized electronic apparatuses such as a personal computer, a laptop computer, a personal digital terminal, a display apparatus for a vehicle, a game console, a portable electronic device, and/or a camera.

FIG. 11 is a view illustrating a vehicle AM in which first to fourth display apparatuses DD-1, DD-2, DD-3, and DD-4 are disposed. At least one among the first to fourth display apparatuses DD-1, DD-2, DD-3, and DD-4 may include the same configuration as the display apparatuses DD, DD-TD, DD-a, DD-b, and DD-c as described with reference to FIGS. 1, 2, and 7 to 10.

FIG. 11 illustrates a vehicle AM, but this is an example, and the first to fourth display apparatuses DD-1, DD-2, DD-3, and DD-4 may be disposed in another transportation vehicles such as bicycles, motorcycles, trains, ships, and/or airplanes. In some embodiments, at least one among the first to fourth display apparatuses DD-1, DD-2, DD-3, and DD-4 including the same configuration as the display apparatuses DD, DD-TD, DD-a, DD-b, and DD-c of an embodiment may be employed in a personal computer, a laptop computer, a personal digital terminal, a game console, a portable electronic device, a television, a monitor, an outdoor billboard, and/or the like. In addition, these are merely provided as embodiments, and thus the first to fourth display apparatuses DD-1, DD-2, DD-3, and DD-4 may be employed in other electronic apparatuses unless departing from the present disclosure.

At least one among the first to fourth display apparatuses DD-1, DD-2, DD-3, and DD-4 may include the light emitting device ED of an embodiment as described with reference to FIGS. 3 to 6. The light emitting device ED of an embodiment may include a heterocyclic compound of an embodiment. At least one among the first to fourth display apparatuses DD-1, DD-2, DD-3, and DD-4 may include the light emitting device ED including a heterocyclic compound of an embodiment, thereby improving a display service life.

Referring to FIG. 11, the vehicle AM may include a steering wheel HA and a gear GR for driving the vehicle AM. In some embodiments, the vehicle AM may include a front window GL disposed so as to face the driver.

The first display apparatus DD-1 may be disposed in a first region overlapping the steering wheel HA. For example, the first display apparatus DD-1 may be a digital cluster for displaying a first information of the vehicle AM. The first information may include a first scale for indicating a driving speed of the vehicle AM, a second scale for indicating an engine speed (that is, revolutions per minute (RPM)), an image for indicating a fuel state, etc. A first scale and a second scale may be indicated as a digital image.

The second display apparatus DD-2 may be disposed in a second region facing the driver's seat and overlapping the front window GL. The driver's seat may be a seat in or over which the steering wheel HA is disposed. For example, the second display apparatus DD-2 may be a head up display (HUD) for displaying a second information of the vehicle AM. The second display apparatus DD-2 may be optically transparent. The second information may include digital numbers for indicating a driving speed, and may further include information such as the current time. Unlike the configuration illustrated, the second information of the second display apparatus DD-2 may be projected to the front window GL to be displayed.

The third display apparatus DD-3 may be disposed in a third region adjacent to the gear GR. For example, the third display apparatus DD-3 may be disposed between the driver's seat and the passenger seat and may be a center information display (CID) for a vehicle for displaying a third information. The passenger seat may be a seat spaced apart from the driver's seat with the gear GR disposed therebetween. The third information may include information about traffic (e.g., navigation information), playing music and/or radio and/or a video (or an image), temperatures inside the vehicle AM, etc.

The fourth display apparatus DD-4 may be spaced apart from the steering wheel HA and the gear GR, and may be disposed in a fourth region adjacent to the side of the vehicle AM. For example, the fourth display apparatus DD-4 may be a digital side-view mirror for displaying a fourth information. The fourth display apparatus DD-4 may display an image outside the vehicle AM taken by a camera module CM disposed outside the vehicle AM. The fourth information may include an image outside the vehicle AM.

The above-described first to fourth information may be examples, and the first to fourth display apparatuses DD-1, DD-2, DD-3, and DD-4 may further display information about the inside and outside of the vehicle AM. The first to fourth information may include different information. However, the embodiment of the present disclosure is not limited thereto, and a part of the first to fourth information may include the same information as one another.

Hereinafter, with reference to Examples and Comparative Examples, a compound according to an embodiment of the present disclosure and a light emitting device of an embodiment will be described in more detail. In addition, Examples described below are only illustrations to assist the understanding of the present disclosure, and the scope of the present disclosure is not limited thereto.

### SYNTHESIS EXAMPLES

A first compound according to an example of the present disclosure may be synthesized, for example, as follows. However, synthesis of the compounds according to examples of the present disclosure is not limited thereto.

### 1. Synthesis of Compound AH1

### Synthesis of Intermediate AH1-1

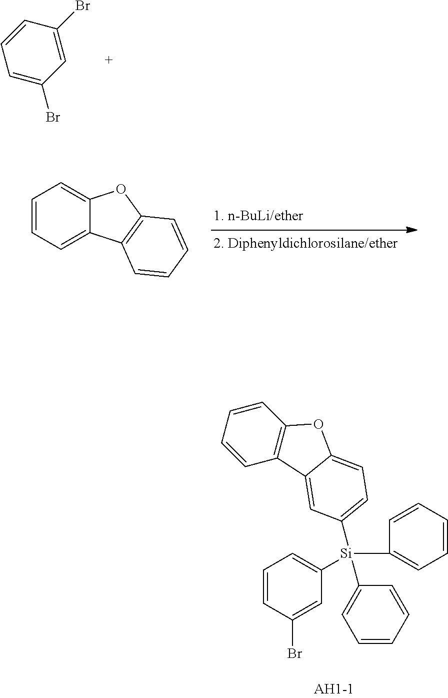 [SMILES: Brc1cccc(Br)c1 ; c1ccc2c(c1)oc1ccccc12 ; Brc1cccc([Si](c2ccccc2)(c2ccccc2)c2ccc3oc4ccccc4c3c2)c1]

Dibenzo[b,d]furan (4.98 g, 29.6 mmol) was added in ether (50 mL), and then n-butyllithium added in hexane (2.5 M, 9.48 mL, 23.70 mmol) was slowly dropped thereto at about −78° C. Then, the mixture was stirred at room temperature for about 20 hours to obtain a dibenzo[b,d]furan-4-yl lithium solution. Further, 1,3-dibromobenzene (2.56 mL, 21.20 mmol) was added in ether (50 mL), and n-butyllithium solution in hexane (2.5 M, 9.48 mL, 23.70 mmol) was slowly dropped thereto at about −78° C., followed by stirring for about 3.5 hours. Then, dichlorodiphenylsilane (4.88 mL, 23.70 mmol) dissolved in ether (50 mL) was added to the reaction solution at about −78° C. The resultant mixture was stirred at about −78° C. for about 2 hours to maintain the reaction, and then the dibenzo[b,d]furan-4-yl lithium solution was slowly added thereto. This reaction was performed at room temperature overnight, extraction was then performed with water and ether, and the resulting product was dried over Na₂SO₄. The solvent was removed, and the residue was purified by column chromatography utilizing a solution of hexane/dichloromethane (9/1, v/v) to obtain Intermediate AH1-1. (m/z: 506.05, yield: 18.3%)

### Synthesis of Compound AH1

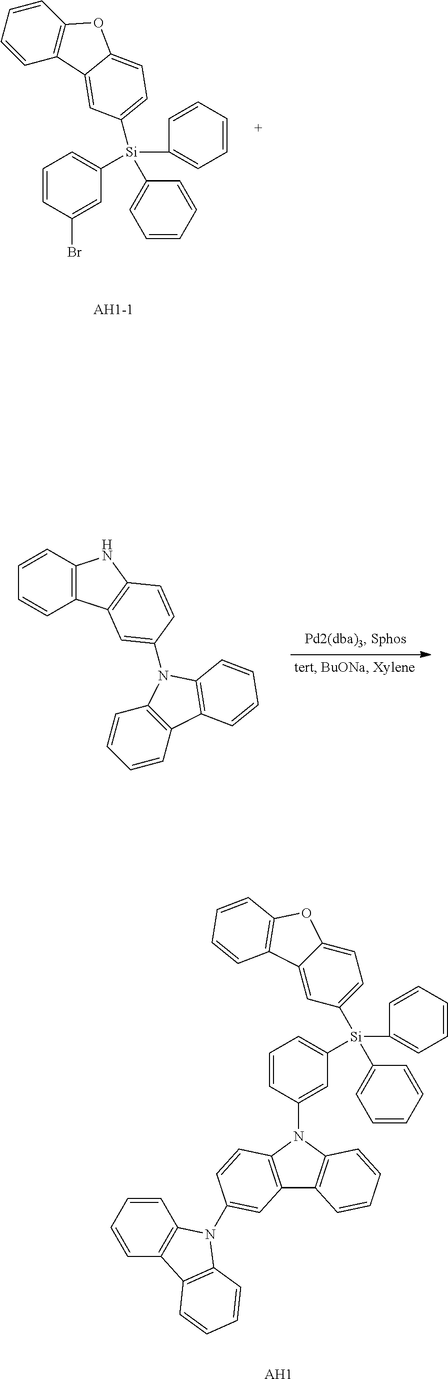 [SMILES: Brc1cccc([Si](c2ccccc2)(c2ccccc2)c2ccc3oc4ccccc4c3c2)c1 ; c1ccc2c(c1)[nH]c1ccc(-n3c4ccccc4c4ccccc43)cc12 ; c1ccc([Si](c2ccccc2)(c2cccc(-n3c4ccccc4c4cc(-n5c6ccccc6c6ccccc65)ccc43)c2)c2ccc3oc4ccccc4c3c2)cc1 ; "AH1"]

Intermediate AH1-1 ((3-bromophenyl)(dibenzo[b,d]furan-2-yl)diphenylsilane) (2.75 g, 5.44 mmol), 9H-3,9′-bicarbazole (1.81 g, 5.44 mmol), Pd₂(dba)₃ (0.10 g, 0.10 mmol), Sphos (0.089 g, 0.22 mmol), and sodium tert-butoxide (1.05 g, 10.88 mmol) were stirred in m-xylene (50 mL) under reflux at about 140° C. overnight. After cooling to room temperature, the resultant mixture was passed through short plug of Celite®, and then washed with dichloromethane. Further, the resulting product was purified by column chromatography utilizing a solution of hexane/dichloromethane (7.5/2.5, v/v) to obtain Compound AH1. (m/z: 756.26, yield: 35%)

### 2. Synthesis of Compound AH20

### Synthesis of Intermediate AH20-1

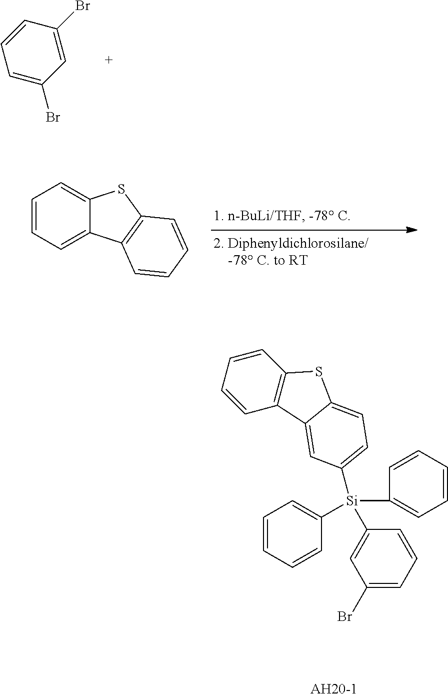 [SMILES: Brc1cccc(Br)c1 ; c1ccc2c(c1)sc1ccccc12 ; Brc1cccc([Si](c2ccccc2)(c2ccccc2)c2ccc3sc4ccccc4c3c2)c1]

Dibenzo[b,d]thiophene (4.80 g, 26.1 mmol) was added in ether (70 mL), and then n-butyllithium added in hexane (2.5 M, 9.48 mL, 23.70 mmol) was slowly dropped thereto at about −78° C. Then, the mixture was stirred at room temperature for about 2 hours to obtain a dibenzo[b,d]thiophen-4-yl lithium solution. Further, 1,3-dibromobenzene (2.56 mL, 21.20 mmol) was added in ether (70 mL), and n-butyllithium solution in hexane (2.5 M, 9.48 mL, 23.70 mmol) was slowly dropped thereto at about −78° C., followed by stirring for about 3.5 hours. Then, dichlorodiphenylsilane (4.88 mL, 23.70 mmol) dissolved in ether (70 mL) was added to the reaction solution at about −78° C. The resultant mixture was stirred at about −78° C. for about 2 hours to maintain the reaction, and then the dibenzo[b,d]thiophen-4-yl lithium solution was slowly added thereto. This reaction was performed at room temperature overnight, extraction was then performed with water and ether, and the resulting product was dried over Na₂SO₄. The solvent was removed, and the residue was purified by column chromatography utilizing a solution of hexane/dichloromethane (9/1, v/v) to obtain Intermediate AH20-1. (m/z: 521.55, yield: 25%)

### Synthesis of Compound AH20

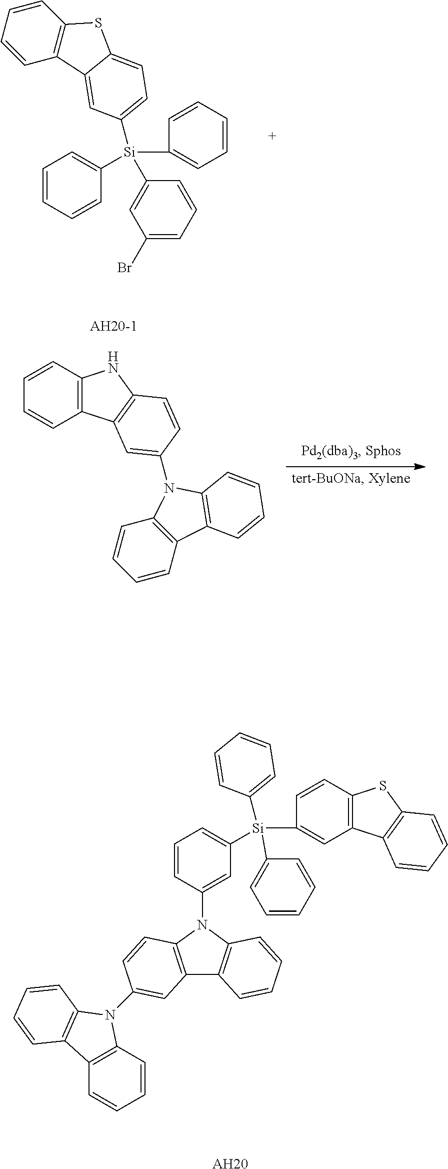 [SMILES: Brc1cccc([Si](c2ccccc2)(c2ccccc2)c2ccc3sc4ccccc4c3c2)c1 ; c1ccc2c(c1)[nH]c1ccc(-n3c4ccccc4c4ccccc43)cc12 ; c1ccc([Si](c2ccccc2)(c2cccc(-n3c4ccccc4c4cc(-n5c6ccccc6c6ccccc65)ccc43)c2)c2ccc3sc4ccccc4c3c2)cc1 ; "AH20"]

Intermediate AH20-1 ((3-bromophenyl)(dibenzo[b,d]thiophen-4-yl)diphenylsilane) (3.4 g, 6.52 mmol), 9H 3,9′-bicarbazole (2.4 g, 7.17 mmol), Pd₂(dba)₃ (0.119 g, 0.130 mmol), Sphos (0.107 g, 0.261 mmol), and sodium tert-butoxide (1.253 g, 13.04 mmol) were stirred in m-xylene (50 mL) under reflux at about 140° C. overnight. After cooling to room temperature, the resultant mixture was passed through short plug of Celite®, and then washed with dichloromethane. Further, the resulting product was purified by column chromatography utilizing a solution of hexane/dichloromethane (7.5/2.5, v/v) to obtain Compound AH20. (m/z: 775.25, yield: 45%)

### First Compounds

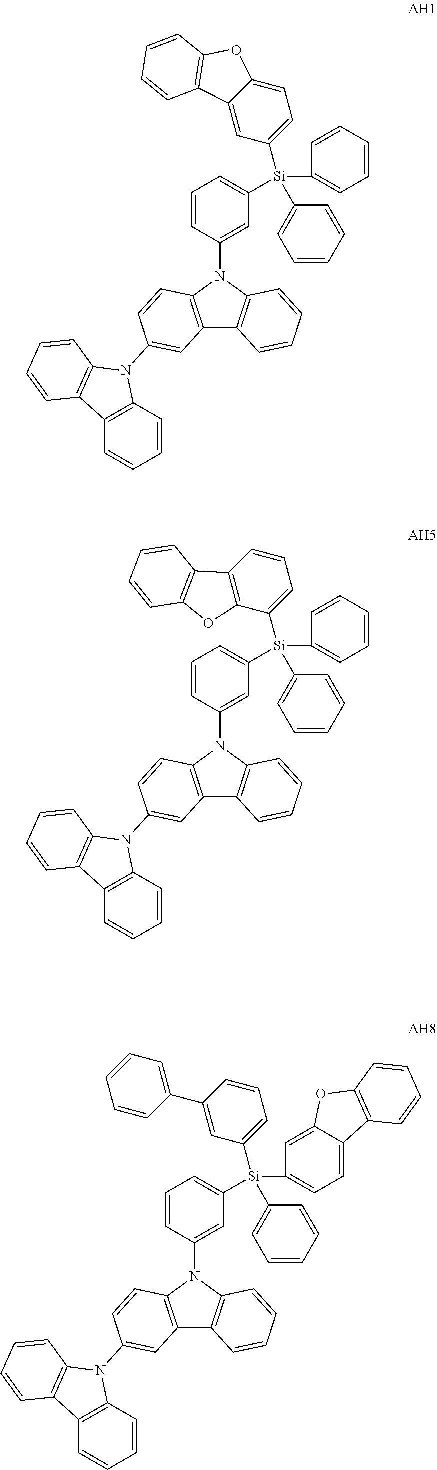 [SMILES: c1ccc([Si](c2ccccc2)(c2cccc(-n3c4ccccc4c4cc(-n5c6ccccc6c6ccccc65)ccc43)c2)c2ccc3oc4ccccc4c3c2)cc1 ; c1ccc([Si](c2ccccc2)(c2cccc(-n3c4ccccc4c4cc(-n5c6ccccc6c6ccccc65)ccc43)c2)c2cccc3c2oc2ccccc23)cc1 ; c1ccc(-c2cccc([Si](c3ccccc3)(c3cccc(-n4c5ccccc5c5cc(-n6c7ccccc7c7ccccc76)ccc54)c3)c3ccc4c(c3)oc3ccccc34)c2)cc1]

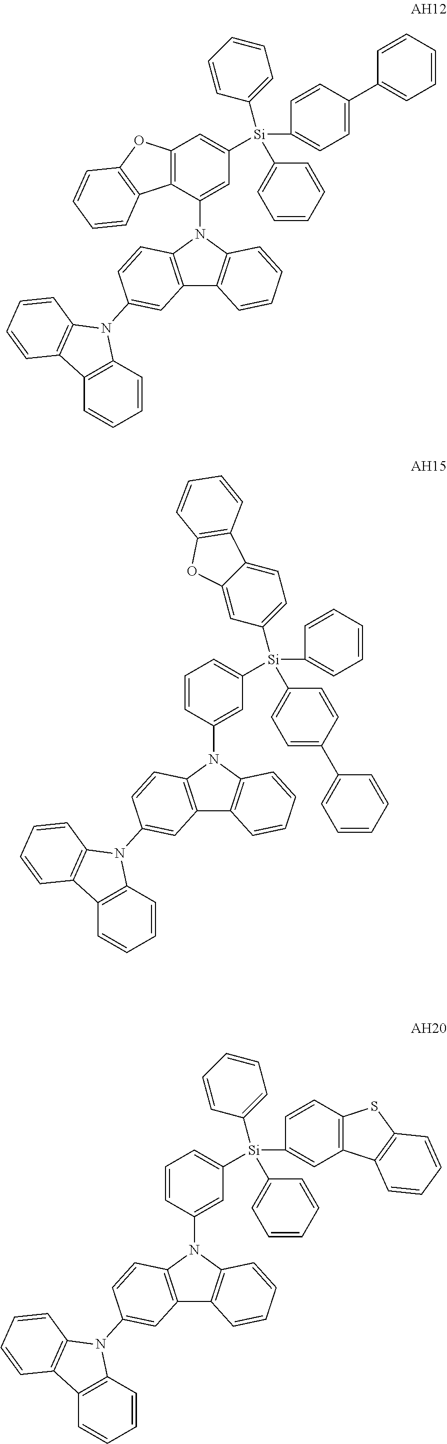 [SMILES: c1ccc(-c2ccc([Si](c3ccccc3)(c3ccccc3)c3cc(-n4c5ccccc5c5cc(-n6c7ccccc7c7ccccc76)ccc54)c4c(c3)oc3ccccc34)cc2)cc1 ; c1ccc(-c2ccc([Si](c3ccccc3)(c3cccc(-n4c5ccccc5c5cc(-n6c7ccccc7c7ccccc76)ccc54)c3)c3ccc4c(c3)oc3ccccc34)cc2)cc1 ; c1ccc([Si](c2ccccc2)(c2cccc(-n3c4ccccc4c4cc(-n5c6ccccc6c6ccccc65)ccc43)c2)c2ccc3sc4ccccc4c3c2)cc1]

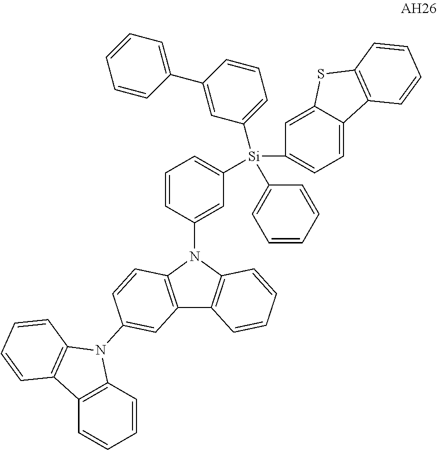 [SMILES: c1ccc(-c2cccc([Si](c3ccccc3)(c3cccc(-n4c5ccccc5c5cc(-n6c7ccccc7c7ccccc76)ccc54)c3)c3ccc4c(c3)sc3ccccc34)c2)cc1]

### Second Compounds

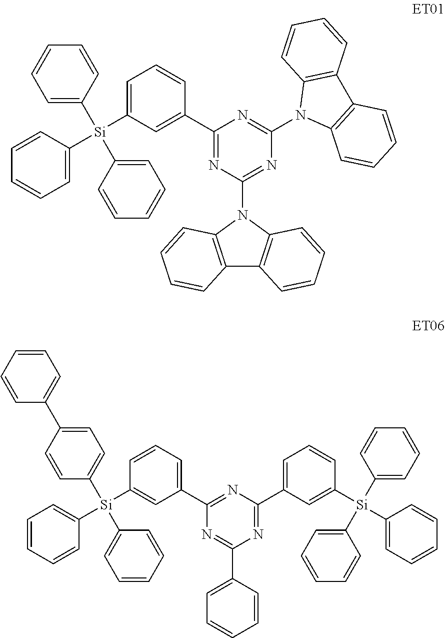 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2ccc([Si](c3ccccc3)(c3ccccc3)c3cccc(-c4nc(-c5ccccc5)nc(-c5cccc([Si](c6ccccc6)(c6ccccc6)c6ccccc6)c5)n4)c3)cc2)cc1]

### Third Compounds

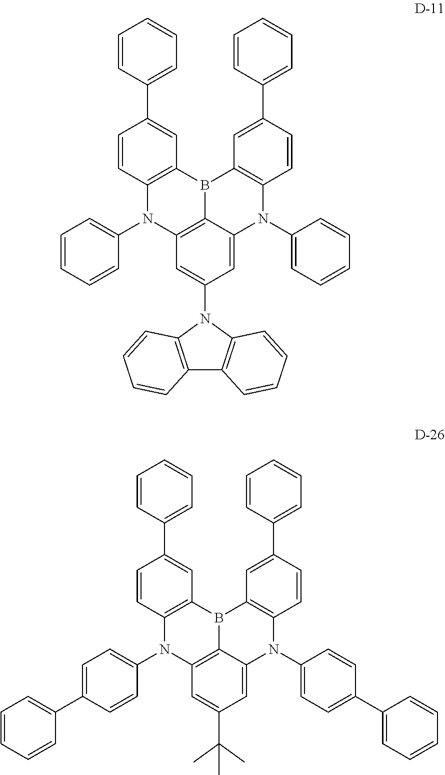 [SMILES: c1ccc(-c2ccc3c(c2)B2c4cc(-c5ccccc5)ccc4N(c4ccccc4)c4cc(-n5c6ccccc6c6ccccc65)cc(c42)N3c2ccccc2)cc1 ; CC(C)(C)c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1]

### Fourth Compounds

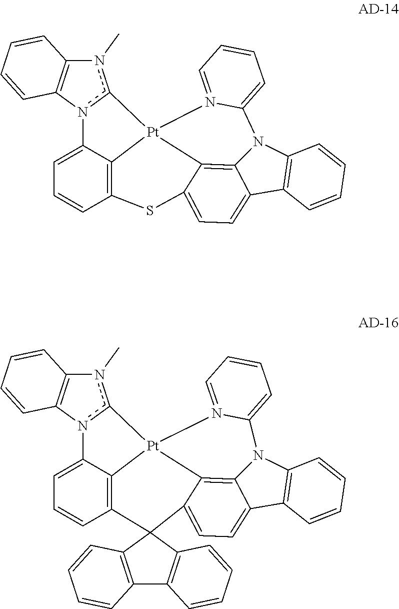

### Comparative Example Compounds

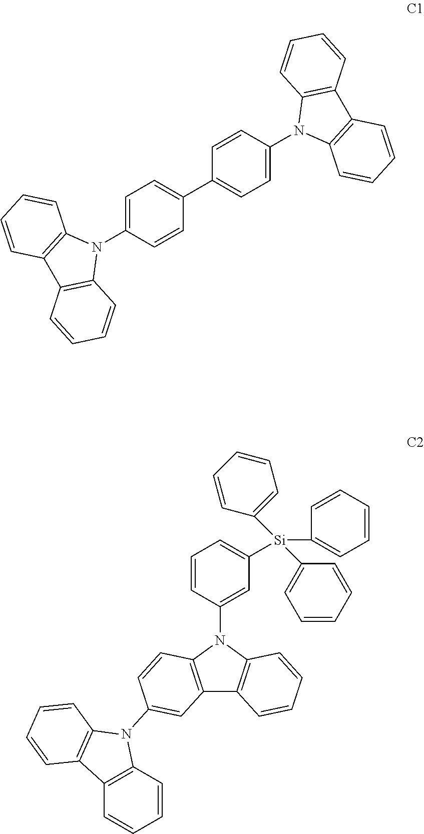 [SMILES: c1ccc2c(c1)c1ccccc1n2-c1ccc(-c2ccc(-n3c4ccccc4c4ccccc43)cc2)cc1 ; c1ccc([Si](c2ccccc2)(c2ccccc2)c2cccc(-n3c4ccccc4c4cc(-n5c6ccccc6c6ccccc65)ccc43)c2)cc1]

### Manufacture of Light Emitting Devices

In the light emitting devices of Examples and Comparative Examples, a glass substrate (made by Corning Co.), on which an ITO electrode of about 15 Ω/cm² (about 1200 Å) is formed as an anode, was cut to a size of about 50 mm×50 mm×0.7 mm, cleansed by ultrasonic waves utilizing isopropyl alcohol and pure water for about five minutes each, and then irradiated with ultraviolet rays for about 30 minutes and exposed to ozone and cleansed. The glass substrate was installed on a vacuum deposition apparatus.

NPD was deposited on the upper portion of the anode to form a 100 Å-thick hole injection layer, TCTA was then deposited on the upper portion of the hole injection layer to form a 600 Å-thick hole transport layer, and CzSi was then deposited on the upper portion of the hole transport layer to form a 50 Å-thick emission-auxiliary layer.

Then, a host compound in which the first compound and the second compound according to an embodiment were mixed in an amount of about 60:40, the fourth compound, and the third compound were co-deposited in a weight ratio of about 80:19:1 to form a 310 Å-thick emission layer, and TSPO1 was deposited on the upper portion of the emission layer to form a 50 Å-thick hole blocking layer. Then, TPBI was deposited on the upper portion of the hole blocking layer to form a 310 Å-thick electron transport layer, and then Yb was deposited on the upper portion of the electron transport layer to form a 15 Å-thick electron injection layer. Next, Mg was deposited on the upper portion of the electron injection layer to form an 800 Å-thick cathode, and then P4 was deposited on the cathode to form a 600 Å-thick capping layer, thereby completing the manufacturing of a light emitting device. Each layer was formed by a vacuum deposition method.

Compounds utilized for manufacturing the light emitting devices of Examples and Comparative Examples are disclosed below. The materials below were utilized to manufacture the devices by subjecting commercial products to sublimation purification.

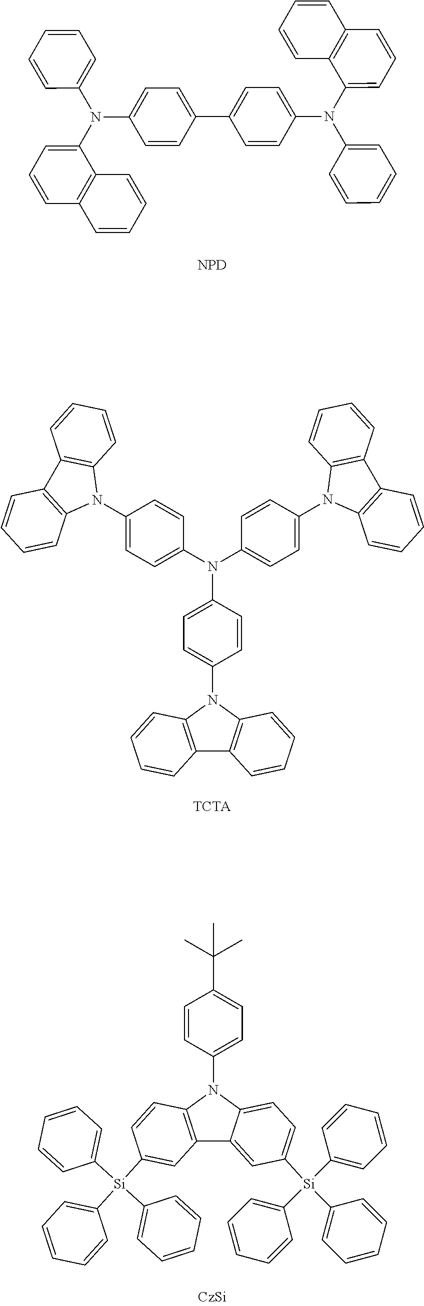 [SMILES: c1ccc(N(c2ccc(-c3ccc(N(c4ccccc4)c4cccc5ccccc45)cc3)cc2)c2cccc3ccccc23)cc1 ; "NPD" ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1]

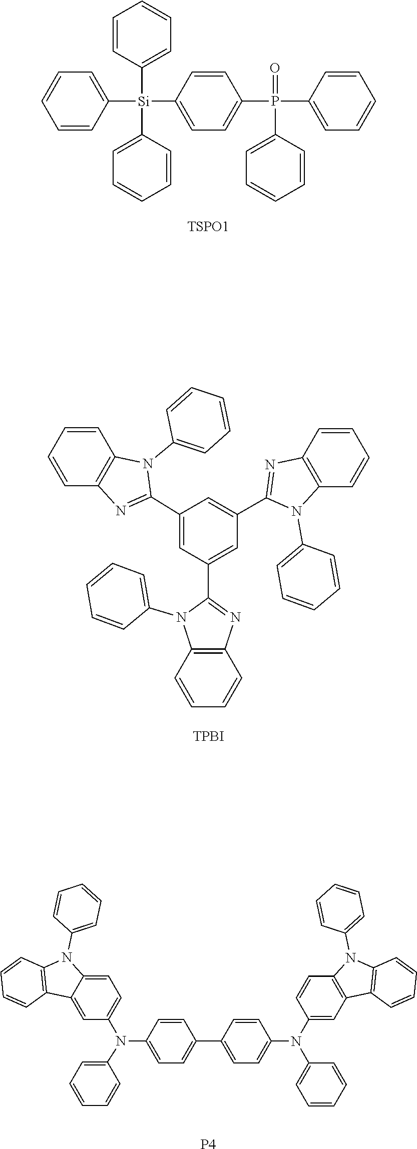

### Evaluation of Light Emitting Device Characteristics

Characteristics of the manufactured light emitting devices were evaluated utilizing a brightness light distribution characteristics measurement device. To evaluate characteristics of the light emitting devices according to Examples and Comparative Examples, driving voltage, brightness, efficiency, and emission wavelength were measured (for each of the examples). Table 1 shows a luminous efficiency at a current density of 10 mA/cm² and a brightness of 1,000 cd/m² with respect to the manufactured light emitting devices. In addition, a brightness spectrum in Examples and Comparative Examples was measured with a spectroradiometer. An emission peak, i.e., the maximum emission wavelength was measured from the measured brightness spectrum.

Example 1 to Example 7 listed in Table 1 are examples of the light emitting devices having a combination of the first compound represented by Formula 1, the second compound represented by Formula 2, the third compound represented by Formula 3, and the fourth compound represented by Formula 4. Example 8 is an example of the light emitting device having a combination of the first compound represented by Formula 1, the second compound represented by Formula 2, and the third compound represented by Formula 3. In Comparative Example 1, Comparative Example Compound C1 was utilized as a host material, and the third compound was utilized as a dopant material. In Comparative Example 2, Comparative Example Compound C2 was provided utilized as a host material, and the third compound was utilized as a dopant material. In Comparative Example 3, Comparative Example Compound C2 was utilized as a host material, and the fourth compound (AD-14) was utilized as a dopant material. In Comparative Example 4, a mixture of Comparative Example Compound C2 and the second compound (ET06) was utilized as a host material, and the fourth compound (AD-14) was utilized as a dopant material. In Comparative Examples 5 and 6, a mixture of Comparative Example Compound C2 and the second compound (ET06 or ET15) was utilized as a host material, and the fourth compound AD-14 was utilized as a sensitizer, and the third compound (D-26) was utilized as a dopant material. For example, Comparative Examples 5 and 6 have a difference in that Comparative Example Compound C2 was utilized as a hole transporting host material rather than the first compound of an example as compared with Examples 1 to 7. In Comparative Example 7, a mixture of the first compound represented by Formula 1 (AH5) and the second compound represented by Formula 2 (ET06) was utilized as a host material, and the fourth compound (AD-14) was utilized as a dopant material. In Comparative Example 8, the first compound represented by Formula 1 (AH5) was utilized as a host material, and the fourth compound represented by Formula 4 (AD-14) was utilized as a dopant material. In Comparative Example 8, the second compound represented by Formula 2 (ET06) was utilized as a host material, and the fourth compound represented by Formula 4 (AD-14) was utilized as a dopant material.

TABLE 1

| | | | | | Driving | | Luminous |
|---|---|---|---|---|---|---|---|
| | First | Second | Third | Fourth | voltage | Efficiency | wavelength |
| | compound | compound | compound | compound | (V) | (Cd/A) | (nm) |
| Example 1 | AH5 | ET06 | D-26 | AD-14 | 4.7 | 45 | 463 |
| Example 2 | AH8 | ET06 | D-26 | AD-14 | 4.6 | 50 | 463 |
| Example 3 | AH12 | ET08 | D-26 | AD-14 | 4.5 | 65 | 462 |
| Example 4 | AH15 | ET08 | D-26 | AD-14 | 4.5 | 70 | 462 |
| Example 5 | AH20 | ET15 | D-26 | AD-14 | 4.4 | 75 | 462 |
| Example 6 | AH26 | ET15 | D-26 | AD-14 | 4.5 | 65 | 461 |
| Example 7 | AH1 | ET01 | D-11 | AD-16 | 4.9 | 45 | 462 |
| Example 8 | AH5 | ET06 | D-26 | — | 5.5 | 50 | 461 |
| Comparative | Comparative | — | D-26 | — | 5.7 | 15 | 462 |
| Example 1 | Example | | | | | | |
| | Compound | | | | | | |
| | C1 | | | | | | |
| Comparative | Comparative | — | D-26 | — | 5.8 | 20 | 462 |
| Example 2 | Example | | | | | | |
| | Compound | | | | | | |
| | C2 | | | | | | |
| Comparative | Comparative | — | — | AD-14 | 5.3 | 9 | 465 |
| Example 3 | Example | | | | | | |
| | Compound | | | | | | |
| | C2 | | | | | | |
| Comparative | Comparative | ET06 | — | AD-14 | 5.5 | 30 | 465 |
| Example 4 | Example | | | | | | |
| | Compound | | | | | | |
| | C2 | | | | | | |
| Comparative | Comparative | ET06 | D-26 | AD-14 | 5.1 | 40 | 462 |
| Example 5 | Example | | | | | | |
| | Compound | | | | | | |
| | C2 | | | | | | |
| Comparative | Comparative | ET15 | D-26 | AD-14 | 5.0 | 42 | 462 |
| Example 6 | Example | | | | | | |
| | Compound | | | | | | |
| | C2 | | | | | | |
| Comparative | AH5 | ET06 | — | AD-14 | 5.0 | 35 | 463 |
| Example 7 | | | | | | | |
| Comparative | AH5 | — | — | AD-14 | 4.8 | 20 | 463 |
| Example 8 | | | | | | | |
| Comparative | — | ET06 | — | AD-14 | 5.6 | 12 | 465 |
| Example 9 | | | | | | | |

Referring to the results of Table 1, it may be confirmed that Examples (each) including the first compound, as the emission layer according to an example have improved efficiencies of light emitting devices as compared with Comparative Examples.

Referring to the results of Examples 1 to 7 and Comparative Examples 5 and 6, it may be seen that Examples exhibited excellent or suitable luminous efficiency as compared with Comparative Examples 5 and 6. Comparative Examples 5 and 6 include a mixed host including a hole transporting host and an electron transporting host, a delayed fluorescent dopant, and a sensitizer similar to Examples, but led to deterioration in luminous efficiency as compared with Examples. Comparative Example Compound C2 included in Comparative Examples 5 and 6 has a silicon atom and a structure in which four benzene rings are linked to the silicon atom and the first substituent is introduced to one benzene ring among the four benzene rings, but does not have a structure in which an additional benzene ring is fused via a heteroatom proposed by the present disclosure, and thus the hole transport characteristics deteriorated as compared with Example Compounds. Therefore, it may be confirmed that Comparative Examples 5 and 6 utilizing Comparative Example Compound C2 as a hole transporting host have deterioration in the luminous efficiency as compared with Examples.

The first compound included in Examples has a structure which includes a silicon atom and the first to fourth benzene rings substituted at the silicon atom, and in which the first substituent is introduced to a specific position of the first benzene ring, and the fifth benzene ring is fused via an oxygen atom or a sulfur atom to at least one benzene ring among the first to fourth benzene rings, and thus may have excellent or suitable hole transport characteristics and a high triplet energy level. Thus, when the first compound having such a structure is applied as a hole transporting host for the emission layer EML, high luminous efficiency may be achieved.

Referring to the results of Examples 1 to 8 and Comparative Examples 1 to 4 and 7, it may be seen that Examples exhibited excellent or suitable luminous efficiency. For example, it may be confirmed that the case of including both (e.g., simultaneously) a mixed host material of the first compound represented by Formula 1 and the second compound represented by Formula 2, and a dopant material represented by Formula 3 in the emission layer exhibited excellent or suitable device characteristics compared to Comparative Examples 1 and 2 including only one host material and the third compound, Comparative Example 3 including only one host material and the fourth compound, and Comparative Examples 4 and 7 including two host materials but not including the third compound. Further, it may be confirmed that Examples 1 to 8 showed the maximum luminous wavelength at about 463 nm or less, thereby emitting blue light. Similar to Examples 1 to 8, when the first compound having a high hole transport property, the second compound having a high electron transport property, and the third compound that is a thermally activated delayed fluorescence dopant are all included in the emission layer, excellent or suitable luminous efficiency characteristics may be exhibited.

Referring to the results of Examples and Comparative Examples 8 and 9, it may be confirmed that Examples exhibited excellent or suitable luminous efficiency as compared with Comparative Examples 8 and 9. For example, it may be confirmed that Examples including two host materials in the emission layer exhibited excellent or suitable device characteristics as compared with Comparative Examples 8 and 9 including only one host material. In addition, it may be confirmed that Comparative Examples 8 and 9 exhibited lower luminous efficiency than Comparative Example 7. It may be confirmed that Comparative Example 7 has improved device characteristics by including two host materials as compared with Comparative Examples 8 and 9 including a single host compound. Compared to the presence of the first compound alone and the second compound alone, when the first compound and the second compound coexist together to form an exciplex, a new energy level is formed, and in this case, the gap between excited singlet state (S1) and excited triplet state (T1), that is, ΔE_{S1-T1} is reduced. When the ΔE_{S1-T1} is reduced, a reverse intersystem crossing (RISC) process from the excited triplet state (T1) to the excited singlet state (S1) is increased, resulting in an increase in Forster resonance energy transfer (FRET). Accordingly, more electrons may be subjected to energy transfer from the host to the emission layer, thereby affecting an increase in the luminous efficiency. Also, compared to a single host, when forming an exciplex, the triplet-triplet annihilation is reduced, and thus a non-radiative process is reduced, thereby affecting an increase in the luminous efficiency.

The light emitting device of an embodiment may exhibit improved device characteristics with high efficiency.

The fused polycyclic compound of an embodiment may be included in the emission layer of the light emitting device to contribute to high efficiency of the light emitting device.

As used herein, the term “and/or” includes any and all combinations of one or more of the associated listed items. Throughout the disclosure, the expression “at least one of a, b or c”, “at least one selected from a, b, and c”, “at least one selected from the group consisting of a, b, and c”, “at least one among a, b, and c”, etc., indicates only a, only b, only c, both (e.g., simultaneously) a and b, both (e.g., simultaneously) a and c, both (e.g., simultaneously) b and c, all of a, b, and c, or variations thereof.

The use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light emitting device comprising:
a first electrode;
a second electrode facing the first electrode; and
a plurality of functional layers between the first electrode and the second electrode,
wherein at least one functional layer among the plurality of functional layers comprises a first compound represented by Formula 1, a second compound represented by Formula 2, and a third compound represented by Formula 3: 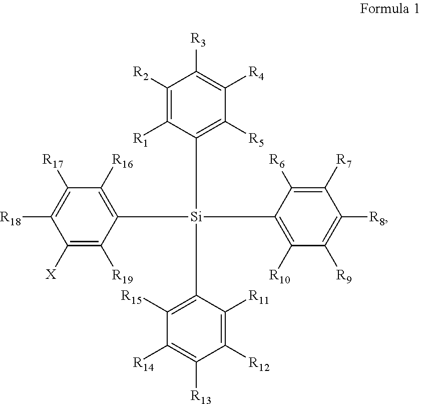
wherein, in Formula 1,
X is a substituted or unsubstituted aryl group having 6 to 30 ring-forming carbon atoms, or a substituted or unsubstituted heteroaryl group having 2 to 30 ring-forming carbon atoms,
R₁ to R₁₉ are each independently a hydrogen atom, a deuterium atom, a halogen atom, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and
at least one pair among adjacent pairs of R₁ to R₁₈ are positions to which a substituent represented by Formula C is fused: 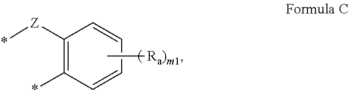
wherein, in Formula C,
^{—}* is a position which is fused to any adjacent one pair among R₁ to R₁₈ in Formula 1,
Z is O or S,
Rₐ is a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
m1 is an integer of 0 to 4, 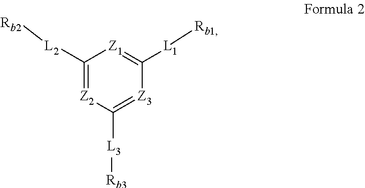
wherein, in Formula 2,
at least one among Z₁ to Z₃ is N, and any remainder thereof are each independently CR_{b4},
R_{b1} to R_{b3} are each independently a hydrogen atom, a deuterium atom, a halogen atom, a substituted or unsubstituted silyl group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
R_{b4} is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₁ to L₃ are each independently a substituted or unsubstituted arylene group having 6 to 30 ring-forming carbon atoms, or a substituted or unsubstituted heteroarylene group having 2 to 30 ring-forming carbon atoms, and 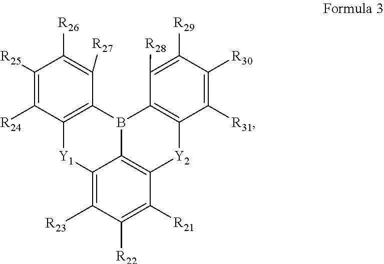
wherein, in Formula 3,
Y₁ and Y₂ are each independently NR₃₂ or O, and
R₂₁ to R₃₂ are each independently a hydrogen atom, a deuterium atom, a halogen atom, a cyano group, a nitro group, a substituted or unsubstituted amine group, a substituted or unsubstituted boron group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

2. The light emitting device of claim 1, wherein the plurality of functional layers comprise:
a hole transport region on the first electrode;
an emission layer on the hole transport region; and
an electron transport region on the emission layer, and
wherein the emission layer comprises the first compound, the second compound and the third compound.

3. The light emitting device of claim 1, wherein the plurality of functional layers comprise:
a hole injection layer on the first electrode;
a hole transport layer on the hole injection layer;
an emission layer on the hole transport layer; and
an electron transport region on the emission layer, and
wherein the hole transport layer comprises the first compound represented by Formula 1.

4. The light emitting device of claim 2, wherein the emission layer is to emit blue light.

5. The light emitting device of claim 1, wherein the first compound represented by Formula 1 is represented by Formula 1-1-1 or Formula 1-1-2: 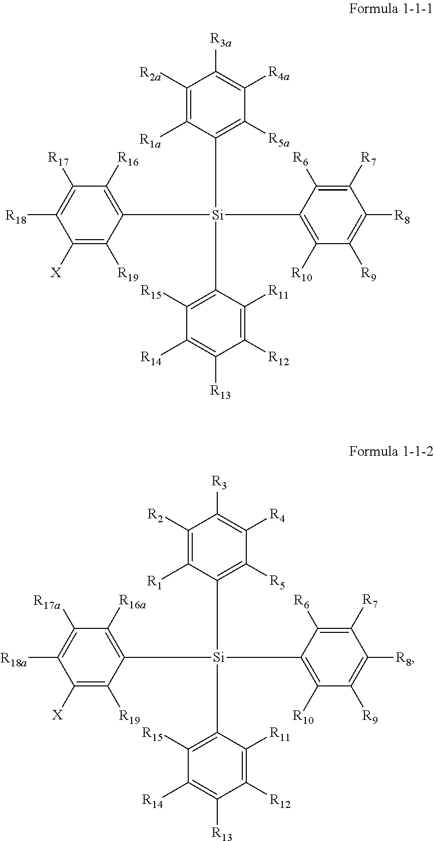
wherein, in Formula 1-1-1 and Formula 1-1-2,
R₁ₐ to R₅ₐ and R₁₆ₐ to R₁₈ₐ are each independently a hydrogen atom, a deuterium atom, a halogen atom, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
wherein, in Formula 1-1-1,
one adjacent pair among R₁ₐ to R₅ₐ are positions to which a substituent represented by Formula C is fused, and
wherein, in Formula 1-1-2,
one adjacent pair among R₁₆ₐ to R₁₈ₐ are positions to which a substituent represented by Formula C is fused, and
X and R₁ to R₁₉ are the same as defined in Formula 1.

6. The light emitting device of claim 1, wherein the first compound represented by Formula 1 is represented by any one among Formula 1-2-1 to Formula 1-2-5: 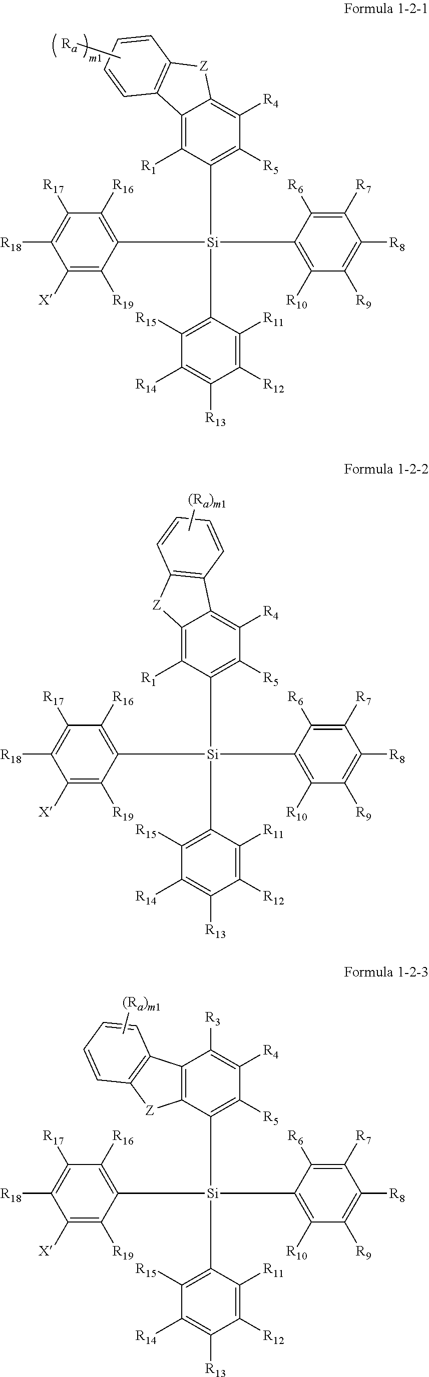 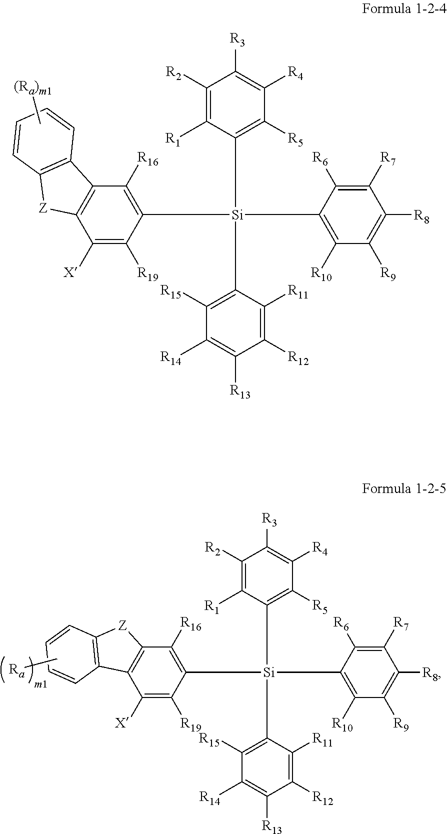
wherein, in Formula 1-2-1 to Formula 1-2-5,
X′ is represented by any one of Formula S-1 to Formula S-3: 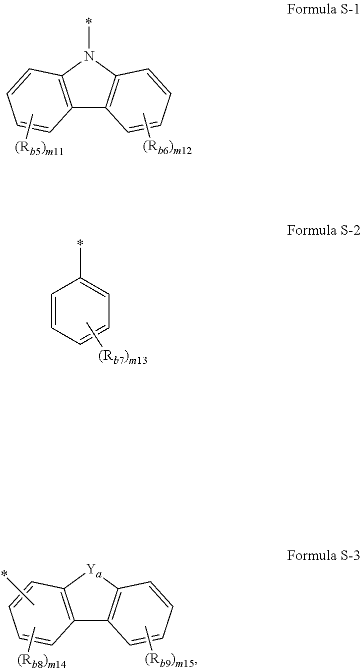
wherein, in Formula S-1 to Formula S-3,
Yₐ is NR_{b10},
R_{b5} to R_{b10} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m11, m12 and m15 are each independently an integer of 0 to 4,
m13 is an integer of 0 to 5, and
m14 is an integer of 0 to 3, and
wherein, in Formula 1-2-1 to Formula 1-2-5,
R₁ to R₁₉, Z, Rₐ, and m1 are the same as defined in Formula 1 and Formula C.

7. The light emitting device of claim 1, wherein the first compound represented by Formula 1 is represented by any one among Formula 1-3-1 to Formula 1-3-3: 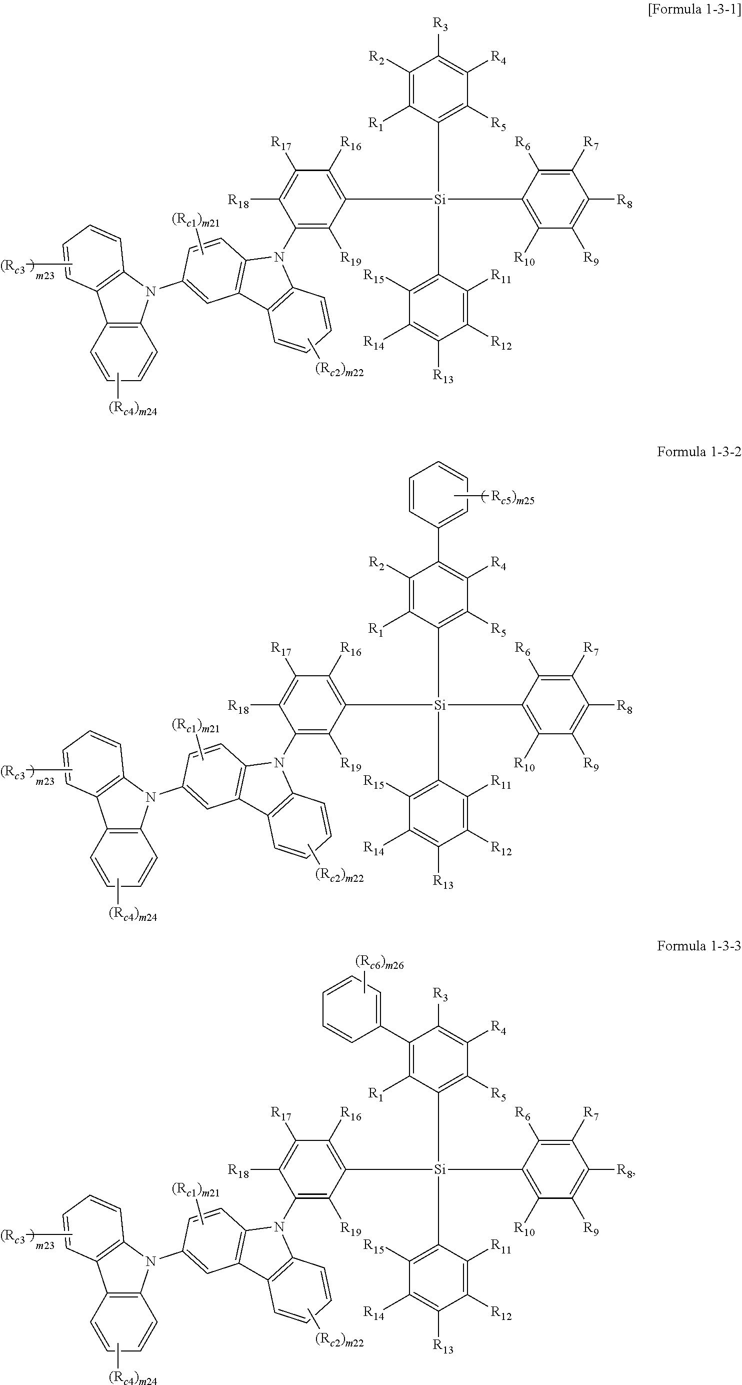
wherein, in Formula 1-3-1 to Formula 1-3-3,
R_{c1} to R_{c6} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m21 is an integer of 0 to 3,
m22 to m24 are each independently an integer of 0 to 4,
m25 and m26 are each independently an integer of 0 to 5, and
R₁ to R₁₉ are the same as defined in Formula 1.

8. The light emitting device of claim 1, wherein the second compound represented by Formula 2 is represented by any one among Formula 2-1-1 to Formula 2-1-3: 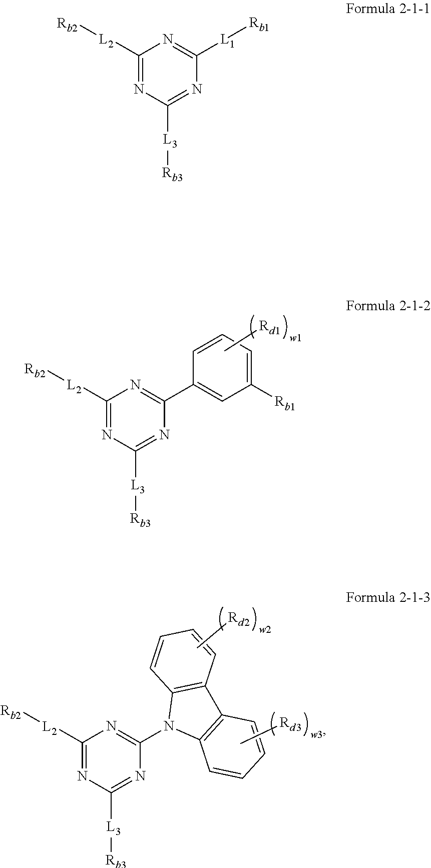
wherein, in Formula 2-1-1 to Formula 2-1-3,
R_{d1} to R_{d3} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
w1 to w3 are each independently an integer of 0 to 4, and
R_{b1} to R_{b3}, and L₁ to L₃ are the same as defined in Formula 2.

9. The light emitting device of claim 1, wherein the third compound represented by Formula 3 is represented by any one among Formula 3-1 to Formula 3-3: 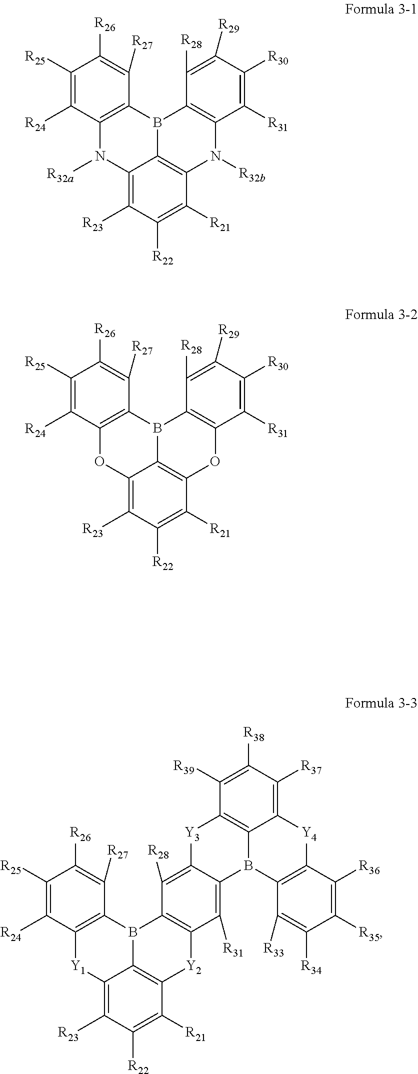
wherein, in Formula 3-1 to Formula 3-3,
R₃₂ₐ and R_{32b} are each independently a substituted or unsubstituted aryl group having 6 to 30 ring-forming carbon atoms, or a substituted or unsubstituted heteroaryl group having 2 to 30 ring-forming carbon atoms,
Y₃ and Y₄ are each independently NR₄₀ or O,
R₃₃ to R₄₀ are each independently a hydrogen atom, a deuterium atom, a halogen atom, a cyano group, a nitro group, a substituted or unsubstituted amine group, a substituted or unsubstituted boron group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and
Y₁, Y₂, R₂₁ to R₂₈, and R₃₁ are the same as defined in Formula 3.

10. The light emitting device of claim 1, wherein the first compound represented by Formula 1 comprises at least one from among compounds in Compound Group 1:

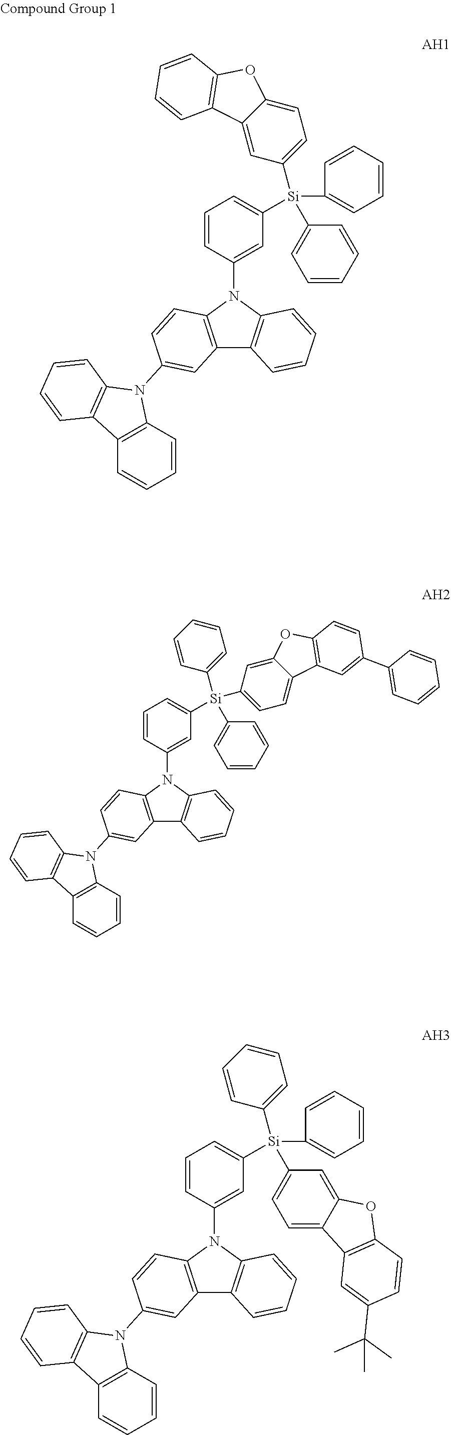 [SMILES: c1ccc([Si](c2ccccc2)(c2cccc(-n3c4ccccc4c4cc(-n5c6ccccc6c6ccccc65)ccc43)c2)c2ccc3oc4ccccc4c3c2)cc1 ; c1ccc(-c2ccc3oc4cc([Si](c5ccccc5)(c5ccccc5)c5cccc(-n6c7ccccc7c7cc(-n8c9ccccc9c9ccccc98)ccc76)c5)ccc4c3c2)cc1 ; CC(C)(C)c1ccc2oc3cc([Si](c4ccccc4)(c4ccccc4)c4cccc(-n5c6ccccc6c6cc(-n7c8ccccc8c8ccccc87)ccc65)c4)ccc3c2c1]

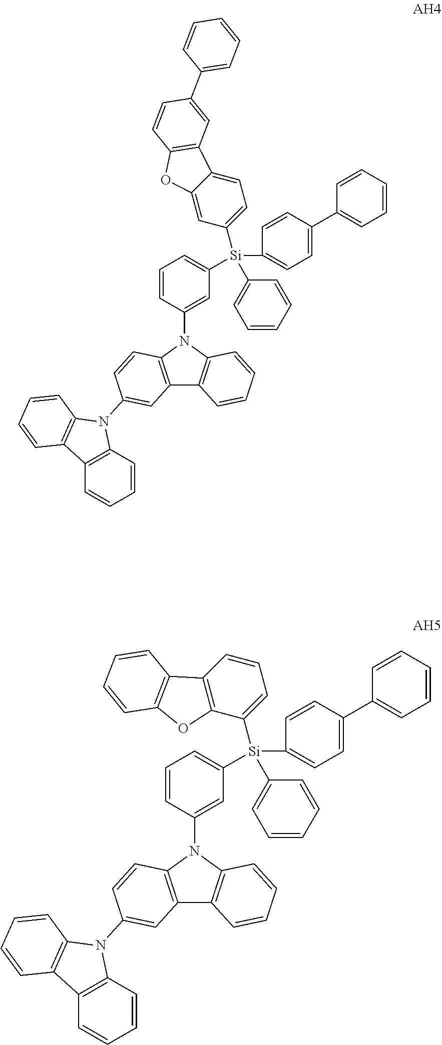 [SMILES: c1ccc(-c2ccc([Si](c3ccccc3)(c3cccc(-n4c5ccccc5c5cc(-n6c7ccccc7c7ccccc76)ccc54)c3)c3ccc4c(c3)oc3ccc(-c5ccccc5)cc34)cc2)cc1 ; c1ccc(-c2ccc([Si](c3ccccc3)(c3cccc(-n4c5ccccc5c5cc(-n6c7ccccc7c7ccccc76)ccc54)c3)c3cccc4c3oc3ccccc34)cc2)cc1]

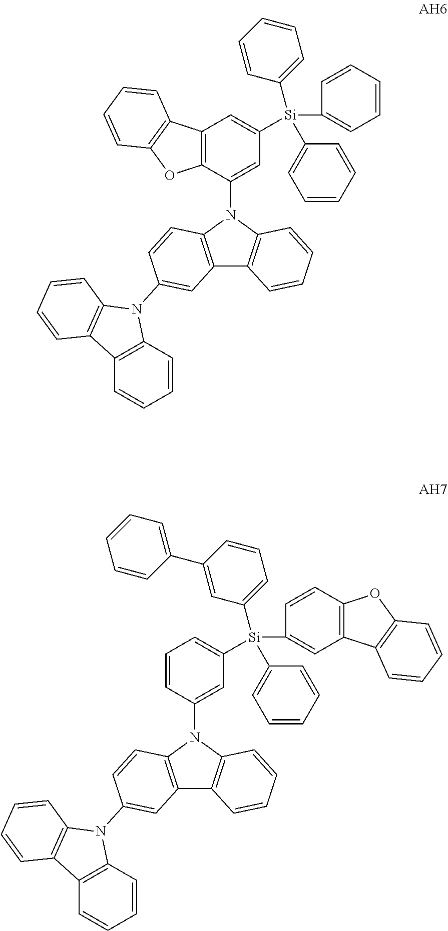 [SMILES: c1ccc([Si](c2ccccc2)(c2ccccc2)c2cc(-n3c4ccccc4c4cc(-n5c6ccccc6c6ccccc65)ccc43)c3oc4ccccc4c3c2)cc1 ; c1ccc(-c2cccc([Si](c3ccccc3)(c3cccc(-n4c5ccccc5c5cc(-n6c7ccccc7c7ccccc76)ccc54)c3)c3ccc4oc5ccccc5c4c3)c2)cc1]

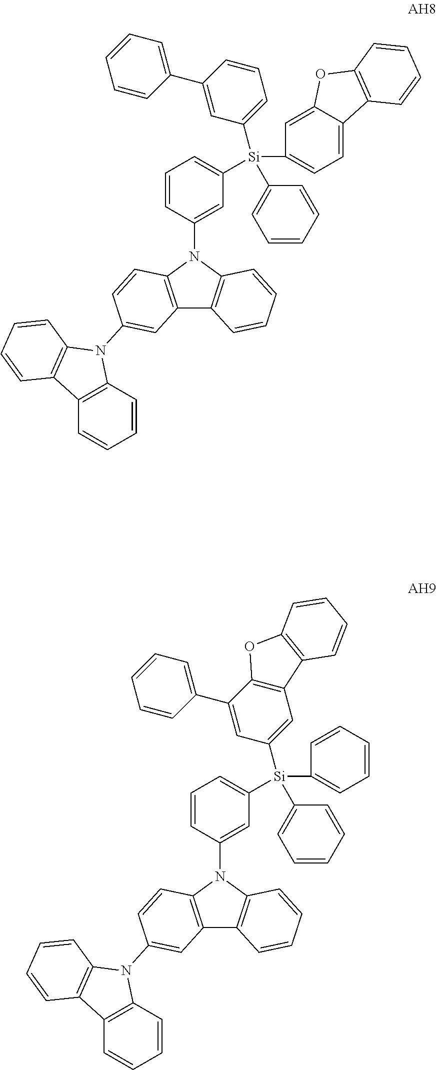 [SMILES: c1ccc(-c2cccc([Si](c3ccccc3)(c3cccc(-n4c5ccccc5c5cc(-n6c7ccccc7c7ccccc76)ccc54)c3)c3ccc4c(c3)oc3ccccc34)c2)cc1 ; c1ccc(-c2cc([Si](c3ccccc3)(c3ccccc3)c3cccc(-n4c5ccccc5c5cc(-n6c7ccccc7c7ccccc76)ccc54)c3)cc3c2oc2ccccc23)cc1]

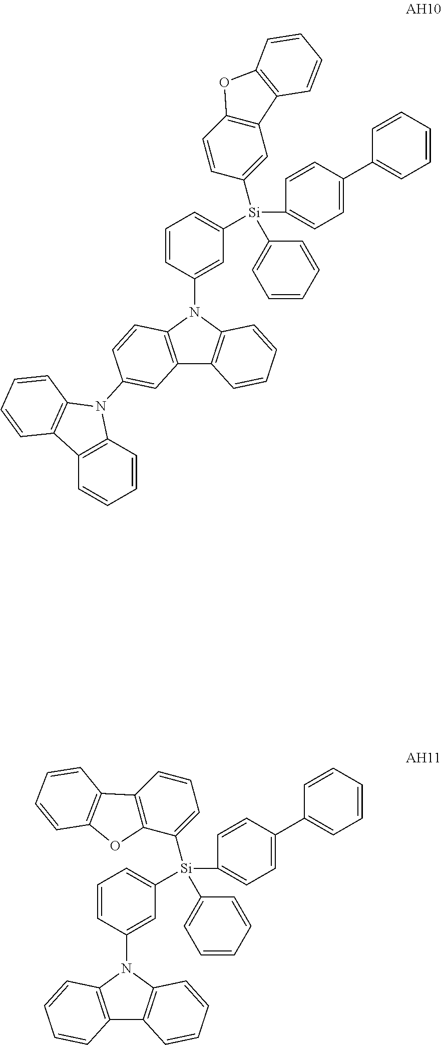 [SMILES: c1ccc(-c2ccc([Si](c3ccccc3)(c3cccc(-n4c5ccccc5c5cc(-n6c7ccccc7c7ccccc76)ccc54)c3)c3ccc4oc5ccccc5c4c3)cc2)cc1 ; c1ccc(-c2ccc([Si](c3ccccc3)(c3cccc(-n4c5ccccc5c5ccccc54)c3)c3cccc4c3oc3ccccc34)cc2)cc1]

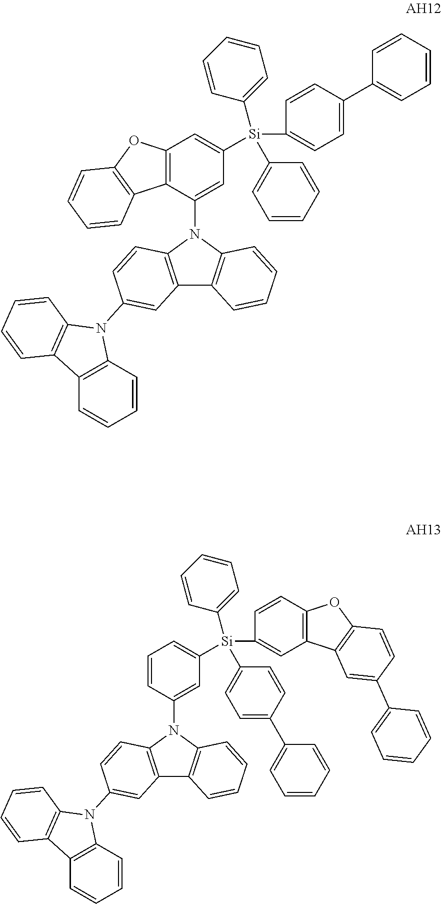 [SMILES: c1ccc(-c2ccc([Si](c3ccccc3)(c3ccccc3)c3cc(-n4c5ccccc5c5cc(-n6c7ccccc7c7ccccc76)ccc54)c4c(c3)oc3ccccc34)cc2)cc1 ; c1ccc(-c2ccc([Si](c3ccccc3)(c3cccc(-n4c5ccccc5c5cc(-n6c7ccccc7c7ccccc76)ccc54)c3)c3ccc4oc5ccc(-c6ccccc6)cc5c4c3)cc2)cc1]

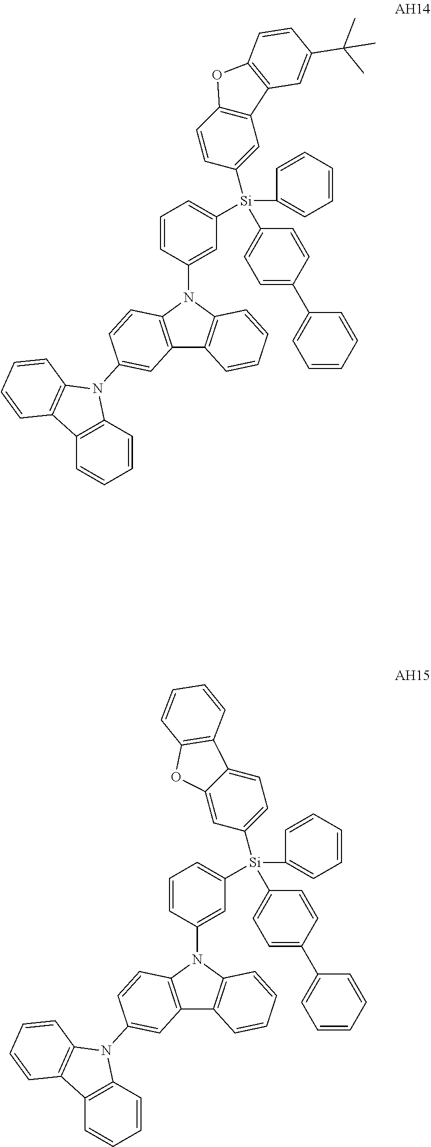 [SMILES: CC(C)(C)c1ccc2oc3ccc([Si](c4ccccc4)(c4ccc(-c5ccccc5)cc4)c4cccc(-n5c6ccccc6c6cc(-n7c8ccccc8c8ccccc87)ccc65)c4)cc3c2c1 ; c1ccc(-c2ccc([Si](c3ccccc3)(c3cccc(-n4c5ccccc5c5cc(-n6c7ccccc7c7ccccc76)ccc54)c3)c3ccc4c(c3)oc3ccccc34)cc2)cc1]

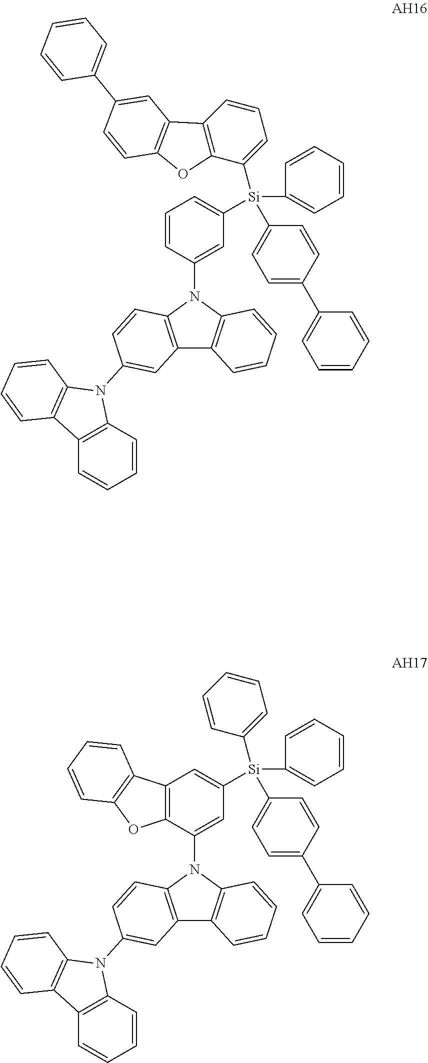 [SMILES: c1ccc(-c2ccc([Si](c3ccccc3)(c3cccc(-n4c5ccccc5c5cc(-n6c7ccccc7c7ccccc76)ccc54)c3)c3cccc4c3oc3ccc(-c5ccccc5)cc34)cc2)cc1 ; c1ccc(-c2ccc([Si](c3ccccc3)(c3ccccc3)c3cc(-n4c5ccccc5c5cc(-n6c7ccccc7c7ccccc76)ccc54)c4oc5ccccc5c4c3)cc2)cc1]

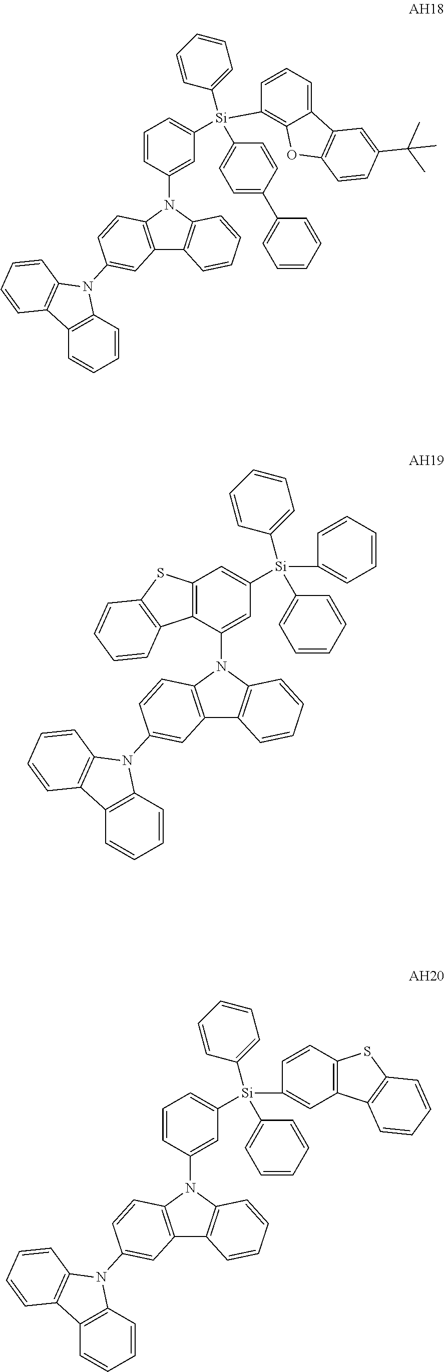 [SMILES: CC(C)(C)c1ccc2oc3c([Si](c4ccccc4)(c4ccc(-c5ccccc5)cc4)c4cccc(-n5c6ccccc6c6cc(-n7c8ccccc8c8ccccc87)ccc65)c4)cccc3c2c1 ; c1ccc([Si](c2ccccc2)(c2ccccc2)c2cc(-n3c4ccccc4c4cc(-n5c6ccccc6c6ccccc65)ccc43)c3c(c2)sc2ccccc23)cc1 ; c1ccc([Si](c2ccccc2)(c2cccc(-n3c4ccccc4c4cc(-n5c6ccccc6c6ccccc65)ccc43)c2)c2ccc3sc4ccccc4c3c2)cc1]

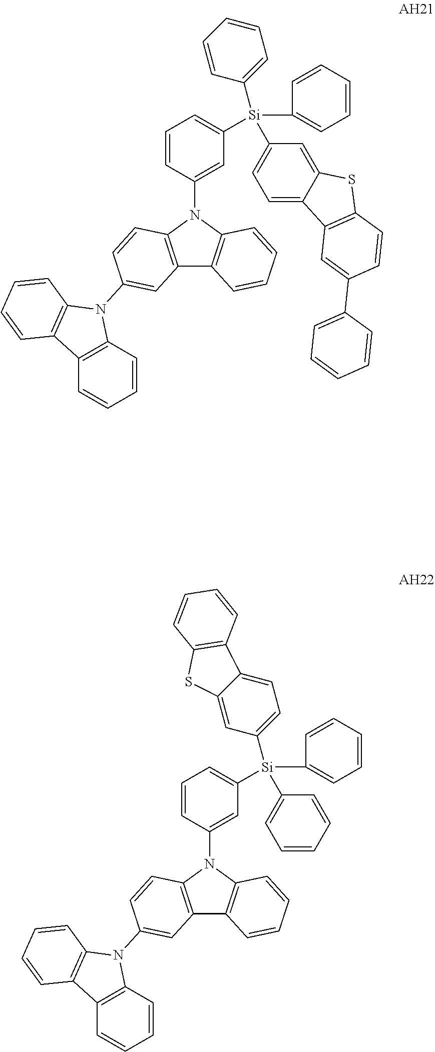 [SMILES: c1ccc(-c2ccc3sc4cc([Si](c5ccccc5)(c5ccccc5)c5cccc(-n6c7ccccc7c7cc(-n8c9ccccc9c9ccccc98)ccc76)c5)ccc4c3c2)cc1 ; c1ccc([Si](c2ccccc2)(c2cccc(-n3c4ccccc4c4cc(-n5c6ccccc6c6ccccc65)ccc43)c2)c2ccc3c(c2)sc2ccccc23)cc1]

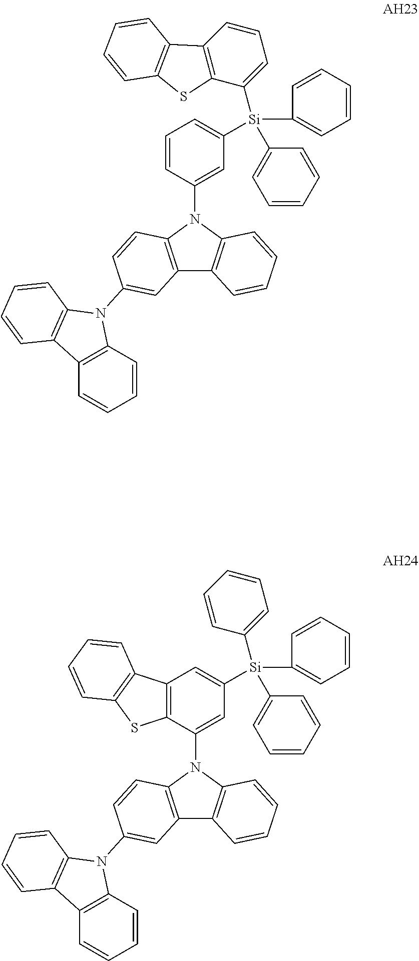 [SMILES: c1ccc([Si](c2ccccc2)(c2cccc(-n3c4ccccc4c4cc(-n5c6ccccc6c6ccccc65)ccc43)c2)c2cccc3c2sc2ccccc23)cc1 ; c1ccc([Si](c2ccccc2)(c2ccccc2)c2cc(-n3c4ccccc4c4cc(-n5c6ccccc6c6ccccc65)ccc43)c3sc4ccccc4c3c2)cc1]

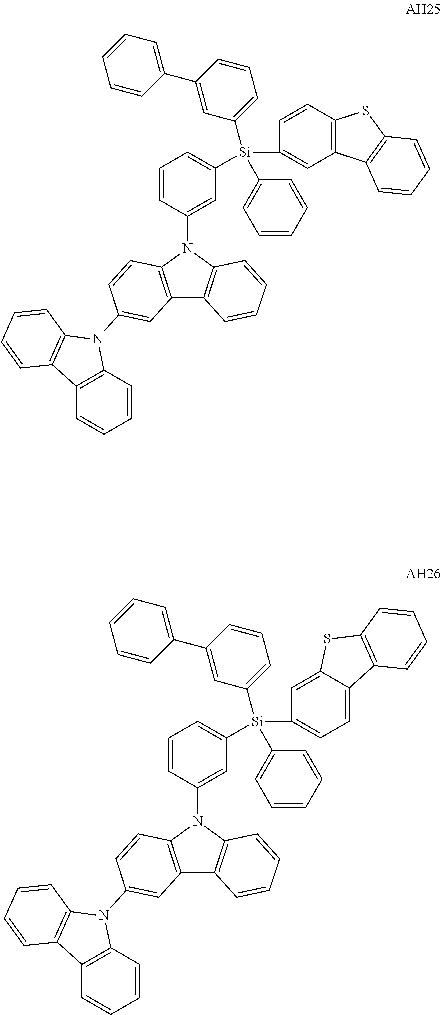 [SMILES: c1ccc(-c2cccc([Si](c3ccccc3)(c3cccc(-n4c5ccccc5c5cc(-n6c7ccccc7c7ccccc76)ccc54)c3)c3ccc4sc5ccccc5c4c3)c2)cc1 ; c1ccc(-c2cccc([Si](c3ccccc3)(c3cccc(-n4c5ccccc5c5cc(-n6c7ccccc7c7ccccc76)ccc54)c3)c3ccc4c(c3)sc3ccccc34)c2)cc1]

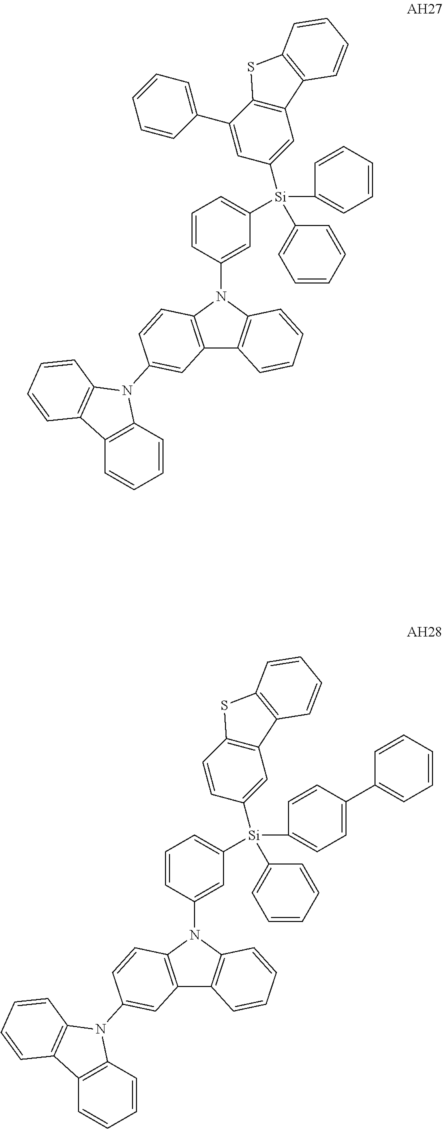 [SMILES: c1ccc(-c2cc([Si](c3ccccc3)(c3ccccc3)c3cccc(-n4c5ccccc5c5cc(-n6c7ccccc7c7ccccc76)ccc54)c3)cc3c2sc2ccccc23)cc1 ; c1ccc(-c2ccc([Si](c3ccccc3)(c3cccc(-n4c5ccccc5c5cc(-n6c7ccccc7c7ccccc76)ccc54)c3)c3ccc4sc5ccccc5c4c3)cc2)cc1]

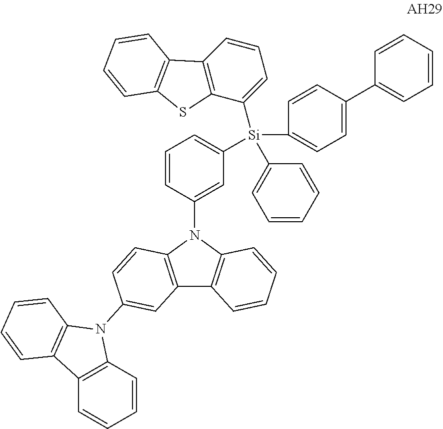 [SMILES: c1ccc(-c2ccc([Si](c3ccccc3)(c3cccc(-n4c5ccccc5c5cc(-n6c7ccccc7c7ccccc76)ccc54)c3)c3cccc4c3sc3ccccc34)cc2)cc1]

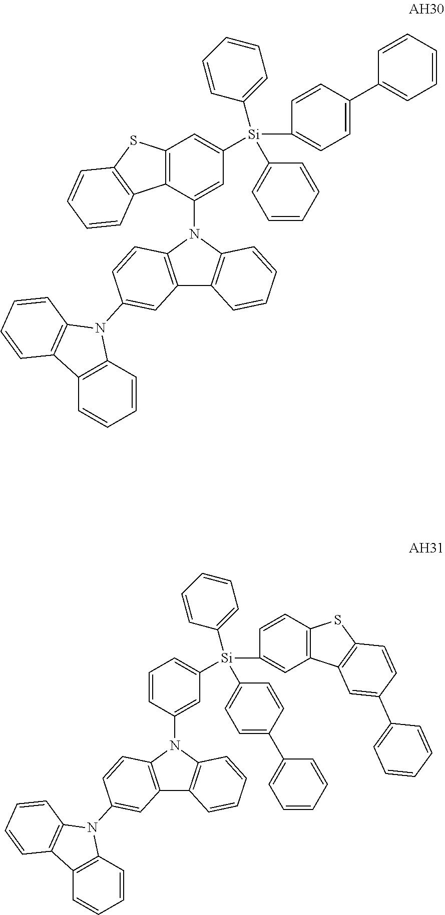 [SMILES: c1ccc(-c2ccc([Si](c3ccccc3)(c3ccccc3)c3cc(-n4c5ccccc5c5cc(-n6c7ccccc7c7ccccc76)ccc54)c4c(c3)sc3ccccc34)cc2)cc1 ; c1ccc(-c2ccc([Si](c3ccccc3)(c3cccc(-n4c5ccccc5c5cc(-n6c7ccccc7c7ccccc76)ccc54)c3)c3ccc4sc5ccc(-c6ccccc6)cc5c4c3)cc2)cc1]

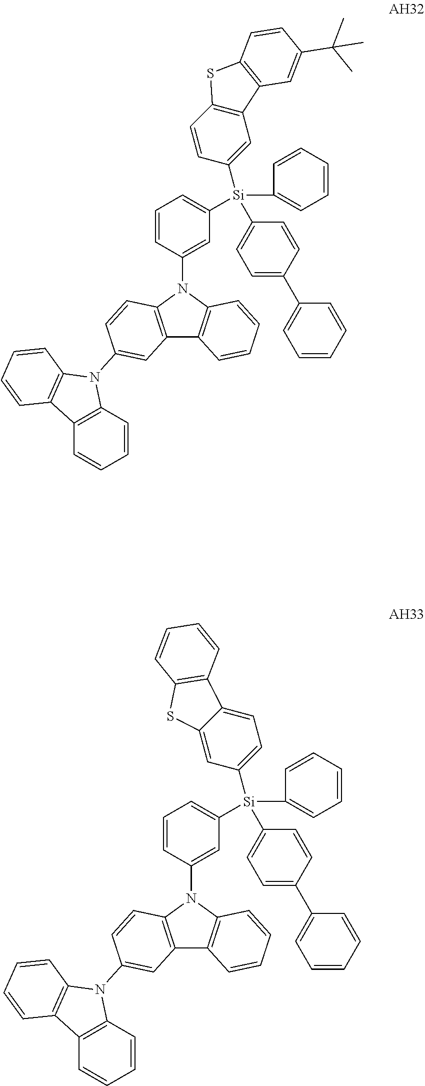 [SMILES: CC(C)(C)c1ccc2sc3ccc([Si](c4ccccc4)(c4ccc(-c5ccccc5)cc4)c4cccc(-n5c6ccccc6c6cc(-n7c8ccccc8c8ccccc87)ccc65)c4)cc3c2c1 ; c1ccc(-c2ccc([Si](c3ccccc3)(c3cccc(-n4c5ccccc5c5cc(-n6c7ccccc7c7ccccc76)ccc54)c3)c3ccc4c(c3)sc3ccccc34)cc2)cc1]

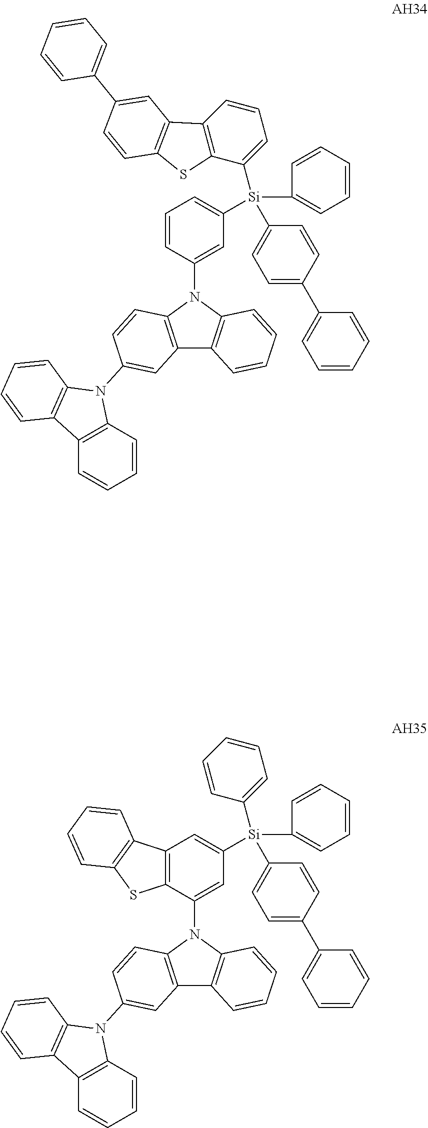 [SMILES: c1ccc(-c2ccc([Si](c3ccccc3)(c3cccc(-n4c5ccccc5c5cc(-n6c7ccccc7c7ccccc76)ccc54)c3)c3cccc4c3sc3ccc(-c5ccccc5)cc34)cc2)cc1 ; c1ccc(-c2ccc([Si](c3ccccc3)(c3ccccc3)c3cc(-n4c5ccccc5c5cc(-n6c7ccccc7c7ccccc76)ccc54)c4sc5ccccc5c4c3)cc2)cc1]

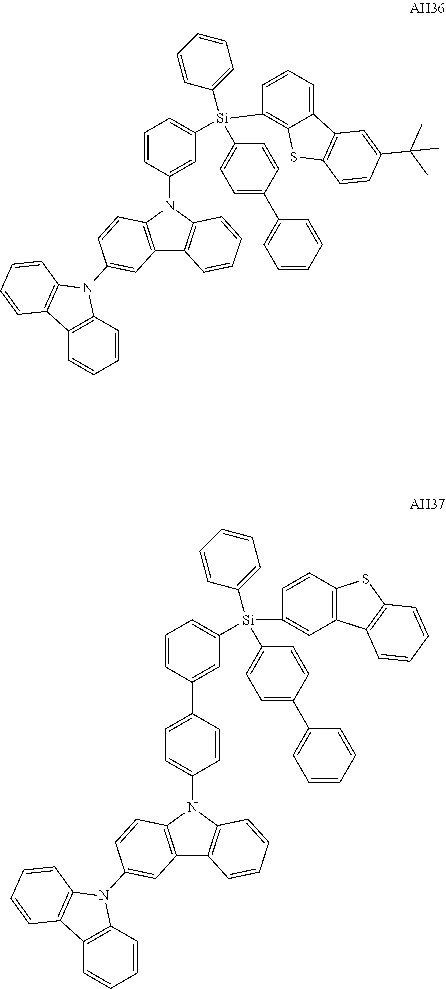 [SMILES: CC(C)(C)c1ccc2sc3c([Si](c4ccccc4)(c4ccc(-c5ccccc5)cc4)c4cccc(-n5c6ccccc6c6cc(-n7c8ccccc8c8ccccc87)ccc65)c4)cccc3c2c1 ; c1ccc(-c2ccc([Si](c3ccccc3)(c3cccc(-c4ccc(-n5c6ccccc6c6cc(-n7c8ccccc8c8ccccc87)ccc65)cc4)c3)c3ccc4sc5ccccc5c4c3)cc2)cc1]

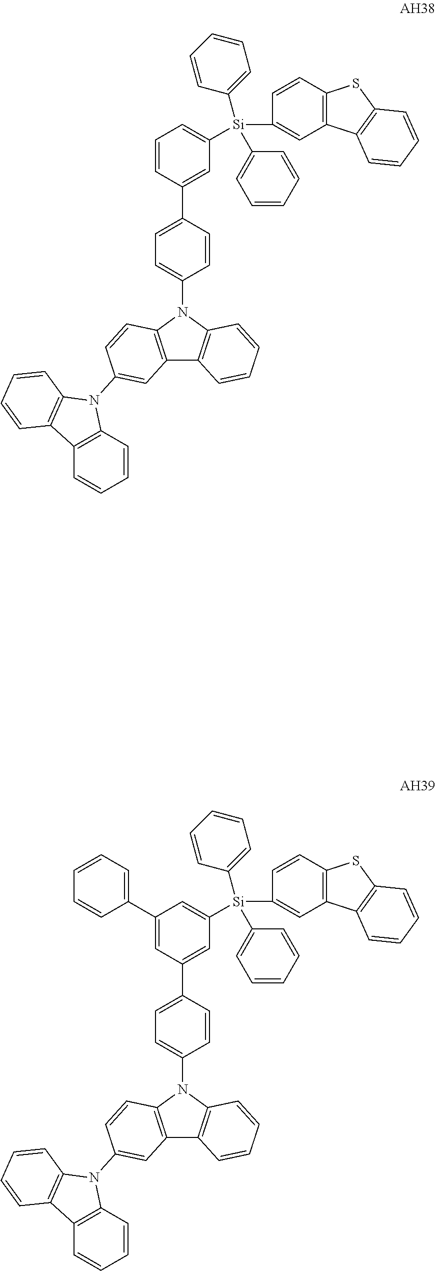 [SMILES: c1ccc([Si](c2ccccc2)(c2cccc(-c3ccc(-n4c5ccccc5c5cc(-n6c7ccccc7c7ccccc76)ccc54)cc3)c2)c2ccc3sc4ccccc4c3c2)cc1 ; c1ccc(-c2cc(-c3ccc(-n4c5ccccc5c5cc(-n6c7ccccc7c7ccccc76)ccc54)cc3)cc([Si](c3ccccc3)(c3ccccc3)c3ccc4sc5ccccc5c4c3)c2)cc1]

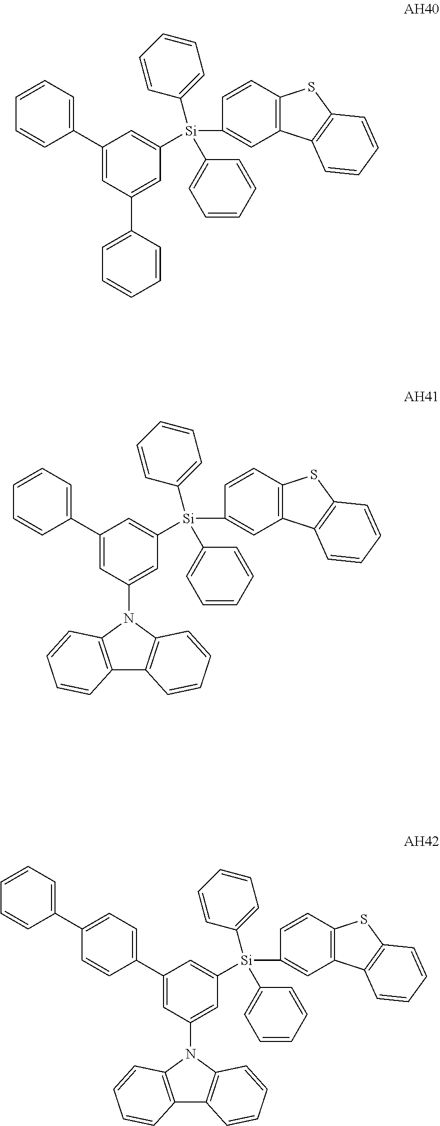 [SMILES: c1ccc(-c2cc(-c3ccccc3)cc([Si](c3ccccc3)(c3ccccc3)c3ccc4sc5ccccc5c4c3)c2)cc1 ; c1ccc(-c2cc(-n3c4ccccc4c4ccccc43)cc([Si](c3ccccc3)(c3ccccc3)c3ccc4sc5ccccc5c4c3)c2)cc1 ; c1ccc(-c2ccc(-c3cc(-n4c5ccccc5c5ccccc54)cc([Si](c4ccccc4)(c4ccccc4)c4ccc5sc6ccccc6c5c4)c3)cc2)cc1]

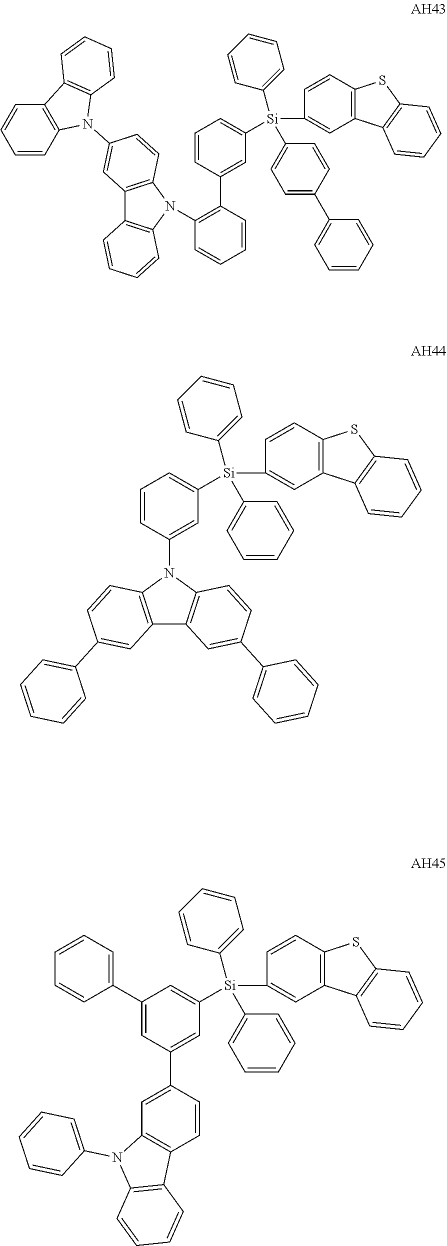 [SMILES: c1ccc(-c2ccc([Si](c3ccccc3)(c3cccc(-c4ccccc4-n4c5ccccc5c5cc(-n6c7ccccc7c7ccccc76)ccc54)c3)c3ccc4sc5ccccc5c4c3)cc2)cc1 ; c1ccc(-c2ccc3c(c2)c2cc(-c4ccccc4)ccc2n3-c2cccc([Si](c3ccccc3)(c3ccccc3)c3ccc4sc5ccccc5c4c3)c2)cc1 ; c1ccc(-c2cc(-c3ccc4c5ccccc5n(-c5ccccc5)c4c3)cc([Si](c3ccccc3)(c3ccccc3)c3ccc4sc5ccccc5c4c3)c2)cc1]

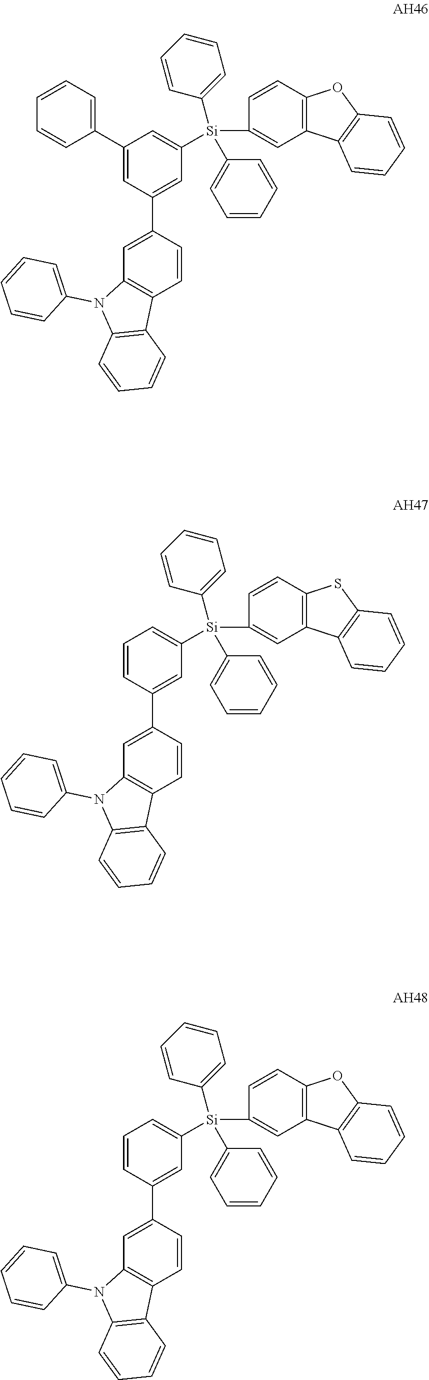 [SMILES: c1ccc(-c2cc(-c3ccc4c5ccccc5n(-c5ccccc5)c4c3)cc([Si](c3ccccc3)(c3ccccc3)c3ccc4oc5ccccc5c4c3)c2)cc1 ; c1ccc(-n2c3ccccc3c3ccc(-c4cccc([Si](c5ccccc5)(c5ccccc5)c5ccc6sc7ccccc7c6c5)c4)cc32)cc1 ; c1ccc(-n2c3ccccc3c3ccc(-c4cccc([Si](c5ccccc5)(c5ccccc5)c5ccc6oc7ccccc7c6c5)c4)cc32)cc1]

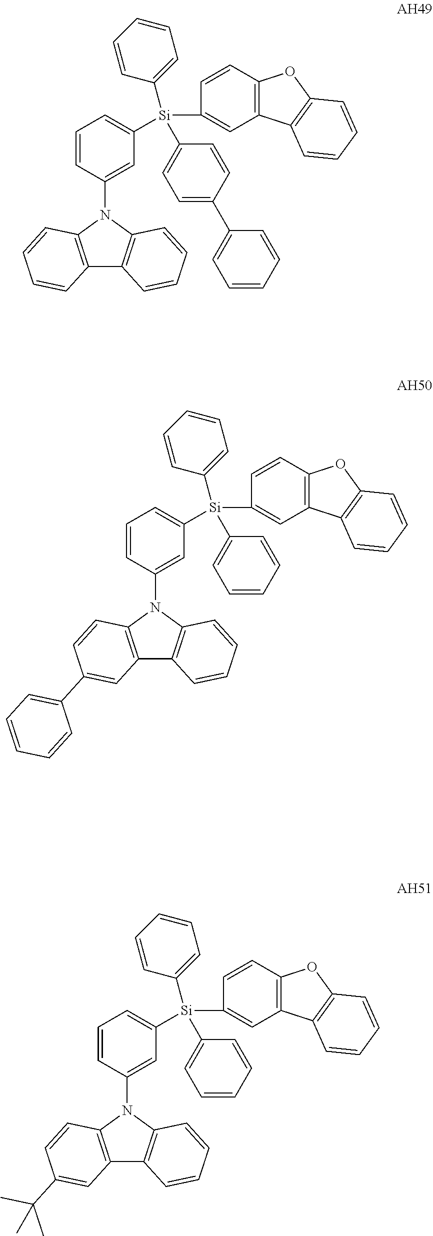 [SMILES: c1ccc(-c2ccc([Si](c3ccccc3)(c3cccc(-n4c5ccccc5c5ccccc54)c3)c3ccc4oc5ccccc5c4c3)cc2)cc1 ; c1ccc(-c2ccc3c(c2)c2ccccc2n3-c2cccc([Si](c3ccccc3)(c3ccccc3)c3ccc4oc5ccccc5c4c3)c2)cc1 ; CC(C)(C)c1ccc2c(c1)c1ccccc1n2-c1cccc([Si](c2ccccc2)(c2ccccc2)c2ccc3oc4ccccc4c3c2)c1]

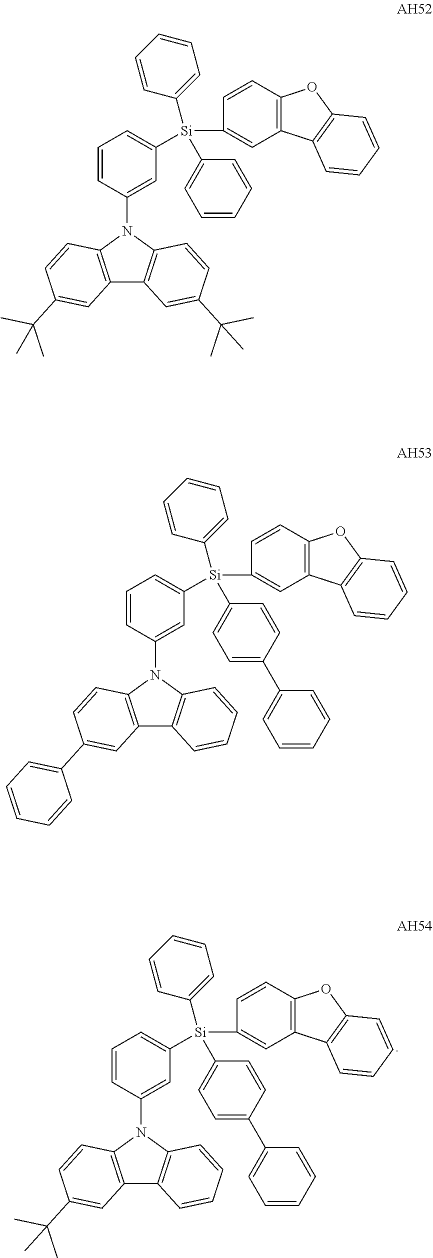 [SMILES: CC(C)(C)c1ccc2c(c1)c1cc(C(C)(C)C)ccc1n2-c1cccc([Si](c2ccccc2)(c2ccccc2)c2ccc3oc4ccccc4c3c2)c1 ; c1ccc(-c2ccc([Si](c3ccccc3)(c3cccc(-n4c5ccccc5c5cc(-c6ccccc6)ccc54)c3)c3ccc4oc5ccccc5c4c3)cc2)cc1 ; CC(C)(C)c1ccc2c(c1)c1ccccc1n2-c1cccc([Si](c2ccccc2)(c2ccc(-c3ccccc3)cc2)c2ccc3oc4ccccc4c3c2)c1]

11. The light emitting device of claim 1, wherein the second compound represented by Formula 2 comprises at least one from among compounds in Compound Group 2:

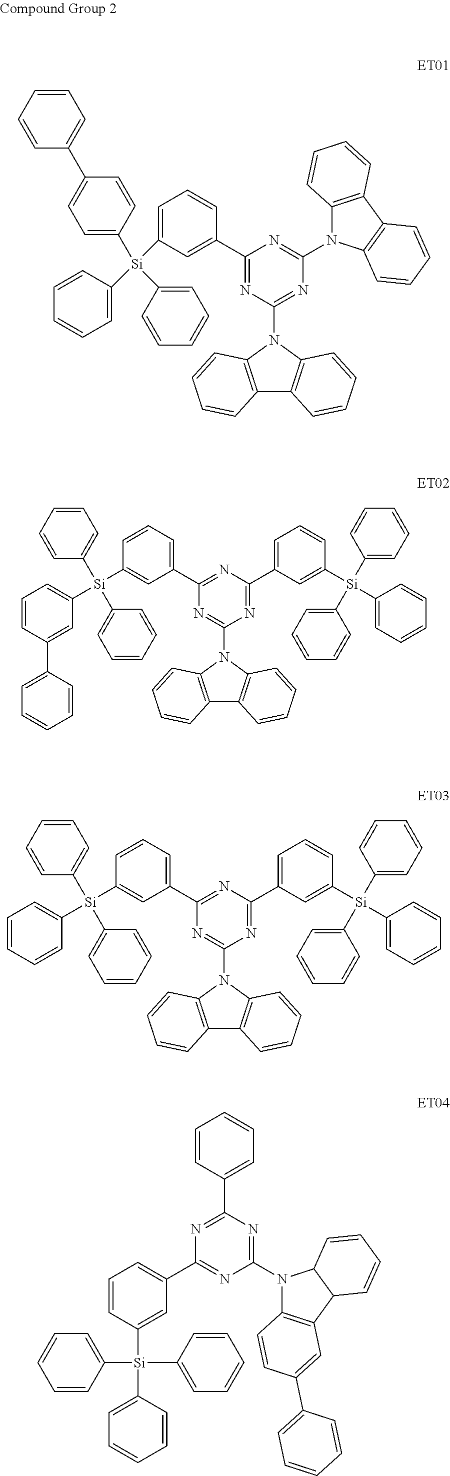 [SMILES: c1ccc(-c2ccc([Si](c3ccccc3)(c3ccccc3)c3cccc(-c4nc(-n5c6ccccc6c6ccccc65)nc(-n5c6ccccc6c6ccccc65)n4)c3)cc2)cc1 ; c1ccc(-c2cccc([Si](c3ccccc3)(c3ccccc3)c3cccc(-c4nc(-c5cccc([Si](c6ccccc6)(c6ccccc6)c6ccccc6)c5)nc(-n5c6ccccc6c6ccccc65)n4)c3)c2)cc1 ; c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; C1=CC2c3cc(-c4ccccc4)ccc3N(c3nc(-c4ccccc4)nc(-c4cccc([Si](c5ccccc5)(c5ccccc5)c5ccccc5)c4)n3)C2C=C1]

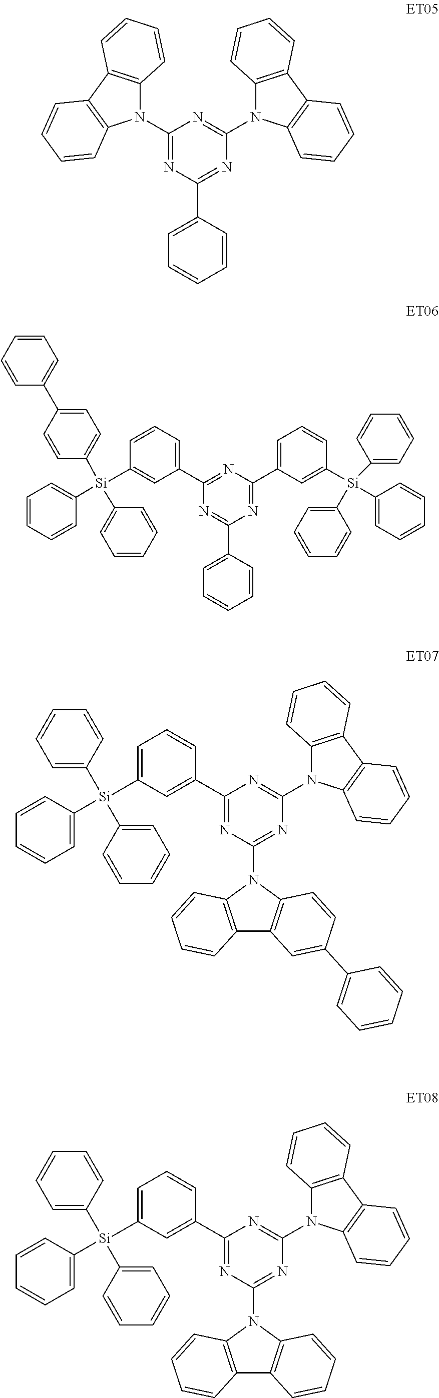 [SMILES: c1ccc(-c2nc(-n3c4ccccc4c4ccccc43)nc(-n3c4ccccc4c4ccccc43)n2)cc1 ; c1ccc(-c2ccc([Si](c3ccccc3)(c3ccccc3)c3cccc(-c4nc(-c5ccccc5)nc(-c5cccc([Si](c6ccccc6)(c6ccccc6)c6ccccc6)c5)n4)c3)cc2)cc1 ; c1ccc(-c2ccc3c(c2)c2ccccc2n3-c2nc(-c3cccc([Si](c4ccccc4)(c4ccccc4)c4ccccc4)c3)nc(-n3c4ccccc4c4ccccc43)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

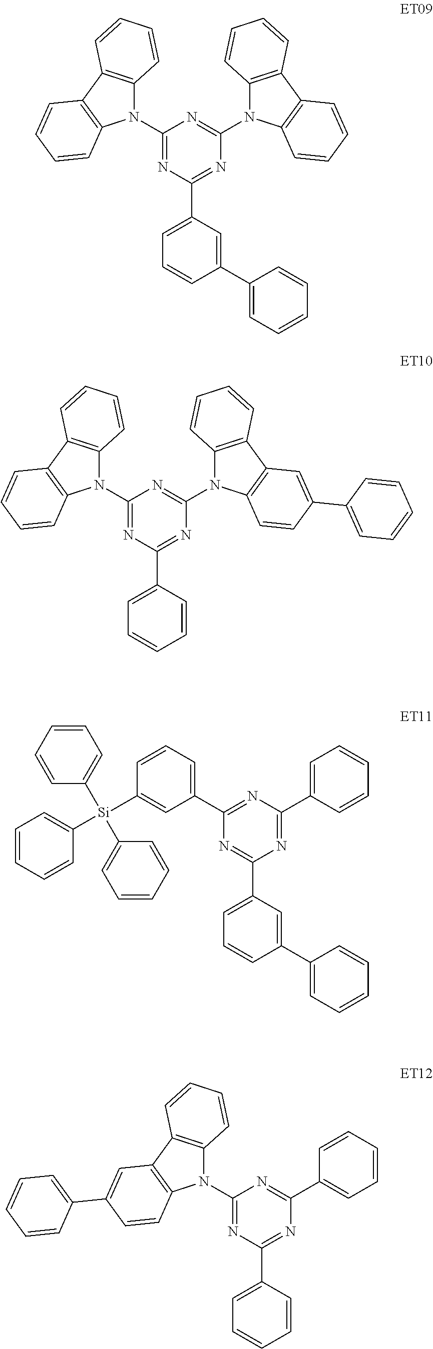 [SMILES: c1ccc(-c2cccc(-c3nc(-n4c5ccccc5c5ccccc54)nc(-n4c5ccccc5c5ccccc54)n3)c2)cc1 ; c1ccc(-c2ccc3c(c2)c2ccccc2n3-c2nc(-c3ccccc3)nc(-n3c4ccccc4c4ccccc43)n2)cc1 ; c1ccc(-c2cccc(-c3nc(-c4ccccc4)nc(-c4cccc([Si](c5ccccc5)(c5ccccc5)c5ccccc5)c4)n3)c2)cc1 ; c1ccc(-c2ccc3c(c2)c2ccccc2n3-c2nc(-c3ccccc3)nc(-c3ccccc3)n2)cc1]

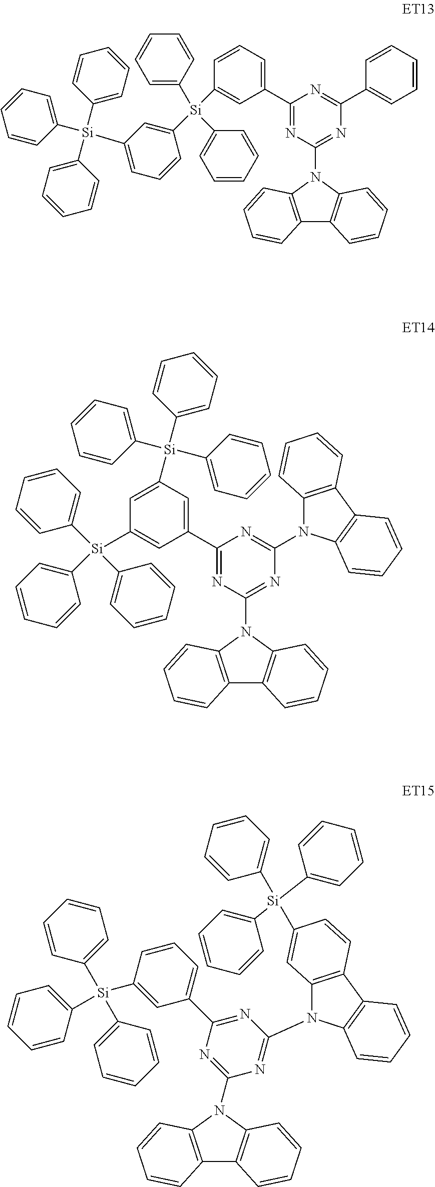 [SMILES: c1ccc(-c2nc(-c3cccc([Si](c4ccccc4)(c4ccccc4)c4cccc([Si](c5ccccc5)(c5ccccc5)c5ccccc5)c4)c3)nc(-n3c4ccccc4c4ccccc43)n2)cc1 ; c1ccc([Si](c2ccccc2)(c2ccccc2)c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1 ; c1ccc([Si](c2ccccc2)(c2ccccc2)c2cccc(-c3nc(-n4c5ccccc5c5ccccc54)nc(-n4c5ccccc5c5ccc([Si](c6ccccc6)(c6ccccc6)c6ccccc6)cc54)n3)c2)cc1]

12. The light emitting device of claim 1, wherein the third compound represented by Formula 3 comprises at least one from among compounds in Compound Group 3:

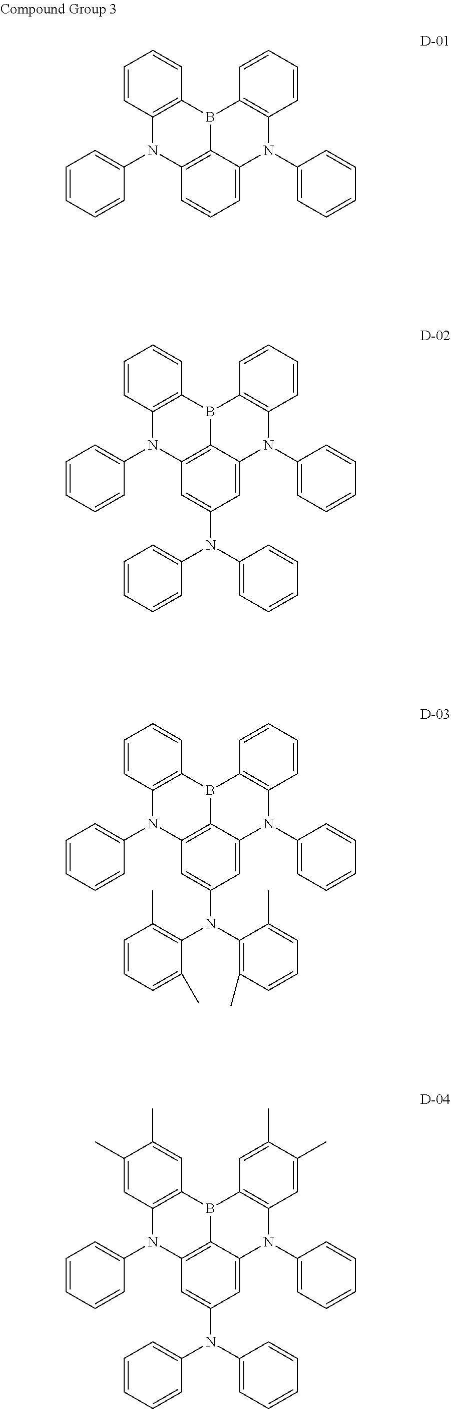 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2ccccc2B4c2ccccc2N3c2ccccc2)cc1 ; Cc1cccc(C)c1N(c1cc2c3c(c1)N(c1ccccc1)c1ccccc1B3c1ccccc1N2c1ccccc1)c1c(C)cccc1C ; Cc1cc2c(cc1C)N(c1ccccc1)c1cc(N(c3ccccc3)c3ccccc3)cc3c1B2c1cc(C)c(C)cc1N3c1ccccc1]

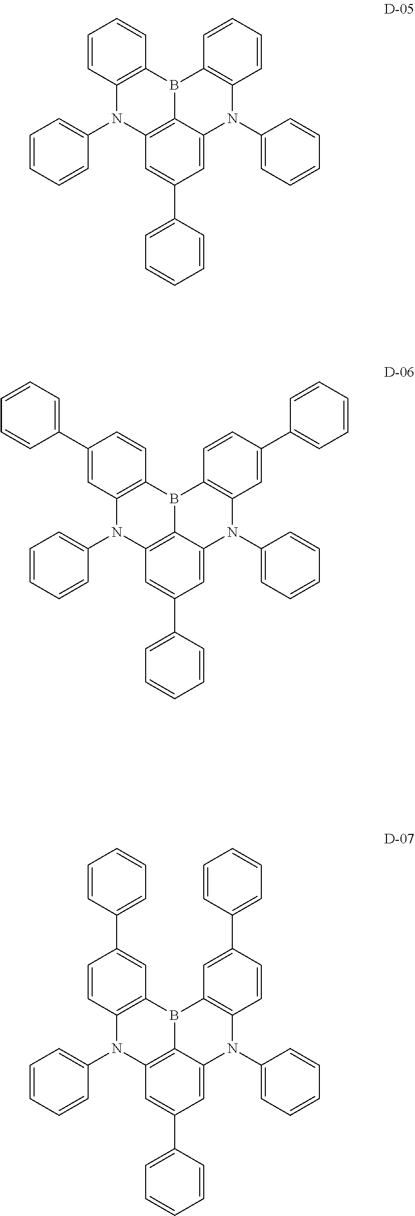 [SMILES: c1ccc(-c2cc3c4c(c2)N(c2ccccc2)c2ccccc2B4c2ccccc2N3c2ccccc2)cc1 ; c1ccc(-c2ccc3c(c2)N(c2ccccc2)c2cc(-c4ccccc4)cc4c2B3c2ccc(-c3ccccc3)cc2N4c2ccccc2)cc1 ; c1ccc(-c2ccc3c(c2)B2c4cc(-c5ccccc5)ccc4N(c4ccccc4)c4cc(-c5ccccc5)cc(c42)N3c2ccccc2)cc1]

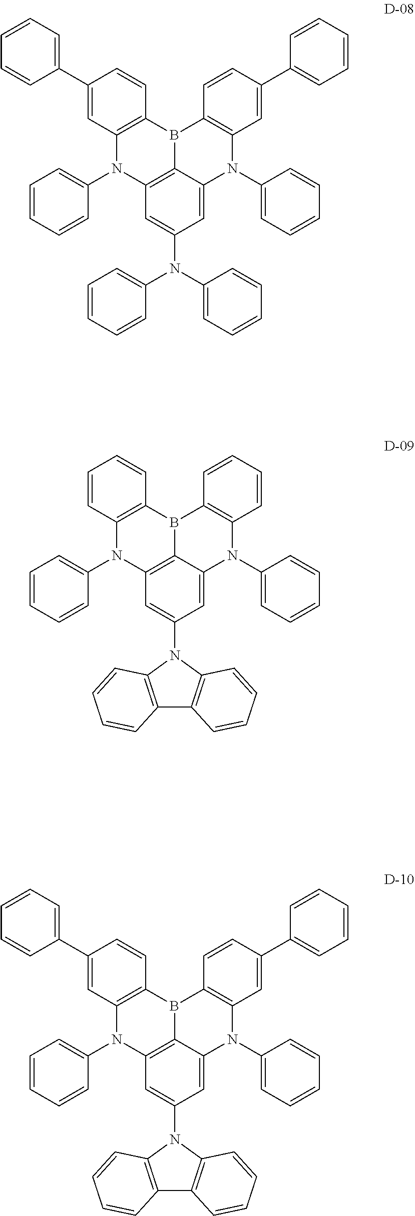 [SMILES: c1ccc(-c2ccc3c(c2)N(c2ccccc2)c2cc(N(c4ccccc4)c4ccccc4)cc4c2B3c2ccc(-c3ccccc3)cc2N4c2ccccc2)cc1 ; c1ccc(N2c3ccccc3B3c4ccccc4N(c4ccccc4)c4cc(-n5c6ccccc6c6ccccc65)cc2c43)cc1 ; c1ccc(-c2ccc3c(c2)N(c2ccccc2)c2cc(-n4c5ccccc5c5ccccc54)cc4c2B3c2ccc(-c3ccccc3)cc2N4c2ccccc2)cc1]

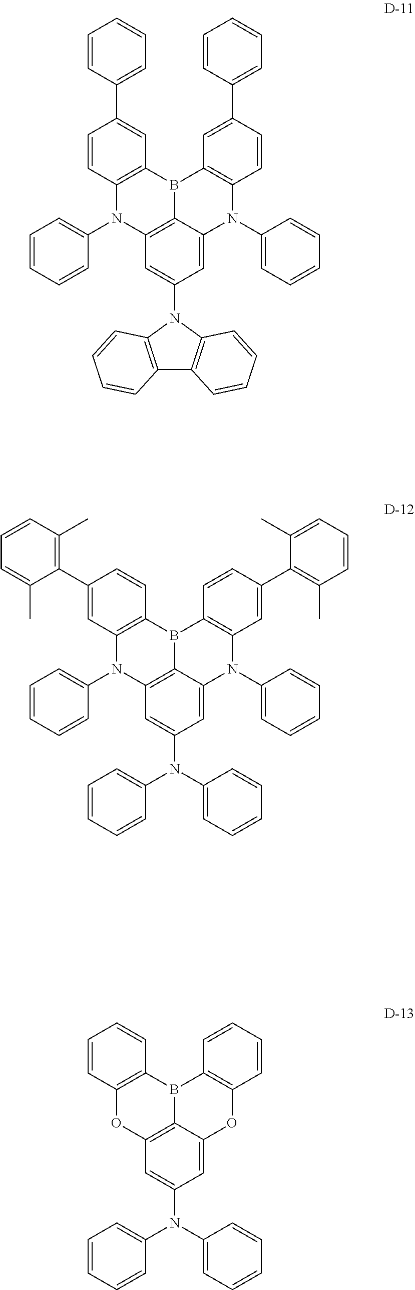 [SMILES: c1ccc(-c2ccc3c(c2)B2c4cc(-c5ccccc5)ccc4N(c4ccccc4)c4cc(-n5c6ccccc6c6ccccc65)cc(c42)N3c2ccccc2)cc1 ; Cc1cccc(C)c1-c1ccc2c(c1)N(c1ccccc1)c1cc(N(c3ccccc3)c3ccccc3)cc3c1B2c1ccc(-c2c(C)cccc2C)cc1N3c1ccccc1 ; c1ccc(N(c2ccccc2)c2cc3c4c(c2)Oc2ccccc2B4c2ccccc2O3)cc1]

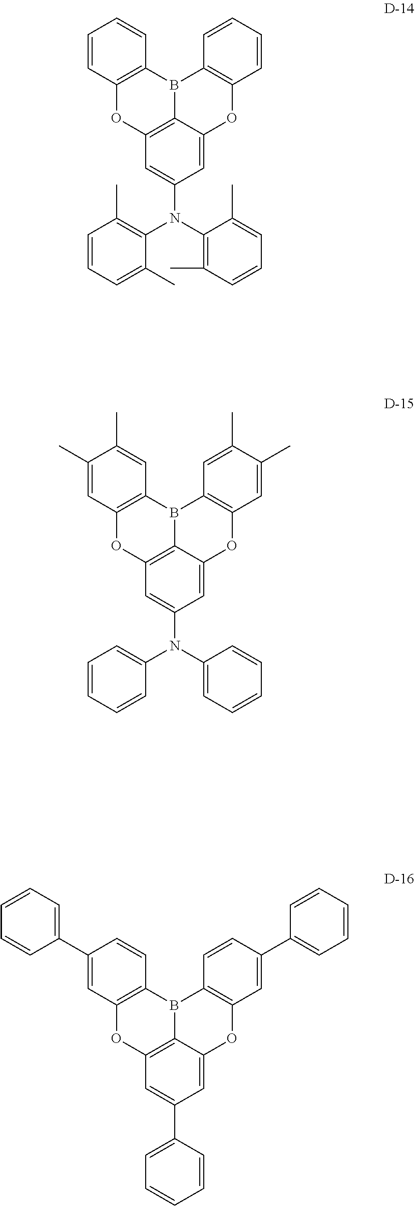

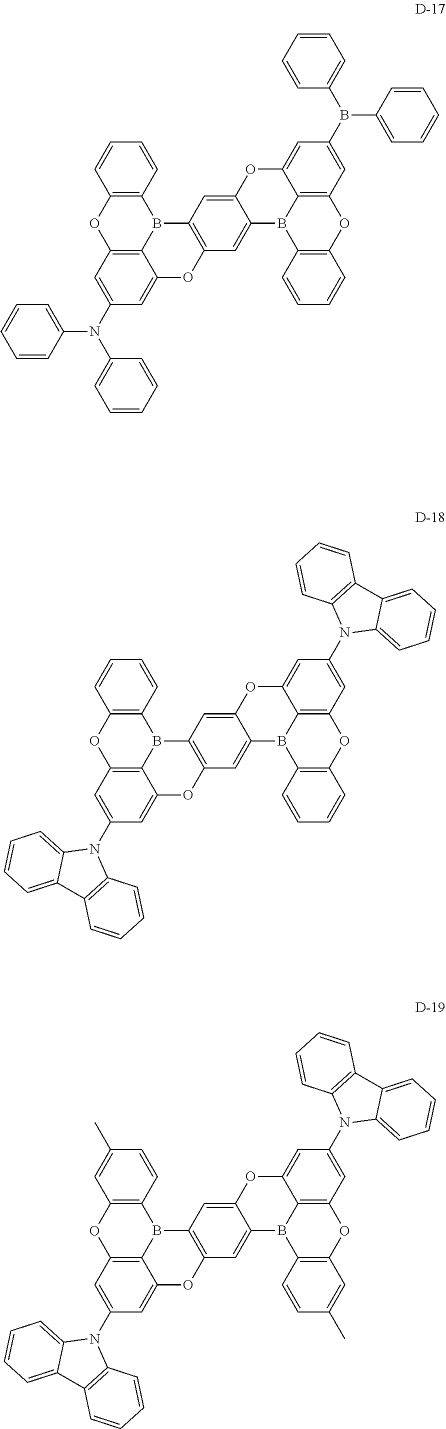 [SMILES: c1ccc(B(c2ccccc2)c2cc3c4c(c2)Oc2cc5c(cc2B4c2ccccc2O3)Oc2cc(N(c3ccccc3)c3ccccc3)cc3c2B5c2ccccc2O3)cc1 ; c1ccc2c(c1)Oc1cc(-n3c4ccccc4c4ccccc43)cc3c1B2c1cc2c(cc1O3)B1c3ccccc3Oc3cc(-n4c5ccccc5c5ccccc54)cc(c31)O2 ; Cc1ccc2c(c1)Oc1cc(-n3c4ccccc4c4ccccc43)cc3c1B2c1cc2c(cc1O3)B1c3ccc(C)cc3Oc3cc(-n4c5ccccc5c5ccccc54)cc(c31)O2]

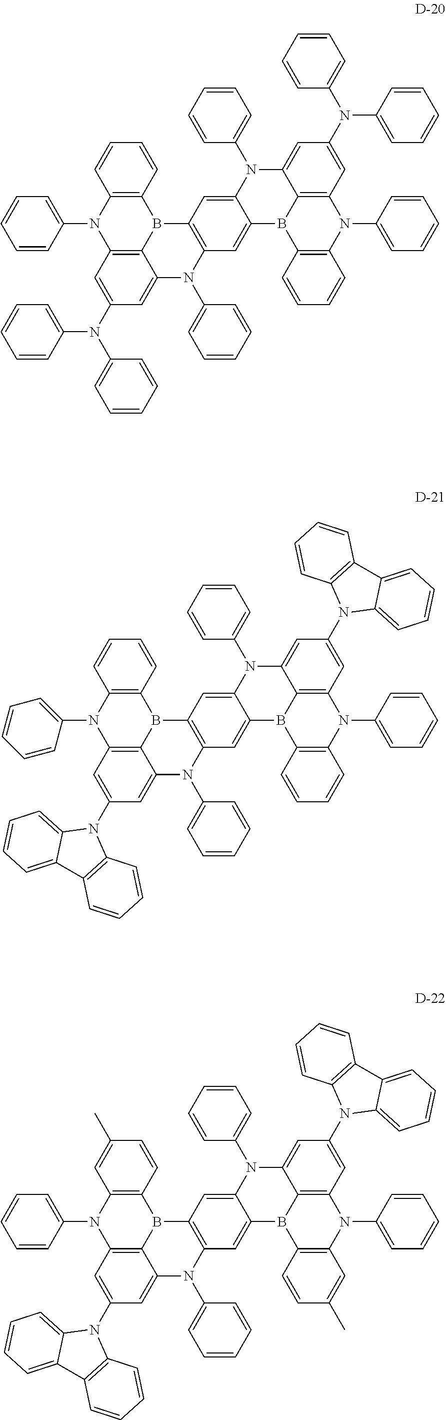 [SMILES: c1ccc(N(c2ccccc2)c2cc3c4c(c2)N(c2ccccc2)c2cc5c(cc2B4c2ccccc2N3c2ccccc2)N(c2ccccc2)c2cc(N(c3ccccc3)c3ccccc3)cc3c2B5c2ccccc2N3c2ccccc2)cc1 ; c1ccc(N2c3ccccc3B3c4cc5c(cc4N(c4ccccc4)c4cc(-n6c7ccccc7c7ccccc76)cc2c43)B2c3ccccc3N(c3ccccc3)c3cc(-n4c6ccccc6c6ccccc64)cc(c32)N5c2ccccc2)cc1 ; Cc1ccc2c(c1)N(c1ccccc1)c1cc(-n3c4ccccc4c4ccccc43)cc3c1B2c1cc2c(cc1N3c1ccccc1)B1c3ccc(C)cc3N(c3ccccc3)c3cc(-n4c5ccccc5c5ccccc54)cc(c31)N2c1ccccc1]

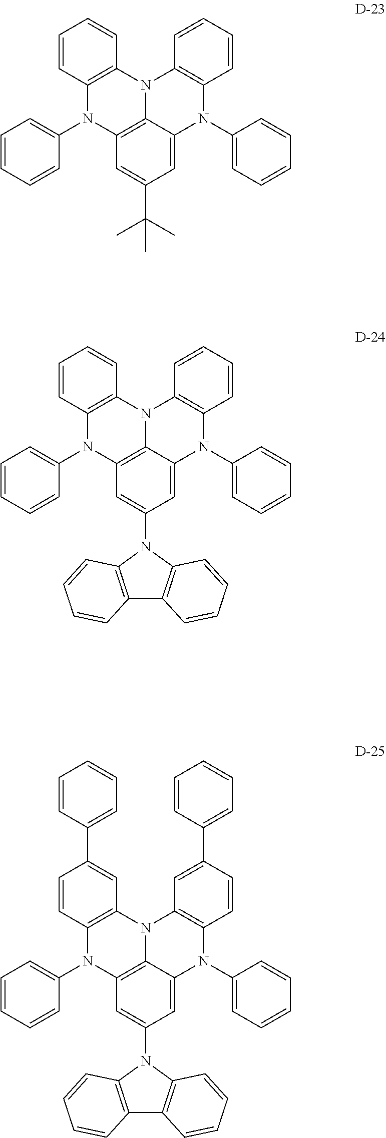 [SMILES: CC(C)(C)c1cc2c3c(c1)N(c1ccccc1)c1ccccc1N3c1ccccc1N2c1ccccc1 ; c1ccc(N2c3ccccc3N3c4ccccc4N(c4ccccc4)c4cc(-n5c6ccccc6c6ccccc65)cc2c43)cc1 ; c1ccc(-c2ccc3c(c2)N2c4cc(-c5ccccc5)ccc4N(c4ccccc4)c4cc(-n5c6ccccc6c6ccccc65)cc(c42)N3c2ccccc2)cc1]

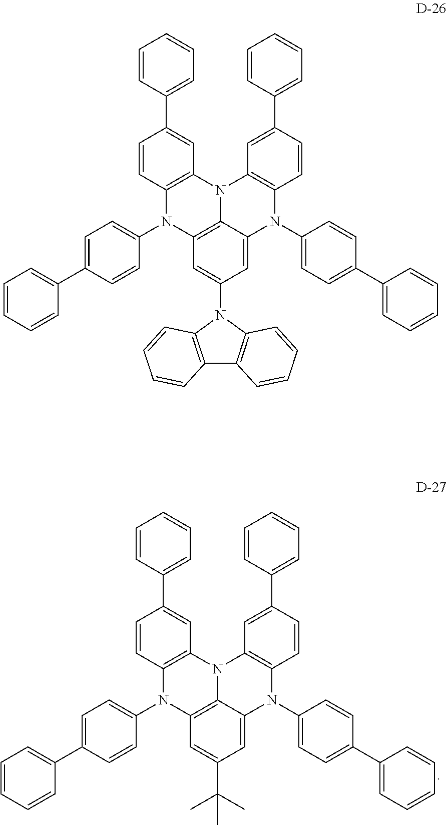 [SMILES: c1ccc(-c2ccc(N3c4ccc(-c5ccccc5)cc4N4c5cc(-c6ccccc6)ccc5N(c5ccc(-c6ccccc6)cc5)c5cc(-n6c7ccccc7c7ccccc76)cc3c54)cc2)cc1 ; CC(C)(C)c1cc2c3c(c1)N(c1ccc(-c4ccccc4)cc1)c1ccc(-c4ccccc4)cc1N3c1cc(-c3ccccc3)ccc1N2c1ccc(-c2ccccc2)cc1]

13. The light emitting device of claim 1, wherein the at least one functional layer further comprises a fourth compound represented by Formula 4: 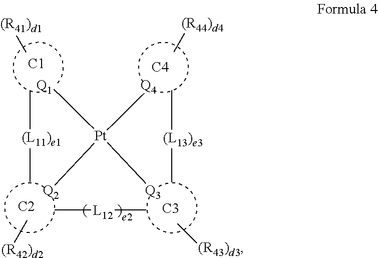
wherein, in Formula 4,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₃ are each independently a direct linkage, 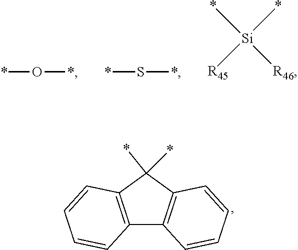
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
R₄₁ to R₄₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or banded to an adjacent group to form a ring,
d1 to d4 are each independently an integer of 0 to 4, and
e1 to e3 are each independently 0 or 1.

14. The light emitting device of claim 13, wherein the fourth compound represented by Formula 4 comprises at least one from among compounds in Compound Group 4:

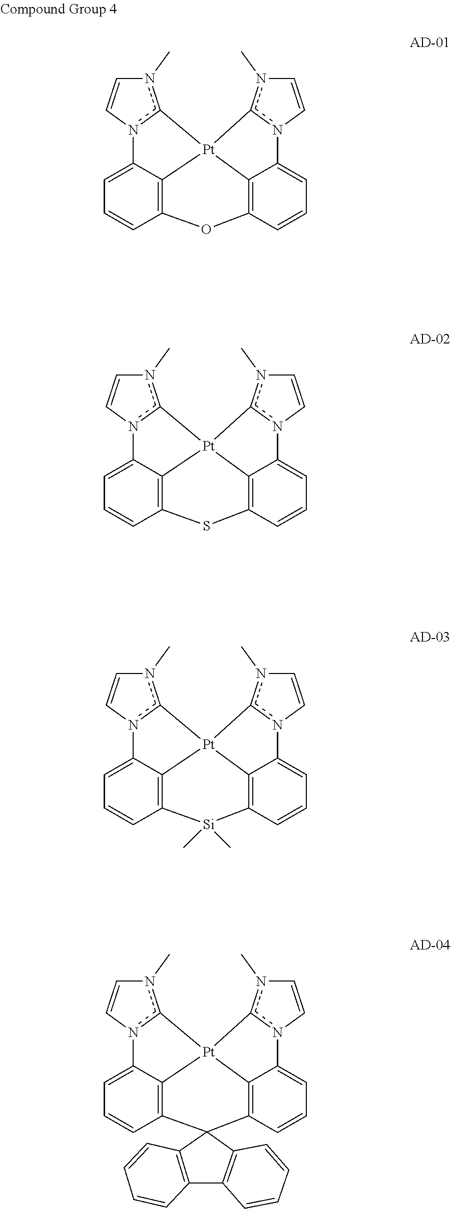

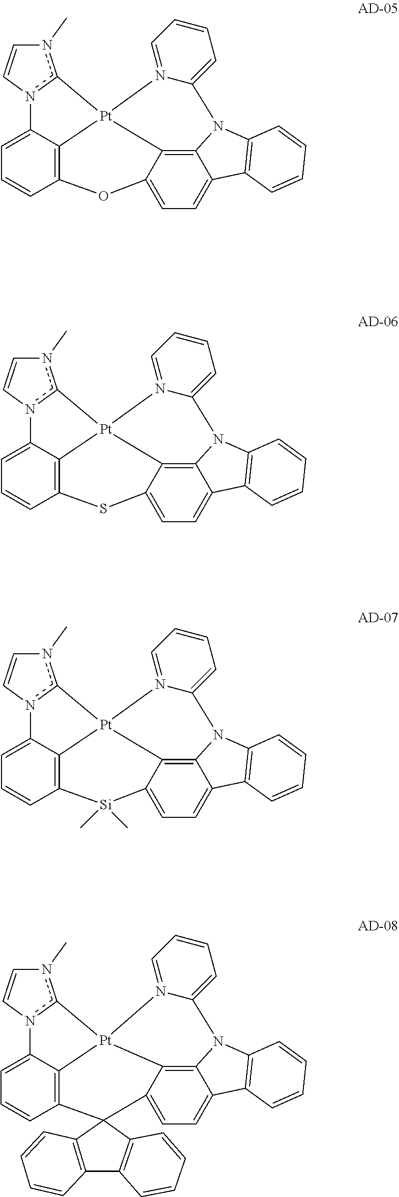

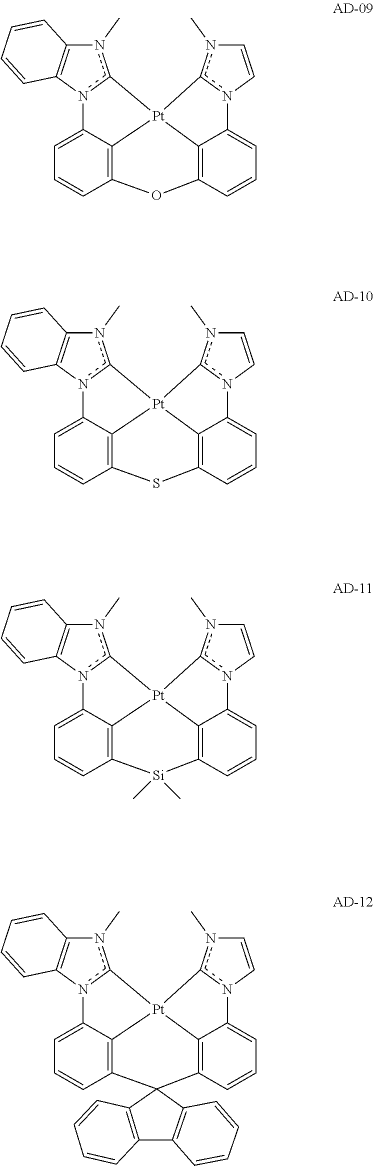

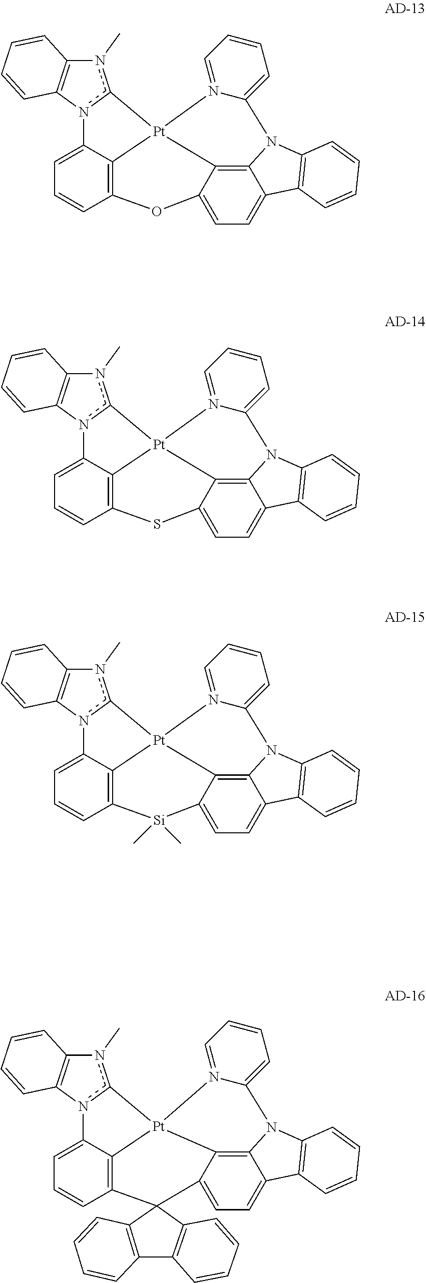

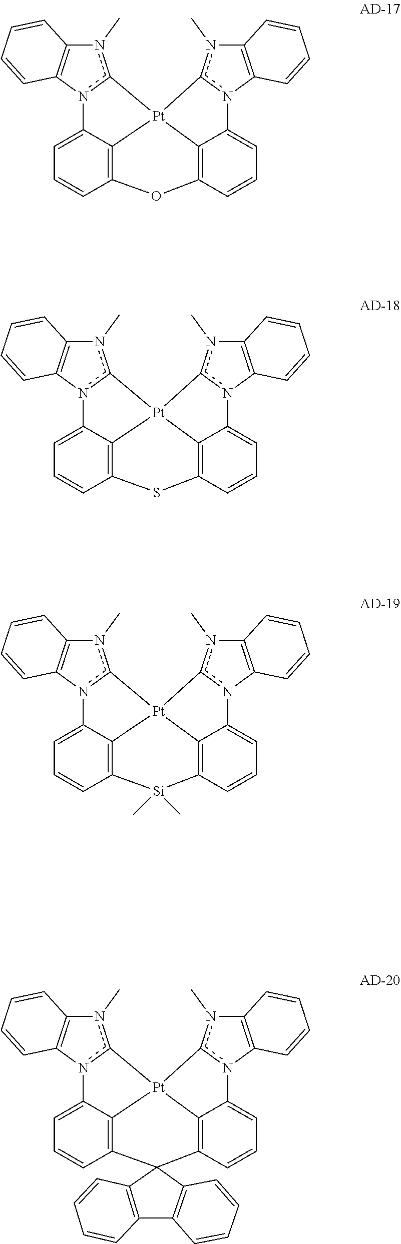

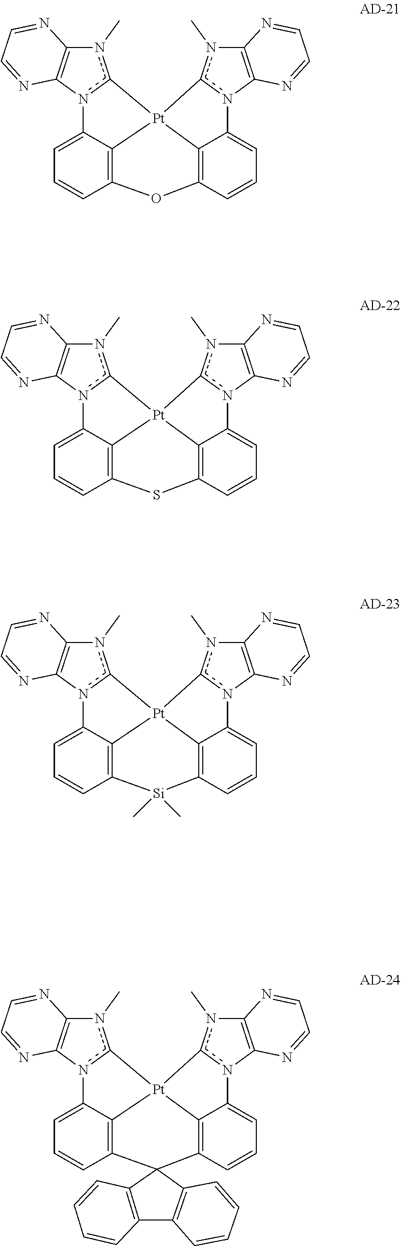

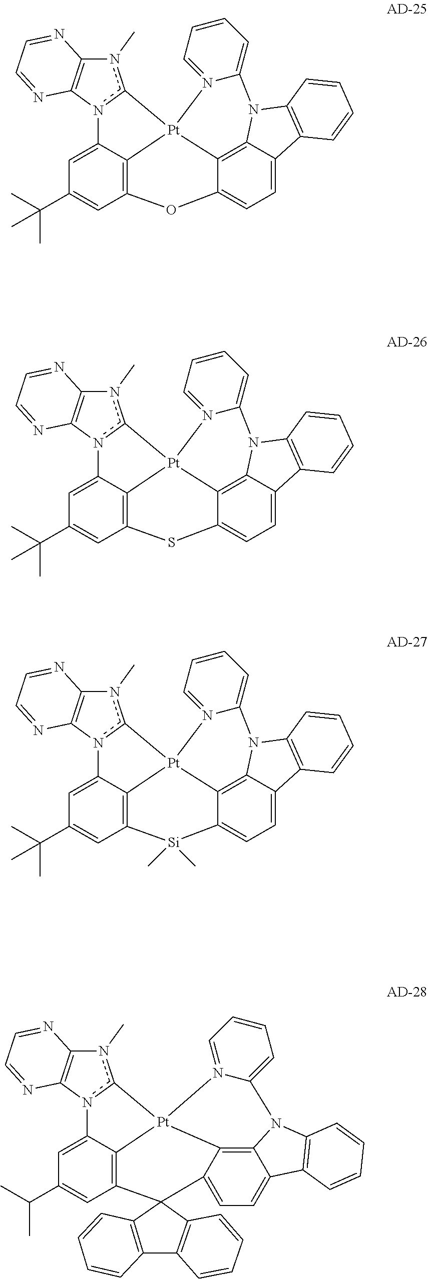

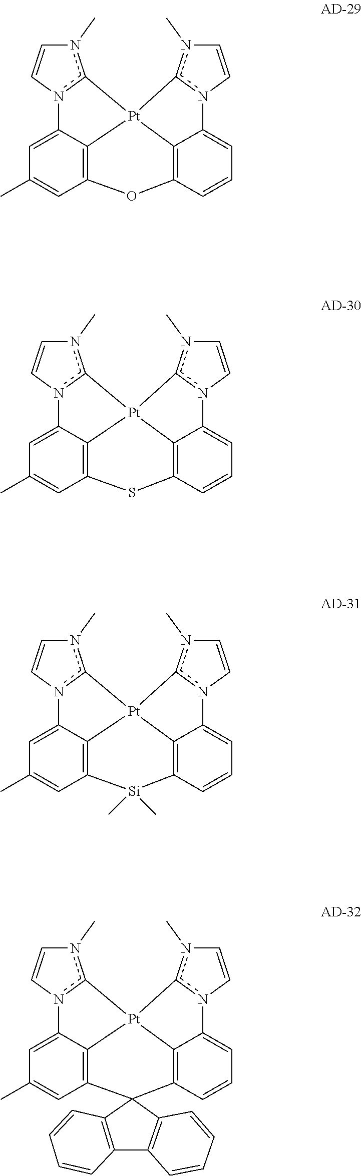

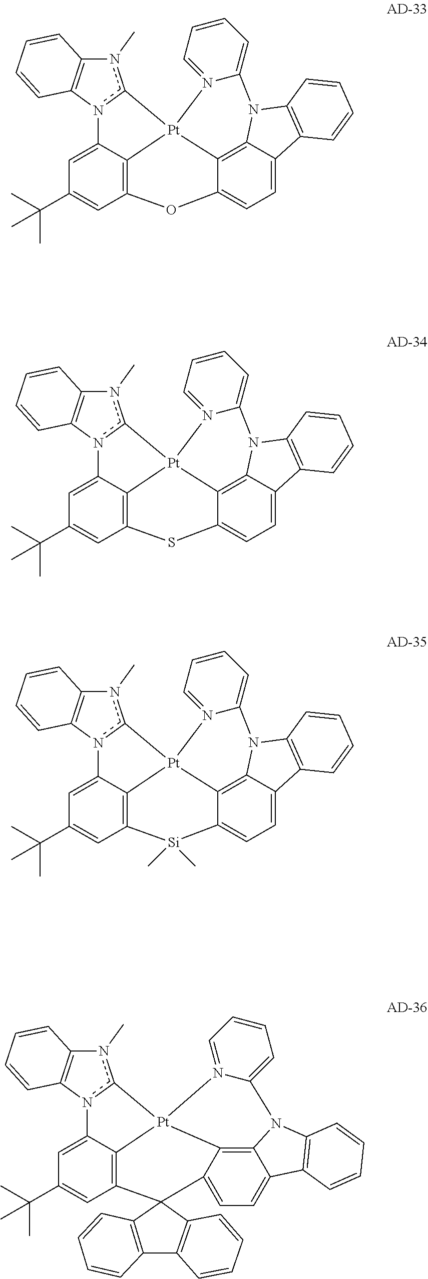

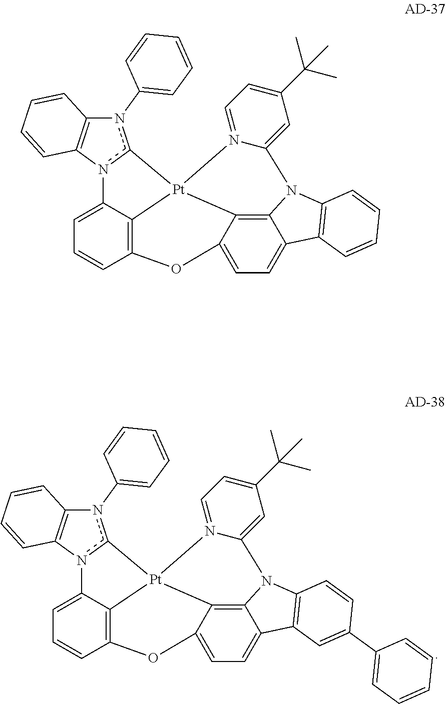

15. A display apparatus comprising:
a base layer having a first light emitting region configured to emit a first light and a second light emitting region configured to emit a second light having different light emitting wavelength from the first light;
a first electrode on the base layer and overlapping the first light emitting region and the second light emitting region;
a hole transport region on the first electrode;
a first emission layer on the hole transport region, overlapping the first light emitting region, and being to emit the first light;
a second emission layer on the hole transport region, overlapping the second light emitting region, and being to emit the second light;
an electron transport region on the first emission layer and the second emission layer;
a second electrode on the electron transport region; and
a capping layer on the second electrode,
wherein the first emission layer comprises:
a first compound represented by Formula 1; and
a third compound represented by Formula 3, and
the capping layer has a refractive index of about 1.6 or more: 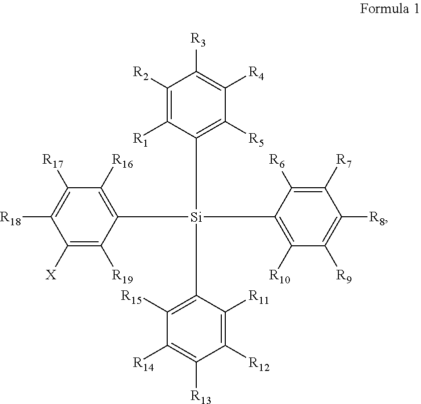
wherein, in Formula 1,
X is a substituted or unsubstituted aryl group having 6 to 30 ring-forming carbon atoms, or a substituted or unsubstituted heteroaryl group having 2 to 30 ring-forming carbon atoms,
R₁ to R₁₉ are each independently a hydrogen atom, a deuterium atom, a halogen atom, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and
at least one pair among adjacent pairs of R₁ to R₁₉ are positions to which a substituent represented by Formula C is fused: 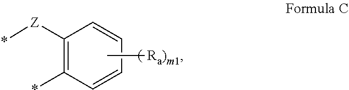
wherein, in Formula C,
^{—}* is a position which is fused to any adjacent one pair among R₁ to R₁₈ in Formula 1,
Z is O or S,
Rₐ is a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
m1 is an integer of 0 to 4, 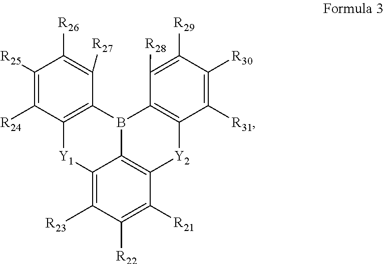
wherein, in Formula 3,
Y₁ and Y₂ are each independently NR₃₂ or O, and
R₂₁ to R₃₂ are each independently a hydrogen atom, a deuterium atom, a halogen atom, a cyano group, a nitro group, a substituted or unsubstituted amine group, a substituted or unsubstituted boron group, a substituted or unsubstituted oxy group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring.

16. The display apparatus of claim 15, wherein the first light is blue light, and the second light is red light or green light.

17. The display apparatus of claim 15, wherein the first compound represented by Formula 1 is represented by Formula 1-1-1 or Formula 1-1-2: 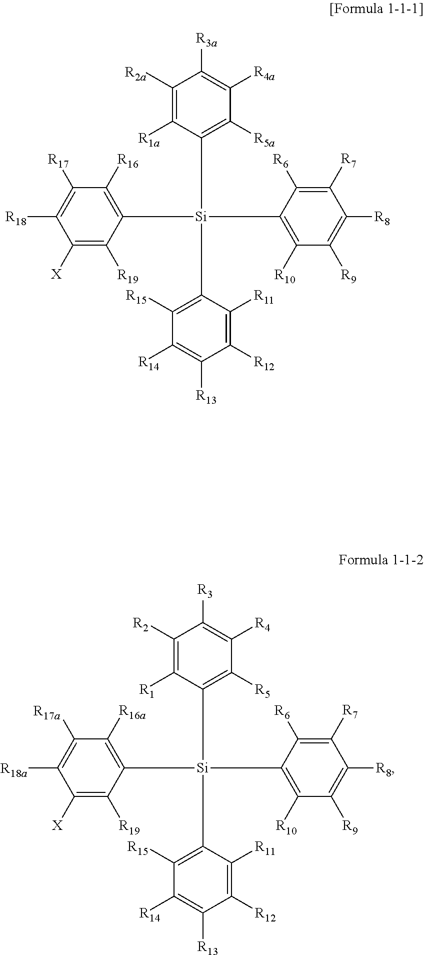
wherein, in Formula 1-1-1 and Formula 1-1-2,
R₁ₐ to R₅ₐ and R₁₆ₐ to R₁₈ₐ are each independently a hydrogen atom, a deuterium atom, a halogen atom, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
wherein, in Formula 1-1-1,
one adjacent pair among R₁ₐ to R₅ₐ are positions to which a substituent represented by Formula C is fused, and
wherein, in Formula 1-1-1,
one adjacent pair among R₁₆ₐ to R₁₈ₐ are positions to which a substituent represented by Formula C is fused, and
X and R₁ to R₁₉ are the same as defined in Formula 1.

18. The display apparatus of claim 15, wherein the first compound represented by Formula 1 is represented by any one among Formula 1-2-1 to Formula 1-2-5: 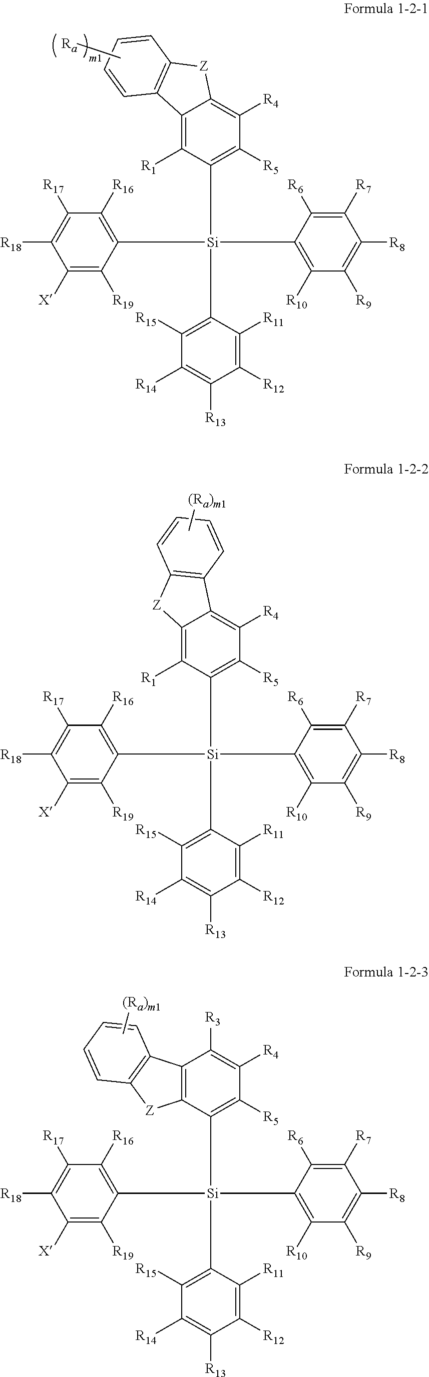 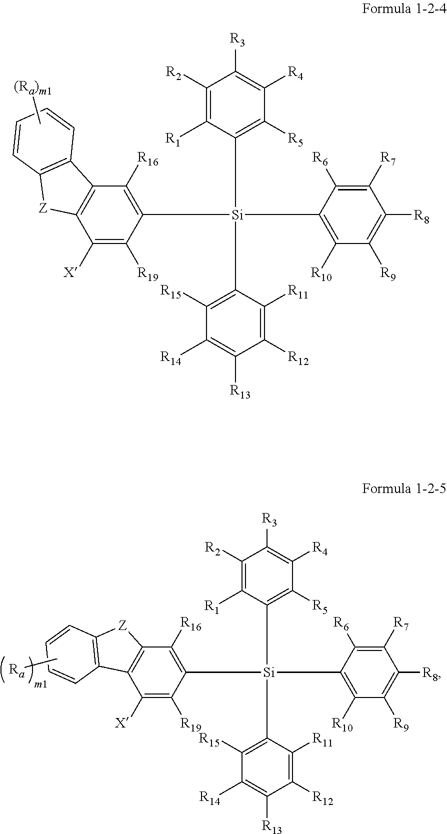
wherein, in Formula 1-2-1 to Formula 1-2-5,
X′ is represented by any one of Formula S-1 to Formula S-3: 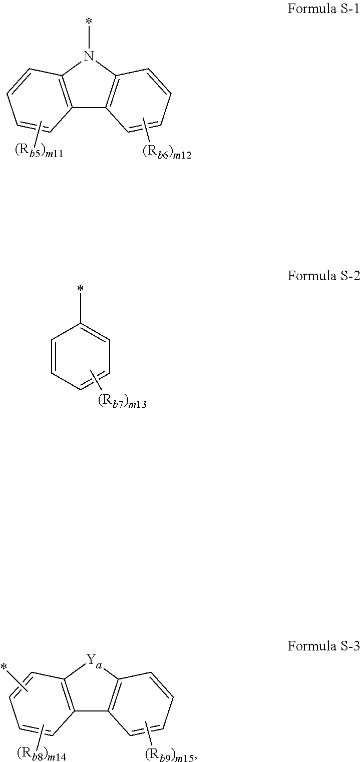
wherein, in Formula S-1 to Formula S-3,
Yₐ is NR_{b10},
R_{b5} to R_{b10} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m11, m12 and m15 are each independently an integer of 0 to 4,
m13 is an integer of 0 to 5, and
m14 is an integer of 0 to 3, and
wherein, in Formula 1-2-1 to Formula 1-2-5,
R₁ to R₁₉, Z, Rₐ, and m1 are the same as defined in Formula 1 and Formula C.

19. The display apparatus of claim 15, wherein the first emission layer further comprises a second compound represented by Formula 2: 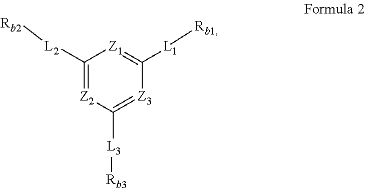
wherein, in Formula 2,
at least one among Z₁ to Z₃ is N, and any remainder thereof are each independently CR_{b4},
R_{b1} to R_{b3} are each independently a hydrogen atom, a deuterium atom, a halogen atom, a substituted or unsubstituted silyl group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
R_{b4} is a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₁ to L₃ are each independently a substituted or unsubstituted arylene group having 6 to 30 ring-forming carbon atoms, or a substituted or unsubstituted heteroarylene group having 2 to 30 ring-forming carbon atoms.

20. The display apparatus of claim 15, wherein the first emission layer further comprises a fourth compound represented by Formula 4: 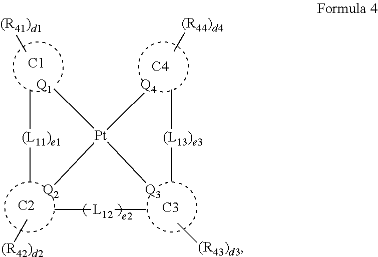
wherein, in Formula 4,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₃ are each independently a direct linkage, 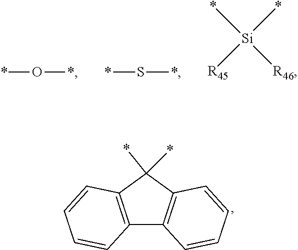
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
R₄₁ to R₄₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring,
d1 to d4 are each independently an integer of 0 to 4, and
e1 to e3 are each independently 0 or 1.
